(19) United States
(12) Patent Application Publication
(10) Pub. No.: US 2018/0120706 A1
(43) Pub. Date: May 3, 2018

(54) PATTERN FORMING METHOD, LAMINATE, AND RESIST COMPOSITION FOR ORGANIC SOLVENT DEVELOPMENT

(71) Applicant: FUJIFILM Corporation, Tokyo (JP)

(72) Inventors: Michihiro SHIRAKAWA, Haibara-gun (JP); Keiyu OU, Haibara-gun (JP); Naoya HATAKEYAMA, Haibara-gun (JP); Akiyoshi GOTO, Haibara-gun (JP); Keita KATO, Haibara-gun (JP); Takashi YAKUSHIJI, Haibara-gun (JP); Tadashi OMATSU, Haibara-gun (JP)

(73) Assignee: FUJIFILM Corporation, Tokyo (JP)

(21) Appl. No.: 15/851,703

(22) Filed: Dec. 21, 2017

Related U.S. Application Data
(63) Continuation of application No. PCT/JP2016/064746, filed on May 18, 2016.

(30) Foreign Application Priority Data
Jun. 24, 2015 (JP) 2015-126789
Feb. 22, 2016 (JP) 2016-030911

(51) Int. Cl. G03F 7/36; G03F 7/038; G03F 7/039; G03F 7/075; G03F 7/20; B32B 27/18; C08F 212/04; C08F 220/06

(52) U.S. Cl. CPC G03F 7/36; G03F 7/038; G03F 7/039; C08F 220/06; G03F 7/20; B32B 27/18; C08F 212/04; G03F 7/0757

(57) ABSTRACT

Provided are a pattern forming method including (1) a step of forming a resist underlayer film on a substrate to be processed, (2) a step of forming a resist film on the resist underlayer film, using a resist composition containing (A) a resin having a repeating unit containing a Si atom, and (B) a compound which generates an acid upon irradiation with actinic rays or radiation, (3) a step of exposing the resist film, (4) a step of developing the exposed resist film using a developer including an organic solvent, thereby forming a negative tone resist pattern, and (5) a step of processing the resist underlayer film and the substrate to be processed, using the resist pattern as a mask, thereby forming a pattern, in which the content of the resin (A) is 20% by mass or more with respect to the total solid content of the resist composition.

### CROSS REFERENCE TO RELATED APPLICATIONS

This is a continuation of International Application No. PCT/JP2016/064746 filed on May 18, 2016, and claims priorities from Japanese Patent Application No. 2015-126789 filed on Jun. 24, 2015 and Japanese Patent Application No. 2016-030911 filed on Feb. 22, 2016, the contents of which are incorporated herein by reference.

### BACKGROUND OF THE INVENTION

### 1. Field of the Invention

The present invention relates to a pattern forming method, a laminate, and a resist composition for organic solvent development. More specifically, the present invention relates to a pattern forming method which is suitable for a process for manufacturing a semiconductor such as an integrated circuit (IC), a process for manufacturing a circuit board for a liquid crystal, a thermal head, or the like, and other lithographic processes for photofabrication; a laminate; and a resist composition for organic solvent development.

### 2. Description of the Related Art

In processes for manufacturing semiconductor devices such as an IC in the related art, microfabrication by lithography using an actinic ray-sensitive or radiation-sensitive resin composition (resist composition) has been carried out.

However, a resist pattern formed by subjecting an actinic ray-sensitive or radiation-sensitive film having a resin as a main component to exposure and development has an increased aspect ratio of the cross-section of the resist pattern as a patterning dimension becomes finer, and thus, the pattern easily collapses.

In order to suppress such problems, a multilayered resist system in which a resist film with multilayers is formed by etching using a difference in etching selection ratios among the multilayers has been developed.

Generally, as the multilayered resist system, a trilayered resist system and a bilayered resist system are known.

As a representative example of the trilayered resist system, a system using a laminate having an organic interlayer (a Spin-on-Carbon (SOC) layer or the like), an inorganic interlayer (a Spin-on-Glass (SOG) layer or the like), and an actinic ray-sensitive or radiation-sensitive film having a hydrocarbon-based resin as a main component in this order on a substrate to be processed, such as a SiO₂ film, is known.

In addition, as the bilayered resist system, a system using a laminate having an organic interlayer (an SOC layer or the like) and an actinic ray-sensitive or radiation-sensitive film having a silicon-based resin as a main component in this order on a substrate to be processed, such as a SiO₂ film, is known (see JP2000-219743A and JP2002-256033A).

### SUMMARY OF THE INVENTION

In a view that as the resist layer becomes multilayered, the bilayered and trilayered resist systems can reduce the thickness of an actinic ray-sensitive or radiation-sensitive film which easily collapses in a case of providing a resist pattern, they have a tendency that the collapse of the resist pattern hardly occurs, as compared with a case of using a monolayered actinic ray-sensitive or radiation-sensitive film as a resist layer.

However, in the bilayered resist systems described in JP2000-219743A and JP2002-256033A, the resolving power in patterning was not sufficient, and thus, in particular, it was difficult to form a contact hole at a high resolution. Further, there has been a demand for a further improvement of depth of focus (DOF) performance as well as development defect performance.

In addition, in the trilayered resist system, there was a problem in that cost for forming a resist pattern is high due to a number of steps of forming layers.

The present invention has been made in consideration of the above-mentioned problems, and has an object to provide a pattern forming method which can satisfy resolution, DOF performance, development defect performance, and etching resistance performance at the same time at high levels in the formation of a trench (groove) pattern or a contact hole pattern, particularly having a small dissolution region of a resist film, while reducing cost for forming the resist pattern; and a laminate and a resist composition for organic solvent development, each applied to the pattern forming method.

The present invention is configured as follows, whereby the objects of the present invention are accomplished.

[1] A pattern forming method comprising:
(1) a step of forming a resist underlayer film on a substrate to be processed;
(2) a step of applying a resist composition containing (A) a resin having a repeating unit containing a Si atom, and (B) a compound which generates an acid upon irradiation with actinic rays or radiation onto the resist underlayer film, thereby forming a resist film;
(3) a step of exposing the resist film;
(4) a step of developing the exposed resist film using a developer including an organic solvent, thereby forming a negative tone resist pattern; and
(5) a step of processing the resist underlayer film and the substrate to be processed, using the resist pattern as a mask, thereby forming a pattern,

in which the content of the resin (A) is 20% by mass or more with respect to the total solid content of the resist composition.

[2] The pattern forming method as described in [1],

in which the resin (A) has a repeating unit having an acid-decomposable group.

[3] The pattern forming method as described in [2],

in which the acid-decomposable group has a structure in which a polar group is protected with a leaving group capable of leaving upon decomposition by the action of an acid, and the leaving group does not contain a Si atom.

[4] The pattern forming method as described in any one of [1] to [3],

in which the content of Si atoms in the resin (A) is 1.0% to 30% by mass with respect to the total amount of the resin (A).

[5] The pattern forming method as described in any one of [1] to [4],

in which the resist composition further contains a crosslinking agent.

[6] The pattern forming method as described in any one of [1] to [5],

in which the resin (A) has at least one selected from the group consisting of a lactone structure, a sultone structure, and a carbonate structure.

[7] The pattern forming method as described in any one of [1] to [6],

in which the developer including an organic solvent includes at least one of butyl acetate or isoamyl acetate.

[8] The pattern forming method as described in any one of [1] to [7],

in which in the step (3), the resist film is exposed by any one of ArF liquid immersion exposure, ArF exposure, and KrF exposure.

[9] The pattern forming method as described in any one of [1] to [8],

in which in the step (3), the resist film is exposed by ArF liquid immersion exposure or ArF exposure.

[10] The pattern forming method as described in any one of [1] to [9],

in which the step (5) is a step of subjecting the resist underlayer film and the substrate to be processed to dry etching, using the resist pattern as a mask, thereby forming a pattern.

[11] The pattern forming method as described in [10],

in which the dry etching for the resist underlayer film is oxygen plasma etching.

[12] A laminate applied to the pattern forming method as described in any one of [1] to [11],

in which a resist underlayer film, and a resist film formed of a resist composition containing (A) a resin having a repeating unit containing a Si atom and (B) a compound which generates an acid upon irradiation with actinic rays or radiation are laminated in this order on a substrate to be processed.

[13] A resist composition for organic solvent development, applied to the pattern forming method as described in any one of [1] to [11].

According to the present invention, it is possible to provide a pattern forming method which can satisfy resolution, DOF performance, development defect performance, and etching resistance performance at the same time at high levels in the formation of a resist pattern of a trench (groove) pattern or a contact hole pattern, particularly having a small dissolution region of a resist film, while reducing cost for forming the resist pattern; and a laminate and a resist composition for organic solvent development, each applied to the pattern forming method.

### DESCRIPTION OF THE PREFERRED EMBODIMENTS

Hereinafter, suitable aspects of the present invention will be described in detail.

In citations for a group and an atomic group in the present specification, in a case where the group is denoted without specifying whether it is substituted or unsubstituted, the group includes both a group and an atomic group not having a substituent, and a group and an atomic group having a substituent. For example, an “alkyl group” which is not denoted about whether it is substituted or unsubstituted includes not only an alkyl group not having a substituent (unsubstituted alkyl group), but also an alkyl group having a substituent (substituted alkyl group).

In the present invention, “actinic rays” or “radiation” means, for example, a bright line spectrum of a mercury lamp, far ultraviolet rays represented by an excimer laser, extreme ultraviolet rays (EUV light), X-rays, particle rays such as electron beams and ion beams, or the like. In addition, in the present invention, “light” means actinic rays or radiation.

Furthermore, “exposure” in the present specification includes, unless otherwise specified, not only exposure by a bright line spectrum of a mercury lamp, far ultraviolet rays represented by an excimer laser, X-rays, extreme ultraviolet rays (EUV light), or the like, but also writing by particle rays such as electron beams and ion beams.

In the present specification, “(meth)acrylate” represents “at least one of acrylate or methacrylate”. In addition, “(meth)acrylic acid” means “at least one of acrylic acid or methacrylic acid”.

In the present specification, “(a value) to (a value)” means a range including the numerical values described before and after “to” as a lower limit value and an upper limit value, respectively.

[Pattern Forming Method]

The pattern forming method of the present invention (hereinafter also referred to as the method of the present invention) includes the following five steps.

(1) a step of forming a resist underlayer film on a substrate to be processed

(2) a step of forming a resist film on the resist underlayer film, using a resist composition containing (A) a resin having a repeating unit containing a Si atom, and (B) a compound which generates an acid upon irradiation with actinic rays or radiation

(3) a step of exposing the resist film

(4) a step of developing the exposed resist film using a developer including an organic solvent, thereby forming a negative tone pattern

(5) a step of processing the resist underlayer film and the substrate to be processed, using the pattern as a mask, thereby forming a pattern

Here, the resist composition contains a resin having a repeating unit with a Si atom, and a compound which generates an acid upon irradiation with actinic rays or radiation, in which the content of the resin in the total solid content of the resist composition is 20% by mass or more.

It is considered that since the method of the present invention has such a configuration, the effects of the present invention are obtained. The reason therefor is not clear but is approximately presumed to be as follows.

First, according to the pattern forming method of the present invention, it is possible to configure a bilayered resist system having a resist underlayer film as the first layer and a resist film as the second layer. Thus, as compared with the trilayered resist system, the number of steps of forming layers can be reduced, and thus, the cost for forming the resist pattern can be reduced (in addition, the cost for processing the substrate to be processed can also be reduced).

Furthermore, as described above, in the pattern forming method of the present invention, a resist film is formed with a resist composition containing a resin having a repeating unit containing a Si atom, and the resist film is exposed and developed using a developer including an organic solvent, thereby forming a negative tone pattern. Here, the resin having a repeating unit containing a Si atom has a low affinity to an alkali developer, but has a high affinity to a developer including an organic solvent. Accordingly, in particular, in a case where a fine region is dissolved in an alkali developer so as to form a trench (groove) pattern or a contact hole pattern, the fine region is hardly alkali-developed, and thus, the resolution is low. On the other hand, in the present invention, in a case where a fine region is dissolved in a developer containing an organic solvent to form a trench (groove) pattern or a contact hole pattern, having a small dissolution region of a resist film, it is considered that the resin having a repeating unit containing a Si atom is reliably dissolved in the developer including an organic solvent, and therefore, the resolution is improved. Further, the mechanism is not clear, but according to the present invention, not only the resolution but also DOF performance and development defect performance can be satisfied at the same time at high levels.

In addition, the content of the resin having a repeating unit containing a Si atom is 20% by mass or more with respect to the total solid content of the resist composition, and therefore, the etching resistance performance of the obtained pattern is high. Thus, in the processing of the substrate to be processed, the shape of a pattern can be more accurately transferred to the substrate to be processed (that is, the etching properties of the resist underlayer film are good).

Hereinafter, the respective steps will be described.

[Step (1): Step of Forming Resist Underlayer Film on Substrate to be Processed]

The substrate to be processed in the step (1) is typically provided on a base layer.

The materials for the base layer, the substrate to be processed, and the resist underlayer film are not particularly limited, but for each of the materials, for example, an inorganic substrate such as silicon, SiO₂, and SiN, and a coating type inorganic substrate such as Spin On Glass (SOG), or a substrate which is generally used in a process for manufacturing a semiconductor such as an IC, a process for manufacturing a circuit board for a liquid crystal, a thermal head, or the like, and other lithographic processes for photofabrication can be used.

In particular, suitable examples of the substrate to be processed include an oxide film layer such as a SiO₂ layer, the resist underlayer film is required to have a function of improving the pattern resolution of a resist layer and a function of transferring the resist pattern to the substrate to be processed while keeping a good pattern shape, and suitable examples thereof include a Spin on Carbon (SOC) layer.

Moreover, suitable examples of the resist underlayer film include a film formed by thermally crosslinking a coating film obtained from a composition containing a resin, a crosslinking agent, a thermal acid generator, and additives to be added, as desired. Materials known in the related art can be appropriately adopted and used as the respective components of the resin, the crosslinking agent, the thermal acid generator, the additives, or the like.

Formation of the substrate to be processed and the resist underlayer film can be carried out by appropriately adopting and using a well-known method, depending on the types of the materials to be used.

Examples of the method for forming a substrate to be processed include a method for applying a liquid containing materials constituting the substrate to be processed on a base layer by a spin coating method, a spray method, a roll coating method, a dip method, or the like, which is known in the related art, followed by drying, and a method in which materials constituting the substrate to be processed are deposited using a CVD method.

Similarly, examples of the method for forming a resist underlayer film include a method for applying a liquid containing materials constituting the resist underlayer film on a substrate to be processed by a spin coating method, a spray method, a roll coating method, a dip method, or the like, which is known in the related art, followed by drying, and a method in which materials constituting the resist underlayer film are deposited using a CVD method.

The film thickness of the substrate to be processed is preferably 10 to 5,000 nm, more preferably 15 to 2,000 nm, and still more preferably 20 to 500 nm.

The film thickness of the resist underlayer film is preferably 30 to 500 nm, more preferably 50 to 300 nm, and still more preferably 60 to 200 nm.

The resist underlayer film used in the present invention is suitably required to have a function of improving the pattern resolution of a resist film, and a function of transferring a resist pattern formed on an upper layer onto a substrate to be processed while maintaining a good pattern shape. As one of the functions of assisting the pattern resolution of the resist film, an optical function of controlling the refractive index and the attenuation coefficient of the resist underlayer film at an exposure wavelength to appropriately control a reflection from the side of the substrate during exposure in a lithographic process, and maintaining an optical image formed during the exposure in a good shape may be mentioned. Incidentally, other functions thereof include a function of improving the structures of the main chain and the side chain of a resin, and the interaction with a resist due to functional groups of a crosslinking agent or other additives to be used in combination therewith, maintaining the rectangularity of a pattern cross-section after development, and aiding the resolution in a developing process after exposure by the action of suppressing development defects such as pattern collapse or bridge, and pattern defects. In addition, a function of maintaining good mask performance as an etching mask at a time of carrying out etching under conditions selected appropriately in correspondence with to the thickness or etching rate of each of the resist film formed on the upper layer, the resist underlayer film, and the substrate to be processed when a pattern shape is transferred onto the substrate to be processed can also be mentioned.

With regard to a method for improving the reflection characteristics during exposure, for example, in a mask exposure process, targeted design information such as a refractive index n value or an extinction coefficient k value of an underlayer film, and a film thickness of the underlayer film so as to improve the reflection characteristics at an exposure wavelength, and as a result, to maintain the rectangularity of an optical image during exposure are determined by means of, for example, a simulation software known under a trade name, PROLITH (manufactured by KLATencor Co., Ltd.), based on the exposure information including the pattern shape or transmittance of a mask, the exposure intensity, the deflection or shape of a projection light source, and the like, and thus, resin structures and additives such as a crosslinking agent, appropriate for the obtained target can be used to obtain good reflection characteristics and resolution. The resist underlayer film of the present invention is preferably designed in consideration of the properties determined above. A preferred range of the refractive index n value of the underlayer film is preferably from 1.2 to 3.0. In addition, the extinction coefficient k value of the underlayer film is preferably from 0.05 to 1.0.

Moreover, with regard to a method for improving the resolution by maintaining the rectangularity of a pattern cross-section and suppressing development defects such as a pattern collapse or bridge, and pattern defects, a mechanism thereof is unknown, but the resolution can be eventually improved by changing a deprotection reaction of a protecting group due to an acid, which proceeds during development by the chemical interactions (intermolecular interactions) between the underlayer and the resist layer, the footing by slight interfacial mixing between the resist layer and the resist underlayer, and the phase transfer of components between the resist underlayer film and the resist layer, and the reaction activity of dissolution of polymers by a developer after the reaction. By selecting a more appropriate resin as the resin that can be used in the resist underlayer film in consideration of the lithography performance and the workability of the substrate to be processed, good resolution and processability can be obtained.

In addition, as for the other functions, it is necessary to form a flat resist underlayer film on a substrate having a concave-and-convex structure depending on the pattern shape in a lithographic process for a processed substrate, and a function of satisfying gap-filling properties and fattening properties after coating can also be mentioned.

<Resin for Resist Underlayer Film>

As a resin which can be used in the resist underlayer film of the present invention (hereinafter also referred to as “a resin for resist underlayer film”), for example, materials known in the related art can be appropriately adopted and used, as described above, but from the viewpoints of satisfying all of the resolution, the defects, and the workability of the substrate to be processed in the lithographic process, it is preferable to arbitrarily design and use a composition using a polymer or resin which will be described later.

That is, as the resin of the resist underlayer film of the present invention, a (meth) acrylic resin, a styrene resin, a cellulose resin, a phenol resin (novolac resin), or the like can be used. In addition, as other resins, an aromatic polyester resin, an aromatic polyimide resin, a polybenzoxazole resin, an aromatic polyamide resin, an acenaphthylene-based resin, an isocyanuric acid-based resin, or the like can be used.

Particularly, as the aromatic polyamide resin or the aromatic polyimide resin, for example, the resin compounds described in JP4120584AB, the resin compounds described in [0021] to [0053] of JP4466877B, or the resin compounds described in [0025] to [0050] of JP4525940B can be used. In addition, as the novolac resin, the resin compounds described in [0015] to [0058] of JP5215825B or [0023] to [0041] of JP5257009B can be used.

Furthermore, as the acenaphthylene-based resin, for example, the resin compounds described in [0032] to [0052] of JP4666166B, the resin compounds described in [0037] to [0043] of JP04388429B, the polymers described in [0026] to [0065] of JP5040839B, the resin compounds described in [0015] to [0032] of JP4892670B, or the like can be used.

The resin for a resist underlayer film is also preferably a resin containing a repeating unit containing a hydroxyl group which is a crosslinking reactive group.

In addition, the resin for a resist underlayer film also preferably contains a repeating unit having a lactone structure which will be described later in the resin (A).

The resin for a resist underlayer film can also be formed by copolymerization of non-crosslinkable monomers, and thus, it is possible to finely adjust a dry etching rate, a reflection rate, or the like. Examples of such the copolymerization monomer include the following monomers: a compound having one addition-polymerizable unsaturated bond selected from acrylic esters, acrylamides, methacrylic esters, methacrylamides, allyl compounds, vinyl ethers, vinyl esters, styrenes, crotonic esters, and the like.

Examples of the acrylic esters include alkyl acrylates in which the alkyl group has 1 to 10 carbon atoms.

Examples of the methacrylic esters include alkyl methacrylates in which the alkyl group has 1 to 10 carbon atoms.

Examples of the acrylamides include acrylamide, N-alkyl acrylamides, N-aryl acrylamides, N,N-dialkyl acrylamides, N,N-diaryl acrylamides, N-methyl-N-phenyl acrylamide, and N-2-acetamidoethyl-N-acetyl acrylamide.

Examples of the methacrylamides include methacrylamide, N-alkyl methacrylamides, N-aryl methacrylamides, N,N-dialkyl methacrylamides, N,N-diaryl methacrylamides, N-methyl-N-phenyl methacrylamide, and N-ethyl-N-phenyl methacrylamide.

Examples of the vinyl ethers include alkyl vinyl ethers and vinyl aryl ethers.

Examples of the vinyl esters include vinyl butyrate, vinyl isobutyrate, and vinyl trimethyl acetate.

Examples of the styrenes include styrene, alkyl styrenes, alkoxy styrenes, and halogenated styrenes.

Examples of the crotonic esters include alkyl crotonates such as butyl crotonate, hexyl crotonate, and glycerin monocrotonate.

Furthermore, examples of the copolymerizable monomer also include dialkyl itaconates, dialkyl esters or monoalkyl esters of maleic acid or fumaric acid, crotonic acid, itaconic acid, maleic anhydride, maleimide, acrylonitrile, methacrylonitrile, and maleylonitrile. In addition, generally, any of addition-polymerizable unsaturated compounds that are copolymerizable with a polymer containing at least one or more hydroxyl groups which are crosslinking reactive groups, per repeating unit, can be used.

The resin for a resist underlayer film may be any one of a random polymer, a block polymer, or a graft polymer. The polymer that forms the antireflection film of the present invention can be synthesized by a method such radical polymerization, anionic polymerization, and cationic polymerization. As for a mode thereof, various methods such as solution polymerization, suspension polymerization, emulsion polymerization, and bulk polymerization can be used.

Furthermore, the resin for a resist underlayer film can use various phenol-based polymers having a phenol structure moiety. Preferred examples thereof include a novolac resin, a p-hydroxystyrene homopolymer, an m-hydroxystyrene homopolymer, a copolymer having a p-hydroxystyrene structure, and a copolymer having an m-hydroxystyrene structure. In these copolymers, the copolymerization moiety preferably has a repeating unit represented by General Formula (1).

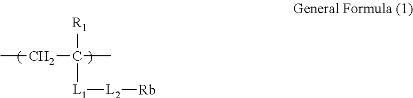

In the formula, R₁ represents a hydrogen atom, an alkyl group having 1 to 3 carbon atoms, a cyano group, or a halogen atom, and is preferably a hydrogen atom or a methyl group. L₁ represents a single bond, —COO—, —CON(R₃)—, or an arylene group, and R₃ represents a hydrogen atom or an alkyl group having 1 to 3 carbon atoms. L₁ is preferably a single bond, —COO—, or a phenylene group. L₂ represents a single bond, an alkylene group having 1 to 10 carbon atoms, an arylene group having 6 to 18 carbon atoms, —COO—, or —O—, and is preferably a single bond, an alkylene group having 1 to 4 carbon atoms, or a phenylene group. Rb represents an alkyl group having 1 to 10 carbon atoms, a cycloalkyl group having 4 to 30 carbon atoms, a bridged alicyclic hydrocarbon group having 5 to 25 carbon atoms, or an aryl group having 6 to 18 carbon atoms, and preferably an alkyl group having 1 to 8 carbon atoms (a methyl group, an ethyl group, a butyl group, a t-butyl group, or the like), a cycloalkyl group having 5 to 8 carbon atoms (a cyclohexyl group, a cyclooctyl group, or the like), a bridged alicyclic hydrocarbon group having 5 to 20 carbon atoms, or an aryl group having 6 to 12 carbon atoms (a phenyl group, a naphthyl group, or the like). These groups each may have a substituent and examples of the substituent include a halogen atom (Cl, Br, or the like), a cyano group, an alkyl group having 1 to 4 carbon atoms, a hydroxy group, an alkoxy group having 1 to 4 carbon atoms, an acyl group having 1 to 4 carbon atoms, and an aryl group having 6 to 12 carbon atoms. Preferred skeletons of the bridged alicyclic hydrocarbon group having 5 to 20 carbon atoms are shown below.

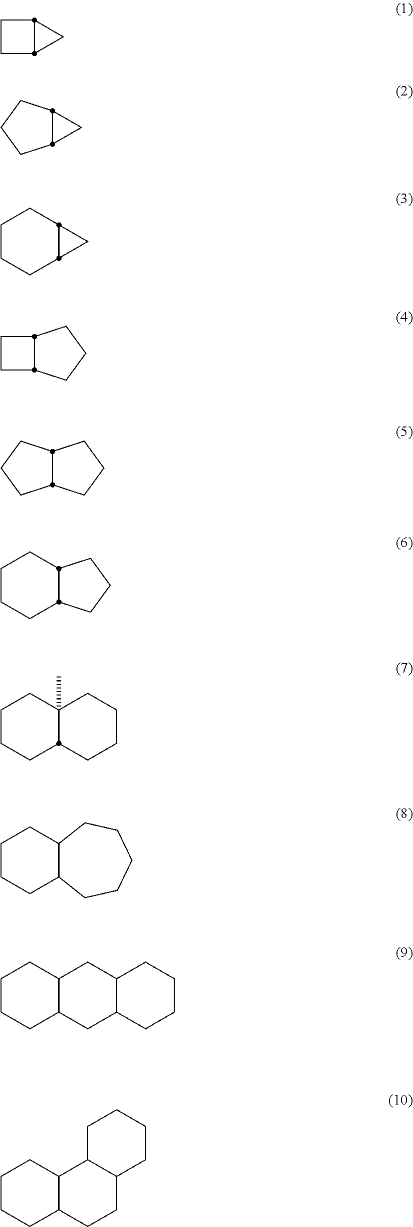

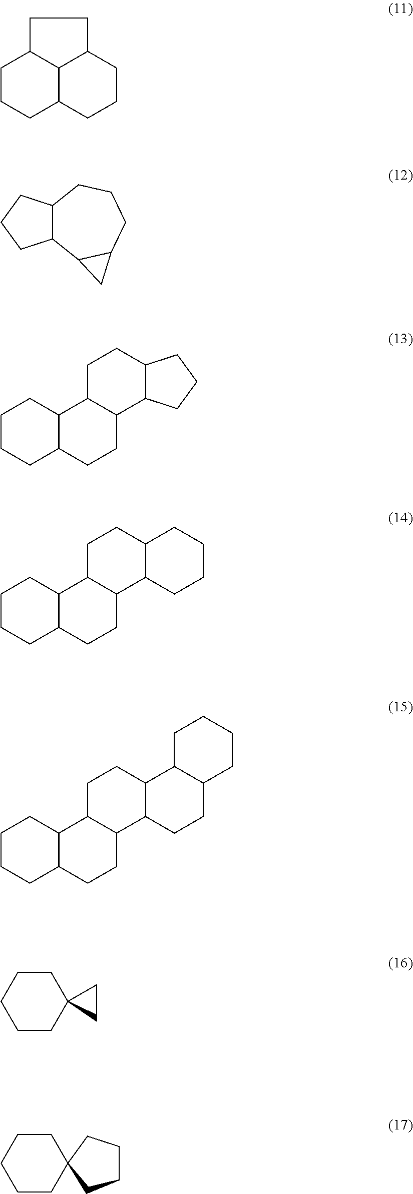

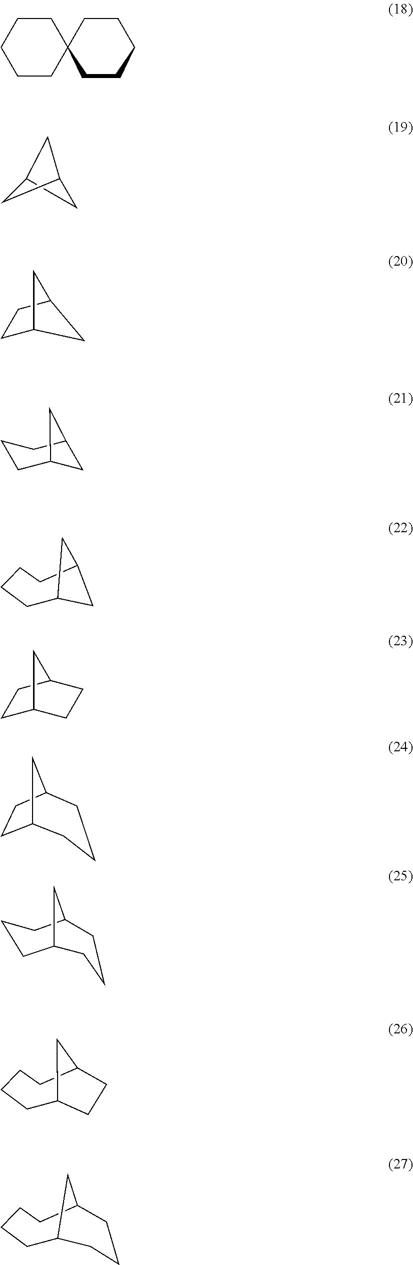

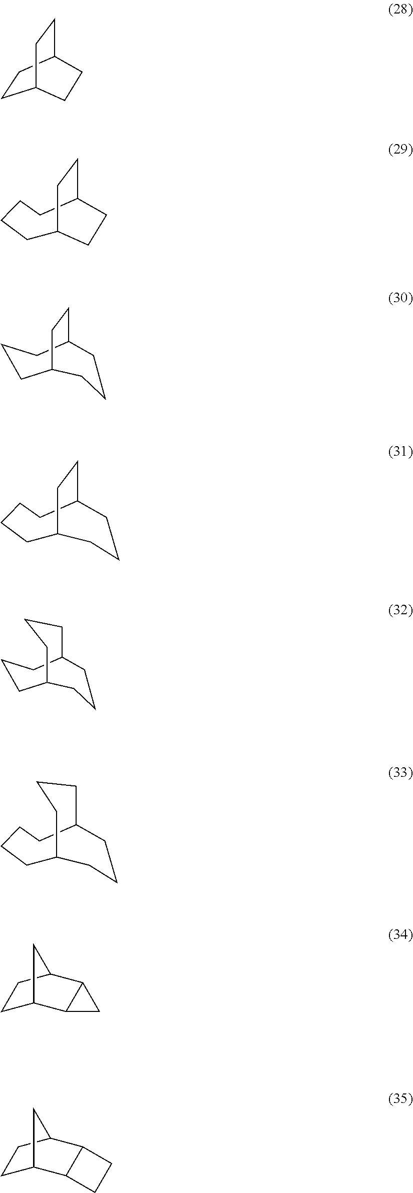

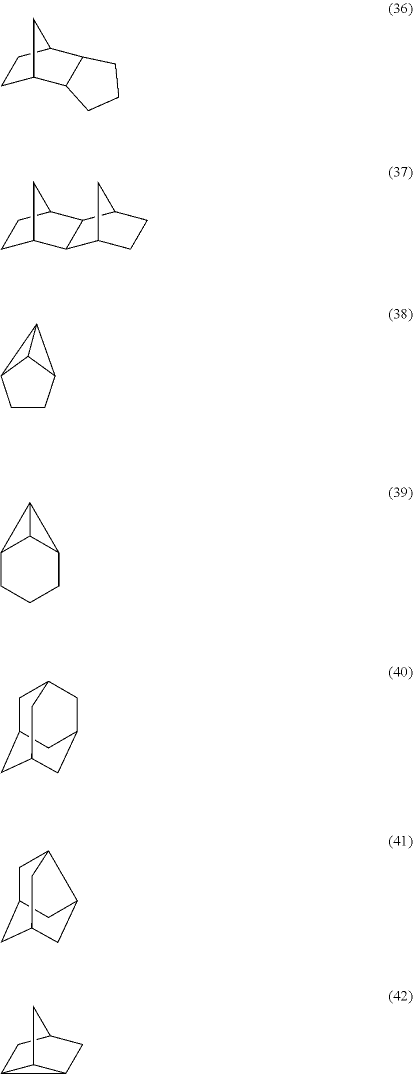

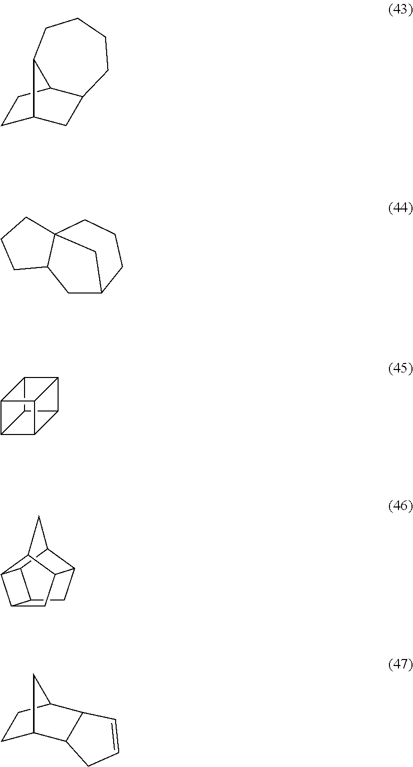 [SMILES: C1CCC2C3CCC2C(C1)C3 ; C1CC2CC3CCCC3(C1)C2 ; C12C3C4C1C1C2C3C41 ; C1C2C3CC4C5CC3C1C5C24 ; C1=CC2C3CCC(C3)C2C1]

Among these groups, particularly preferred examples of the groups include (5), (6), (7), (8), (9), (10), (13), (14), (15), (23), (28), (36), (37), (40), (42), and (47).

In a case where the resin for a resist underlayer film used in the present invention is the copolymer, the content of the repeating unit represented by General Formula (1) is preferably 0% to 80% by mole, and more preferably 0% to 60% by mole, with respect to all the repeating units of the copolymer. Further, this copolymer may be a copolymer further having other repeating units, in addition to the repeating units, for the purpose of improving film formability, adhesiveness, developability, or the like.

The resin for a resist underlayer film used in the present invention may be a copolymer further having other repeating units, in addition to the repeating unit represented by General Formula (1), for the purpose of improving film formability, adhesiveness, developability, or the like. Examples of the monomers corresponding to such other repeating units include compounds having one addition-polymerizable unsaturated bond selected from acrylic esters, methacrylic esters, acrylamides, methacrylamides, allyl compound, vinyl ethers, vinyl esters, and the like.

Specific examples thereof include acrylic esters, for example, alkyl acrylates (in which the number of carbon atoms of the alkyl group is preferably 1 to 10) (for example, methyl acrylate, ethyl acrylate, propyl acrylate, amyl acrylate, cyclohexyl acrylate, ethylhexyl acrylate, octyl acrylate, t-octyl acrylate, chlorethyl acrylate, trimethylolpropane monoacrylate, pentaerythritol monoacrylate, benzyl acrylate, methoxybenzyl acrylate, furfuryl acrylate, and tetrahydrofurfuryl acrylate);

methacrylate esters include alkyl methacrylates (in which the number of carbon atoms of the alkyl group is preferably 1 to 10) (for example, methyl methacrylate, ethyl methacrylate, propyl methacrylate, isopropyl methacrylate, amyl methacrylate, hexyl methacrylate, cyclohexyl methacrylate, benzyl methacrylate, chlorbenzyl methacrylate, octyl methacrylate, trimethylol propane monomethacrylate, pentaerythritol monomethacrylate, furfuryl methacrylate, and tetrahydrofurfuryl methacrylate);

acrylamides, for example, acrylamide, N-alkyl acrylamides (in which the number of carbon atoms of the alkyl group is 1 to 10, and examples of the alkyl group include a methyl group, an ethyl group, a propyl group, a butyl group, a t-butyl group, a heptyl group, an octyl group, a cyclohexyl group, and a hydroxyethyl group), N,N-dialkyl acrylamides (in which the number of carbon atoms of the alkyl group is 1 to 10, and examples of the alkyl group include a methyl group, an ethyl group, a butyl group, an isobutyl group, an ethylhexyl group, and a cyclohexyl group), N-hydroxyethyl-N-methyl acrylamide, and N-2-acetoamidoethyl-N-acetyl acrylamide;

methacrylamides, for example, methacrylamide, N-alkyl methacrylamides (in which the number of carbon atoms of the alkyl group is 1 to 10, and examples of the alkyl group include a methyl group, an ethyl group, a t-butyl group, an ethylhexyl group, a hydroxylethyl group, and a cyclohexyl group), N,N-dialkyl methacrylamides (examples of the alkyl group include an ethyl group, a propyl group, and a butyl group), and N-hydroxyethyl-N-methyl methacrylamide;

allyl compounds, for example, allyl esters (for example, allyl acetate, allyl caproate, allyl caprylate, allyl laurate, allyl palmitate, allyl stearate, allyl benzoate, allyl acetoacetate, and allyl lactate), and allyloxyethanol;

vinyl ethers, for example, alkyl vinyl ethers (for example, hexylvinyl ether, octylvinyl ether, decylvinyl ether, ethylhexylvinyl ether, methoxyethylvinyl ether, ethoxyethylvinyl ether, chlorethylvinyl ether, 1-methyl-2,2-dimethylpropylvinyl ether, 2-ethylbutylvinyl ether, hydroxylethylvinyl ether, diethylene glycol vinyl ether, dimethylaminoethylvinyl ether, diethylaminoethylvinyl ether, butylaminoethylvinyl ether, benzylvinyl ether, and tetrahydrofurfurylvinyl ether);

vinyl esters, for example, vinyl butyrate, vinyl isobutyrate, vinyltrimethyl acetate, vinyldiethyl acetate, vinyl valerate, vinyl caproate, vinyl chloracetate, vinyl dichloracetate, vinyl methoxyacetate, vinyl butoxyacetate, vinyl acetoacetate, vinyl lactate, vinyl-β-phenyl butyrate, and vinylcyclohexyl carboxylate; and

dialkyl itaconates (for example, dimethyl itaconate, diethyl itaconate, and dibutyl itaconate); dialkyl esters (for example, dibutyl fumarate) or monoalkyl esters of fumaric acid;

an acrylic acid, a methacrylic acid, a crotonic acid, an itaconic acid, a maleic anhydride, a maleimide, an acrylonitrile, a methacrylonitrile, and a maleylonitrile. Other than these, addition-polymerizable unsaturated compounds copolymerizable with the various repeating units may also be used.

Suitable examples of the phenol-based polymer include the following polymers.

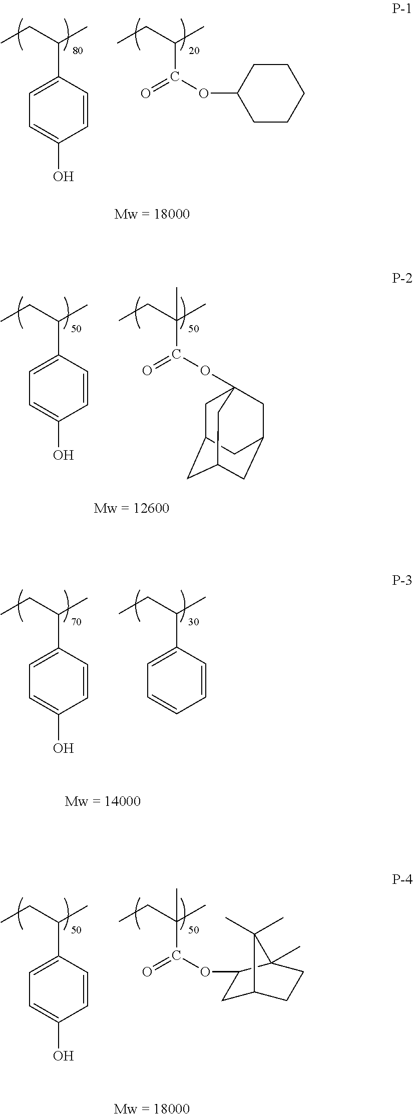

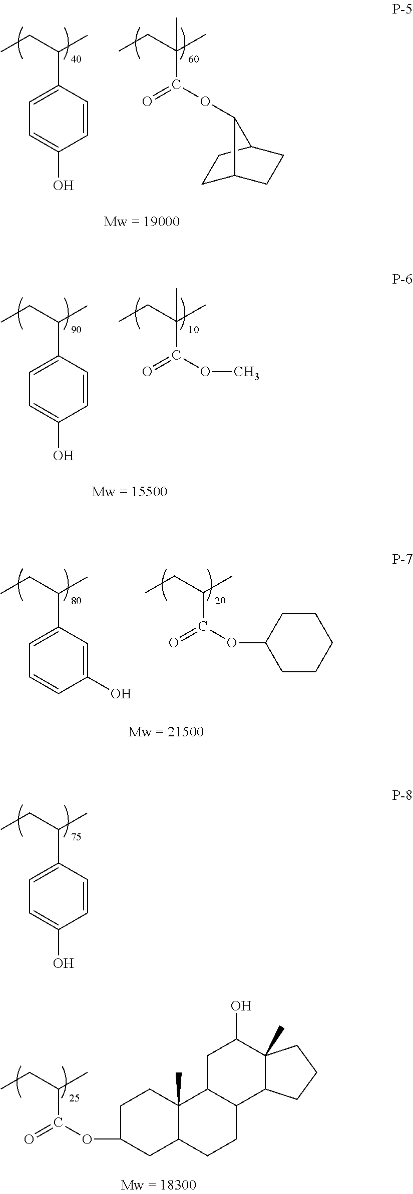

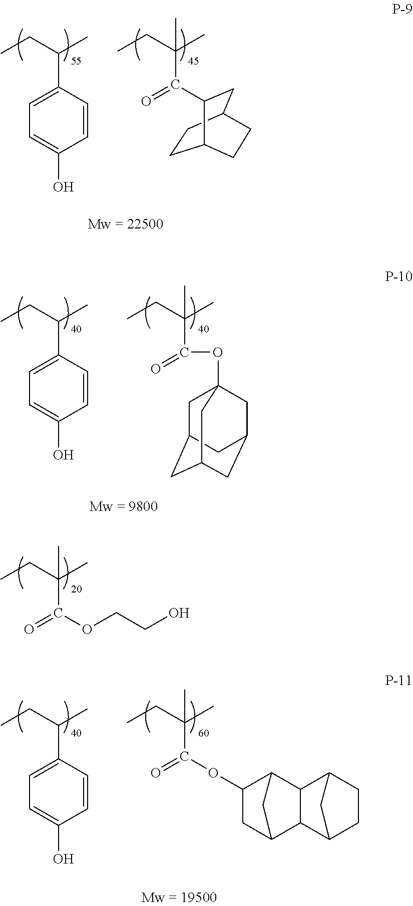

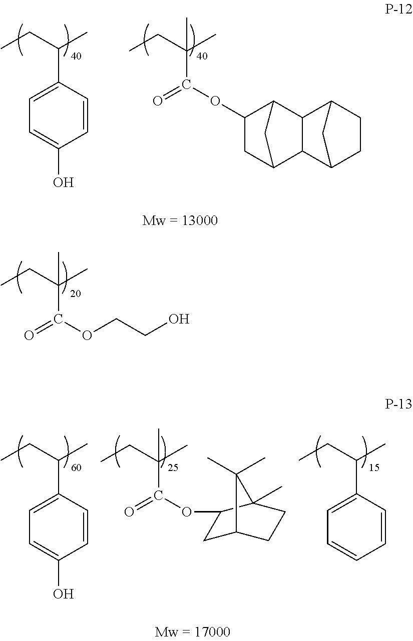

In a suitable embodiment, the composition for forming a resist underlayer film includes, in addition to the resin, a solvent, an acid generator, a crosslinking agent, a surfactant, or the like.

<Acid Generator>

The resist underlayer film-forming composition may include an acid generator, as desired. This acid generator is a component which generates an acid upon exposure or heating. By incorporation of the acid generator, it is possible to solve a problem of inhibiting a crosslinking reaction in a resist underlayer film (a problem in that an acid contained in a resist underlayer film is inactivated due to diffusion of a substance (for example, a base such as OH—, CH₃—, and NH₂—) generated from a substrate (in particular, a low-dielectric-constant film) into the resist underlayer film, thereby inhibiting a crosslinking reaction). That is, by reacting the acid generator contained in the formed resist underlayer film with the inhibiting substance, it is possible to prevent diffusion of the inhibiting substance into the resist underlayer film.

Examples of the acid generator which generates an acid upon exposure (hereinafter referred to as a “photoacid generator”) include the compounds described in paragraphs [0076] to [0081] of WO07/105776A.

Among these photoacid generators, diphenyliodonium trifluoromethanesulfonate, diphenyliodonium nonafluoro-n-butanesulfonate, diphenyliodonium pyrenesulfonate, diphenyliodonium n-dodecyl benzenesulfonate, diphenyliodonium 10-camphorsulfonate, diphenyliodonium naphthalenesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium n-dodecylbenzenesulfonate, bis(4-t-butylphenyl)iodonium 10-camphorsulfonate, or bis(4-t-butylphenyl)iodonium naphthalenesulfonate is preferable, and bis(4-t-butylphenyl)iodonium nonafluoro-n-butanesulfonate is more preferable. Further, these photoacid generators may be used singly or in combination of two or more kinds thereof.

As the photoacid generator, the photoacid generator which will be described later can also be preferably used in the resist composition.

Moreover, examples of the acid generator which generates an acid upon heating (hereinafter referred to as a “thermal acid generator”) include 2,4,4,6-tetrabromocyclohexadiene, benzoin tosylate, 2-nitrobenzyl tosylate, and alkyl sulfonates. These thermal acid generators may be used singly or in combination of two or more kinds thereof. Incidentally, the photoacid generator and the thermal acid generator may be used in combination as the acid generator.

The content of the acid generator is preferably 100 parts by mass or less, more preferably 0.1 parts by mass to 30 parts by mass, and particularly preferably 0.1 parts by mass to 10 parts by mass, with respect to 100 parts by mass of the resin for a resist underlayer film.

<Crosslinking Agent>

By incorporating a crosslinking agent into the composition for forming a resist underlayer film, the resist underlayer film is cured at a lower temperature, and thus, it is possible to form a protecting film for the substrate to be processed.

As such the crosslinking agent, various curing agents can be used, in addition to polynuclear phenols. Examples of the polynuclear phenols include binuclear phenols such as 4,4′-biphenyl diol, 4,4′-methylene bisphenol, 4,4′-ethylidene bisphenol, and bisphenol A; trinuclear phenols such as 4,4′,4″-methylidene trisphenol and 4,4′-[1-[4-[1-(4-hydroxyphenyl)-1-methylethyl]phenyl]ethylidene] bisphenol; and polyphenols such as novolac. Among these, 4,4′-[1-[4-[1-(4-hydroxyphenyl)-1-methyl ethyl] phenyl] ethylidene] bisphenol and novolac are preferable. Incidentally, these polynuclear phenols may be used singly or in combination of two or more kinds thereof.

Furthermore, examples of the curing agent include diisocyanates, epoxy compounds, melamine-based curing agents, benzoguanamine-based curing agents, and glycoluril-based curing agents. Among these, the melamine-based curing agents and the glycoluril-based curing agents are preferable, and 1,3,4,6-tetrakis(methoxymethyl)glycoluril uril are more preferable. In addition, Further, these curing agents may be used singly or in combination of two or more kinds thereof. Further, as the crosslinking agent, the polynuclear phenols can be used in combination of the curing agent.

The content of the crosslinking agent is preferably 100 parts by mass or less, more preferably 1 part by mass to 20 parts by mass, and particularly preferably 1 part by mass to 10 parts by mass, with respect to 100 parts by mass of the resin for a resist underlayer film.

As the crosslinking agent, the crosslinking agent which will be described later can also be preferably used in the resist composition.

<Other Optional Components>

The composition for forming a resist underlayer film may also contain other optional components such as a thermosetting polymer, a radiation absorber, a storage stabilizer, an antifoaming agent, and an adhesion aiding agent, as desired, in addition to the above components.

[Step (2): Resist Film Forming Step]

In the step (2), a resist film is formed on a resist underlayer film, using a resist composition.

First, the members and the materials used in the step (2) will be described, and then the procedure of the step (2) will be described.

[Resist Composition]

The resist composition of the present invention contains (A) a resin having a repeating unit containing a Si atom, and (B) a compound which generates an acid upon irradiation with actinic rays or radiation, in which the content of the resin (A) is 20% by mass or more, with respect to the total solid content of the resist composition.

In addition, the resist composition of the present invention is typically a negative tone resist composition, and is also a chemical amplification-type resist composition.

Hereinafter, the respective components which can be contained in the resist composition of the present invention will be described.

[1] (A) Resin

The composition of the present invention contains a resin having a repeating unit containing a Si atom (hereinafter also referred to as a resin (A)).

Here, the content of Si atoms is preferably 1.0% to 30% by mass, more preferably 3% to 25% by mass, and particularly preferably 5% to 20% by mass, with respect to the total amount of the resin (A).

Here, the content of Si atoms with respect to the total amount of the resin (A) corresponds to a sum of the atomic amount of all the Si atoms in the resin (A) with respect to a sum of the atomic amount of all the atoms constituting the resin (A), in which the sum of the atomic amount of all the atoms constituting the resin (A) is calculated, based on the molecular weights of the respective monomers corresponding to the respective repeating units constituting the resin (A) and the molar ratio of the respective repeating units in the resin (A), and the sum of the atomic amount of all the Si atoms in the resin (A) is calculated, based on the sum of the atomic amount of all the Si atoms included in the respective monomers and the molar ratio of the respective repeating units in the resin (A).

In addition, it is preferable that the repeating unit having a Si atom does not have an acid-decomposable group (details of which will be described later).

Since the repeating unit having a Si atom is hydrophobic, it exhibits high solubility in a developer including an organic solvent. Thus, the development defects are reduced.

[1-1] Repeating Unit Having Si Atom

The repeating unit having a Si atom is not particularly limited as long as it has a Si atom. Examples thereof include a silane-based repeating unit (—SiR₂—: R₂ is an organic group), siloxane-based repeating unit (—SiR₂—O—: R₂ is an organic group), a (meth)acrylate-based repeating unit having a Si atom, and a vinyl-based repeating unit having a Si atom.

The repeating unit having a Si atom is preferably a repeating unit having a silsesquioxane structure. Further, the repeating unit has the silsesquioxane structure in either the main chain or the side chain, but preferably in the side chain. By having the silsesquioxane structure in the side chain, the storage stability of the resin is improved.

Examples of the silsesquioxane structure include a cage type silsesquioxane structure, a ladder type silsesquioxane structure, and a random type silsesquioxane structure. Among these, the cage type silsesquioxane structure is preferable.

Here, the cage type silsesquioxane structure is a silsesquioxane structure having a cage shape skeleton. The cage type silsesquioxane structure may be either a full cage type silsesquioxane structure or a partial cage type silsesquioxane structure, with the full cage type silsesquioxane structure being preferable.

Furthermore, the ladder type silsesquioxane structure is a silsesquioxane structure having a ladder shape skeleton.

In addition, the random type silsesquioxane structure is a silsesquioxane structure having a random skeleton.

The cage type silsesquioxane structure is preferably a siloxane structure represented by Formula (S).

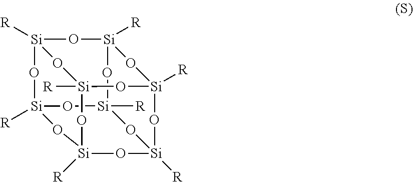

In Formula (S), R represents a monovalent organic group. R's which are present in plural numbers may be the same as or different from each other.

The monovalent organic group is not particularly limited, but specific examples thereof include a halogen atom, a hydroxyl group, a nitro group, a carboxyl group, an alkoxy group, an amino group, a mercapto group, a blocked mercapto group (for example, a mercapto group blocked (protected) with an acyl group), an acyl group, an imido group, a phosphino group, a phosphinyl group, a silyl group, a vinyl group, a hydrocarbon group which may have a heteroatom, a (meth)acryl group-containing group, and an epoxy group-containing group.

Examples of the halogen atom include a fluorine atom, a chlorine atom, a bromine atom, and an iodine atom.

Examples of the heteroatom of the hydrocarbon group which may have the heteroatom include an oxygen atom, a nitrogen atom, a sulfur atom, and a phosphorus atom.

Examples of the hydrocarbon group in the hydrocarbon group which may have the heteroatom include an aliphatic hydrocarbon group, an aromatic hydrocarbon group, and a group formed by combining these groups.

The aliphatic hydrocarbon group may be linear, branched, or cyclic. Specific examples of the aliphatic hydrocarbon group include a linear or branched alkyl group (in particular, having 1 to 30 carbon atoms), a linear or branched alkenyl group (in particular, having 2 to 30 carbon atoms), and a linear or branched alkynyl group (in particular, having 2 to 30 carbon atoms).

Examples of the aromatic hydrocarbon group include aromatic hydrocarbon groups having 6 to 18 carbon atoms, such as a phenyl group, a tolyl group, a xylyl group, and a naphthyl group.

The repeating unit having a Si atom is preferably represented by Formula (I).

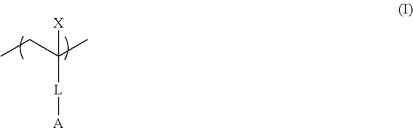

In Formula (I), L represents a single bond or a divalent linking group.

Examples of the divalent linking group include an alkylene group, a —COO-Rt- group, and an —O-Rt- group. In the formula, Rt represents an alkylene group or a cycloalkylene group.

L is preferably a single bond or a —COO-Rt- group. Rt is preferably an alkylene group having 1 to 5 carbon atoms, and more preferably a —CH₂— group, a —(CH₂)₂— group, or a —(CH₂)₃— group.

In Formula (I), X represents a hydrogen atom or an organic group.

Examples of the organic group include an alkyl group which may have a substituent such as a fluorine atom and a hydroxyl group, with the hydrogen atom, the methyl group, the trifluoromethyl group, and the hydroxymethyl group being preferable.

In Formula (I), A represents a Si-containing group. Among these, a group represented by Formula (a) or (b) is preferable.

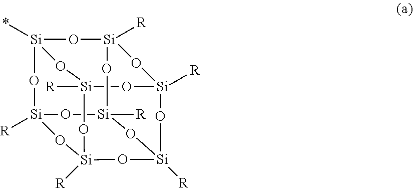

In Formula (a), R represents a monovalent organic group. R's which are present in plural numbers may be the same as or different from each other. Specific examples and suitable aspects of R are the same as in Formula (S) described above. In addition, in a case where A in Formula (I) is the group represented by Formula (a), Formula (I) is represented by Formula (I-a).

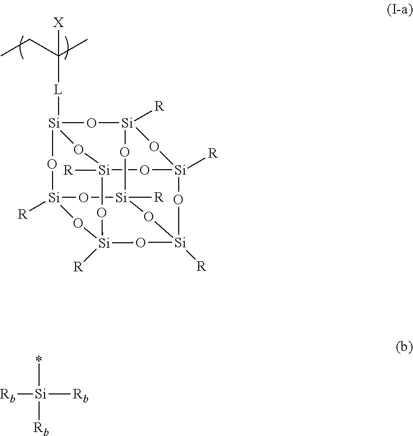

In Formula (b), R_{b} represents a hydrocarbon group which may have a heteroatom. Specific examples and suitable aspects of the hydrocarbon group which may have a heteroatom are the same as that for R in Formula (S) above.

The resin (A) may have one kind or two or more kinds of repeating unit having a Si atom.

The content of the repeating unit having a Si atom with respect to all the repeating units of the resin (A) is not particularly limited, but is preferably 1% to 100% by mole, and more preferably 3% to 50% by mole.

In the resist composition containing a silicon, by making silicon-containing substance generated as an outgas during exposure or eluted into an immersion liquid during liquid immersion exposure, there is a concern that the silicon-containing substance may be adhered to the surface of a projection lens, resulting in a decrease in transmittance. As for an aspect for reducing such the outgassing or elution, it is preferable that the repeating unit having a Si atom is stable to an exposure wavelength or the molecular weight thereof is large. From this point of view, it is more preferable that the repeating unit having a Si atom, with a high molecular weight, has a main chain silsesquioxane structure, in which the polymer main chain has a silicon atom, or has a main chain silicone structure.

The repeating unit having a Si atom, included in the resin, is preferably a repeating unit obtained from monomers having a turbidity of 1 ppm or less, based on JIS K0101: 1998 in an integrating sphere measurement system as a measurement system, using formazin as a standard substance. By using monomers having a turbidity of 1 ppm or less, scum defects are relieved.

The turbidity is preferably 0.8 ppm or less, and more preferably 0.1 ppm or less. The turbidity is usually 0.01 ppm or more.

As a method for obtaining the monomer having a Si atom of the turbidity, for example, a method involving purifying monomers having post-synthesis or commercially available silicon atoms such that the turbidity becomes 1 ppm or less is preferable. As a purification method, a known purification method can be adopted and used, and specific examples of the purification method include filtration, centrifugation, adsorption, liquid separation, distillation, sublimation, crystallization, and a combination of two or more thereof.

The repeating unit having a Si atom include in the resin is preferably a repeating unit obtained from monomers having a purity (GPC purity) defined from a gel permeation chromatography (GPC) area of 95% or more. By using the monomers having a GPC purity of 95% or more, scum defects after patterning can be relieved.

The GPC purity is more preferably 97% or more, and still more preferably 99% or more. The GPC purity is usually 99.9% or less.

The GPC purity can be measured in a test method described below.

Method for measuring GPC purity: Measurement is carried out by means of gel permeation chromatography (GPC). TSKgel SuperHZ 2000 (4.6 mmI.D×15 cm, Tosoh Co., Ltd.) and TSKgel SuperHZ 1000 (4.6 mmI.D×15 cm, Tosoh Co., Ltd.) connected with each other are used as columns, tetrahydrofuran is used as an eluent, the flow rate is 1.0 mL/min, the column temperature is 40° C., a differential refractometer is used as a detector, a tetrahydrofuran solution at a 0.1%-by-weight concentration is used as a sample, and the injection volume is 100 μL. In the obtained chromatogram, in a case where peaks are separated, they are vertically divided from the minimum value between the peaks, and in a case where peaks are overlapped, they are vertically divided from inflection points between the peaks, and an area percentage of the main peak is calculated from the area values of the obtained respective peaks.

In a case of synthesizing monomers having a Si atom, as a synthesis method therefor, known methods can all be adopted and used, and examples thereof include the methods described in JP2008-523220A, WO01/10871A, and the like.

In the resist system in the present invention, the resist film can be sufficiently made thin by using a difference in etching selectivity between a resist film (that is, layer having a silicon-based resin as a main component) a resist underlayer film (typically, an SOC layer), and therefore, it can have a system capable of sufficiently improving resolving power. A mechanism for providing etching selectivity is as follows. In a case where the layer having a silicon-based resin as a main component is subjected to oxygen plasma etching (O₂RIE), silicon oxide is produced by the oxidation reaction of Si atoms, and it remains in the film and is concentrated, which provides the film with a very low etching rate, with an improvement in the etching selectivity to the SOC layer. In other words, the resist film of the present invention acquires the same etching resistance as that of Spin On Carbon (SOG) by plasma etching.

In order to sufficiently express the function, it is presumed, although not certain, that silicon oxide is preferably efficiently produced and remains in the film. In the definition of the former, a silsesquioxane compound having a Si—O bond is preferred to an organic silane compound having a Si—C bond. Further, in the definition of the latter, it is presumed, although not certain, a lower volatility of the Si-containing skeleton is preferred. From this viewpoint, the repeating unit having a Si atom in the resin (A) is preferably, for example, a high-molecular-weight unit, and more preferably has a main chain silsesquioxane structure, in which the polymer main chain has a silicon atom, or has a main chain silicone structure.

[1-2] Repeating Unit Having Acid-Decomposable Group

In a suitable embodiment, the resin (A) has a repeating unit having an acid-decomposable group.

The repeating unit having an acid-decomposable group may or may not have a Si atom, but it is preferable that the repeating unit does not have a Si atom.

Furthermore, in the present specification, the repeating unit having both a Si atom and an acid-decomposable group corresponds to both a repeating unit having a Si atom and a repeating unit having an acid-decomposable group. For example, a resin including only repeating units having both of a Si atom and an acid-decomposable group corresponds to a resin including a repeating unit having a Si atom and a repeating unit having an acid-decomposable group.

The acid-decomposable group refers to a group which decomposes by the action of an acid to generate a polar group.

The acid-decomposable group preferably has a structure in which a polar group is protected with a group (leaving group) capable of leaving upon decomposition by the action of an acid.

The polar group is not particularly limited as long as it is a group sparingly soluble or insoluble in a developer including an organic solvent, but examples of the polar group include acidic groups (groups which are dissociated in a 2.38%-by-mass aqueous tetramethylammoniumhydroxide solution, used as a developer in the resist in the related art) such as a phenolic hydroxyl group, a carboxyl group, a fluorinated alcohol group (preferably a hexafluoroisopropanol group), a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group, or an alcoholic hydroxyl group.

Moreover, the alcoholic hydroxyl group refers to a hydroxyl group bonded to a hydrocarbon group, and the hydroxyl group is a hydroxyl group other than a hydroxyl group (phenolic hydroxyl group) directly bonded onto an aromatic ring, excluding an aliphatic alcohol (for example, a fluorinated alcohol group (a hexafluoroisopropanol group or the like)) substituted with an electron withdrawing group such as a fluorine atom at the α-position as the hydroxyl group. The alcoholic hydroxyl group is preferably a hydroxyl group having a pKa (acid dissociation constant) from 12 to 20.

Preferred examples of the polar group include a carboxyl group, a fluorinated alcohol group (preferably a hexafluoroisopropanol group), and sulfonic acid group.

A group which is preferred as the acid-decomposable group is a group obtained by substituting a hydrogen atom of these groups with a group that leaves by the action of an acid.

Examples of the group (leaving group) that leaves by the action of an acid include —C(R₃₆)(R₃₇)(R₃₈), —C(R₃₆)(R₃₇)(OR₃₉), and —C(R₀₁)(R₀₂)(OR₃₉).

In Formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

The alkyl group of R₃₆ to R₃₉, R₀₁, and R₀₂ is preferably an alkyl group having 1 to 8 carbon atoms, and examples thereof may include a methyl group, an ethyl group, a propyl group, an n-butyl group, a sec-butyl group, a hexyl group, and an octyl group.

The cycloalkyl groups of R₃₆ to R₃₉, R₀₁, and R₀₂ may be a monocyclic type or a polycyclic type. The monocyclic type is preferably a cycloalkyl group having 3 to 8 carbon atoms, and examples thereof may include a cyclopropyl group, a cyclobutyl group, a cyclopentyl group, a cyclohexyl group, a cyclooctyl group and the like. The polycyclic type is preferably a cycloalkyl group having 6 to 20 carbon atoms, and examples thereof may include an adamantyl group, a norbornyl group, an isobornyl group, a camphanyl group, a dicyclopentyl, an α-pinene group, a tricyclodecanyl group, a tetracyclododecyl group, an androstanyl group, and the like. In addition, at least one carbon atom in the cycloalkyl group may be substituted with a heteroatom such as an oxygen atom.

The aryl group of R₃₆ to R₃₉, R₀₁, and R₀₂ is preferably an aryl group having 6 to 10 carbon atoms, and examples thereof may include a phenyl group, a naphthyl group, an anthryl group, and the like.

The aralkyl group of R₃₆ to R₃₉, R₀₁, and R₀₂ is preferably an aralkyl group having 7 to 12 carbon atoms, and examples thereof may include a benzyl group, a phenethyl group, a naphthylmethyl group, and the like.

The alkenyl group of R₃₆ to R₃₉, R₀₁, and R₀₂ is preferably an alkenyl group having 2 to 8 carbon atoms, and examples thereof may include a vinyl group, an allyl group, a butenyl group, a cyclohexenyl group, and the like.

The ring formed by the bonding of R₃₆ and R₃₇ is preferably a cycloalkyl group (monocyclic or polycyclic). The cycloalkyl group is preferably a monocyclic cycloalkyl group such as a cyclopentyl group or a cyclohexyl group, or a polycyclic cycloalkyl group such as a norbornyl group, a tetracyclodecanyl group, tetracyclododecanyl group, or an adamantyl group, more preferably a monocyclic cycloalkyl group having 5 or 6 carbon atoms, and particularly preferably a monocyclic cycloalkyl group having 5 carbon atoms.

As the repeating unit having an acid-decomposable group, a repeating unit having a group in which a carboxy group is protected with an acetal, or a group in which a carboxy group is protected with a ketal is also preferable. Further, the acid-decomposable group is also preferably a group in which a carboxy group is protected with an acetal or ketal represented by General Formula (a1-1). In addition, in a case where a carboxy group is protected with an acetal or ketal represented by General Formula (a1-1), the acid-decomposable group entirely has a structure of —(C═O)—O—CR¹R²(OR³).

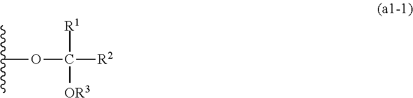

(In General Formula (a1-1), R¹ and R² each independently represent a hydrogen atom or an alkyl group, provided that a case where both R¹ and R² are hydrogen atoms at the same time. R³ represents an alkyl group. R¹ or R², and R³ may be linked to each other to form a cyclic ether.)

In Formula (a1-1), R¹ to R³ each independently represent a hydrogen atom or an alkyl group, and the alkyl group may be any of a linear alkyl group, a branched alkyl group, and a cyclic alkyl group. Here, R¹ and R² do not represent hydrogen atoms at the same time, and at least one of R¹ or R² represents an alkyl group.

In Formula (a1-1), in a case where R¹, R², and R³ each represent an alkyl group, the alkyl group may be any of a linear alkyl group, a branched alkyl group, and a cyclic alkyl group. The linear or branched alkyl group preferably has 1 to 12 carbon atoms, more preferably has 1 to 6 carbon atoms, and still more preferably has 1 to 4 carbon atoms. Specific examples thereof include a methyl group, an ethyl group, an n-propyl group, an i-propyl group, an n-butyl group, an i-butyl group, a sec-butyl group, a t-butyl group, an n-pentyl group, a neopentyl group, an n-hexyl group, a thexyl group (2,3-dimethyl-2-butyl group), an n-heptyl group, an n-octyl group, a 2-ethylhexyl group, an n-nonyl group, and an n-decyl group.

The cyclic alkyl group preferably has 3 to 12 carbon atoms, more preferably has 4 to 8 carbon atoms, and still more preferably has 4 to 6 carbon atoms. Examples of the cyclic alkyl group include a cyclopropyl group, a cyclobutyl group, a cyclopentyl group, a cyclohexyl group, a cycloheptyl group, a cyclooctyl group, a norbornyl group, and an isobornyl group.

The alkyl group may have a substituent and examples of the substituent include a halogen atom, an aryl group, and an alkoxy group. In a case wherein the alkyl group has a halogen atom as the substituent, R¹, R², and R³ each become a haloalkyl group and, in a case wherein the alkyl group has an aryl group as the substituent, R¹, R², and R³ each become an aralkyl group.

Examples of the halogen atom include a fluorine atom, a chlorine atom, a bromine atom, and an iodine atom and, and among these, a fluorine atom or a chlorine atom is preferable.

The aryl group is preferably an aryl group having 6 to 20 carbon atoms and more preferably an aryl group having 6 to 12 carbon atoms. Specific examples thereof include a phenyl group, an α-methylphenyl group, a naphthyl group, and the like, and examples of the entire alkyl group substituted by an aryl group, that is, the aralkyl group include a benzyl group, an α-methylbenzyl group, a phenethyl group, and a naphthylmethyl group.

The alkoxy group is preferably an alkoxy group having 1 to 6 carbon atoms and more preferably an alkoxy group having 1 to 4 carbon atoms, and a methoxy group or an ethoxy group is more preferred.

In a case where the alkyl group is a cycloalkyl group, the cycloalkyl group may have a linear or branched alkyl group having 1 to 10 carbon atoms as the substituent and, in a case where the alkyl group is a linear or branched alkyl group, the linear or branched alkyl group may have a cycloalkyl group having 3 to 12 carbon atoms as the substituent.

These substituents may be further substituted by the above-described substituent.

In General Formula (a1-1), in a case where R¹, R², and R³ each represent an aryl group, the aryl group preferably has 6 to 12 carbon atoms and more preferably has 6 to 10 carbon atoms. The aryl group may have a substituent and preferable examples of the substituent include alkyl groups having 1 to 6 carbon atoms. Examples of the aryl group include a phenyl group, a tolyl group, a silyl group, a cumenyl group, and a 1-naphthyl group.

In addition, R¹, R², and R³ may be bonded to each other to form a ring, together with a carbon atom. Examples of a ring structure obtained in a case where R¹ and R², R¹ and R³, or R² and R³ are bonded to each other include a cyclobutyl group, a cyclopentyl group, a cyclohexyl group, a cycloheptyl group, a tetrahydrofuranyl group, an adamantyl group, and a tetrahydropyranyl group.

Furthermore, in Formula (a1-1), either of R¹ and R² is preferably a hydrogen atom or a methyl group.

Specific preferred examples of the monomer unit (a1-1) having a residue in which a carboxy group is protected with an acid-decomposable group include the following monomer units. Further, R represents a hydrogen atom or a methyl group.

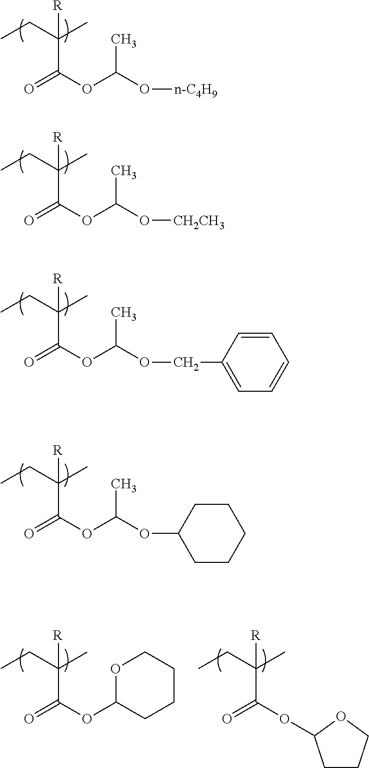

In a case where the repeating unit having a structure in which a polar group is protected with a leaving group capable of leaving upon decomposition by the action of an acid has a Si atom, that is, in a case where the repeating unit having a Si atom has a structure in which a polar group is protected with a leaving group capable of leaving upon decomposition by the action of an acid, it is preferable that the leaving group does not contain a Si atom.

The acid-decomposable group is preferably a cumyl ester group, an enol ester group, an acetal ester group, a tertiary alkyl ester group, or the like, and more preferably a tertiary alkyl ester group.

The resin (A) preferably has a repeating unit represented by General Formula (AI) as the repeating unit having an acid-decomposable group. The repeating unit represented by General Formula (AI) generates a carboxyl group as a polar group by the action of an acid, and since a plurality of carboxyl groups exhibits a high interaction due to hydrogen bonds, the formed negative tone pattern can be more reliably insoluble or sparingly soluble in the above-mentioned solvent in the composition of the present invention.

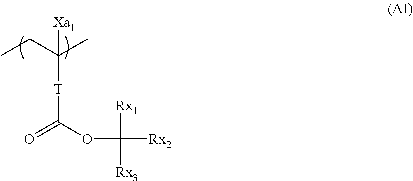

In General Formula (AI),

Xa₁ represents a hydrogen atom, an alkyl group, a cyano group, or a halogen atom.

T represents a single bond or a divalent linking group.

Rx₁ to Rx₃ each independently represents an alkyl group or a cycloalkyl group.

Two of Rx₁ to Rx₃ may be bonded to each other to form a ring structure.

Examples of the divalent linking group of T include an alkylene group, a —COO-Rt- group, a —O-Rt-group, and a phenylene group. In the formula, Rt represents an alkylene group or a cycloalkylene group.

T represents preferably a single bond or a —COO-Rt-group. Rt is preferably an alkylene group having 1 to 5 carbon atoms, and more preferably a —CH₂— group, a —(CH₂)₂— group, or a —(CH₂)₃— group. T is more preferably a single bond.

The alkyl group of Xₐ₁ may have a substituent, and examples of the substituent include a hydroxyl group and a halogen atom (preferably a fluorine atom).

The alkyl group of Xₐ₁ is preferably an alkyl group having 1 to 4 carbon atoms, and examples thereof include a methyl group, an ethyl group, a propyl group, a hydroxymethyl group, and a trifluoromethyl group, with the methyl group being preferable.

Xₐ₁ is preferably a hydrogen atom or a methyl group.

The alkyl group of each of Rₓ₁, Rₓ₂, and Rₓ₃ may be linear or branched, and preferred examples thereof include a methyl group, an ethyl group, an n-propyl group, an isopropyl group, an n-butyl group, an isobutyl group, and a t-butyl group. The number of carbon atoms of the alkyl group is preferably 1 to 10, and more preferably 1 to 5.

The cycloalkyl group of each of Rₓ₁, Rₓ₂, and Rₓ₃ is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group.

The ring structure formed by the bonding of two of Rₓ₁, Rₓ₂, and Rₓ₃ is preferably a monocyclic cycloalkane ring such as a cyclopentyl ring and a cyclohexyl ring, or a polycyclic cycloalkyl group such as a norbornane ring, a tetracyclodecane rings, a tetracyclododecanyl group, and an adamantane ring. A monocyclic cycloalkane ring having 5 or 6 carbon atoms is particularly preferable.

Rₓ₁, Rₓ₂, and Rₓ₃ are each independently preferably an alkyl group, and more preferably a linear or branched alkyl group having 1 to 4 carbon atoms.

Each of the groups may have a substituent, and examples of the substituent include an alkyl group (having 1 to 4 carbon atoms), a cycloalkyl group (having 3 to 8 carbon atoms), a halogen atom, an alkoxy group (having 1 to 4 carbon atoms), a carboxyl group, and an alkoxycarbonyl group (having 2 to 6 carbon atoms). The group having 8 or less carbon atoms is preferable. Among those, from the viewpoint of further improving the dissolution contrast to a developer including an organic solvent before and after acid decomposition, a substituent having no heteroatoms, such as an oxygen atom, a nitrogen atom, and a sulfur atom is more preferable (for example, the group which is not an alkyl group substituted with a hydroxyl group is more preferable). A group containing hydrogen and carbon atoms is still more preferable, and a linear or branched alkyl group or a cycloalkyl group is particularly preferable.

In General Formula (AI), Rx₁ to Rx₃ are each independently represent an alkyl group, and it is preferable that two of Rx₁ to Rx₃ are not bonded to each other to form a ring structure. Thus, an increase in the volume of a group represented by —C(Rx₁)(Rx₂)(Rx₃) as the group capable of leaving upon decomposition by the action of an acid can be suppressed, and thus, in an exposing step and a post-exposure heating step which may be carried out after the exposing step, there is a tendency that a shrinkage in the volume of the exposed area can be suppressed.

Specific examples of the repeating unit represented by General Formula (AI) are shown below, but the present invention is not limited to these specific examples.

In the specific examples, Rx represents a hydrogen atom, CH₃, CF₃, or CH₂OH. Rxa and Rxb each independently represent an alkyl group (preferably an alkyl group having carbon atoms 1 to 10, and more preferably an alkyl group having carbon atoms 1 to 5). Xa₁ represents a hydrogen atom, CH₃, CF₃, or CH₂OH. Z represents a substituent, and in a case where a plurality of Z's are present, the plurality of Z's may be the same as or different from each other. p represents 0 or a positive integer. Specific examples and preferred examples of Z are the same as the specific examples and preferred examples of the substituent which may be obtained in each of the groups such as Rx₁ to Rx₃.

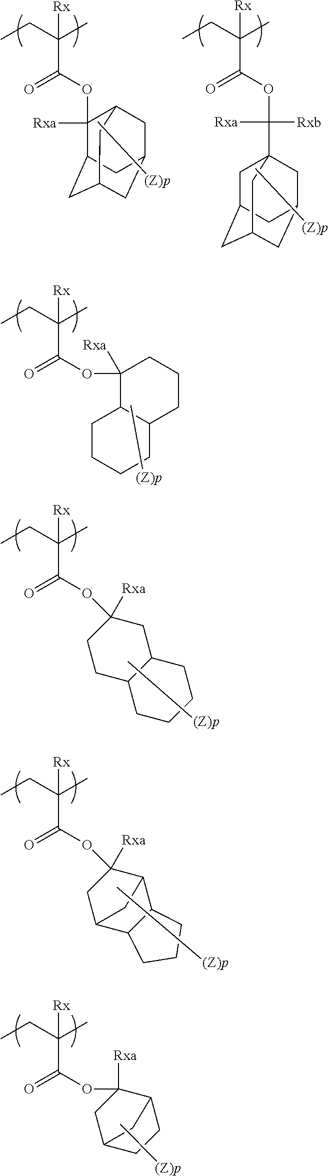

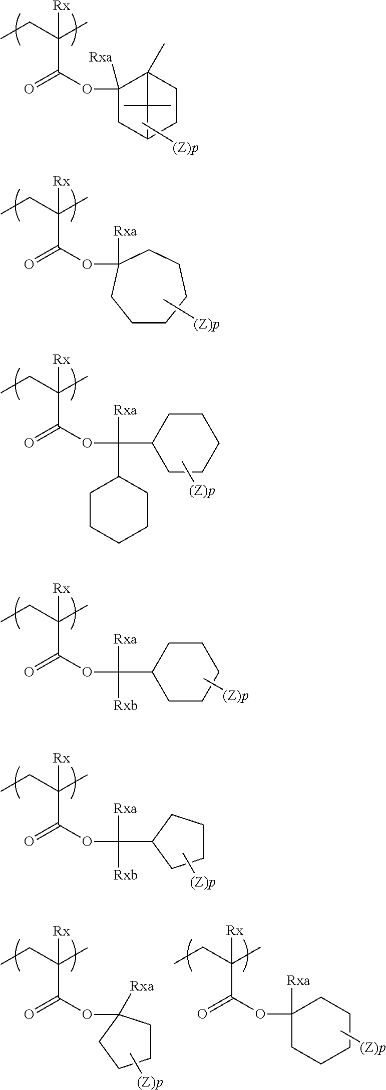

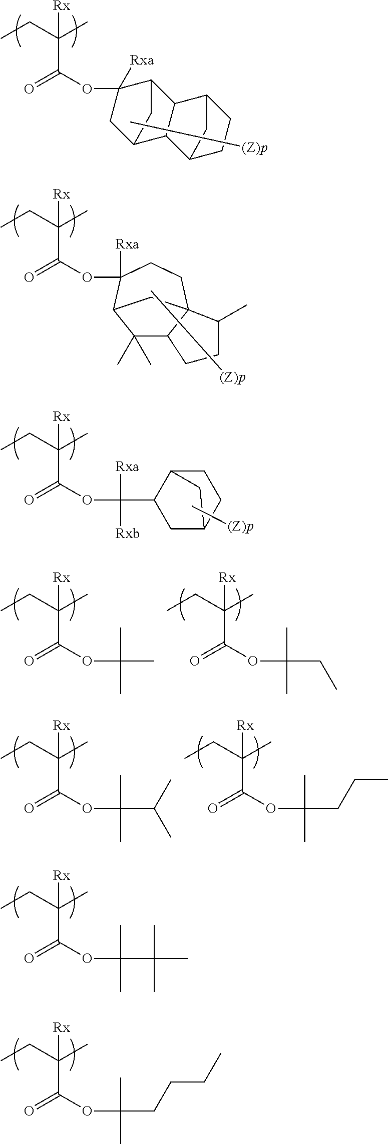

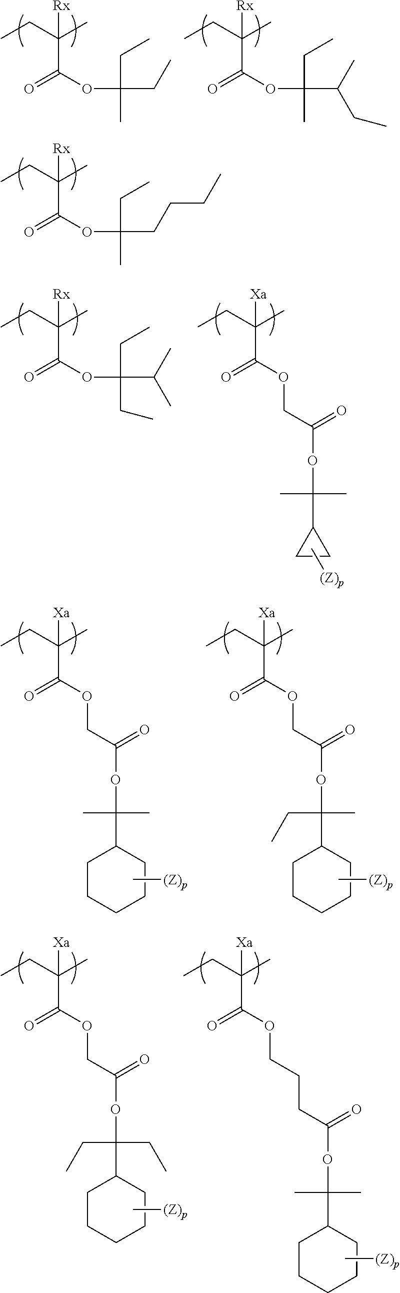

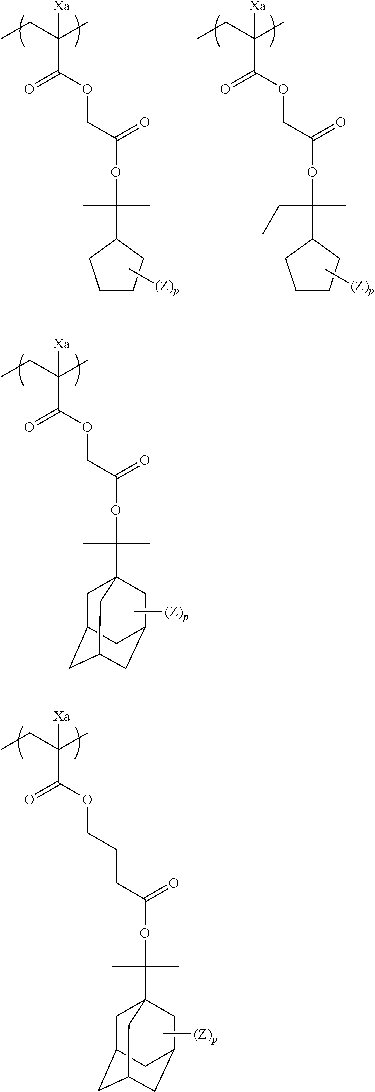

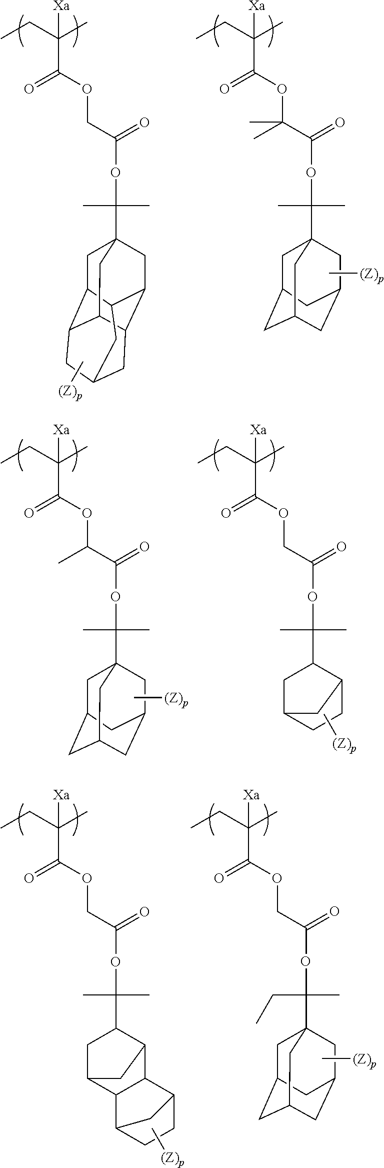

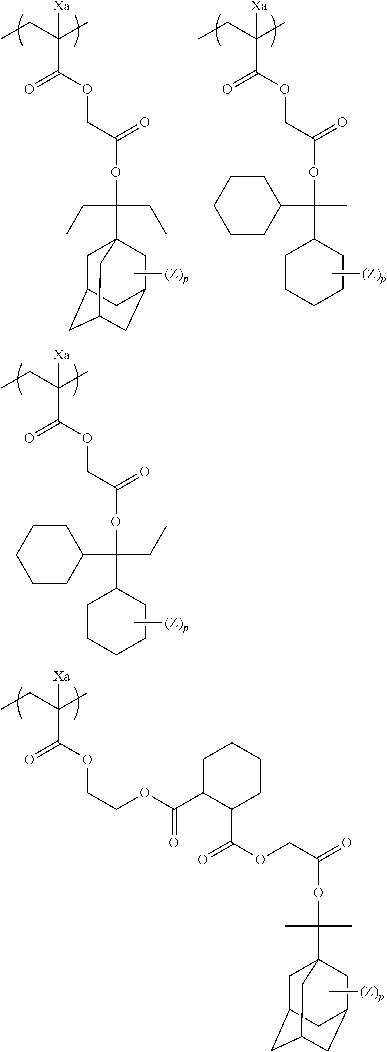

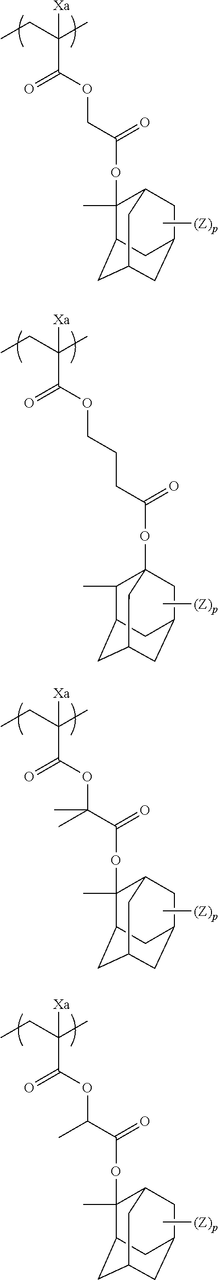

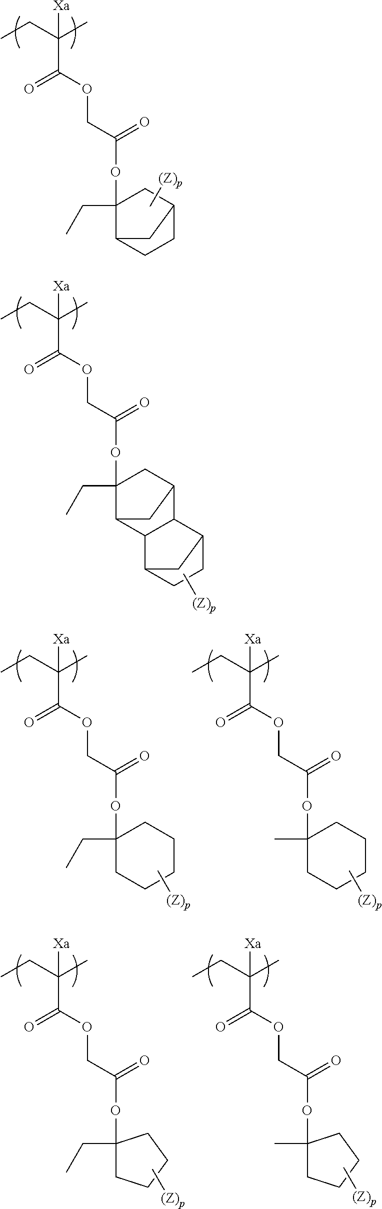

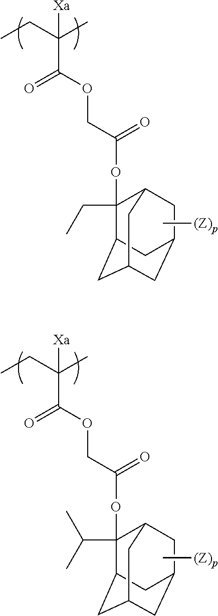

Moreover, the resin (A) preferably has the repeating units described in paragraph [0057] to [0071] of JP2014-202969A as the repeating unit having an acid-decomposable group.

Furthermore, the resin (A) may have the repeating units which generate alcoholic hydroxyl groups, described in paragraph [0072] and [0073] of JP2014-202969A, as the repeating unit having an acid-decomposable group.

The repeating unit having an acid-decomposable group may be of one kind or may be used in combination of two or more kinds thereof.

The content of the repeating unit having an acid-decomposable group included in the resin (A) (a total sum of contents in a case where a plurality of the repeating units having an acid-decomposable group are present) is preferably 20% to 90% by mole, and more preferably 40% to 80% by mole, with respect to all the repeating units of the resin (A). Among those, it is preferable that the resin (A) has the repeating unit represented by General Formula (AI), and the content of the repeating unit represented by General Formula (AI) is 40% by mole or more, with respect to all the repeating units of the resin (A).

From the viewpoints of reliably reducing the solubility in a developer containing an organic solvent in the exposed area, and thus, the effects of the present invention can be further improved, it is preferable that the resin (A) has a repeating unit having at least one selected from the group consisting of a lactone structure, a sultone structure, and a carbonate structure.

As the lactone structure or the sultone structure, any one having a lactone structure or a sultone structure can be used. The lactone structure or the sultone structure is preferably a 5- to 7-membered ring lactone structure or a 5- to 7-membered ring sultone structure, and more preferably a 5- to 7-membered ring lactone structure to which another ring structure is fused so as to form a bicyclo structure or a spiro structure, or a 5- to 7-membered ring sultone structure to which another ring structure is fused so as to form a bicyclo structure or a spiro structure. The resin (A) still more preferably has a repeating unit having a lactone structure represented by any one of General Formulae (LC1-1) to (LC1-21) or a repeating unit having a sultone structure represented by any one of General Formulae (SL1-1) to (SL1-3). Further, the lactone structure or the sultone structure may be bonded directly to the main chain. The lactone structure is preferably (LC1-1), (LC1-4), (LC1-5), (LC1-6), (LC1-13), (LC1-14), or (LC1-17), and particularly preferably (LC1-4). By using such specific lactone structures, LER and development defects are relieved.

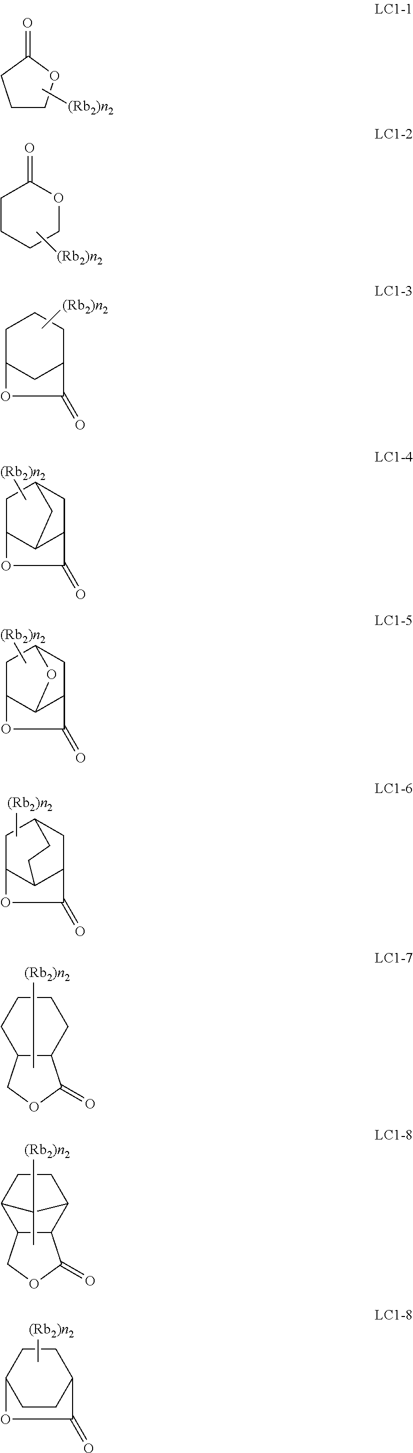

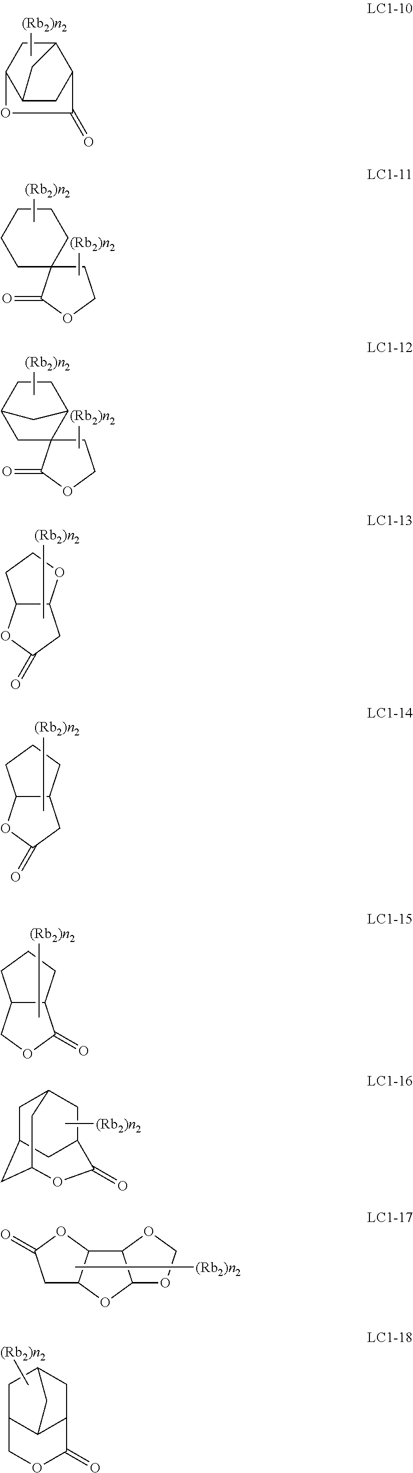

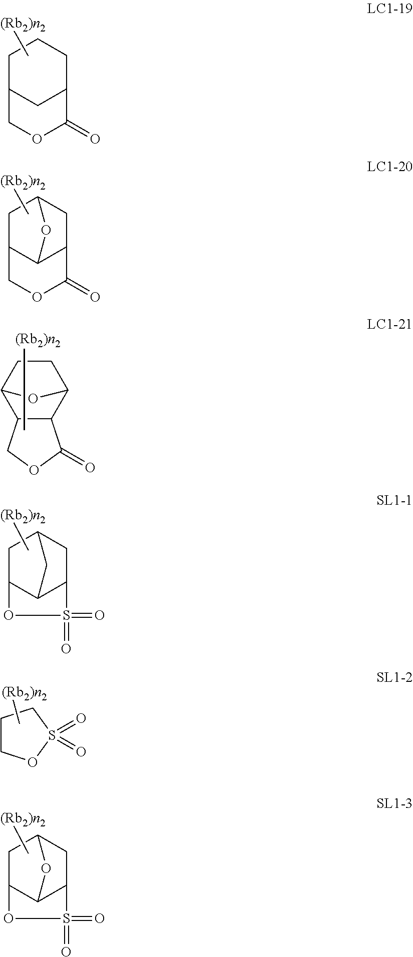

The lactone structure moiety or the sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. Among these, an alkyl group having 1 to 4 carbon atoms, a cyano group, and an acid-decomposable group are more preferable. n₂ represents an integer of 0 to 4. In a case where n₂ is 2 or more, the substituents (Rb₂) which are present in plural numbers may be the same as or different from each other, and further, the substituents (Rb₂) which are present in plural numbers may be bonded to each other to form a ring.

The repeating unit having a lactone structure or a sultone structure usually has an optical isomer, and any optical isomer may be used. Further, one kind of optical isomer may be used singly or a plurality of optical isomers may be mixed and used. In a case of mainly using one kind of optical isomer, the optical purity (ee) thereof is preferably 90% or more, and more preferably 95% or more.

The repeating unit having a lactone structure or a sultone structure is preferably a repeating unit represented by General Formula (III).

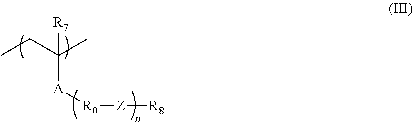

In General Formula (III),

A represents an ester bond (a group represented by —COO—) or an amide bond (a group represented by —CONH—).

In a case where a plurality of R₀'s are present, they each independently represent an alkylene group, a cycloalkylene group, or a combination thereof.

In a case where plurality of Z's are present, they each independently represent a single bond, an ether bond, an ester bond, an amide bond, a urethane bond

(a group represented by

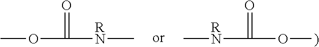

or a urea bond

(a group represented by

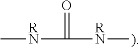

Here, R's each independently represent a hydrogen atom, an alkyl group, a cycloalkyl group, or an aryl group.

R₈ represents a monovalent organic group having a lactone structure or a sultone structure.

n is the repetition number of the structure represented by —R₀—Z—, represents an integer of 0 to 5, and is preferably 0 or 1, and more preferably 0. In a case where n is 0, —R₀—Z— is not present, resulting in a single bond.

R₇ represents a hydrogen atom, a halogen atom, or an alkyl group.

The alkylene group or the cycloalkylene group of R₀ may have a substituent.

Z is preferably an ether bond or an ester bond, and particularly preferably an ester bond.

The alkyl group of R₇ is preferably an alkyl group having 1 to 4 carbon atoms, more preferably a methyl group or an ethyl group, and particularly preferably a methyl group.

The alkylene group or the cycloalkylene group of R₀, and the alkyl group in R₇ may be each substituted, and examples of the substituent include halogen atoms such as a fluorine atom, a chlorine atom, and a bromine atom; a mercapto group; a hydroxy group; alkoxy groups such as a methoxy group, an ethoxy group, an isopropoxy group, a t-butoxy group, and a benzyloxy group; and acyloxy groups such as an acetyloxy group and a propionyloxy group.

R₇ is preferably a hydrogen atom, a methyl group, a trifluoromethyl group, or a hydroxymethyl group.

Preferred chain alkylene group in R₀ is preferably a chain alkylene having 1 to 10 carbon atoms and more preferably 1 to 5 carbon atoms, and examples thereof include a methylene group, an ethylene group, and a propylene group. A preferred cycloalkylene group is a cycloalkylene group having 3 to 20 carbon atoms, and examples thereof include a cyclohexylene group, a cyclopentylene group, a norbornylene group, and an adamantylene group. In order to express the effects of the present invention, a chain alkylene group is more preferable, and a methylene group is particularly preferable.

The monovalent organic group having a lactone structure or a sultone structure represented by R₈ is not limited as long as it has a lactone structure or a sultone structure. Specific examples thereof include a lactone structure or a sultone structure represented by any one of General Formulae (LC1-1) to (LC1-21), and (SL1-1) to (SL1-3). Among these, a structure represented by (LC1-4) is particularly preferable. In addition, n₂ in (LC1-1) to (LC1-21) is more preferably 2 or less.

Furthermore, R₈ is preferably a monovalent organic group having an unsubstituted lactone structure or sultone structure, or a monovalent organic group having a lactone structure or sultone structure having a methyl group, a cyano group or an alkoxycarbonyl group as a substituent, and more preferably a monovalent organic group having a lactone structure (cyano lactone) having a cyano group as the substituent.

As the repeating unit having a group having a lactone structure or a sultone structure, a hydrophilic repeating unit is preferable. Thus, swelling during development is suppressed.

Specific examples of the repeating unit having a group having a lactone structure or a sultone structure are shown below, but the present invention is not limited thereto.

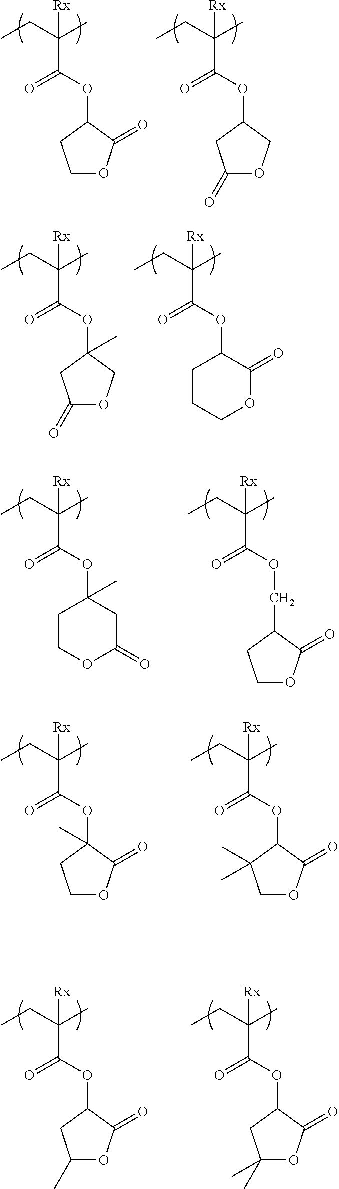

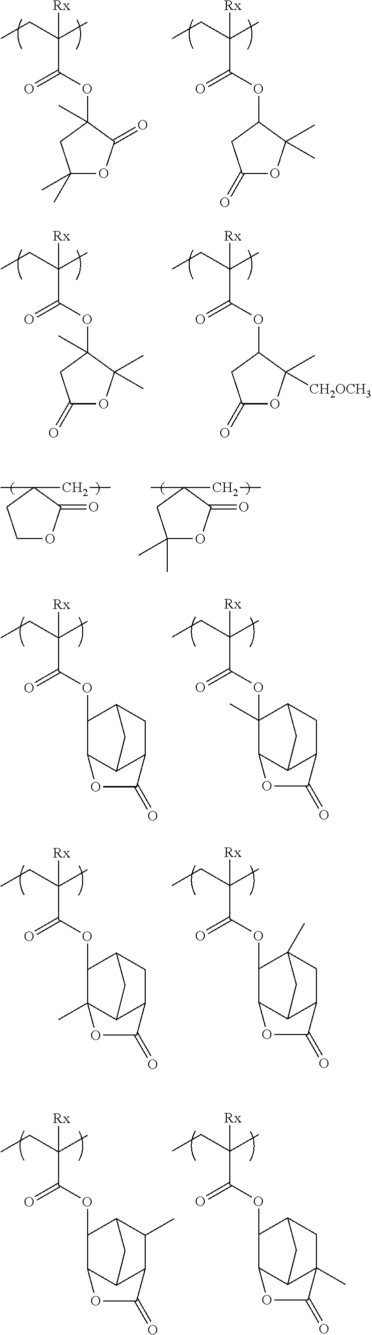

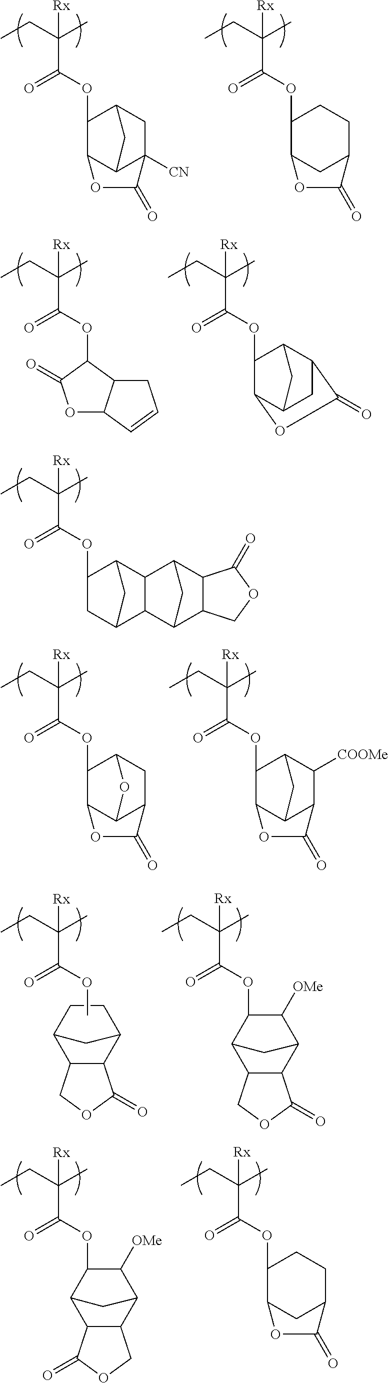

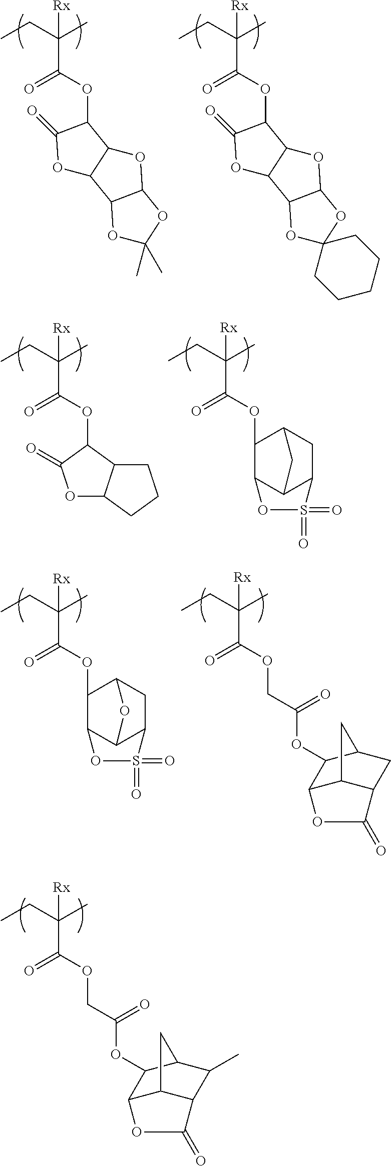

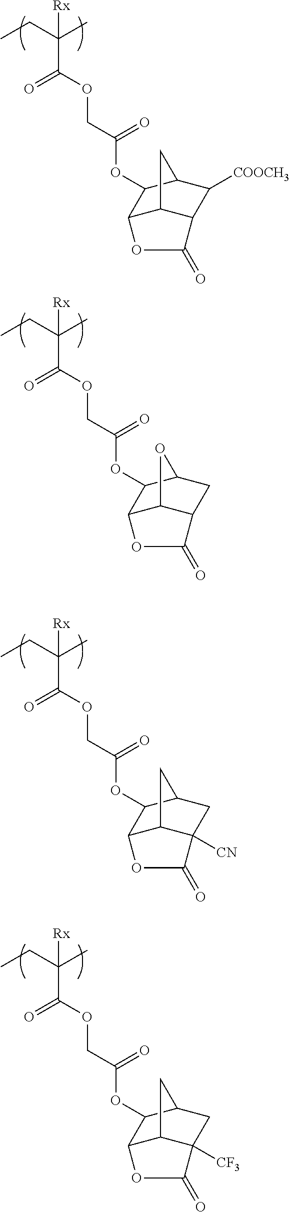

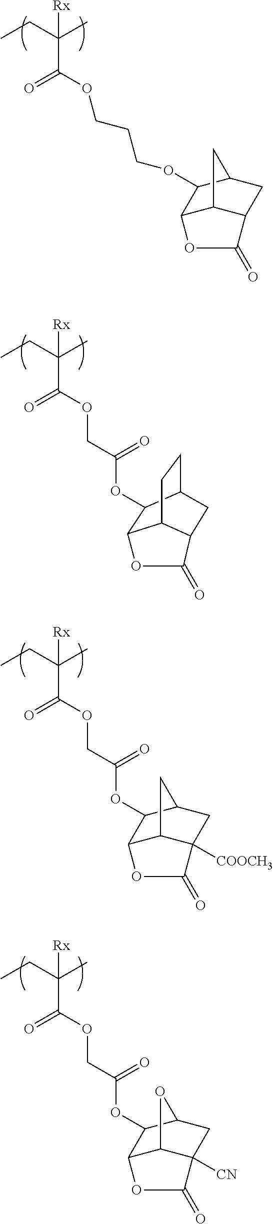

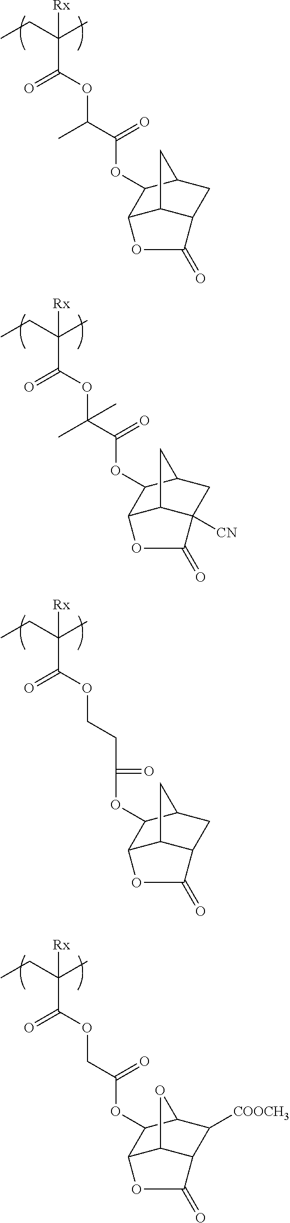

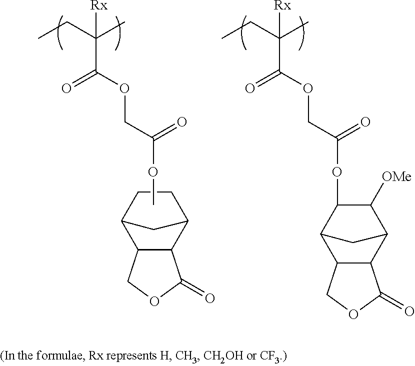

In order to enhance the effect of the present invention, it is also possible to use in combination of the repeating units having two or more kinds of lactone structures or sultone structures.

In a case where the resin (A) contains a repeating unit having a lactone structure or a sultone structure, the content of the repeating unit having a lactone structure or a sultone structure is preferably 5% to 60% by mole, more preferably 5% to 55% by mole, and still more preferably 10% to 50% by mole, with respect to all the repeating units of the resin (A).

Furthermore, the resin (A) may have a repeating unit having a carbonate structure. In this case, the carbonate structure is preferably a cyclic carbonic ester structure. As the repeating unit having a cyclic carbonic ester structure, a hydrophilic repeating unit is preferable. Thus, swelling during development is suppressed.

The repeating unit having a cyclic carbonic ester structure is preferably a repeating unit represented by General Formula (A-1).

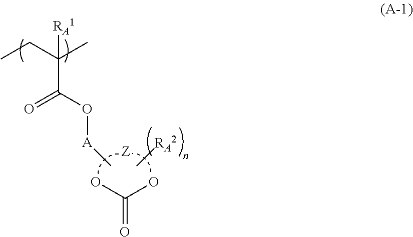

In General Formula (A-1), R_{A}¹ represents a hydrogen atom or an alkyl group.

In a case where n is 2 or more, R_{A}²'s each independently represent a substituent.

A represents a single bond or a divalent linking group.

Z represents an atomic group which forms a monocyclic or polycyclic structure, together with a group represented by —O—C(═O)—O— in the formula.

n represents an integer of 0 or more.

General Formula (A-1) will be described in detail.

The alkyl group represented by R_{A}¹ may have a substituent such as a fluorine atom. R_{A}¹ preferably represents a hydrogen atom, a methyl group, or a trifluoromethyl group, and more preferably a methyl group.

The substituent represented by R_{A}² is, for example, an alkyl group, a cycloalkyl group, a hydroxyl group, an alkoxy group, an amino group, or an alkoxycarbonyl amino group. Preferred is an alkyl group having 1 to 5 carbon atoms, and examples thereof include a linear alkyl group having 1 to 5 carbon atoms, such as a methyl group, an ethyl group, a propyl group, and a butyl group; and a branched alkyl group having 3 to 5 carbon atoms, such as an isopropyl group, an isobutyl group, and a t-butyl group. The alkyl group may have a substituent such as a hydroxyl group.

n is an integer of 0 or more, representing the number of substituents. n is, for example, preferably 0 to 4 and more preferably 0.

Examples of the divalent linking group represented by A include an alkylene group, a cycloalkylene group, an ester bond, an amide bond, an ether bond, a urethane bond, a urea bond, or a combination thereof. The alkylene group is preferably an alkylene group having 1 to 10 carbon atoms and more preferably an alkylene group having 1 to 5 carbon atoms, and examples thereof include a methylene group, an ethylene group, and a propylene group.

In one embodiment of the present invention, A is preferably a single bond or an alkylene group.

Examples of the monocyclic ring containing a —O—C(═O)—O—, represented by Z, include a 5- to 7-membered ring in a cyclic carbonic ester represented by General Formula (a) in which n_{A}=2 to 4, preferably a 5- or 6-membered ring (n_{A}=2 or 3), and more preferably a 5-membered ring (n_{A}=2).

Examples of the polycyclic ring containing a —O—C(═O)—O—, represented by Z, include a structure in which a cyclic carbonic ester represented by General Formula (a) and one or two or more other ring structures are combined together to form a fused ring, or a structure which forms a Spiro ring. “Other ring structures” capable of forming a fused ring or a Spiro ring may be an alicyclic hydrocarbon group, or an aromatic hydrocarbon group, or a heterocycle.

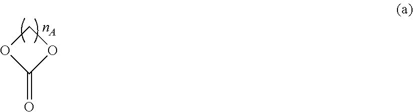

A monomer corresponding to the repeating unit represented by General Formula (A-1) may be synthesized by publicly known methods in the related art, which are described in, for example, Tetrahedron Letters. Vol. 27, No. 32, p. 3741 (1986), Organic Letters, Vol. 4, No. 15, p. 2561 (2002), and the like.

The resin (A) may include one kind or two or more kinds of the repeating unit represented by General Formula (A-1).

In the resin (A), the content of the repeating unit having a cyclic carbonic ester structure (preferably the repeating unit represented by General Formula (A-1)) is preferably 3% to 80% by mole, more preferably 3% to 60% by mole, particularly preferably 3% to 30% by mole, and most preferably 10% to 15% by mole, with respect to all the repeating units constituting the resin (A). By using such content, developability, low defectivity, low line width roughness (LWR), low post exposure bake (PEB) temperature dependence, and profiles, and the like as a resist may be improved.

Specific examples of the repeating unit represented by General Formula (A-1) (repeating units (A-1a) to (A-1w)) are shown below, but the present invention is not limited thereto.

Furthermore, R_{A}¹ in the following specific examples has the same definition as R_{A}¹ in General Formula (A-1).

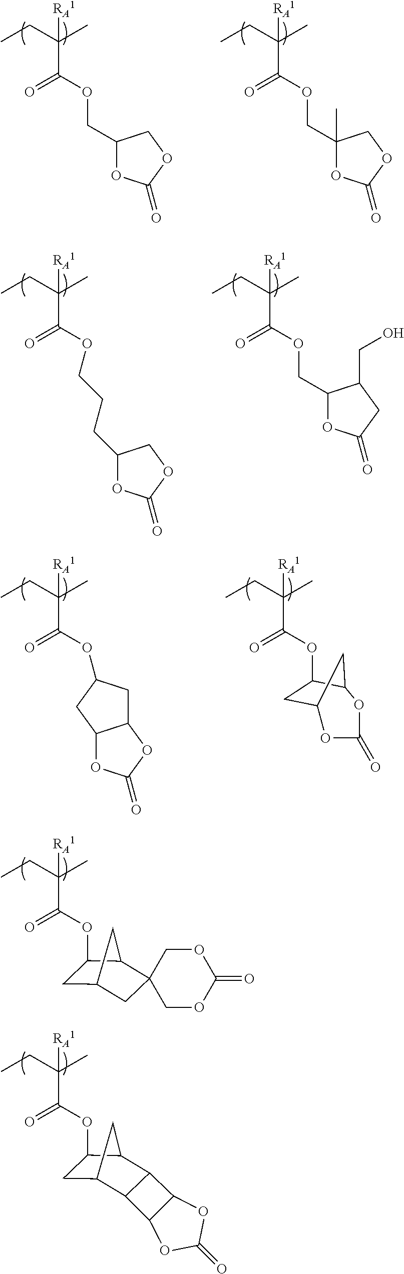

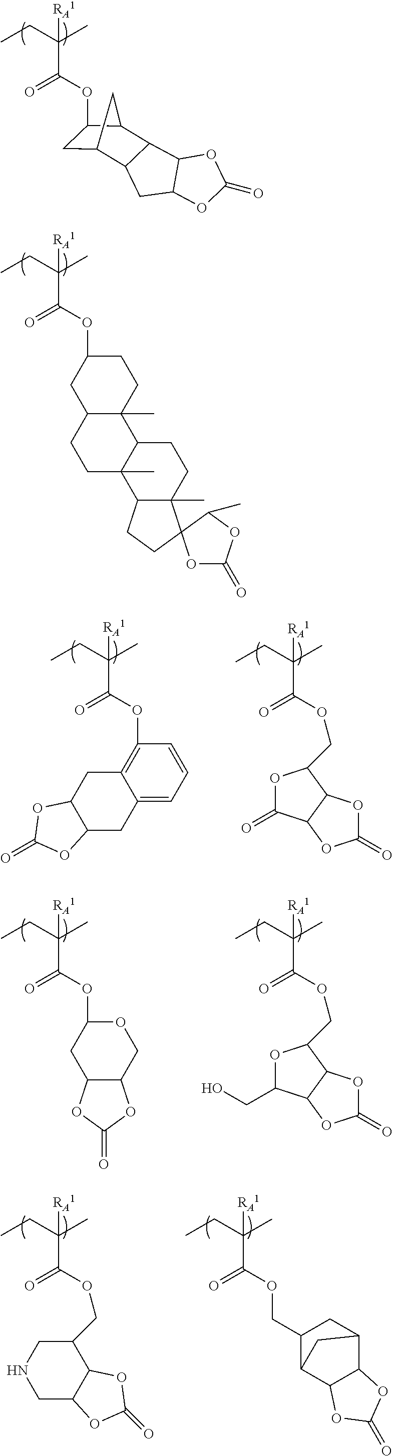

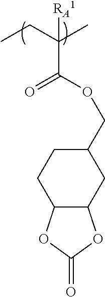

The resin (A) may include a repeating unit having a hydroxyl group or a cyano group. Examples of such a repeating unit include the repeating units described in paragraphs [0081] to [0084] of JP2014-098921A.

Furthermore, the resin (A) may have a repeating unit having an acid group. Examples of the acid group include a carboxyl group, a sulfonamido group, a sulfonylimido group, a bisulfonylimido group, and an aliphatic alcohol group with the α-position being substituted with an electron withdrawing group (for example, a hexafluoroisopropanol group). Examples of the repeating unit having an acid group include the repeating units described in paragraphs [0085] and [0086] of JP2014-098921A.

Moreover, the resin (A) can have a repeating unit which further has an alicyclic hydrocarbon structure not having a polar group (for example, an acid group, a hydroxyl group, and a cyano group), and does not exhibit acid decomposability. Examples of such a repeating unit include the repeating units described in paragraphs [0114] to [0123] of JP2014-106299A.

In particular, in a case where the resin (A) does not have a repeating unit having an acid-decomposable group, the resist composition preferably contains a crosslinking agent which will be described later. In this case, the resin (A) preferably has a repeating unit having a polar group (for example, an acid group and a hydroxyl group), and more preferably has a repeating unit having an acid group. The content of the repeating unit having an acid group is preferably 5% to 50% by mole, more preferably 10% to 40% by mole, and particularly preferably 15% to 30% by mole, with respect to all the repeating units constituting the resin (A).

In addition, the resin (A) may include the repeating units described in, for example, paragraphs [0045] to [0065] of JP2009-258586A.

In addition to the repeating structural units, the resin (A) used in the method of the present invention can have a variety of repeating structural units for the purpose of adjusting dry etching resistance, suitability for a standard developer, adhesiveness to a substrate, and a resist profile, and in addition, resolving power, heat resistance, sensitivity, and the like, which are characteristics generally required for the resist. Examples of such repeating structural units include, but are not limited to, repeating structural units corresponding to the following monomers.

Thus, it becomes possible to perform fine adjustments to performance required for the resin (A) used in the method of the present invention, in particular, (1) solubility with respect to a coating solvent, (2) film formability (glass transition point), (3) alkali developability, (4) films (selection of hydrophilic, hydrophobic, or alkali-soluble groups), (5) adhesiveness of an unexposed area to a substrate, (6) dry etching resistance, and the like.

Examples of such a monomer include a compound having one addition-polymerizable unsaturated bond selected from acrylic esters, methacrylic esters, acrylamides, methacrylamides, allyl compounds, vinyl ethers, vinyl esters, and the like.

In addition to these, an addition-polymerizable unsaturated compound that is copolymerizable with the monomers corresponding to various repeating structural units as described above may be copolymerized.

In the resin (A), the molar ratio of each repeating structural unit content is appropriately set in order to adjust dry etching resistance, suitability for a standard developer, adhesiveness to a substrate, and a resist profile of the resist, and in addition, resolving power, heat resistance, sensitivity, and the like, each of which is performance generally required for the resist.

In a case where the composition of the present invention is for ArF exposure, it is preferable that the resin (A) does not substantially have an aromatic group in terms of transparency to ArF light. More specifically, the proportion of repeating units having an aromatic group in all the repeating units of the resin (A) is preferably 5% by mole or less, and more preferably 3% by mole or less, and ideally, the proportion is still more preferably 0% by mole of all the repeating units, that is, the resin (A) does not have a repeating unit having an aromatic group. Further, it is preferable that the resin (A) has a monocyclic or polycyclic alicyclic hydrocarbon structure.

The resin (A) is preferably a resin in which all the repeating units include (meth)acrylate-based repeating units. In this case, all the repeating units may be methacrylate-based repeating units, all the repeating units may be acrylate-based repeating units, or all the repeating units may include methacrylate-based repeating units and acrylate-based repeating units, but the acrylate-based repeating units preferably accounts for 50% by mole or less with respect to all the repeating units.

In a case where the composition of the present invention is for a use in KrF exposure, EB exposure, or EUV exposure, it is preferable that the resin (A) has an aromatic group. It is more preferable that the resin (A) includes a repeating unit containing a phenolic hydroxyl group, and examples of the repeating unit containing a phenolic hydroxyl group include a hydroxylstyrene repeating unit and a hydroxylstyrene (meth)acrylate repeating unit.

The resin (A) may be any one of a random polymer, a block polymer, and a graft polymer.

The resin (A) can be synthesized in accordance with an ordinary method (for example, radical polymerization). Examples of the general synthesis method include a bulk polymerization method in which polymerization is carried out by dissolving monomer species and an initiator in a solvent and heating the solution, a dropwise addition polymerization method in which a solution of monomer species and an initiator is added dropwise to a heating solvent for 1 to 10 hours, with the dropwise addition polymerization method being preferable. In the dropwise addition polymerization method, some of the monomer types may be introduced into a polymerization container. By doing so, it is possible to obtain a copolymer having a compositional ratio which is uniform in a range from the initiation of the polymerization to the completion of the polymerization, and thus, the solubility in a developer becomes uniform. For example, in the present invention, it is preferable to perform dropwise addition polymerization in the state where at least one of monomers having a Si atom or monomers having an acid-decomposable group is introduced into a polymerization container. Examples of the reaction solvent include ethers such as tetrahydrofuran, 1,4-dioxane, and diisopropyl ether, ketones such as methyl ethyl ketone and methyl isobutyl ketone, ester solvents such as ethyl acetate, amide solvents such as dimethyl formamide and dimethyl acetamide, and a solvent which dissolves the composition of the present invention, such as propylene glycol monomethyl ether acetate, propylene glycol monomethyl ether, and cyclohexanone, which will be described later. It is more preferable to perform polymerization using the same solvent as the solvent used in the composition of the present invention. Thus, generation of the particles during storage can be inhibited.

It is preferable that the polymerization reaction is carried out in an inert gas atmosphere such as nitrogen and argon. As the polymerization initiator, commercially available radical initiators (an azo-based initiator, a peroxide, or the like) are used to initiate the polymerization. As the radical initiator, an azo-based initiator is preferable, and the azo-based initiator having an ester group, a cyano group, or a carboxyl group is preferable. Preferable initiators include azobisisobutyronitrile, azobisdimethylvaleronitrile, dimethyl 2,2′-azobis(2-methyl propionate), or the like. The initiator is added or added in portionwise, as desired, a desired polymer is recovered after the reaction is completed, the reaction mixture is poured into a solvent, and then a method such as powder or solid recovery is used. The concentration of the solid content in the reaction solution is 5% to 50% by mass, and preferably 10% to 30% by mass. The reaction temperature is usually 10° C. to 150° C., preferably 30° C. to 120° C., and more preferably 60° C. to 100° C.

The weight-average molecular weight of the resin (A) is preferably 1,000 to 200,000, more preferably 2,000 to 20,000, still more preferably 3,000 to 15,000, and particularly preferably 3,000 to 11,000. By setting the weight-average molecular weight to 1,000 to 200,000, it is possible to prevent the deterioration of heat resistance or dry etching resistance, and also prevent the deterioration of film formability due to deteriorated developability or increased viscosity.

The dispersity (molecular weight distribution) is usually 1.0 to 3.0, and a dispersity in the range of preferably 1.0 to 2.6, more preferably 1.0 to 2.0, and particularly preferably 1.1 to 2.0 is used. As the molecular weight distribution is smaller, the resolution and the resist shape are better, the side wall of the resist pattern is smoother, and the roughness is better.

Furthermore, in the present specification, the weight-average molecular weight is a value in terms of polystyrene, determined by a gel permeation chromatography (GPC) under the following conditions.
Type of columns: TSK gel Multipore HXL-M (manufactured by TOSOH Corporation, 7.8 mmID×30.0 cm)
Developing solvent: Tetrahydrofuran (THF)
Column temperature: 40° C.
Flow rate: 1 ml/min
Amount of sample to be injected: 10 μl
Device name: HLC-8120 (manufactured by Tosoh Corporation)

The content of the resin (A) in the total solid content of the composition of the present invention is 20% by mass or more. Within the range, the content is preferably 40% by mass or more, more preferably 60% by mass or more, and still more preferably 80% by mass or more. The upper limit is not particularly limited, but is preferably 99% by mass or less, more preferably 97% by mass or less, and still more preferably 95% by mass or less.

In the present invention, the resin (A) may be used singly or in combination of a plurality of kinds thereof.

[2] Compound Which Generates Acid upon Irradiation with Actinic Rays or Radiation

The composition of the present invention contains a compound which generates an acid upon irradiation with actinic rays or radiation (hereinafter also referred to as a “photoacid generator”). The photoacid generator is not particularly limited, but is preferably a compound which generates an organic acid upon irradiation with actinic rays or radiation. In addition, the photoacid generator may also be included in the above-mentioned resin (A) and/or a resin other than the resin (A). More specifically, the photoacid generator may also be linked to the resin (A) and/or a resin other than the resin (A) via a chemical bond.

The photoacid generator may be appropriately selected from known compounds that generate an acid upon irradiation with actinic rays or radiation which are used for a photo-initiator for cationic photopolymerization, a photo-initiator for radical photopolymerization, a photo-decoloring agent for dyes, a photo-discoloring agent, a microresist or the like, and a mixture thereof, and used. Examples thereof include the compounds described in paragraphs [0039] to [0103] of JP2010-61043A, the compounds described in paragraphs [0284] to [0389] of JP2013-4820A, and the like, but the present invention is not limited thereto.

Examples of such the photoacid generator include a diazonium salt, a phosphonium salt, a sulfonium salt, an iodonium salt, imide sulfonate, oxime sulfonate, diazodisulfone, disulfone, and o-nitrobenzyl sulfonate.

Suitable examples of the photoacid generator contained in the composition of the present invention include a compound (a specific acid generator) which generates an acid upon irradiation with actinic rays or radiation represented by General Formula (3).

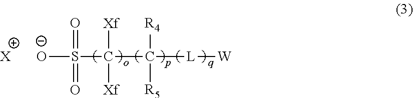

(Anion)

In General Formula (3),

Xf's each independently represent a fluorine atom or an alkyl group substituted with at least one fluorine atom.

R₄ and R₅ each independently represent a hydrogen atom, a fluorine atom, an alkyl group, or an alkyl group substituted with at least one fluorine atom, and in a case where a plurality of each of R₄'s and R₅'s are present, they may be the same as or different from each other.

L represents a divalent linking group, and in a case where a plurality of L's are present, they may be the same as or different from each other.

W represents an organic group including a cyclic structure.

o represents an integer of 1 to 3. p represents an integer of 0 to 10. q represents an integer of 0 to 10.

Xf represents a fluorine atom or an alkyl group substituted with at least one fluorine atom. The number of carbon atoms of the alkyl group is preferably 1 to 10, and more preferably 1 to 4. Further, the alkyl group substituted with at least one fluorine atom is preferably a perfluoroalkyl group.

Xf is preferably a fluorine atom or a perfluoroalkyl group having 1 to 4 carbon atoms. Xf is more preferably a fluorine atom or CF₃. It is particularly preferable that both Xf's are fluorine atoms.

R₄ and R₅ each independently represent a hydrogen atom, a fluorine atom, an alkyl group, or an alkyl group substituted with at least one fluorine atom, and in a case where a plurality of R₄'s and R₅'s are present, they may be the same as or different from each other.

The alkyl group as R₄ and R₅ may have a substituent, and preferably has 1 to 4 carbon atoms. R₄ and R₅ are each preferably a hydrogen atom.

Specific examples and suitable aspects of the alkyl group substituted with at least one fluorine atom are the same as the specific examples and suitable aspects of Xf in General Formula (3).

L represents a divalent linking group, and in a case where a plurality of L's are present, they may be the same as or different from each other.

Examples of the divalent linking group include —COO—(—C(═O)—O—), —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), or a divalent linking group formed by combination of these plurality of groups. Among these, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- is more preferable.

W represents an organic group including a cyclic structure. Above all, it is preferably a cyclic organic group.

Examples of the cyclic organic group include an alicyclic group, an aryl group, and a heterocyclic group.

The alicyclic group may be monocyclic or polycyclic, and examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among these, an alicyclic group having a bulky structure having 7 or more carbon atoms, such as a norbornyl group, a tricyclodecanyl group, a tetracyclodecanyl group, a tetracyclododecanyl group, and an adamantyl group is preferable from the viewpoints of inhibiting diffusivity into the film during post-exposure baking (PEB) process and improving Mask Error Enhancement Factor (MEEF).

The aryl group may be monocyclic or polycyclic. Examples of the aryl group include a phenyl group, a naphthyl group, a phenanthryl group, and an anthryl group. Among these, a naphthyl group showing a relatively low light absorbance at 193 nm is preferable.

The heterocyclic group may be monocyclic or polycyclic, but is polycyclic so as to further suppress acid diffusion. Further, the heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle having no aromaticity include a tetrahydropyran ring, a lactone ring, a sultone ring, and a decahydroisoquinoline ring. As a heterocycle in the heterocyclic group, a furan ring, a thiophene ring, a pyridine ring, or a decahydroisoquinoline ring is particularly preferable. Further, examples of the lactone ring and the sultone ring include the lactone structures and sultone structures exemplified in the above-mentioned resin.

The cyclic organic group may have a substituent. Examples of the substituent include, an alkyl group (which may be linear or branched, and preferably has 1 to 12 carbon atoms), a cycloalkyl group (which may be monocyclic, polycyclic, or spiro ring, and preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic ester group. Incidentally, the carbon constituting the cyclic organic group (the carbon contributing to ring formation) may be carbonyl carbon.

In the anion of General Formula (3), preferred examples of the combination of the partial structure other than W include SO₃⁻—CF₂—CH₂—OCO—, SO₃⁻—CF₂—CHF—CH₂—OCO—, SO₃⁻—CF₂—COO—, SO₃⁻—CF₂—CF₂—CH₂—, and SO₃⁻—CF₂—CH(CF₃)—OCO—.

o represents an integer of 1 to 3. p represents an integer of 0 to 10. q represents an integer of 0 to 10.

In one aspect, it is preferable that in General Formula (3), o is an integer of 1 to 3, p is an integer of 1 to 10, and q is 0. Xf is preferably a fluorine atom, R₄ and R₅ are preferably both hydrogen atoms, and W is preferably a polycyclic hydrocarbon group. o is more preferably 1 or 2, and still more preferably 1. p is more preferably an integer of 1 to 3, still more preferably 1 or 2, and particularly preferably 1. W is more preferably a polycyclic cycloalkyl group, and still more preferably an adamantyl group or a diadamantyl group.

(Cation)

In General Formula (3), X⁺ represents a cation.

X⁺ is not particularly limited as long as it is a cation, but suitable aspects thereof include cations (moieties other than Z⁻) in General Formula (ZI), (ZII), or (ZIII) which will be described later.

(Suitable Aspects)

Suitable aspects of the specific acid generator include a compound represented by General Formula (ZI), (ZII), or (ZIII).

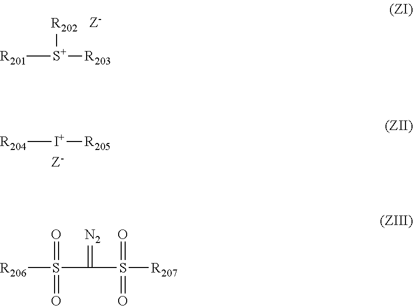

In General Formula (ZI),

R₂₀₁, R₂₀₂, and R₂₀₃ each independently represent an organic group.

The number of carbon atoms of the organic group as R₂₀₁, R₂₀₂, and R²⁰³ is generally 1 to 30, and preferably 1 to 20.

Furthermore, two members out of R₂₀₁ to R₂₀₃ may be bonded to each other to form a ring structure, and the ring includes an oxygen atom, a sulfur atom, an ester bond, an amide bond, or a carbonyl group, and examples of the group formed by the bonding of two members out of 8201 to 8203 include an alkylene group (for example, a butylene group and a pentylene group).

Z⁻ represents an anion in General Formula (3), and specifically represents the following anion.

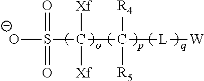

Examples of the organic group represented by R₂₀₁, R₂₀₂, and R₂₀₃ include groups corresponding to the compounds (ZI-1), (ZI-2), (ZI-3), and (ZI-4), which will be described later.

Incidentally, it may be a compound having a plurality of structures represented by General Formula (ZI). For example, it may be a compound having a structure in which at least one of R₂₀₁, . . . , or R²⁰³ in the compound represented by General Formula (ZI) is bonded to at least one of R₂₀₁, . . . , or R₂₀₃ of another compound represented by General Formula (ZI) through a single bond or a linking group.

More preferred examples of the component (ZI) include the compounds (ZI-1), (ZI-2), (ZI-3), and (ZI-4) described below.

First, the compound (ZI-1) will be described.

The compound (ZI-1) is an arylsulfonium compound, that is, a compound having arylsulfonium as a cation, in which at least one of R₂₀₁, . . . , or R₂₀₃ in General Formula (ZI) is an aryl group.

In the arylsulfonium compound, all of R₂₀₁ to R²⁰³ may be an aryl group, or a part of R₂₀₁ to R₂₀₃ may be an aryl group, with the remainder being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

The aryl group in the arylsulfonium compound is preferably a phenyl group or a naphthyl group, and more preferably a phenyl group. The aryl group may be an aryl group having a heterocyclic structure containing an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium compound has two or more aryl groups, these two or more aryl groups may be the same as or different from each other.

The alkyl group or the cycloalkyl group which may be contained, if desired, in the arylsulfonium compound, is preferably a linear or branched alkyl group having 1 to 15 carbon atoms or a cycloalkyl group having 3 to 15 carbon atoms, for example, a methyl group, an ethyl group, a propyl group, an n-butyl group, a sec-butyl group, a t-butyl group, a cyclopropyl group, a cyclobutyl group, and a cyclohexyl group.

The aryl group, the alkyl group, and the cycloalkyl group of R₂₀₁ to R₂₀₃ may have, an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, or a phenylthio group as the substituent.

Next, the compound (ZI-2) will be described.

The compound (ZI-2) is a compound in which R₂₀₁ to R₂₀₃ in Formula (ZI) each independently represent an organic group not having an aromatic ring. Here, the aromatic ring also encompasses an aromatic ring containing a heteroatom.

The organic group not containing an aromatic ring as R₂₀₁ to R₂₀₃ has generally 1 to 30 carbon atoms, and preferably 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and particularly preferably a linear or branched 2-oxoalkyl group.

Preferred examples of the alkyl group and the cycloalkyl group of R₂₀₁ to R₂₀₃ include linear or branched alkyl groups having 1 to 10 carbon atoms (for example, a methyl group, an ethyl group, a propyl group, a butyl group, and a pentyl group), and cycloalkyl groups having 3 to 10 carbon atoms (a cyclopentyl group, a cyclohexyl group, and a norbornyl group).

R₂₀₁ to R₂₀₃ may further be substituted with a halogen atom, an alkoxy group (for example, an alkoxy group having 1 to 5 carbon atoms), a hydroxyl group, a cyano group, or a nitro group.

Next, the compound (ZI-3) will be described.

The compound (ZI-3) is a compound represented by General Formula (ZI-3), which is a compound having a phenacylsulfonium salt structure.

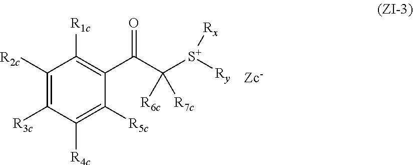

In General Formula (ZI-3),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Among any two or more members out of R_{1c} to R_{5c}, R_{5c} and R_{6c}, R_{6c} and R_{7c}, R_{5c} and Rₓ, and Rₓ and R_{y} each may be bonded to each other to form a ring structure, and the ring structure may contain an oxygen atom, a sulfur atom, a ketone group, an ester bond, or an amide bond.

Examples of the ring structure include an aromatic or non-aromatic hydrocarbon ring, an aromatic or non-aromatic heterocycle, or a polycyclic fused ring including two or more of these rings. Examples of the ring structure include 3- to 10-membered rings, and the ring structures are preferably 4- to 8-membered ring, and more preferably 5- or 6-membered rings.

Examples of groups formed by the bonding of any two or more of R_{1c} to R_{5c}, R_{6c} and R_{7c}, and Rₓ and R_{y} include a butylene group and a pentylene group.

As groups formed by the bonding of R_{5c} and R_{6c}, and R_{5c} and Rₓ, a single bond or alkylene group is preferable, and examples of the alkylene group include a methylene group and an ethylene group.

Zc⁻ represents an anion in General Formula (3), and specifically, is the same as described above.

Specific examples of the alkoxy group in the alkoxycarbonyl group as R_{1c} to R_{5c} are the same as the specific examples of the alkoxy group as R_{1c} to R_{5c}.

Specific examples of the alkyl group in the alkylcarbonyloxy group and the alkylthio group as R_{1c} to R_{5c} are the same as the specific examples of the alkyl group as R_{1c} to R_{5c}.

Specific examples of the cycloalkyl group in the cycloalkylcarbonyloxy group as R_{1c} to R_{5c} are the same as the specific examples of the cycloalkyl group as R_{1c} to R_{5c}.

Specific examples of the aryl group in the aryloxy group and the arylthio group as R_{1c} to R_{5c} are the same as the specific examples of the aryl group as R_{1c} to R_{5c}.

Examples of the cation in the compound (ZI-2) or (ZI-3) in the present invention include the cations described under and after paragraph [0036] of the specification of US2012/0076996A.

Next, the compound (ZI-4) will be described.

The compound (ZI-4) is represented by General Formula (ZI-4).

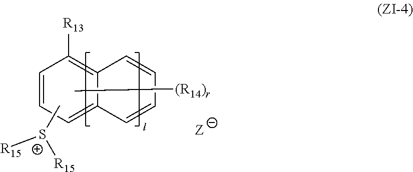

In General Formula (ZI-4),

R₁₃ represents a hydrogen atom, a fluorine atom, a hydroxyl group, an alkyl group, a cycloalkyl group, an alkoxy group, an alkoxycarbonyl group, or a group having a cycloalkyl group. These groups may have a substituent.

In a case where a plurality of R₁₄'s are present numbers, they each independently represent a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group. These groups may have a substituent.

R₁₅'s each independently represent an alkyl group, a cycloalkyl group, or a naphthyl group. These groups may have a substituent. Two R₁₅'s may be bonded to each other to form a ring. When two R₁₅'s are bonded to each other to form a ring, the ring skeleton include a heteroatom such as an oxygen atom and a nitrogen atom. In one aspect, it is preferable that two R₁₅'s are alkylene groups, and are bonded to each other to form a ring structure.

l represents an integer of 0 to 2.

r represents an integer of 0 to 8.

Z⁻ represents an anion in General Formula (3), and specifically, is as described above.

In General Formula (ZI-4), as the alkyl group of R₁₃, R₁₄, and R₁₅, an alkyl which is linear or branched and has 1 to 10 carbon atoms is preferable, and preferred examples thereof include a methyl group, an ethyl group, an n-butyl group, and a t-butyl group.

Examples of the cation of the compound represented by General Formula (ZI-4) in the present invention include the cations described in paragraphs [0121], [0123], and [0124] of JP2010-256842A, paragraphs [0127], [0129], and [0130] of JP2011-76056A, and the like.

Next, General Formulae (ZII) and (ZIII) will be described.

In General Formulae (ZII) and (ZIII), R₂₀₄ to R₂₀₇ each independently represent an aryl group, an alkyl group, or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group having a heterocyclic structure containing an oxygen atom, a nitrogen atom, a sulfur atom, or the like. Examples of the skeleton of the aryl group having a heterocyclic structure include pyrrole, furan, thiophene, indole, benzofuran, and benzothiophene.

Preferred examples of the alkyl group and the cycloalkyl group in R₂₀₄ to R₂₀₇ include linear or branched alkyl groups having 1 to 10 carbon atoms (for example, a methyl group, an ethyl group, a propyl group, a butyl group, and a pentyl group), and cycloalkyl groups having 3 to 10 carbon atoms (a cyclopentyl group, a cyclohexyl group, and a norbornyl group).

The aryl group, the alkyl group, or the cycloalkyl group of R₂₀₄ to R₂₀₇ may have a substituent. Examples of the substituent which the aryl group, the alkyl group, or the cycloalkyl group of R₂₀₄ to R₂₀₇ may have include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

Z⁻ represents an anion in General Formula (3), and specifically, is as described above.

The photoacid generator (including a specific acid generator, which applies hereinafter) may be in a form of a low-molecular-weight compound or in a form introduced into a part of a polymer. Further, a combination of the form of a low-molecular-weight compound and the form introduced into a part of a polymer may also be used.

In a case where the photoacid generator is in the form of a low-molecular-weight compound, the molecular weight is preferably 580 or more, more preferably 600 or more, still more preferably 620 or more, and particularly preferably 640 or more. The upper limit is not particularly limited, but is preferably 3,000 or less, more preferably 2,000 or less, and still more preferably 1,000 or less.

In a case where the photoacid generator is in the form introduced into a part of a polymer, it may be introduced into a part of the resin as described above or into a resin other than the resin.

The photoacid generator can be synthesized by a known method, and can be synthesized by, for example, the method described in JP2007-161707A.

The photoacid generators may be used singly or in combination of two or more kinds thereof.

The content of the photoacid generator (a total sum of contents in a case where a plurality of the photoacid generators are present) in the composition is preferably 0.1% to 30% by mass, more preferably 0.5% to 25% by mass, still more preferably 3% to 20% by mass, and particularly preferably 3% to 15% by mass, with respect to the total solid content of the composition.

In a case where the composition includes the compound represented by General Formula (ZI-3) or (ZI-4) as the photoacid generator, the content of the photoacid generator (a total sum of contents in a case where the photoacid generators are present in plural kinds) is preferably 5% to 35% by mass, more preferably 8% to 30% by mass, still more preferably 9% to 30% by mass, and particularly preferably 9% to 25% by mass, with respect to the total solid content of the composition.

[3] Crosslinking Agent

In a suitable embodiment, the resist composition of the present invention contains a crosslinking agent. Here, known crosslinking agents can be effectively used.

The crosslinking agent may be in a form of a low-molecular-weight compound or in a form introduced into a part of a polymer. Further, a combination of the form of a low-molecular-weight compound and the form introduced into a part of a polymer may also be used.

In a case where the crosslinking agent is in the form of a low-molecular-weight compound, the molecular weight is preferably 3,000 or less, more preferably 2,000 or less, and still more preferably 1,000 or less.

In a case where the crosslinking agent is in the form introduced into a part of a polymer, it may be introduced into a part of the resin (A) as described above or into a resin other than the resin (A).

The crosslinking agent is typically a compound having a crosslinkable group which can crosslink the resin (A), and examples of the crosslinkable group include a hydroxymethyl group, an alkoxymethyl group, a vinyl ether group, and an epoxy group. The crosslinking agent preferably has two or more of the crosslinkable groups.

The crosslinking agent is preferably a crosslinking agent of a melamine-based compound, a urea-based compound, an alkylene urea-based compound, or a glycoluril-based compound.

Preferred examples of the crosslinking agent include a compound having an N-hydroxymethyl group, an N-alkoxymethyl group, or an N-acyloxymethyl group.

As the compound having an N-hydroxymethyl group, an N-alkoxymethyl group, or an N-acyloxymethyl group, a compound having 2 or more (preferably 2 to 8) partial structures represented by General formula (CLNM-1) is preferable.

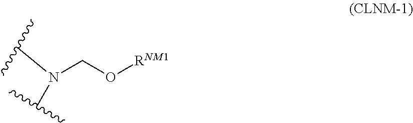

In General Formula (CLNM-1), R^{NM1} represents a hydrogen atom, an alkyl group, a cycloalkyl group, or an oxoalkyl group. The alkyl group of R^{NM1} in General Formula (CLNM-1) is preferably a linear or branched alkyl group having 1 to 6 carbon atoms, and the cycloalkyl group of R^{NM1} is preferably a cycloalkyl group having 5 to 6 carbon atoms. The oxoalkyl group of R^{NM1} is preferably an oxoalkyl group having 3 to 6 carbon atoms, and examples thereof include a β-oxopropyl group, a β-oxobutyl group, a β-oxopentyl group, and a β-oxohexyl group.

More preferred aspects of the compound having two or more partial structures represented by General Formula (CLNM-1) include a urea-based crosslinking agent represented by General Formula (CLNM-2), an alkylene urea-based crosslinking agent represented by General Formula (CLNM-3), a glycoluril-based crosslinking agent represented by General Formula (CLNM-4), and a melamine-based crosslinking agent represented by General Formula (CLNM-5).

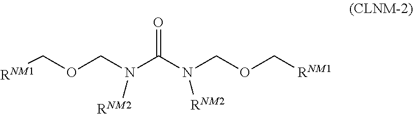

In General Formula (CLNM-2),

R^{NM1}'s each independently have the same definitions as R^{NM1} in General Formula (CLNM-1).

R^{NM2}'s each independently represent a hydrogen atom, an alkyl group (preferably having 1 to 6 carbon atoms), or a cycloalkyl group (preferably having 5 or 6 carbon atoms).

Specific examples of the urea-based crosslinking agent represented by General Formula (CLNM-2) include N,N-di(methoxymethyl)urea, N,N-di(ethoxymethyl)urea, N,N-di(propoxymethyl)urea, N,N-di(isopropoxymethyl)urea, N,N-di(butoxymethyl)urea, N,N-di(t-butoxymethyl)urea, N,N-di(cyclohexyloxymethyl)urea, N,N-di(cyclopentyloxymethyl)urea, N,N-di(adamantyloxymethyl)urea, and N,N-di(norbornyloxymethyl)urea.

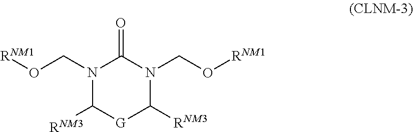

In General Formula (CLNM-3),

R^{NM1}'s each independently have the same definitions as R^{NM1} in General Formula (CLNM-1).

R^{NM3}'s each independently represent a hydrogen atom, a hydroxyl group, a linear or branched alkyl group (preferably having 1 to 6 carbon atoms), a cycloalkyl group (preferably having 5 or 6 carbon atoms), an oxoalkyl group (preferably having 3 to 6 carbon atoms), an alkoxy group (preferably having 1 to 6 carbon atoms), or an oxoalkoxy group (preferably having 1 to 6 carbon atoms).

G represents a single bond, an oxygen atom, a sulfur atom, an alkylene group (preferably having 1 to 3 carbon atoms), or a carbonyl group. More specific examples thereof include a methylene group, an ethylene group, a propylene group, a 1-methylethylene group, a hydroxyl methylene group, and a cyanomethylene group.

Specific examples of the alkylene urea-based crosslinking agent represented by General Formula (CLNM-3) include N,N-di(methoxymethyl)-4,5-di(methoxymethyl)ethylene urea, N,N-di(ethoxymethyl)-4,5-di(ethoxymethyl)ethylene urea, N,N-di(propoxymethyl)-4,5-di(propoxymethyl)ethylene urea, N,N-di(isopropoxymethyl)-4,5-di(isopropoxymethyl)ethylene urea, N,N-di(butoxymethyl)-4,5-di(butoxymethyl)ethylene urea, N,N-di(t-butoxymethyl)-4,5-di(t-butoxymethyl)ethylene urea, N,N-di(cyclohexyloxymethyl)-4,5-di(cyclohexyloxymethyl)ethylene urea, N,N-di(cyclopentyloxymethyl)-4,5-di(cyclopentyloxymethyl)ethylene urea, N,N-di(adamantyloxymethyl)-4,5-di(adamantyloxymethyl)ethylene urea, and N,N-di(norbornyloxymethyl)-4,5-di(norbornyloxymethyl)ethylene urea.

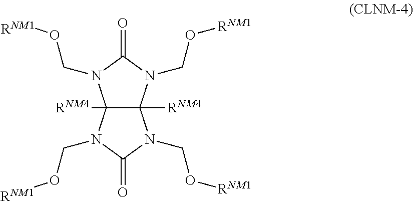

In General Formula (CLNM-4),

R^{NM1}'s each independently have the same definition as R^{NM1} in General Formula (CLNM-1).

R^{NM4} each independently represent a hydrogen atom, a hydroxyl group, an alkyl group, a cycloalkyl group, or an alkoxy group.

More specific examples of the alkyl group (preferably having 1 to 6 carbon atoms), the cycloalkyl group (preferably having 5 or 6 carbon atoms), and the alkoxy group (preferably having 1 to 6 carbon atoms) of R^{NM4} include a methyl group, an ethyl group, a butyl group, a cyclopentyl group, a cyclohexyl group, a methoxy group, an ethoxy group, and a butoxy group.

Specific examples of the glycoluril-based crosslinking agent represented by General Formula (CLNM-4) include N,N,N,N-tetra(methoxymethyl)glycoluril, N,N,N,N-tetra(ethoxymethyl)glycoluril, N,N,N,N-tetra(propoxymethyl)glycoluril, N,N,N,N-tetra(isopropoxymethyl)glycoluril, N,N,N,N-tetra(butoxymethyl)glycoluril, N,N,N,N-tetra(t-butoxymethyl)glycoluril, N,N,N,N-tetra(cyclohexyloxymethyl)glycoluril, N,N,N,N-tetra(cyclopentyloxymethyl)glycoluril, N,N,N,N-tetra(adamantyloxymethyl)glycoluril, and N,N,N,N-tetra(norbornyloxymethyl)glycoluril.

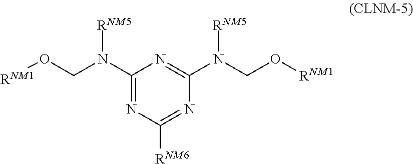

In General Formula (CLNM-5),

R^{NM1}'s each independently have the same definition as R^{NM1} in General Formula (CLNM-1).

R^{NM5}'s each independently represent a hydrogen atom, an alkyl group, a cycloalkyl group, an aryl group, or an atomic group represented by General Formula (CLNM-5′).

R^{NM6} represents a hydrogen atom, an alkyl group, a cycloalkyl group, an aryl group, or an atomic group represented by General Formula (CLNM-5″).

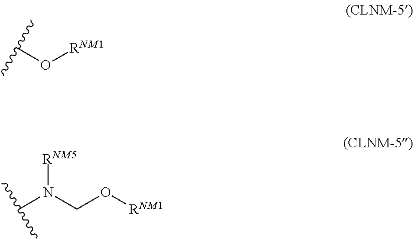

In General Formula (CLNM-5′),

R^{NM1} has the same definition as R^{NM1} in General Formula (CLNM-1).

In General Formula (CLNM-5″),

R^{NM1} has the same definition as R^{NM1} in General Formula (CLNM-1), and R^{NM5} has the same definition as R^{NM5} in General Formula (CLNM-5).

More specific examples of the alkyl group (preferably having 1 to 6 carbon atoms), the cycloalkyl group (preferably having 5 or 6 carbon atoms), and the aryl group (preferably having 6 to 10 carbon atoms) of each of R^{NM5} and R^{NM6} include a methyl group, an ethyl group, a propyl group, an isopropyl group, a butyl group, an isobutyl group, a t-butyl group, a pentyl group, a cyclopentyl group, a hexyl group, a cyclohexyl group, a phenyl group, and a naphthyl group.

Examples of the melamine-based crosslinking agent represented by General Formula (CLNM-5) include N,N,N,N,N,N-hexa(methoxymethyl)melamine, N,N,N,N,N,N-hexa(ethoxymethyl)melamine, N,N,N,N,N,N-hexa(propoxymethyl)melamine, N,N,N,N,N,N-hexa(isopropoxymethyl)melamine, N,N,N,N,N,N-hexa(butoxymethyl)melamine, N,N,N,N,N,N-hexa(t-butoxymethyl)melamine, N,N,N,N,N,N-hexa(cyclohexyloxymethyl)melamine, N,N,N,N,N,N-hexa(cyclopentyloxymethyl)melamine, N,N,N,N,N,N-hexa(adamantyloxymethyl)melamine, N,N,N,N,N,N-hexa(norbornyloxymethyl)melamine, N,N,N,N,N,N-hexa(methoxymethyl)acetoguanamine, N,N,N,N,N,N-hexa(ethoxymethyl)acetoguanamine, N,N,N,N,N,N-hexa(propoxymethyl)acetoguanamine, N,N,N,N,N,N-hexa(isopropoxymethyl)acetoguanamine, N,N,N,N,N,N-hexa(butoxymethyl)acetoguanamine, N,N,N,N,N,N-hexa(t-butoxymethyl)acetoguanamine, N,N,N,N,N,N-hexa(methoxymethyl)benzoguanamine, N,N,N,N,N,N-hexa(ethoxymethyl)benzoguanamine, N,N,N,N,N,N-hexa(propoxymethyl)benzoguanamine, N,N,N,N,N,N-hexa(isopropoxymethyl)benzoguanamine, N,N,N,N,N,N-hexa(butoxymethyl)benzoguanamine, and N,N,N,N,N,N-hexa(t-butoxymethyl)benzoguanamine.

The group represented by each of R^{NM1} to R^{NM6} in General Formulae (CLNM-1) to (CLNM-5) may further have a substituent. Examples of the substituent which R^{NM1} to R^{NM6} may have include a halogen atom, a hydroxyl group, a nitro group, a cyano group, a carboxyl group, a cycloalkyl group (preferably having 3 to 20 carbon atoms), an aryl group (preferably having 6 to 14 carbon atoms), an alkoxy group (preferably having 1 to 20 carbon atoms), a cycloalkoxy group (preferably having 4 to 20 carbon atoms), an acyl group (preferably having 2 to 20 carbon atoms), and an acyloxy group (preferably having 2 to 20 carbon atoms).

The crosslinking agent may be a phenol compound having a benzene ring in the molecule thereof.

As the phenol compound, preferred is a phenol derivative having a molecular weight of 1,200 or less, containing from 3 to 5 benzene rings in the molecule and further having 2 or more hydroxymethyl groups or alkoxymethyl groups in total, in which the hydroxymethyl groups or alkoxymethyl groups are bonded in a concentrated manner to at least any one benzene ring or distributed among the benzene rings. By using such a phenol derivative, the effects of the present invention can be more remarkably exhibited. The alkoxymethyl group bonded to the benzene ring is preferably an alkoxymethyl group having 6 or less carbon atoms. Specifically, a methoxymethyl group, an ethoxymethyl group, an n-propoxymethyl group, an i-propoxymethyl group, an n-butoxymethyl group, an i-butoxymethyl group, a sec-butoxymethyl group, or a t-butoxymethyl group is preferable. An alkoxy-substituted alkoxy group such as a 2-methoxyethoxy group and a 2-methoxy-1-propyl group is also preferable.

As the phenol compound, a phenol compound having two or more benzene rings in the molecule is more preferable, and a phenol compound not containing a nitrogen atom is preferable.

Specifically, a phenol compound having 2 to 8 crosslinkable groups capable of crosslinking the resin (A), in one molecule, is preferable, with the phenol compound having 3 to 6 crosslinkable groups being more preferable.

Among these phenol derivatives, particularly preferable compounds are shown below. In the formulae, L¹ to L⁸ each represent a crosslinkable group, and may be the same as or different from each other, and the crosslinkable group is preferably a hydroxymethyl group, a methoxymethyl group, or an ethoxymethyl group.

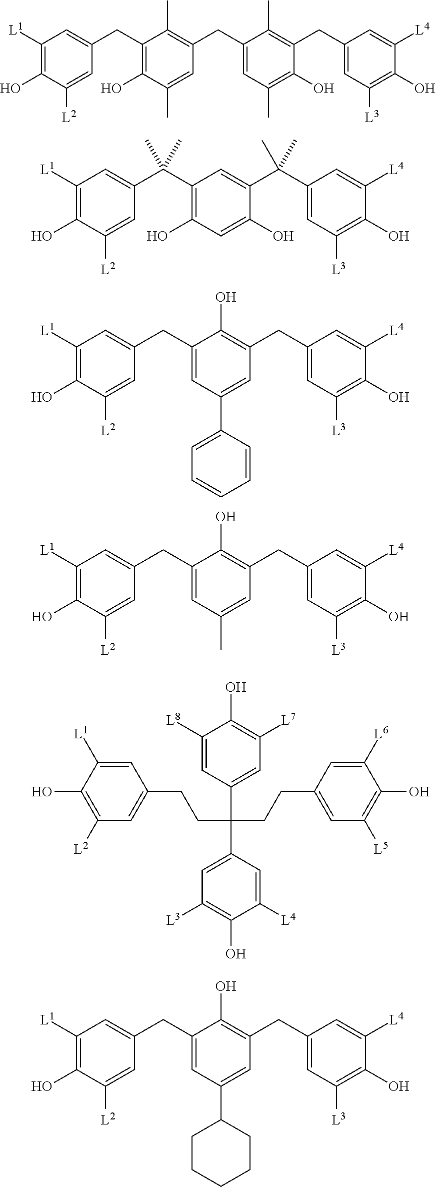

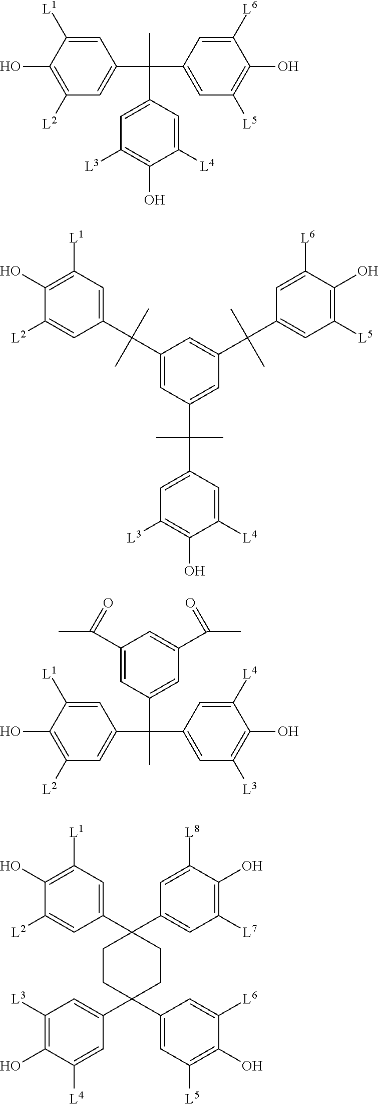

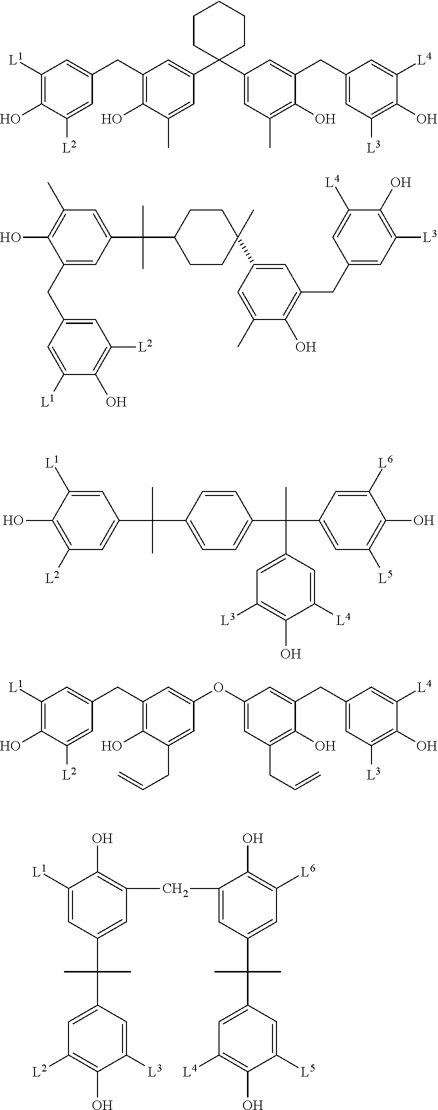

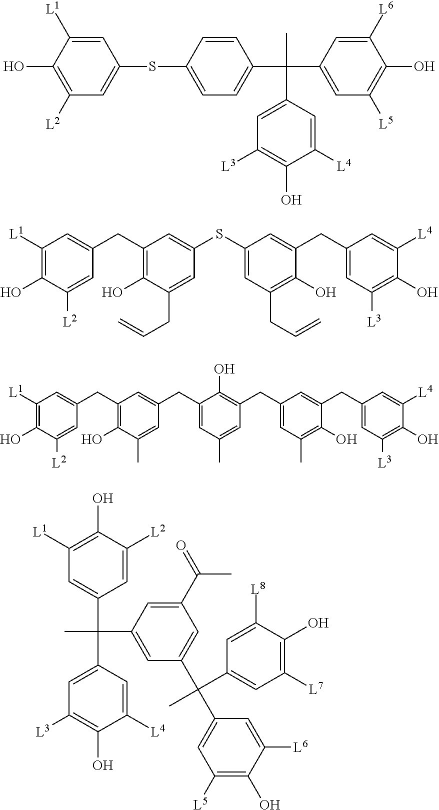

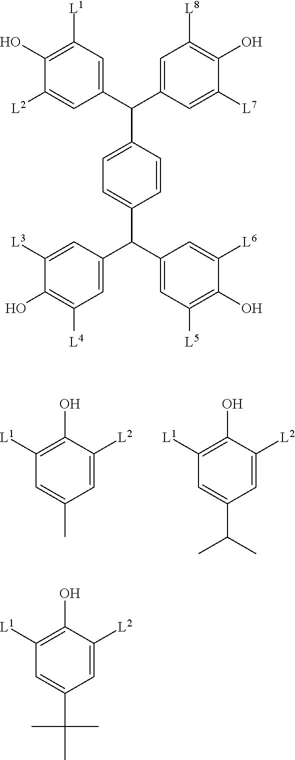

As the phenol compound, commercially available products can also be used, or the phenol compound can also be synthesized by a known method. For example, a phenol derivative having a hydroxymethyl group can be obtained by reacting a phenol compound (a compound of the above formula in which L¹ to L⁸ are each a hydrogen atom) which does not have a corresponding hydroxymethyl group with a formaldehyde in the presence of a base catalyst. At this time, in order to prevent resinification or gelation, the reaction is preferably carried out at a reaction temperature of 60° C. or lower. Specifically, synthesis can be carried out by the methods described in JP1994-282067A (JP-H06-282067A), JP1995-64285A (JP-H07-64285A), and the like.

The phenol derivative having an alkoxymethyl group can be obtained by reacting a phenol derivative having a corresponding hydroxymethyl group with an alcohol in the presence of an acid catalyst. In such a case, in order to prevent resinification or gelation, the reaction is preferably carried out at a reaction temperature of 100° C. or lower. Specifically, it is possible for the compounds to be synthesized with the methods which are described in EP632003A1 and the like. The phenol derivative having a hydroxymethyl group or an alkoxymethyl group, synthesized in this manner is preferable from the viewpoint of stability during storage, and, the phenol derivative having an alkoxymethyl group is particularly preferable from the viewpoint of stability during storage. The phenol derivatives which have two or more combined hydroxymethyl groups or alkoxymethyl groups in which either are concentrated in the benzene rings or distributably bonded thereto may be used singly or in combination of two or more kinds thereof.

The crosslinking agent may be an epoxy compound having an epoxy group within the molecule thereof.

Examples of the epoxy compound include a compound represented by General Formula (EP2).

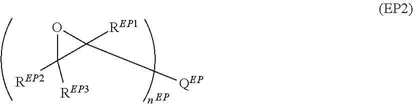

In Formula (EP2),

R^{EP1} to R^{EP3} each independently represent a hydrogen atom, a halogen atom, an alkyl group, or a cycloalkyl group, and the alkyl group and the cycloalkyl group may have a substituent. Further, R^{EP1} and R^{EP2}, or R^{EP2} and R^{EP3} may be bonded to each other to form a ring structure.

Examples of the substituent which may be contained in the alkyl group and cycloalkyl group include a hydroxyl group, a cyano group, an alkoxy group, an alkylcarbonyl group, an alkoxycarbonyl group, an alkylcarbonyloxy group, an alkylthio group, an alkylsulfone group, an alkylsulfonyl group, an alkylamino group, and an alkylamido group.

Q^{EP} represents a single bond or an n^{EP}-valent organic group. R^{EP1} to R^{EP3} may be bonded not only to each other but also to Q^{EP} to form a ring structure.

n^{EP} represents an integer of 2 or more, and is preferably 2 to 10, and more preferably 2 to 6, provided that in a case where Q^{EP} is a single bond, n^{EP} is 2.

In the case where Q^{EP} is an n^{EP}-valent organic group, the organic group is preferably, for example, a chain or cyclic saturated hydrocarbon structure (preferably having 2 to 20 carbon atoms), an aromatic ring structure (preferably having 6 to 30 carbon atoms), or a group having a structure where these are linked to a structure such as an ether, an ester, an amide, and a sulfonamide.

Specific examples of the compound having an epoxy structure are shown below, but the present invention is not limited thereto.

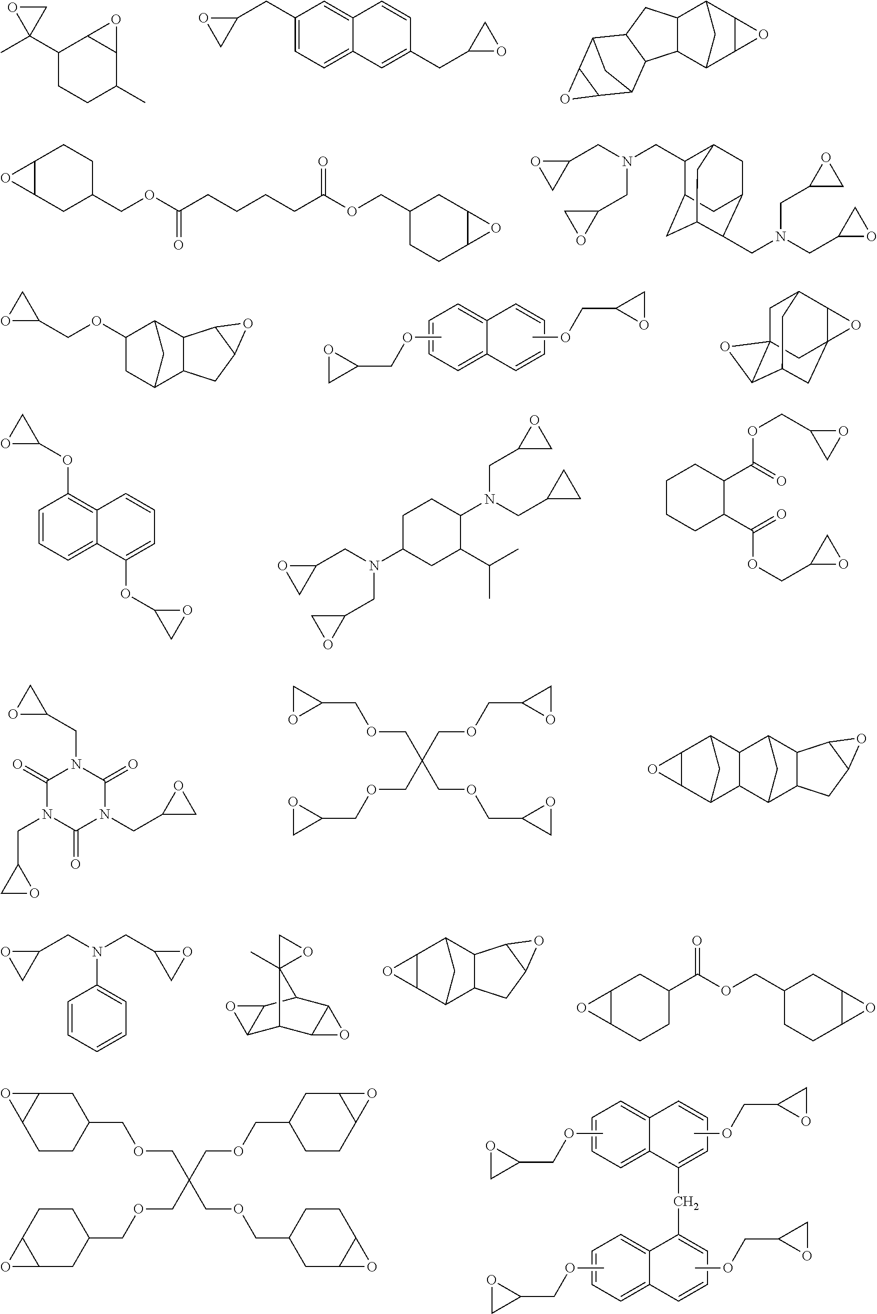

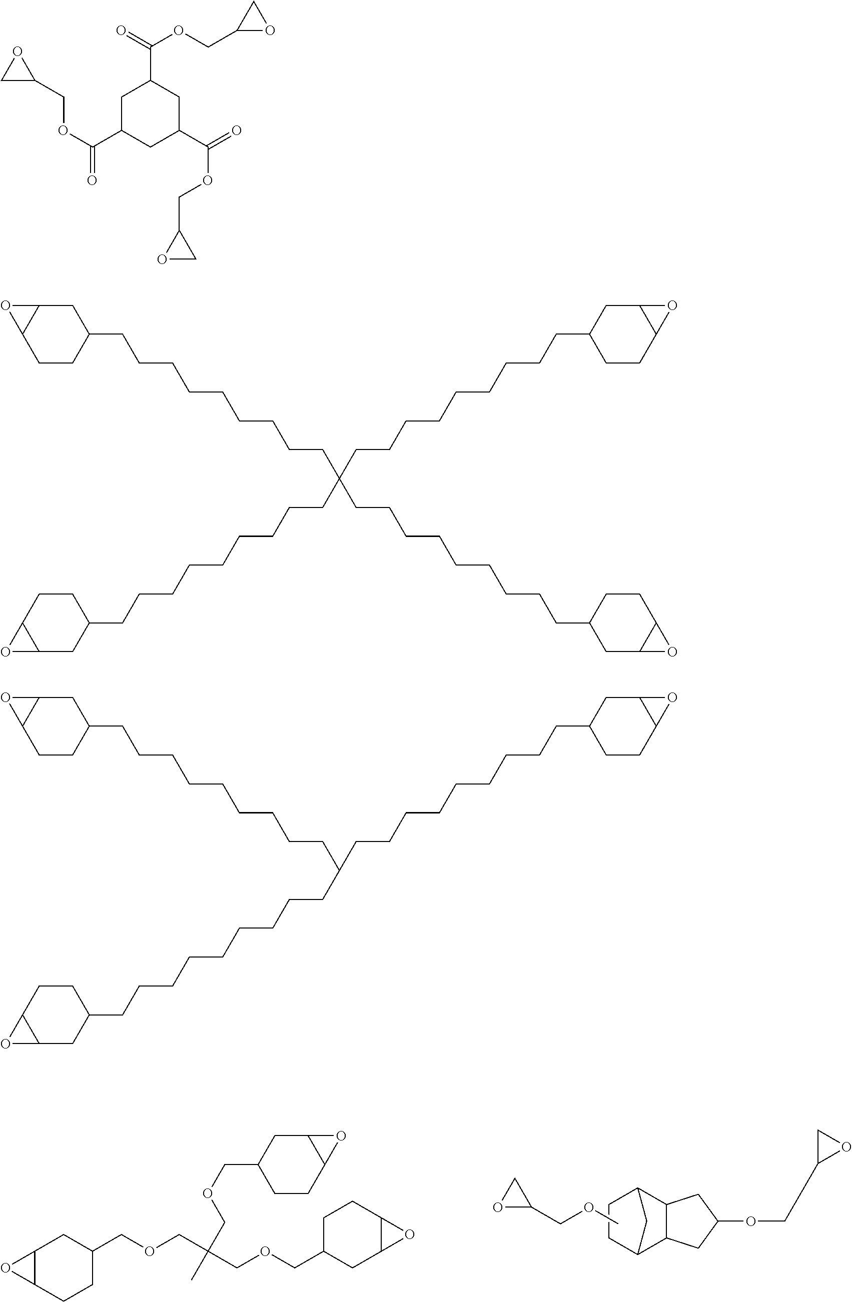

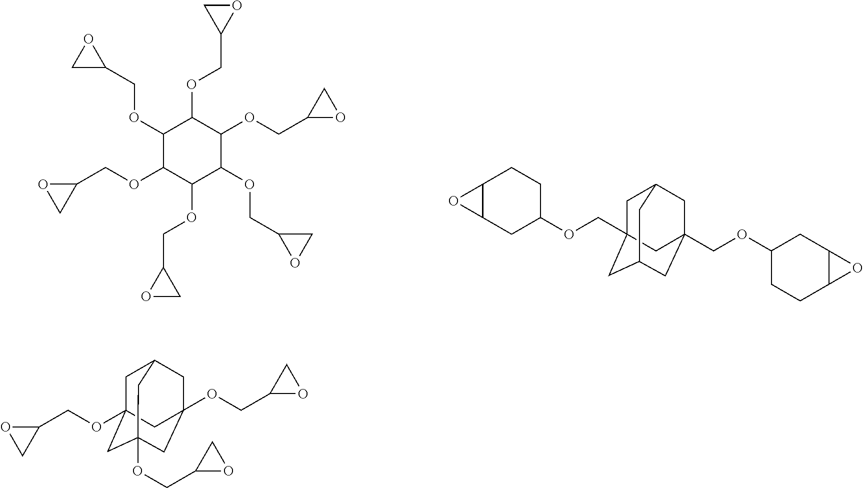 [SMILES: C1OC1COC1C(OCC2CO2)C(OCC2CO2)C(OCC2CO2)C(OCC2CO2)C1OCC1CO1 ; C1C2CC3(COC4CCC5OC5C4)CC1CC(COC1CCC4OC4C1)(C2)C3 ; C1OC1COC12CC3CC(OCC4CO4)(C1)CC(OCC1CO1)(C3)C2]

In the present invention, the crosslinking agent may be used singly or in combination of two or more kinds thereof.

The content of the crosslinking agent in the resist composition is preferably 3% to 20% by mass, more preferably 4% to 15% by mass, and still more preferably 5% to 10% by mass, with respect to the total solid content of the resist composition.

[4] Hydrophobic Resin

The resist composition of the present invention may contain a hydrophobic resin (hereinafter also referred to as a “hydrophobic resin (D)” or simply a “resin (D)”). Further, the hydrophobic resin (D) is preferably different from the resin (A).

Although the hydrophobic resin (D) is preferably designed to be unevenly distributed on an interface as described above, it does not necessarily have to have a hydrophilic group in its molecule as different from the surfactant, and does not need to contribute to uniform mixing of polar/nonpolar materials.

Examples of the effect of addition of the hydrophobic resin include control of the static/dynamic contact angle of the resist film surface with respect to water, improvement of the immersion liquid tracking properties, and suppression of out gas.

The hydrophobic resin (D) preferably has at least one of a “fluorine atom”, a “silicon atom”, or a “CH₃ partial structure which is contained in a side chain moiety of a resin” from the viewpoint of uneven distribution on the film surface layer, and more preferably has two or more kinds.

In a case where hydrophobic resin (D) includes a fluorine atom and/or a silicon atom, the fluorine atom and/or the silicon atom in the hydrophobic resin (D) may be contained in the main chain or the side chain of the resin.

In a case where the hydrophobic resin (D) contains a fluorine atom, the resin is preferably a resin which contains an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom and the aryl group having a fluorine atom are a cycloalkyl group in which one hydrogen atom is substituted with a fluorine atom, and an aryl group having a fluorine atom, respectively, and may further have a substituent other than a fluorine atom.

Preferred examples of the alkyl group having a fluorine atom, the cycloalkyl group having a fluorine atom, and the aryl group having a fluorine atom include groups represented by General Formulae (F2) to (F4), but the present invention is not limited thereto.

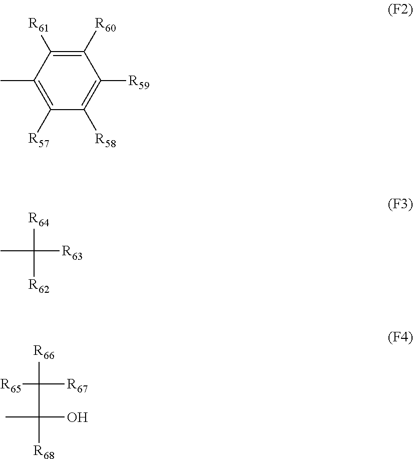

In General Formulae (F2) to (F4),

R₅₇ to R₆₈ each independently represent a hydrogen atom, a fluorine atom, or an (linear or branched) alkyl group, a provided that at least one of R₅₇, . . . , or R₆₁, at least one of R₆₂, . . . , or R₆₄, and at least one of R₆₅, . . . , or R₆₈ each independently represent a fluorine atom or an alkyl group (preferably having 1 to 4 carbon atoms) in which at least one hydrogen atom is substituted with a fluorine atom.

It is preferable that all of R₅₇ to R₆₁, and R₆₅ to R₆₇ are fluorine atoms. R₆₂, R₆₃, and R₆₈ are each preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be linked to each other to form a ring.

The hydrophobic resin (D) may contain a silicon atom. It is preferably a resin having, as the partial structure having a silicon atom, an alkylsilyl structure (preferably a trialkylsilyl group) or a cyclic siloxane structure.

Examples of the repeating unit having a fluorine atom or a silicon atom include those exemplified in [0519] of US2012/0251948A1.

Moreover, it is also preferable that the hydrophobic resin (D) contains a CH₃ partial structure in the side chain moiety as described above.

Here, the CH₃ partial structure (hereinafter also simply referred to as a “side chain CH₃ partial structure”) contained in the side chain moiety in the hydrophobic resin (D) includes a side chain CH₃ partial structure contained in an ethyl group, a propyl group, and the like.

On the other hand, a methyl group bonded directly to the main chain of the hydrophobic resin (D) (for example, an α-methyl group in the repeating unit having a methacrylic acid structure) makes only a small contribution of uneven distribution to the surface of the hydrophobic resin (D) due to the effect of the main chain, and it is therefore not included in the side chain CH₃ partial structure in the present invention.

More specifically, in a case where the hydrophobic resin (D) contains a repeating unit derived from a monomer having a polymerizable moiety with a carbon-carbon double bond, such as a repeating unit represented by General Formula (M), and in addition, R₁₁ to R₁₄ are CH₃ “themselves”, such CH₃ is not included in the CH₃ partial structure contained in the side chain moiety in the present invention.

On the other hand, a side chain CH₃ partial structure which is present via a certain atom from a C—C main chain corresponds to the side chain CH₃ partial structure in the present invention. For example, in a case where R₁₁ is an ethyl group (CH₂CH₃), the hydrophobic resin has “one” side chain CH₃ partial structure in the present invention.

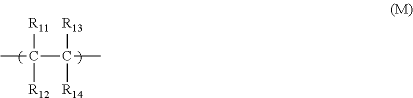

In General Formula (M),

R₁₁ to R₁₄ each independently represent a side chain moiety.

Examples of R₁₁ to R₁₄ at the side chain moiety include a hydrogen atom and a monovalent organic group.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, each of which may further have a substituent.

The hydrophobic resin (D) is preferably a resin including a repeating unit having the CH₃ partial structure in the side chain moiety thereof. Further, the hydrophobic resin more preferably has, as such a repeating unit, at least one repeating unit (x) selected from a repeating unit represented by General Formula (II) or a repeating unit represented by General Formula (III).

Hereinafter, the repeating unit represented by General Formula (II) will be described in detail.

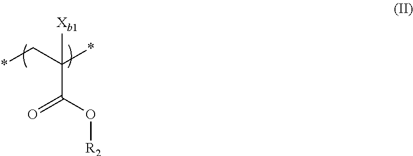

In General Formula (II), X_{b1} represents a hydrogen atom, an alkyl group, a cyano group, or a halogen atom, and R₂ represents an organic group which has one or more CH₃ partial structures and is stable against an acid. Here, it is preferable that the organic group which is stable against an acid is more specifically an organic group having no acid-decomposable group described above with respect to the resin P.

The alkyl group of X_{b1} is preferably an alkyl group having 1 to 4 carbon atoms, and examples thereof include a methyl group, an ethyl group, a propyl group, a hydroxymethyl group, and a trifluoromethyl group, with the methyl group being preferable.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ partial structures. Each of the cycloalkyl group, the alkenyl group, the cycloalkenyl group, the aryl group and the aralkyl group may further have an alkyl group as a substituent.

R₂ is preferably an alkyl group or an alkyl-substituted cycloalkyl group, each of which has one or more CH₃ partial structures.

The number of the CH₃ partial structures contained in the organic group which has one or more CH₃ partial structures and is stable against an acid as R₂ is preferably 2 to 10, and more preferably 2 to 8.

Specific preferred examples of the repeating unit represented by General Formula (II) are shown below, but the present invention is not limited thereto.

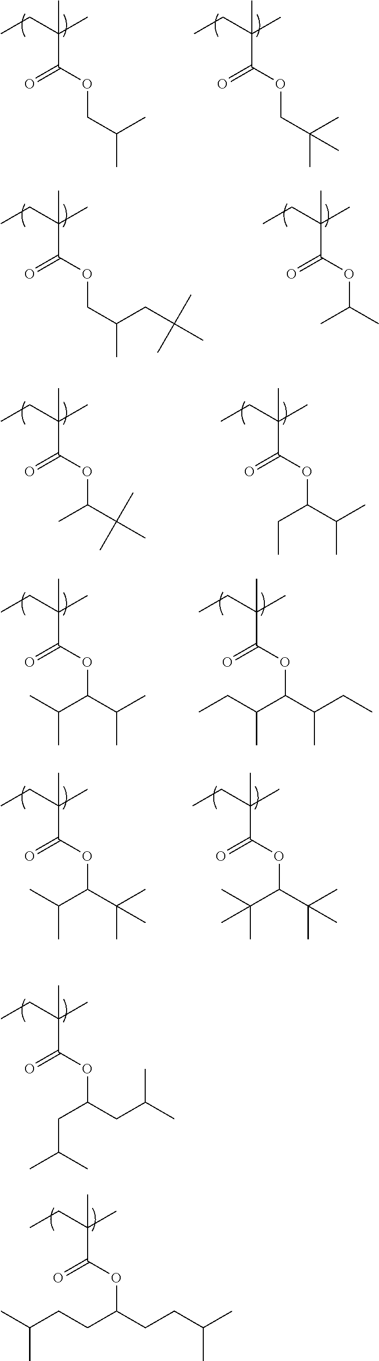

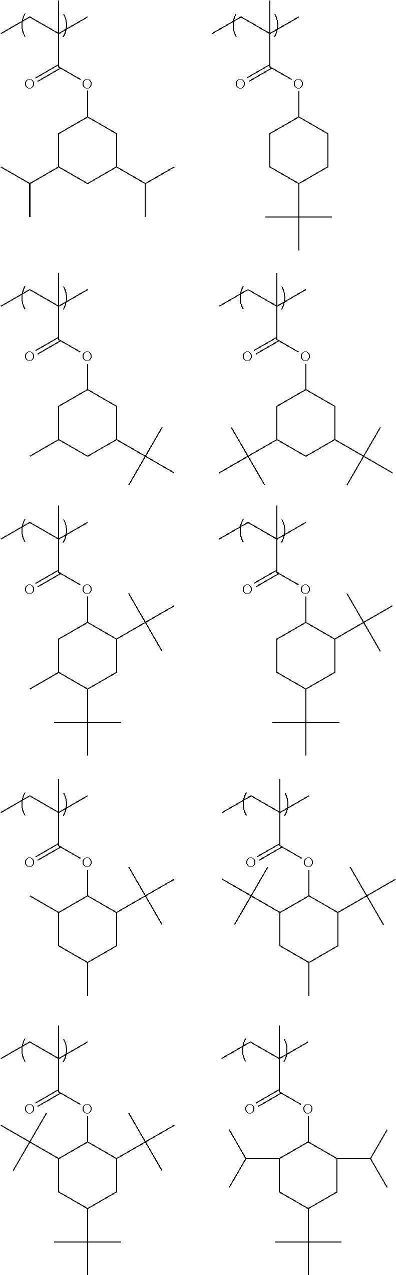

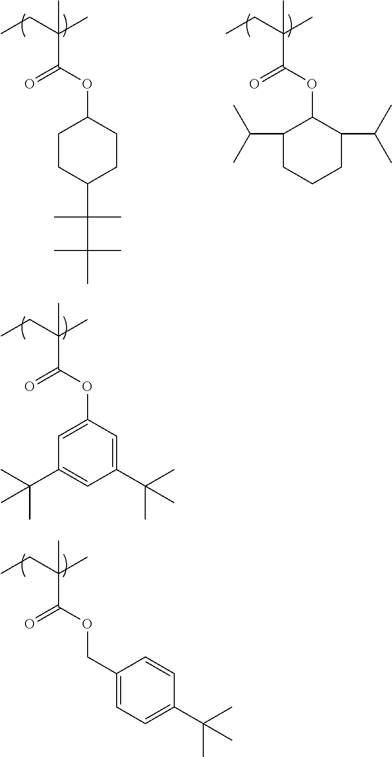

The repeating unit represented by General Formula (II) is preferably a repeating unit which is stable against an acid (acid-indecomposable), and specifically, it is preferably a repeating unit not having a group which decomposes by the action of an acid to generate a polar group.

Hereinafter, the repeating unit represented by General Formula (III) will be described in detail.

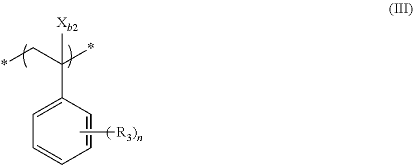

In General Formula (III), X_{b2} represents a hydrogen atom, an alkyl group, a cyano group, or a halogen atom, R₃ represents an organic group which has one or more CH₃ partial structures and is stable against an acid, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, and a trifluoromethyl group, but a hydrogen atom is preferable.

X_{b2} is preferably a hydrogen atom.

Since R₃ is an organic group stable against an acid, it is preferable that R₃ is more specifically an organic group not having the “acid-decomposable group” described above for the resin (A).

Examples of R₃ include an alkyl group having one or more CH₃ partial structures.

The number of the CH₃ partial structures contained in the organic group which has one or more CH₃ partial structures and is stable against an acid as R₃ is preferably 1 to 10, more preferably 1 to 8, and still more preferably 1 to 4.

n represents an integer of 1 to 5, more preferably 1 to 3, and still more preferably 1 or 2.

Specific preferred examples of the repeating unit represented by General Formula (III) are shown below, but the present invention is not limited thereto.

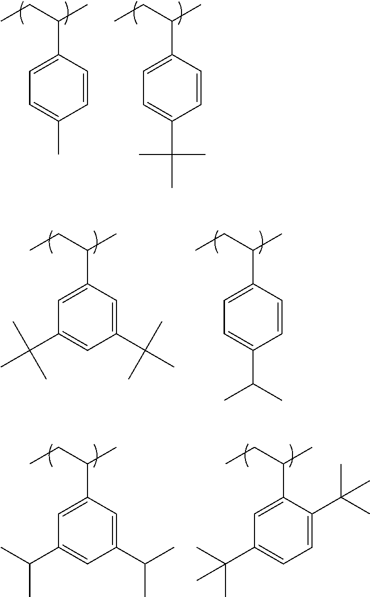

The repeating unit represented by General Formula (III) is preferably a repeating unit which is stable against an acid (acid-indecomposable), and specifically, it is preferably a repeating unit which does not have a group which decomposes by the action of an acid to generate a polar group.

In a case where the hydrophobic resin (D) includes a CH₃ partial structure in the side chain moiety thereof, and in particular, it has neither a fluorine atom nor a silicon atom, the content of at least one repeating unit (x) of the repeating unit represented by General Formula (II) or the repeating unit represented by General Formula (III) is preferably 90% by mole or more, and more preferably 95% by mole or more, with respect to all the repeating units of the hydrophobic resin (D). Further, the content is usually 100% by mole or less with respect to all the repeating units of the hydrophobic resin (D).

By incorporating at least one repeating unit (x) of the repeating unit represented by General Formula (II) or the repeating unit represented by General Formula (III) in a proportion of 90% by mole or more with respect to all the repeating units of the hydrophobic resin (D) into the hydrophobic resin (D), the surface free energy of the hydrophobic resin (D) is increased. As a result, it is difficult for the hydrophobic resin (D) to be unevenly distributed on the surface of the resist film and the static/dynamic contact angle of the resist film with respect to water can be securely increased, thereby enhancing the immersion liquid tracking properties.

In addition, in a case where the hydrophobic resin (D) contains (i) a fluorine atom and/or a silicon atom or (ii) a CH₃ partial structure in the side chain moiety, the hydrophobic resin may have at least one group selected from the following groups (x) to (z):

(x) an acid group,

(y) a group having a lactone structure, an acid anhydride group, or an acid imido group, and

(z) a group which decomposes by the action of an acid.

Examples of the acid group (x) include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

Preferred examples of the acid group include a fluorinated alcohol group (preferably hexafluoroisopropanol), a sulfonimido group, and a bis(alkylcarbonyl)methylene group.

Examples of the repeating unit containing an acid group (x) include a repeating unit in which the acid group is directly bonded to the main chain of the resin, such as a repeating unit by an acrylic acid or a methacrylic acid, and a repeating unit in which the acid group is bonded to the main chain of the resin through a linking group, and the acid group may also be introduced into the polymer chain terminal by using a polymerization initiator or chain transfer agent containing an acid group during the polymerization. All of these cases are preferable. The repeating unit having an acid group (x) may have at least one of a fluorine atom or a silicon atom.

The content of the repeating units containing an acid group (x) is preferably 1% to 50% by mole, more preferably 3% to 35% by mole, and still more preferably 5% to 20% by mole, with respect to all the repeating units in the hydrophobic resin (D).

Specific examples of the repeating unit having an acid group (x) are shown below, but the present invention is not limited thereto. In the formulae, Rx represents a hydrogen atom, CH₃, CF₃, or CH₂OH.

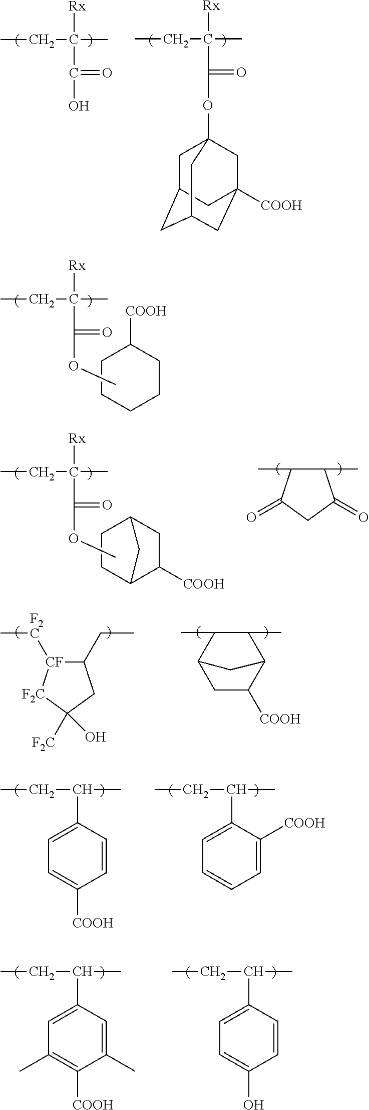

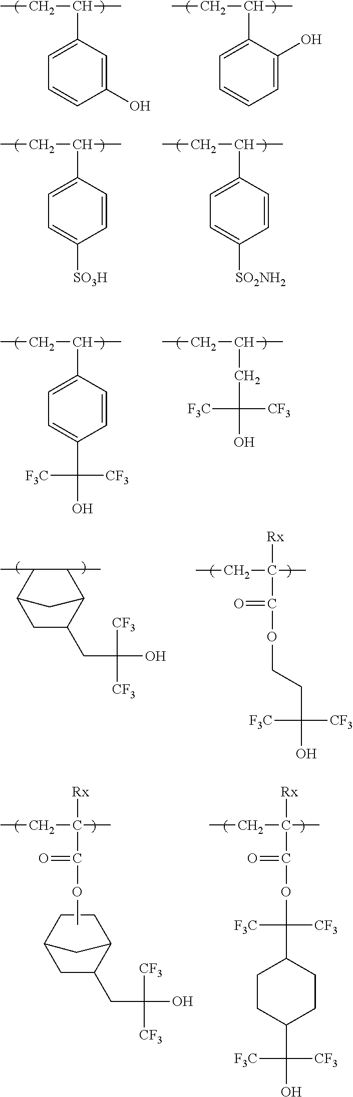

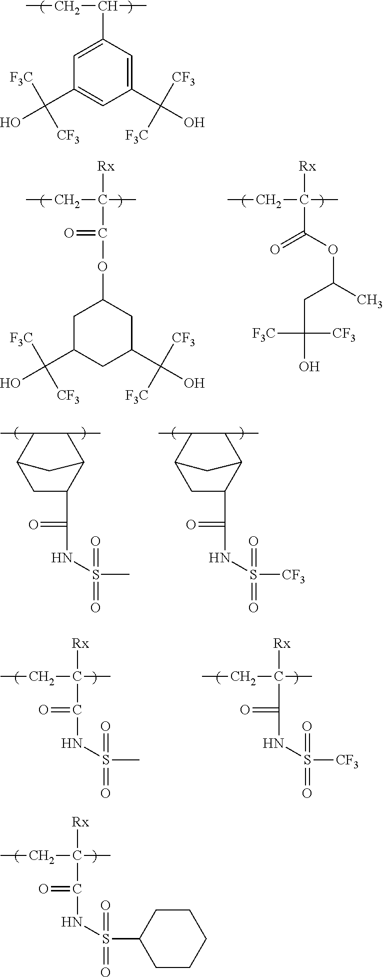

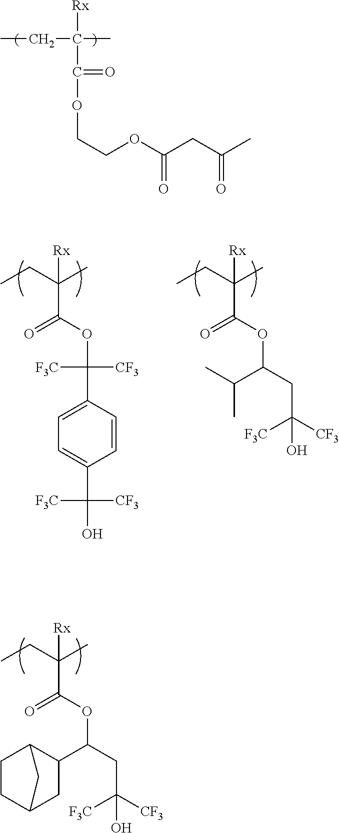

As the group having a lactone structure, the acid anhydride group, or the acid imido group (y), a group having a lactone structure is particularly preferable.

The repeating unit including such a group is, for example, a repeating unit in which the group is directly bonded to the main chain of the resin, such as a repeating unit by an acrylic ester or a methacrylic ester. This repeating unit may be a repeating unit in which the group is bonded to the main chain of the resin through a linking group. Alternatively, this repeating unit may be introduced into the terminal of the resin by using a polymerization initiator or chain transfer agent containing the group during the polymerization.

Examples of the repeating unit containing a group having a lactone structure include the same ones as the repeating unit having a lactone structure as described earlier in the section of the resin (A).

The content of the repeating units having a group having a lactone structure, an acid anhydride group, or an acid imido group is preferably 1% to 100% by mole, more preferably 3% to 98% by mole, and still more preferably 5% to 95% by mole, with respect to all the repeating units in the hydrophobic resin (D).

With respect to the hydrophobic resin (D), examples of the repeating unit having a group (z) which decomposes by the action of an acid include the same ones as the repeating units having an acid-decomposable group, as mentioned with respect to the resin (A). The repeating unit having a group (z) which decomposes by the action of an acid may have at least one of a fluorine atom or a silicon atom. With respect to the hydrophobic resin (D), the content of the repeating units having a group (z) which decomposes by the action of an acid is preferably 1% to 80% by mole, more preferably 10% to 80% by mole, and still more preferably 20% to 60% by mole, with respect to all the repeating units in the resin (D).

The hydrophobic resin (D) may further have repeating units different from the above-mentioned repeating units.

The content of the repeating units including a fluorine atom is preferably 10% to 100% by mole, and more preferably 30% to 100% by mole, with respect to all the repeating units included in the hydrophobic resin (D). Further, the content of the repeating units including a silicon atom is preferably 10% to 100% by mole, and more preferably 20% to 100% by mole, with respect to all the repeating units included in the hydrophobic resin (D).

On the other hand, in particular, in a case where the hydrophobic resin (D) includes a CH₃ partial structure in the side chain moiety thereof, it is also preferable that the hydrophobic resin (D) has a form not having substantially any one of a fluorine atom and a silicon atom. Further, it is preferable that the hydrophobic resin (D) substantially includes only repeating units, which include only atoms selected from a carbon atom, an oxygen atom, a hydrogen atom, a nitrogen atom, and a sulfur atom.

The weight-average molecular weight of the hydrophobic resin (D) in terms of standard polystyrene is preferably 1,000 to 100,000, and more preferably 1,000 to 50,000.

Furthermore, the hydrophobic resins (D) may be used singly or in combination of plural kinds thereof.

The content of the hydrophobic resin (D) in the composition is preferably 0.01% to 10% by mass, and more preferably 0.05% to 8% by mass, with respect to the total solid content of the composition of the present invention.

In the hydrophobic resin (D), the content of residual monomers or oligomer components is also preferably 0.01% to 5% by mass, and more preferably 0.01% to 3% by mass. Further, the molecular weight distribution (Mw/Mn, also referred to as a dispersity) is preferably in the range of 1 to 5, and more preferably in the range of 1 to 3.

As the hydrophobic resin (D), various commercially available products may also be used, or the resin may be synthesized by an ordinary method (for example, radical polymerization).

[5] Acid Diffusion Control Agent

The resist composition of the present invention preferably contains an acid diffusion control agent. The acid diffusion control agent acts as a quencher that inhibits a reaction of the acid-decomposable resin in the unexposed area by excessive generated acids by trapping the acids generated from a photoacid generator or the like upon exposure. As the acid diffusion control agent, a basic compound, a low-molecular-weight compound which has a nitrogen atom and a group that leaves by the action of an acid, a basic compound whose basicity is reduced or lost upon irradiation with actinic rays or radiation, or an onium salt which serves as a relatively weak acid relative to the photoacid generator can be used.

Preferred examples of the basic compound include compounds having structures represented by Formulae (A) to (E).

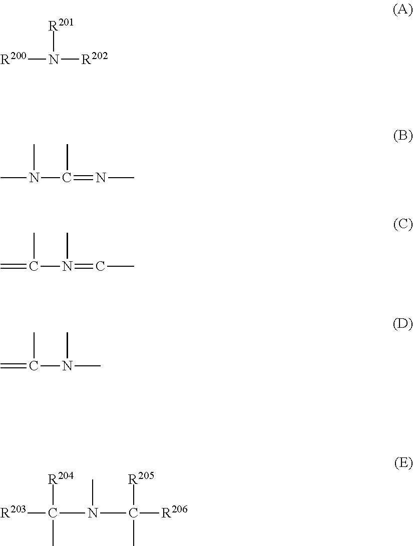

In General Formulae (A) and (E),

R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms), and R²⁰¹ and R²⁰² may be bonded to each other to form a ring.

R²⁰³, R²⁰⁴, R²⁰⁵, and R²⁰⁶ may be the same as or different from each other, and each represent an alkyl group having 1 to 20 carbon atoms.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl groups in General Formulae (A) and (E) are more preferably unsubstituted.

Preferred examples of the compound include guanidine, aminopyrrolidine, pyrazole, pyrazoline, piperazine, aminomorpholine, aminoalkylmorpholine, and piperidine. More preferred examples of the compound include a compound having an imidazole structure, a diazabicyclo structure, an onium hydroxide structure, an onium carboxylate structure, a trialkylamine structure, an aniline structure, or a pyridine structure; an alkylamine derivative having a hydroxyl group and/or an ether bond; and an aniline derivative having a hydroxyl group and/or an ether bond.

Specific preferred examples of the compound include the compounds exemplified in paragraph [0379] in the specification of US2012/0219913A1.

Preferred examples of the basic compound include an amine compound having a phenoxy group, an ammonium salt compound having a phenoxy group, an amine compound containing a sulfonic ester group, and an ammonium salt compound having a sulfonic ester group.

These basic compounds may be used singly or in combination of two or more kinds thereof.

The composition of the present invention may or may not contain the basic compound, but in a case where it contains the basic compound, the content of the basic compound is usually 0.001% to 10% by mass, and preferably 0.01% to 5% by mass, with respect to the solid content of the composition.

The ratio between the photoacid generator to the basic compound to be used in the composition, in terms of the photoacid generator/the basic compound (molar ratio), is preferably 2.5 to 300, more preferably 5.0 to 200, and still more preferably 7.0 to 150.

The low-molecular-weight compound (hereinafter referred to as a “compound (C)”) which has a nitrogen atom and a group that leaves by the action of an acid is preferably an amine derivative having a group that leaves by the action of an acid on a nitrogen atom.

As the group that leaves by the action of an acid, an acetal group, a carbonate group, a carbamate group, a tertiary ester group, a tertiary hydroxyl group, or a hemiaminal ether group are preferable, and a carbamate group or a hemiaminal ether group is particularly preferable.

The molecular weight of the compound (C) is preferably 100 to 1,000, more preferably 100 to 700, and particularly preferably 100 to 500.

The compound (C) may have a carbamate group having a protecting group on a nitrogen atom. The protecting group constituting the carbamate group can be represented by General Formula (d-1).

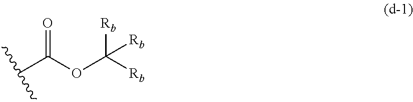

In General Formula (d-1),

R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be linked to each other to form a ring.

The alkyl group, the cycloalkyl group, the aryl group, or the aralkyl group represented by R_{b} may be substituted with a functional group such as a hydroxyl group, a cyano group, an amino group, a pyrrolidino group, a piperidino group, a morpholino group, and an oxo group, an alkoxy group, or a halogen atom. This shall apply to the alkoxyalkyl group represented by R_{b}.

R_{b} is preferably a linear or branched alkyl group, a cycloalkyl group, or an aryl group, and more preferably a linear or branched alkyl group, or a cycloalkyl group.

Examples of the ring formed by the mutual linking of two R_{b}'s include an alicyclic hydrocarbon group, an aromatic hydrocarbon group, a heterocyclic hydrocarbon group, and derivatives thereof.

Examples of the specific structure of the group represented by General Formula (d-1) include, but are not limited to, the structures disclosed in paragraph [0466] in the specification of US2012/0135348A1.

It is particularly preferable that the compound (C) has a structure of General Formula (6).

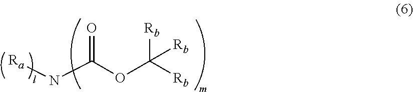

In General Formula (6), Rₐ represents a hydrogen atom, an alkyl group, a cycloalkyl group, an aryl group, or an aralkyl group. In a case where 1 is 2, two Rₐ's may be the same as or different from each other. Two Rₐ's may be linked to each other to form a heterocycle, together with the nitrogen atom in the formula. The heterocycle may contain a heteroatom other than the nitrogen atom in the formula.

R_{b} has the same definition as R_{b} in General Formula (d-1), and preferred examples are also the same.

1 represents an integer of 0 to 2 and m represents an integer of 1 to 3, satisfying 1+m=3.

In General Formula (6), the alkyl group, the cycloalkyl group, the aryl group, and the aralkyl group as Rₐ may be substituted with the same groups as the group mentioned above as a group which may be substituted in the alkyl group, the cycloalkyl group, the aryl group, and the aralkyl group as R_{b}.

Specific examples of the alkyl group, the cycloalkyl group, the aryl group, and the aralkyl group (such the alkyl group, a cycloalkyl group, an aryl group, and aralkyl group may be substituted with the groups as described above) of Rₐ include the same groups as the specific examples as described above with respect to R_{b}.

Specific examples of the particularly preferable compound (C) in the present invention include, but are not limited to, the compounds disclosed in paragraph [0475] in the specification of US2012/0135348A1.

The compounds represented by General Formula (6) can be synthesized in accordance with JP2007-298569A, JP2009-199021A, and the like.

In the present invention, the low-molecular-weight compound (C) having a group that leaves by the action of an acid on a nitrogen atom may be used singly or in combination of two or more kinds thereof.

The content of the compound (C) in the composition of the present invention is preferably 0.001% to 20% by mass, more preferably 0.001% to 10% by mass, and still more preferably 0.01% to 5% by mass, with respect to the total solid content of the composition.

A basic compound (hereinafter also referred to as a “compound (PA)”) whose proton-accepting properties are reduced or lost upon irradiation with actinic rays or radiation is a compound having a proton-accepting functional group, whose proton-accepting properties are reduced or lost, or which is changed from having proton-accepting properties to be acidic, by decomposing upon irradiation with actinic rays or radiation.

The proton-accepting functional group refers to a functional group having a group or electron which is capable of electrostatically interacting with a proton, and for example, means a functional group with a macrocyclic structure, such as a cyclic polyether; or a functional group containing a nitrogen atom having an unshared electron pair not contributing to π-conjugation. The nitrogen atom having an unshared electron pair not contributing to π-conjugation is, for example, a nitrogen atom having a partial structure represented by the following general formula.

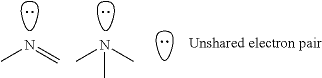

Preferred examples of the partial structure of the proton-accepting functional group include crown ether, azacrown ether, primary to tertiary amines, pyridine, imidazole, and pyrazine structures.

The compound (PA) decomposes upon irradiation with actinic rays or radiation to generate a compound exhibiting deterioration in proton-accepting properties, no proton-accepting properties, or a change from the proton-accepting properties to acid properties. Here, exhibiting deterioration in proton-accepting properties, no proton-accepting properties, or a change from the proton-accepting properties to acid properties means a change of proton-accepting properties due to the proton being added to the proton-accepting functional group, and specifically a decrease in the equilibrium constant at chemical equilibrium in a case where a proton adduct is generated from the compound (PA) having the proton-accepting functional group and the proton.

The proton-accepting properties can be confirmed by carrying out pH measurement.

In the present invention, the acid dissociation constant pKa of the compound generated by the decomposition of the compound (PA) upon irradiation with actinic rays or radiation preferably satisfies pKa<−1, more preferably −13<pKa<−1, and still more preferably −13<pKa<−3.

In the present invention, the acid dissociation constant pKa indicates an acid dissociation constant pKa in an aqueous solution, and is described, for example, in Chemical Handbook (II) (Revised 4^{th} Edition, 1993, compiled by the Chemical Society of Japan, Maruzen Inc.), and a lower value thereof indicates higher acid strength. Specifically, the acid dissociation constant pKa in an aqueous solution may be measured by using an infinite-dilution aqueous solution and measuring the acid dissociation constant at 25° C., or a value with respect to the Hammett substituent constants and the database of publicly known literature value data can also be obtained by computation using the following software package 1. All the values of pKa described in the present specification indicate values determined by computation using this software package.

Software package 1: Advanced Chemistry Development (ACD/Labs) Software V 8.14 for Solaris (1994-2007 ACD/Labs).

The compound (PA) generates a compound represented by General Formula (PA-1), for example, as the proton adduct generated by decomposition upon irradiation with actinic rays or radiation. The compound represented by General Formula (PA-1) is a compound exhibiting deterioration in proton-accepting properties, no proton-accepting properties, or a change from the proton-accepting properties to acid properties since the compound has a proton-accepting functional group as well as an acidic group, as compared with the compound (PA).

Q-A-(X)ₙ—B—R (PA-1)

In General Formula (PA-1),

Q represents —SO₃H, —CO₂H, or —W₁NHW₂R_{f}, in which R_{f} represents an alkyl group (preferably having 1 to 20 carbon atoms), a cycloalkyl group (preferably having 3 to 20 carbon atoms), or an aryl group (preferably having 6 to 30 carbon atoms), and W₁ and W₂ each independently represent —SO₂— or —CO—.

A represents a single bond or a divalent linking group.

X represents —SO₂— or —CO—.

n is 0 or 1.

B represents a single bond, an oxygen atom, or —N(Rₓ)R_{y}—, in which Rₓ represents a hydrogen atom or a monovalent organic group, and R_{y} represents a single bond or a divalent organic group, a provided that Rₓ may be bonded to R_{y} to form a ring or may be bonded to R to form a ring.

R represents a monovalent organic group having a proton-accepting functional group.

The compound (PA) is preferably an ionic compound. The proton-accepting functional group may be contained in an anion moiety or a cation moiety, and it is preferable that the functional group is contained in an anion moiety.

Furthermore, in the present invention, compounds (PA) other than a compound which generates the compound represented by General Formula (PA-1) can also be appropriately selected. For example, a compound containing a proton acceptor moiety at its cation moiety may be used as an ionic compound. More specific examples thereof include a compound represented by General Formula (7).

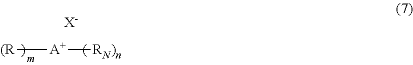

In the formula, A represents a sulfur atom or an iodine atom.

m represents 1 or 2 and n represents 1 or 2, provided that m+n=3 in a case where A is a sulfur atom and that m+n=2 in a case where A is an iodine atom.

R represents an aryl group.

R_{N} represents an aryl group substituted with the proton-accepting functional group, and X⁻ represents a counter anion.

Specific examples of X⁻ include the same anions as those of the photoacid generators as described above.

Specific preferred examples of the aryl group of R and R_{N} include a phenyl group.

Specific examples of the proton-accepting functional group contained in R_{N} are the same as those of the proton-accepting functional group as described above in Formula (PA-1).

Specific examples of the ionic compounds having a proton acceptor site at a cationic moiety include the compounds exemplified in [0291] of US2011/0269072A1.

Furthermore, such compounds can be synthesized, for example, with reference to the methods described in JP2007-230913A, JP2009-122623A, and the like.

The compound (PA) may be used singly or in combination of two or more kinds thereof.

The content of the compound (PA) is preferably 0.1% to 10% by mass, and more preferably 1% to 8% by mass, with respect to the total solid content of the composition.

In the composition of the present invention, an onium salt which serves as a relatively weak acid with respect to the photoacid generator can be used as an acid diffusion control agent.

In a case of mixing the photoacid generator and the onium salt which generates an acid which is a relatively weak acid with respect to an acid generated from the photoacid generator, and then using the mixture, if the acid generated from the photoacid generator upon irradiation with actinic rays or radiation collides with an onium salt having an unreacted weak acid anion, a weak acid is discharged by salt exchange, thereby generating an onium salt having a strong acid anion. In this process, the strong acid is exchanged with a weak acid having a lower catalytic ability, and therefore, the acid is deactivated in appearance, and thus, it is possible to carry out the control of acid diffusion.

As the onium salt which serves as a relatively weak acid with respect to the photoacid generator, compounds represented by General Formulae (d1-1) to (d1-3) are preferable.

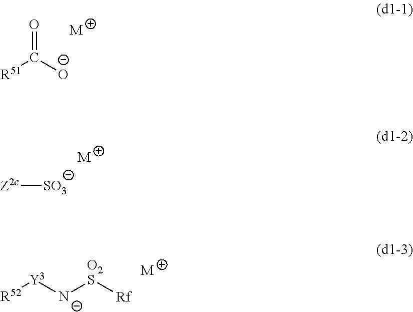

In the formulae, R⁵¹ is a hydrocarbon group which may have a substituent, Z^{2c} is a hydrocarbon group (provided that carbon adjacent to S is not substituted with a fluorine atom) having 1 to 30 carbon atoms, which may have a substituent, R⁵² is an organic group, Y³ is a linear, branched, or cyclic alkylene group or arylene group, Rf is a hydrocarbon group containing a fluorine atom, and M⁺'s are each independently a sulfonium or iodonium cation.

Preferred examples of the sulfonium cation or the iodonium cation represented by M⁺ include the sulfonium cations exemplified by General Formula (ZI) and the iodonium cations exemplified by General Formula (ZII).

Preferred examples of the anionic moiety of the compound represented by General Formula (d1-1) include the structures exemplified in paragraph [0198] of JP2012-242799A.

Preferred examples of the anionic moiety of the compound represented by General Formula (d1-2) include the structures exemplified in paragraph [0201] of JP2012-242799A.

Preferred examples of the anionic moiety of the compound represented by General Formula (d1-3) include the structures exemplified in paragraphs [0209] and [0210] of JP2012-242799A.

The onium salt which serves as a relatively weak acid with respect to the acid generator may be a compound (hereinafter also referred to as a “compound (CA)”) having a cationic moiety (C) and an anionic moiety in the same molecule, in which the cationic moiety and the anionic moiety are linked to each other through a covalent bond.

As the compound (CA), a compound represented by any one of General Formulae (C-1) to (C-3) is preferable.

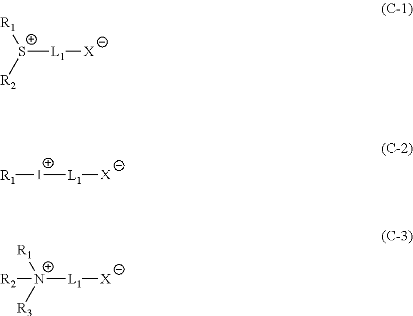

In General Formulae (C-1) to (C-3),

R₁, R₂, and R₃ represent a substituent having 1 or more carbon atoms.

L₁ represents a divalent linking group that links a cationic moiety with an anionic moiety, or a single bond.

—X⁻ represents an anionic moiety selected from —COO⁻, —SO₃⁻, —SO₂⁻, and —N⁻—R₄. R₄ represents a monovalent substituent having a carbonyl group: —C(═O)—, a sulfonyl group: —S(═O)₂—, or a sulfinyl group: —S(═O)— at a site for linking to an adjacent N atom.

R₁, R₂, R₃, R₄, and L₁ may be bonded to one another to form a ring structure. Further, in (C-3), two members out of R₁ to R₃ may be combined to form a double bond with an N atom.

Examples of the substituent having one or more carbon atoms in R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, and preferably an alkyl group, a cycloalkyl group, and an aryl group.

Examples of L₁ as a divalent linking group include a linear or branched alkylene group, a cycloalkylene group, an arylene group, a carbonyl group, an ether bond, ester bond, amide bond, a urethane bond, a urea bond, and a group formed by a combination of two or more kinds of these groups. L₁ is more preferably an alkylene group, an arylene group, an ether bond, ester bond, and a group formed by a combination of two or more kinds of these groups.

Preferred examples of the compound represented by General Formula (C-1) include the compounds exemplified in paragraphs [0037] to [0039] of JP2013-6827A and paragraphs [0027] to [0029] of JP2013-8020A.

Preferred examples of the compound represented by General Formula (C-2) include the compounds exemplified in paragraphs [0012] to [0013] of JP2012-189977A.

Preferred examples of the compound represented by General Formula (C-3) include the compounds exemplified in paragraphs [0029] to [0031] of JP2012-252124A.

The content of the onium salt which serves as a relatively weak acid with respect to the photoacid generator is preferably 0.5% to 10.0% by mass, more preferably 0.5% to 8.0% by mass, and still more preferably 1.0% to 8.0% by mass, with respect to the solid content of the composition.

The acid diffusion control agents may be used singly or in combination of two or more kinds thereof.

[6] Solvent

The resist composition of the present invention usually contains a solvent.

Examples of the solvent which can be used in the preparation of the composition include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

Specific examples of such the solvent include the solvents described in [0441] to [0455] in the specification of US2008/0187860A. These solvents may be used singly or in combination of two or more kinds thereof.

In the present invention, a mixed solvent obtained by mixing a solvent containing a hydroxyl group and a solvent containing no hydroxyl group in the structure may be used as the organic solvent.

As the solvent containing a hydroxyl group and the solvent containing no hydroxyl group, the above-mentioned exemplary compounds can be appropriately selected, but as the solvent containing a hydroxyl group, an alkylene glycol monoalkyl ether, alkyl lactate, and the like are preferable, and propylene glycol monomethyl ether (PGME, alternative name: 1-methoxy-2-propanol), methyl 2-hydroxyisobutyrate, and ethyl lactate are more preferable. Further, as the solvent containing no hydroxyl group, alkylene glycol monoalkyl ether acetate, alkyl alkoxy propionate, a monoketone compound which may contain a ring, cyclic lactone, alkyl acetate, and the like are preferable. Among these, propylene glycol monomethyl ether acetate (PGMEA, alternative name: 1-methoxy-2-acetoxypropane), ethyl ethoxypropionate, 2-heptanone, γ-butyrolactone, cyclohexanone, and butyl acetate are particularly preferable, and propylene glycol monomethyl ether acetate, ethyl ethoxypropionate, and 2-heptanone are the most preferable.

The mixing ratio (mass) of the solvent containing a hydroxyl group to the solvent containing no hydroxyl group is 1/99 to 99/1, preferably 10/90 to 90/10, and more preferably 20/80 to 60/40. A mixed solvent whose proportion of the solvent containing no hydroxyl group is 50% by mass or more is particularly preferable from the viewpoint of coating evenness.

The solvent preferably contains propylene glycol monomethyl ether acetate, and is preferably a solvent including propylene glycol monomethyl ether acetate singly or a mixed solvent of two or more kinds of solvents including propylene glycol monomethyl ether acetate.

[7] Surfactant

The composition of the present invention may or may not further contain a surfactant. In a case where the composition contains the surfactant, it is more preferable that the composition contains any one or two or more of fluorine- and/or silicon-based surfactants (a fluorine-based surfactant, a silicon-based surfactant, and a surfactant having both a fluorine atom and a silicon atom).

By incorporating the surfactant into the composition of the present invention, it becomes possible to provide a resist pattern having improved adhesiveness and decreased development defects with good sensitivity and resolution in a case where an exposure light source of 250 nm or less, and particularly 220 nm or less, is used.

Examples of the fluorine- and/or silicon-based surfactants include the surfactants described in paragraph [0276] in the specification of US2008/0248425A.

In addition, in the present invention, surfactants other than the fluorine- and/or silicon-based surfactants described in paragraph [0280] in the specification of US2008/0248425A can also be used.

These surfactants may be used singly or in combination of several surfactants.

In a case where the composition of the present invention contains a surfactant, the content of the surfactant is preferably 0.0001% to 2% by mass, and more preferably 0.0005% to 1% by mass, with respect to the total solid content of the composition.

On the other hand, by setting the amount of the surfactant to be added to 10 ppm or less with respect to the total amount (excluding the solvent) of the composition, the hydrophobic resin is more unevenly distributed to the surface, so that the resist film surface can be made more hydrophobic, which can enhance the water tracking properties during the liquid immersion exposure.

[8] Other Additives

The resist composition of the present invention may or may not contain an onium carboxylate salt. Examples of such an onium carboxylate salt include those described in [0605] to [0606] in the specification of US2008/0187860A.

The onium carboxylate salt can be synthesized by reacting sulfonium hydroxide, iodonium hydroxide, or ammonium hydroxide and carboxylic acid with silver oxide in an appropriate solvent.

In a case where the composition of the present invention has an onium carboxylate salt, the content of the onium carboxylate salt is generally 0.1% to 20% by mass, preferably 0.5% to 10% by mass, and more preferably 1% to 7% by mass, with respect to the total solid content of the composition.

The composition of the present invention can further contain an acid proliferation agent, a dye, a plasticizer, a light sensitizer, a light absorbent, an alkali-soluble resin, a dissolution inhibitor, a compound promoting a solubility in a developer (for example, a phenol compound with a molecular weight of 1,000 or less, and an alicyclic or aliphatic compound having a carboxyl group), a hydrophilic compound (for example, glycerin and polyethylene glycol), and the like, as desired.

Such a phenol compound having a molecular weight of 1,000 or less may be easily synthesized by those skilled in the art with reference to the method described in, for example, JP1992-122938A (JP-H04-122938A), JP1990-28531A (JP-H02-28531A), U.S. Pat. No. 4,916,210A, EP219294B, and the like.

Specific examples of the alicyclic or aliphatic compound having a carboxyl group include, but are not limited to, a carboxylic acid derivative having a steroid structure such as a cholic acid, deoxycholic acid or lithocholic acid, an adamantane carboxylic acid derivative, adamantane dicarboxylic acid, cyclohexane carboxylic acid, and cyclohexane dicarboxylic acid.

The concentration of the solid content of the resist composition according to the present invention is usually 1.0% to 10% by mass, preferably 2.0% to 5.7% by mass, and more preferably 2.0% to 5.3% by mass. By setting the concentration of the solid content to these ranges, it is possible to uniformly coat the resist solution on a substrate and additionally, it is possible to form a resist pattern having excellent line width roughness. The reason is not clear; however, it is considered that, by setting the concentration of the solid content to 10% by mass or less, and preferably 5.7% by mass or less, the aggregation of materials, particularly the photoacid generator, in the resist solution is suppressed and, as the result, it is possible to form a uniform resist film.

The concentration of the solid content is a weight percentage of the weight of other resist components excluding the solvent, with respect to the total weight of the composition.

A method for preparing the composition of the present invention is not particularly limited, but is preferably a method in which the above-mentioned respective components are dissolved in a predetermined organic solvent, and preferably the mixed solvent, and filtered through a filter. The filter for use in filtration through the filter is preferably a polytetrafluoroethylene-, polyethylene-, or nylon-made filter having a pore size of 0.1 μm or less, more preferably 0.05 μm or less, and still more preferably 0.03 μm or less. In the filtration using a filter, as described in, for example, JP2002-62667A, circulating filtration may be carried out, or the filtration may be carried out by connecting plural kinds of filters in series or in parallel. In addition, the composition may be filtered in plural times. Furthermore, the composition may be subjected to a deaeration treatment or the like before or after filtration using a filter.

[Procedure of Step (2)]

The procedure of the step (2) is not particularly limited, but examples thereof include a method (coating method) in which a resist composition is applied onto a resist underlayer film, and as desired, a curing treatment is carried out, and a method in which a resist film is formed on a temporary support and the resist film is transferred onto a substrate. Among these, from the viewpoint of excellent productivity, the coating method is preferable.

[Resist Film]

The thickness of the resist film is not particularly limited, but is preferably 1 to 500 nm, and more preferably 1 to 100 nm for a reason that a more accurate fine pattern can be formed. A suitable viscosity can be provided by setting the concentration of the solid content in the composition to an appropriate range, and the coatability and the film formability can be improved, thereby attaining such a film thickness.

For the purpose of reducing peeling or collapse in the resist pattern, an adhesion aiding layer may be provided between the resist underlayer film and the resist film.

Suitable examples of a method for forming the adhesion aiding layer on a substrate include a method of forming an adhesion aiding layer having a polymerizable group. It is considered that the polymerizable group in the adhesion aiding layer formed by the present method forms a chemical or physical bond between the substrate and the resist film, and as a result, excellent adhesiveness is exhibited between the resist film and the substrate.

The adhesion aiding layer preferably has a polymerizable group. More specifically, a material (particularly preferably a resin) for forming the adhesion aiding layer preferably has a polymerizable group.

The type of the polymerizable group is not particularly limited, but examples of the polymerizable group include a (meth)acryloyl group, an epoxy group, an oxetanyl group, a maleimido group, an itaconic ester group, a crotonic ester group, an isocrotonic ester group, a maleic ester group, a styryl group, a vinyl group, an acrylamido group, and a methacrylamido group. Among those, a (meth)acryloyl group, an epoxy group, an oxetanyl group, a maleimido group, or a (meth)acryloyl group is more preferable.

The thickness of the adhesion aiding layer is not particularly limited, but is preferably 1 to 100 nm, more preferably 1 to 50 nm, still more preferably 1 to 10 nm, and particularly preferably 1 to 5 nm for a reason that a more accurate fine pattern can be formed.

A method for forming the adhesion aiding layer is not particularly limited, but examples thereof include a method (coating method) in which a composition for forming an adhesion aiding layer is applied onto a substrate, and as desired, a curing treatment is carried out to form an adhesion aiding layer, and a method in which an adhesion aiding layer is formed on a temporary support and the adhesion aiding layer is transferred onto a substrate. Among these, from the viewpoint of excellent productivity, the coating method is preferable.

A method for applying a composition for forming an adhesion aiding layer onto a substrate is not particularly limited, and known methods can be used. However, spin coating is preferably used in the semiconductor manufacturing field.

After applying the composition for forming an adhesion aiding layer onto the substrate, a curing treatment may be carried out, as desired. The curing treatment is not particularly limited, but examples thereof include an exposure treatment and a heating treatment.

For the exposure treatment, light irradiation using a UV lamp, visible light, or the like is used. Examples of the light source include a mercury lamp, a metal halide lamp, a xenon lamp, a chemical lamp, and a carbon arc lamp. Examples of the radiation include electron beams, X-rays, ion beams, and far infrared rays. In a specific aspect, suitable examples thereof include scanning exposure with an infrared laser, high-intensity flash exposure with a xenon discharge lamp or the like, and infrared lamp exposure.

The exposure time varies depending on the reactivity and the light source of a polymer, but is usually between 10 seconds to 5 hours. The exposure energy may be any one in a range of approximately 10 to 10,000 mJ/cm², and is preferably in a range of approximately 100 to 8,000 mJ/cm².

In addition, in a case of using a heating treatment, an air dryer, an oven, an infrared dryer, a heating drum, or the like can be used.

The exposure treatment and the heating treatment may be used in combination.

[Step (3): Exposing Step]

The step (3) is a step of irradiating (exposing) the film (resist film) formed in the step (1) with actinic rays or radiation.

The light used for exposure is not particularly limited, but examples thereof include infrared light, visible light, ultraviolet light, far ultraviolet light, extreme ultraviolet light, X-rays, and electron beams, with the wavelength of far ultraviolet light being preferably 250 nm or less, more preferably 220 nm or less, and still more preferably 1 to 200 nm.

More specific examples of the light include a KrF excimer laser (248 nm), an ArF excimer laser (193 nm), an F₂ excimer laser (157 nm), X-rays, EUV (13 nm), and electron beams. Among these, a KrF excimer laser, an ArF excimer laser, EUV, or electron beams are preferable, and an ArF excimer laser is more preferable.

A liquid immersion exposure method can be applied to the exposing step. It is possible to combine the liquid immersion exposure method with super-resolution technology such as a phase shift method and a modified illumination method. The liquid immersion exposure can be carried out by, for example, the method described in paragraphs [0594] to [0601] of JP2013-242397A.

In the step (3), the resist film is preferably exposed by any one of ArF liquid immersion exposure, ArF exposure, and KrF exposure, and more preferably exposed by ArF liquid immersion exposure or ArF exposure.

Moreover, if the receding contact angle of the resist film formed using the composition in the present invention is extremely small, the resist film cannot be suitably used in a case where the exposure is carried out through a liquid immersion medium. Further, the effect of reducing watermark defects cannot be sufficiently exhibited. In order to realize a favorable receding contact angle, it is preferable to incorporate the hydrophobic resin (D) into the composition. Alternatively, a film (hereinafter also referred to as a “topcoat”) sparingly soluble in an immersion liquid, which is formed of the hydrophobic resin (D), may be formed on the upper layer of the resist film. A topcoat may be provided on a resist including the hydrophobic resin (D). The functions required for the topcoat are coating suitability on the upper layer part of a resist film, and sparing solubility in an immersion liquid. It is preferable that the topcoat is not mixed with the composition film and can be uniformly applied onto the upper layer of a composition film.

The topcoat is not particularly limited, and topcoats known in the related art can be formed according to the methods known in the related art, and can be formed, for example, according to the description in paragraphs [0072] to [0082] of JP2014-059543A.

It is preferable that a topcoat containing the basic compound described in JP2013-61648A is formed on a resist film.

In addition, even in a case where exposure is carried out by a liquid immersion exposure method, a topcoat may be formed on a resist film.

In the liquid immersion exposure step, it is necessary for the immersion liquid to move on a wafer following the movement of an exposure head which scans the wafer at a high speed to form an exposure pattern. Therefore, the contact angle of the immersion liquid for the resist film in a dynamic state is important, and the resist is required to have a performance of allowing the immersion liquid to follow the high-speed scanning of an exposure head with no remaining of a liquid droplet.

After the step (3), the film which has been irradiated with actinic rays or radiation in the step (3) may be subjected to a heating treatment (PEB: Post Exposure Bake) before the step (4) which will be described later. By this scheme, the reaction of the exposed area is promoted. The heating treatment (PEB) may be carried out in plural times.

The temperature of the heating treatment is preferably 70° C. to 130° C., and more preferably 80° C. to 120° C.

The time the heating treatment is preferably 30 to 300 seconds, more preferably 30 to 180 seconds, and still more preferably 30 to 90 seconds.

The heating treatment can be carried out using a means installed in an ordinary exposure machine or development machine, or may be carried out using a hot plate or the like.

[Step (4): Developing Step]

The step (4) is a step in which the film which has been irradiated with actinic rays or radiation in the step (3), that is, the exposed film is developed using a developer (hereinafter also referred to as an organic developer) including an organic solvent, thereby forming a negative tone resist pattern.

As the organic developer, a polar solvent such as a ketone-based solvent, an ester-based solvent, an alcohol-based solvent, an amide-based solvent, and an ether-based solvent, or a hydrocarbon-based solvent can be used.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, methyl 2-hydroxyisobutyrate, isobutyl isobutyrate, butyl propionate, butyl butyrate, and isoamyl acetate.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, diethylene glycol, and triethylene glycol; and glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

Examples of the ether-based solvent include dioxane and tetrahydrofuran, in addition to the glycol ether-based solvents above.

Examples of the amide-based solvent which can be used include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include aromatic hydrocarbon-based solvents such as toluene and xylene; and aliphatic hydrocarbon-based solvents such as pentane, hexane, octane, and decane.

The above solvents can be used by mixing a plurality of the solvents or by mixing the solvent of water or solvents other than the solvents. However, in order to sufficiently exhibit the effects of the present invention, the moisture content in the entire developer is preferably less than 10% by mass, but a developer having substantially no water is preferable.

That is, the amount of the organic solvent to be used with respect to the organic developer is preferably from 90% by mass to 100% by mass, and more preferably from 95% by mass to 100% by mass, with respect to the total amount of the developer.

The organic developer is preferably a developer containing at least one organic solvent selected from the group consisting of a ketone-based solvent, an ester-based solvent, an alcohol-based solvent, an amide-based solvent, and an ether-based solvent, and more preferably includes at least one of butyl acetate or isoamyl acetate.

The vapor pressure of the organic developer at 20° C. is preferably 5 kPa or less, more preferably 3 kPa or less, and particularly preferably 2 kPa or less. By setting the vapor pressure of the organic developer to 5 kPa or less, the evaporation of the developer on the substrate or in a developing cup is inhibited, the temperature uniformity in the wafer surface is improved, and as a result, the dimensional uniformity within a wafer surface is improved.

It is possible to add an appropriate amount of a surfactant to the organic developer, if necessary.

The surfactant is not particularly limited, but it is possible to use, for example, ionic or non-ionic fluorine- and/or silicon-based surfactants, or the like. Examples of the fluorine- and/or silicon-based surfactant include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H7-230165A), JP 1996-62834A (JP-H8-62834A), JP1997-54432A (JP-H9-54432A), JP1997-5988A (JP-H9-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and non-ionic surfactants are preferable. The non-ionic surfactant is not particularly limited, but it is more preferable to use a fluorine-based surfactant or a silicon-based surfactant.

The amount of the surfactant to be used is usually 0.001% to 5% by mass, preferably 0.005% to 2% by mass, and more preferably 0.01% to 0.5% by mass, with respect to the total amount of the developer.

The organic developer may also include a basic compound. Specific and preferred examples of the basic compound which can be included in the organic developer used in the present invention include the same ones as for the basic compound which can be included in the composition, mentioned above as the acid diffusion control agent.

As the developing method, for example, a method in which a substrate is immersed in a tank filled with a developer for a certain period of time (a dip method), a method in which a developer is heaped up to the surface of a substrate by surface tension and developed by stopping for a certain period of time (a puddle method), a method in which a developer is sprayed on the surface of a substrate (a spray method), a method in which a developer is continuously discharged on a substrate rotated at a constant rate while scanning a developer discharging nozzle at a constant rate (a dynamic dispense method), or the like, can be applied. Incidentally, suitable ranges of the discharge pressure of the developer to be discharged, methods for adjusting the discharge pressure of the developer, and the like are not particularly limited, and for example, the ranges and the methods described in paragraphs [0631] to [0636] of JP2013-242397A can be used.

In the pattern forming method of the present invention, a step of carrying out development by using a developer containing an organic solvent (organic solvent developing step) and a step of carrying out development by using an aqueous alkali-solution (alkali developing step) may be used in combination. Due to this combination, a finer pattern can be formed.

The alkali developer is not particularly limited, but examples thereof include the alkali developers described in paragraph [0460] of JP2014-048500A.

As a rinsing liquid in the rinsing treatment to be carried out after the alkali development, pure water is used, and an appropriate amount of a surfactant may also be added and used.

In the present invention, an area with a low exposure intensity is removed in the organic solvent developing step, and by further carrying out the alkali developing step, an area with a high exposure intensity is also removed. By virtue of a multiple development process in which development is carried out plural times in this way, a pattern can be formed by keeping only a region with an intermediate exposure intensity from being dissolved, so that a finer pattern than usual can be formed (the same mechanism as in [0077] of JP2008-292975A).

In the pattern forming method of the present invention, the order of the alkali developing step and the organic solvent developing step is not particularly limited, but the alkali development is more preferably carried out before the organic solvent developing step.

A washing step using a rinsing liquid is preferably included after the step of carrying out development using a developer including an organic solvent.

The rinsing liquid used in the rinsing step after the step of carrying out development using a developer including an organic solvent is not particularly limited as long as it does not dissolve the resist pattern, and a solution including a general organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent are the same as those described for the developer including an organic solvent.

After the developing step using a developer including an organic solvent, it is more preferable to carry out a step of carrying out washing using a rinsing liquid containing at least one organic solvent selected from the group consisting of a ketone-based solvent, an ester-based solvent, an alcohol-based solvent, an amide-based solvent, and a hydrocarbon-based solvent, it is still more preferable to carry out a step of carrying out washing using a rinsing liquid containing an alcohol-based solvent or an ester-based solvent, it is particularly preferable to carry out a step of carrying out washing using a rinsing liquid containing a monohydric alcohol, and it is the most preferable to carry out a step of carrying out washing using a rinsing liquid containing a monohydric alcohol having 5 or more carbon atoms.

The rinsing liquid containing the hydrocarbon-based solvent is preferably a hydrocarbon compound having 6 to 30 carbon atoms, more preferably a hydrocarbon compound having 8 to 30 carbon atoms, still more preferably a hydrocarbon compound having 10 to 30 carbon atoms. By using a rinsing liquid including decane and/or undecane among these, pattern collapse is suppressed.

In a case of using an ester-based solvent as the organic solvent, a glycol ether-based solvent may be used, in addition to the ester-based solvent (one kind or two or more kinds). Specific examples of such a case include use of an ester-based solvent (preferably butyl acetate) as a main component and a glycol ether-based solvent (preferably propylene glycol monomethyl ether (PGME)) as a side component. Thus, residue defects are suppressed.

Here, examples of the monohydric alcohol used in the rinsing step include linear, branched, or cyclic monohydric alcohols, and specifically, 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol, or the like can be used. Further, 1-hexanol, 2-hexanol, 4-methyl-2-pentanol, 1-pentanol, 3-methyl-1-butanol, or the like can be used as a particularly preferable monohydric alcohol having 5 or more carbon atoms.

A plurality of the respective components may be mixed, or the components may be used after being mixed with an organic solvent other than the above solvents.

The moisture content of the rinsing liquid is preferably 10% by mass or less, more preferably 5% by mass or less, and particularly preferably 3% by mass or less. By setting the moisture content to 10% by mass or less, good development characteristics can be obtained.

The vapor pressure at 20° C. of the rinsing liquid which is used after the step of carrying out development using a developer including an organic solvent is preferably from 0.05 kPa to 5 kPa, more preferably from 0.1 kPa to 5 kPa, and most preferably from 0.12 kPa to 3 kPa. By setting the vapor pressure of the rinsing liquid to a range from 0.05 kPa to 5 kPa, the temperature uniformity within a wafer surface is improved, and further, the dimensional uniformity within a wafer surface is enhanced by suppression of swelling due to the permeation of the rinsing liquid.

The rinsing liquid can also be used after adding an appropriate amount of a surfactant thereto.

In the rinsing step, the wafer which has been subjected to development using a developer including an organic solvent is subjected to a washing treatment using the rinsing liquid including an organic solvent. A method for the washing treatment is not particularly limited, and for example, a method in which a rinsing liquid is continuously discharged on a substrate rotated at a constant rate (a rotation application method), a method in which a substrate is immersed in a tank filled with a rinsing liquid for a certain period of time (a dip method), a method in which a rinsing liquid is sprayed on a substrate surface (a spray method), or the like, can be applied. Among these, a method in which a washing treatment is carried out using the rotation application method, and a substrate is rotated at a rotation speed of 2,000 rpm to 4,000 rpm after washing, thereby removing the rinsing liquid from the substrate, is preferable. Further, it is preferable that a heating step (Post Bake) is included after the rinsing step. The residual developer and the rinsing liquid between and inside the patterns are removed by the baking. The heating step after the rinsing step is carried out at typically 40° C. to 160° C., and preferably at 70° C. to 95° C., and typically for 10 seconds to 3 minutes, and preferably for 30 seconds to 90 seconds.

It is preferable that various materials (for example, a resist solvent, a developer, a rinsing liquid, a composition for forming an antireflection film, and a composition for forming a topcoat) used in the composition of the present invention and the pattern forming method of in the present invention do not include impurities such as metals. The content of the impurities included in these materials is preferably 1 ppm or less, more preferably 10 ppb or less, still more preferably 100 ppt or less, and particularly preferably 10 ppt or less, but the material not having substantially metal components (within a detection limit of a determination device or less) is the most preferable.

Examples of a method for removing impurities such as metals from the various materials include filtration using a filter. As for the filter pore diameter, the pore size is preferably 50 nm or less, more preferably 10 nm or less, and still more preferably 5 nm or less. As for the materials of a filter, a polytetrafluoroethylene-made filter, a polyethylene-made filter, and a nylon-made filter are preferable. The filter may be formed of a composite material formed by combining this material with an ion exchange medium. In the step of filtration using a filter, plural kinds of filters may be connected in series or in parallel, and used. In a case of using plural kinds of filters, a combination of filters having different pore diameters and/or materials may be used. In addition, various materials may be filtered plural times, and a step of filtering plural times may be a circulatory filtration step.

Moreover, examples of the method for reducing the impurities such as metals included in the various materials include a method involving selecting raw materials having a small content of metals as raw materials constituting various materials, and a method involving subjecting raw materials constituting various materials to filtration using a filter. The preferred conditions for filtration using a filter, which is carried out for raw materials constituting various materials, are the same as described above.

In addition to filtration using a filter, removal of impurities by an adsorbing material may be carried out, or a combination of filtration using a filter and an adsorbing material may be used. As the adsorbing material, known adsorbing materials may be used, and for example, inorganic adsorbing materials such as silica gel and zeolite, and organic adsorbing materials such as activated carbon can be used.

A method for improving the surface roughness of a pattern may be applied to the pattern formed by the method of the present invention. Examples of the method for improving the surface roughness of a pattern include the method of treating a resist pattern with plasma of a hydrogen-containing gas disclosed in WO2014/002808A1. In addition, known methods as described in JP2004-235468A, US2010/0020297A, JP2008-83384A, and Proc. of SPIE Vol. 8328 83280 N-1 “EUV Resist Curing Technique for LWR Reduction and Etch Selectivity Enhancement” may be applied.

The pattern forming method of the present invention can also be used for a guide pattern formation in a directed self-assembly (DSA) (see, for example, ACS Nano Vol. 4 No. 8 Pages 4815 to 4823).

In addition, a resist pattern formed by the method can be used as a core material (core) of the spacer process disclosed in JP1991-270227A (JP-H03-270227A) and JP2013-164509A. At this time, by appropriately selecting a gas flow ratio during etching, it is possible to form a core material (core) trimmed to a desired dimension at the same time with the etching.

Furthermore, a process for obtaining a finer pattern may be applied to the pattern formed by the method of the present invention. Examples of the process for forming a finer pattern include a technique in which a composition for forming a finer pattern is applied onto a pattern and heated to increase the width of a resist pattern width, as shown in JP2013-145290A or JP2014-071424A. In addition, in order to maintain the etching resistance of the resist pattern after the process for forming a finer pattern, it is preferable that the composition for forming a finer pattern contains silicon atoms.

[Step (5): Pattern Forming Step]

The step (5) is a step of forming a pattern by processing a resist underlayer film and a substrate to be processed, using the resist pattern formed in the step (4) as a mask.

The resist underlayer film and processing of the substrate to be processed method is not particularly limited, but the step (5) is preferably a step of forming a pattern by subjecting a resist underlayer film and a substrate to be processed to dry etching, using the resist pattern as a mask.

Dry etching may be one-stage etching or etching including a plurality of stages. In a case of the etching including a plurality of stages, etching at each stage may be the same treatment or different treatments.

The system of a dry etching device is not particularly limited, but in particular, a system capable of independently controlling a plasma density and a bias voltage, such as an inductive coupled plasma (ICP) type, a dual-frequency conductive coupled plasma (CCP) type, and an electron cyclotron resonance (ECR) type is more preferable.

For etching, any known method can be used, and various conditions and the like are appropriately determined according to the type of the substrate, the usage, and the like. Etching can be carried out, for example, in accordance with Proc. of SPIE, Vol. 6924, 692420 (2008), JP2009-267112A, and the like. In addition, etching can also be carried out in accordance with “Chapter 4 Etching” in “Semiconductor Process Text Book, 4^{th} Ed., published in 2007, publisher: SEMI Japan”.

Among those, dry etching for the resist underlayer film is preferably oxygen plasma etching.

The oxygen plasma etching as mentioned herein means plasma etching using an oxygen atom-containing gas, and specifically, is at least one selected from the group consisting of O₂, O₃, CO, CO₂, NO, NO₂, N₂P, SO, SO₂, COS, and the like. Further, in addition to the oxygen-containing gas, at least one selected from the group consisting of Ar, He, Xe, Kr, and N₂ as a dilution gas, and at least one selected from the group consisting of Cl₂, HBr, BCl₃, CH₄, and NH₄ as an additive gas may further be added.

If the oxygen atom-containing gas is used, etching of the resist underlayer film is promoted by the irradiation effect of oxygen radicals and oxygen ions generated in the plasma, whereas with regard to the silicon-containing resist film, the silicon components in the resist film have increased etching resistance due to the oxidation⋅aggregation of the silicon components, and thus, it is possible to increase the selection ratios of the silicon-containing resist film and the resist underlayer film.

In a case of suppressing variation in pattern dimensions between before and after etching, by increasing the ratio of an oxygen-containing gas containing an oxygen atom, and at least one of C, N, S, and the like (for example, CO, CO₂, NO, NO₂, N₂O, SO, SO₂, and COS), depositable components produced in the plasma are adhered to the side wall of etching processing pattern, the side etching effect due to oxygen radicals is suppressed, and thus, it is possible to reduce a decrease in the line width between before and after etching. In the same manner, the effect is exerted in a case of adding CH₄ or NH₄ as an oxygen-containing gas to an oxygen containing gas (for example, O₂, O₃, CO, CO₂, NO, NO₂, N₂O, SO, SO₂, and COS).

In addition, if a gas containing a halogen element other than fluorine, such as Cl₂ and HBr, is used, carbon chloride or carbon bromide having a high boiling point as an etching product of the underlayer film is formed, and thus, adhesiveness to the side wall of the processing pattern is enhanced. Also, in this case, an effect of suppressing the side etching due to oxygen radicals can be expected.

On the one hand, by appropriately selecting the mixing ratio of the O₂ or O₃ gas and the dilution gas, it is possible to control of the side etching amount of the silicon-containing resist film and the resist underlayer film, and carry out etching and a trimming treatment at a desired dimension amount at the same time.

In a case of carrying out double patterning according to a spacer process, it is required to control the trimming amount of a core material (core) to a range of 5 to 30 nm according to a desired pattern dimension. In a case of a mixed gas of an O₂ gas and a dilute gas, it is possible to control the trimming amount within the range by setting the ratio of the oxygen gas to 10% to 40%.

In the production of a semiconductor device, a resist underlayer film or a resist film is applied onto a substrate, and then exposure and development treatments, and the like are carried out to form a pattern, and in an ordinary case, there is a step of checking if a desired pattern dimension is substantially formed after patterning. Further, for deviation from an acceptable range, a technique in which an underlayer film or a resist layer is peeled and removed, and patterning is formed by application of the resist underlayer film or the resist film is generally carried out (rework step).

In this case, it is important to completely peel and remove the resist underlayer film or the resist film on the substrate so as to prevent generation of defects in an exposing or developing treatment. In an ordinary resist film peeling method, it is possible to peel a resist film almost completely by removing most of organic compounds on a substrate by a dry treatment (ashing) using an oxygen gas, and as desired, carrying out a rinsing treatment, which has been widely carried out.

However, in a bilayered resist system using a silicon-containing resist film, in a case where the ashing treatment is carried out, there is a concern that the silicon-containing resist film remains in the form of silicon oxide, and is hard to remove completely.

As a result, in a case where a rework is carried out in the dry treatment, it is necessary to select an etching gas to prevent the etching rate of a silicon-containing resist film from being low. For example, a fluorine-based gas such as CF₄ can be applied to this application.

In a case of the dry treatment, in a view that there is a concern of limitation in the type of the resist underlayer film or the substrate, a wet treatment is preferable as a rework method of the silicon-containing resist film. Examples of the treatment liquid (peeling liquid) to be applied to this case include, but not limited to, a mixed liquid of sulfuric acid and a hydrogen peroxide solution, a dilute aqueous fluorine solution, an aqueous alkali solution, and an organic solvent.

The wet treatment is more preferable in a case where addition of a surfactant to a treatment liquid is effectively carried out in carrying out wet peeling. Examples of the surfactant include a fluorine-based surfactant and a silicon-based surfactant.

Before the wet peeling step, a silicon wafer having a resist film formed thereon can also be subjected to a process such as full-surface exposure and heating. By promoting the polarity conversion reaction of the resist film, an effect of enhancing the solubility in a wet treatment liquid can be expected.

The present invention also relates to a laminate, applied to the pattern forming method of the present invention, in which a resist underlayer film and a resist film formed of a resist composition containing (A) a resin having a repeating unit containing a Si atom and (B) a compound which generates an acid upon irradiation with actinic rays or radiation are laminated in this order on a substrate to be processed.

Furthermore, the present invention also relates to a resist composition for organic solvent development, applied to the pattern forming method of the present invention.

In addition, the present invention also relates to a method for manufacturing an electronic device, including the pattern forming method of the present invention, and an electronic device manufactured by the manufacturing method.

The electronic device of the present invention is suitably mounted on electric or electronic equipment (household electronic appliance, office automation (OA)⋅media-related equipment, optical equipment, telecommunication equipment, and the like).

### EXAMPLES

Hereinafter, the present invention will be described with reference to Examples, but the present invention is not limited thereto.

### Synthesis Example 1: Synthesis of Resin PRP-1

Under a nitrogen stream, 194.3 g of cyclohexanone was put into a three-neck flask and heated at 80° C. A solution of 18.0 g, 17.8 g, and 17.0 g of the monomers, corresponding to the respective repeating units of a resin PRP-1 described below, in the order from the left side, and a polymerization initiator, V-601 (manufactured by Wako Pure Chemical Industries, Ltd., 3.17 g), which had been dissolved in 105 g of cyclohexanone, was added dropwise thereto for 6 hours. After completion of the dropwise addition, the solution was further allowed to undergo a reaction at 80° C. for 2 hours. The reaction solution was left to be cooled, and then added dropwise to a mixed liquid of methanol:water for 20 minutes, and the precipitated powder was collected by filtration and dried to obtain a resin PRP-1 (31.6 g) which is an acid-decomposable resin. The compositional ratio (molar ratio) of the repeating unit, determined by a nuclear magnetic resonance (NMR) method, was 10/50/40. The weight-average molecular weight and the dispersity (Mw/Mn) of the obtained resin PRP-1, in terms of standard polystyrene, determined by GPC, were 8,000 and 1.6, respectively.

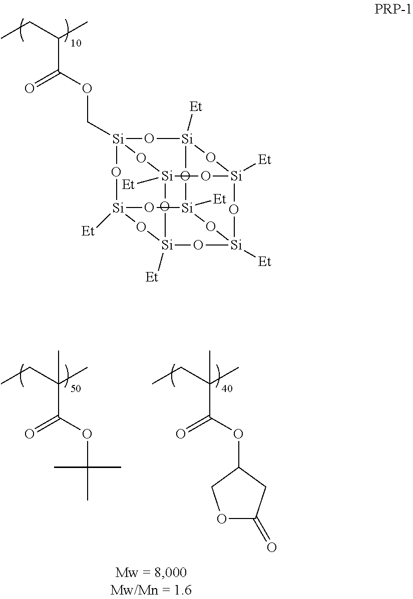

The other polymers were synthesized by the same procedure or by the exiting procedure.

The structures of the resins PRP-1 to 61 were shown below. Further, the compositional ratio (molar ratio), the weight-average molecular weight (Mw), and the dispersity of the respective resins are shown in Table 1 below. The compositional ratios correspond to the respective repeating units in the order from the left side.

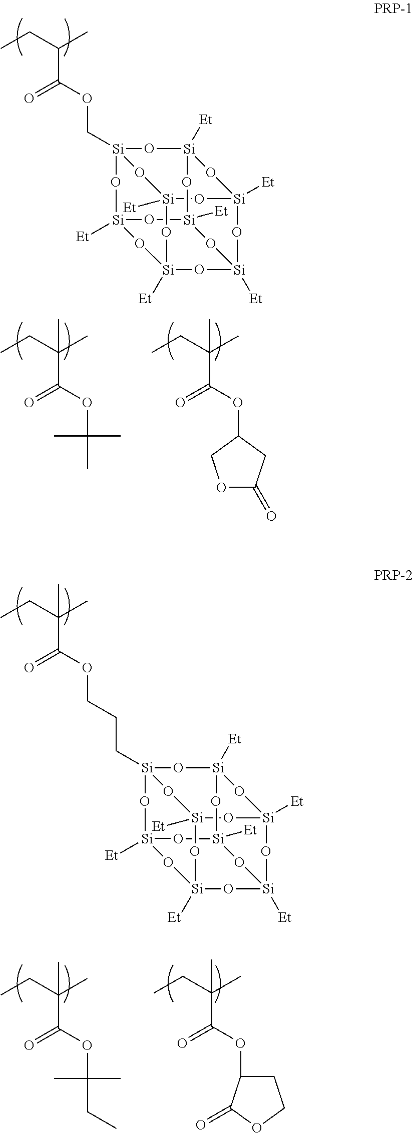

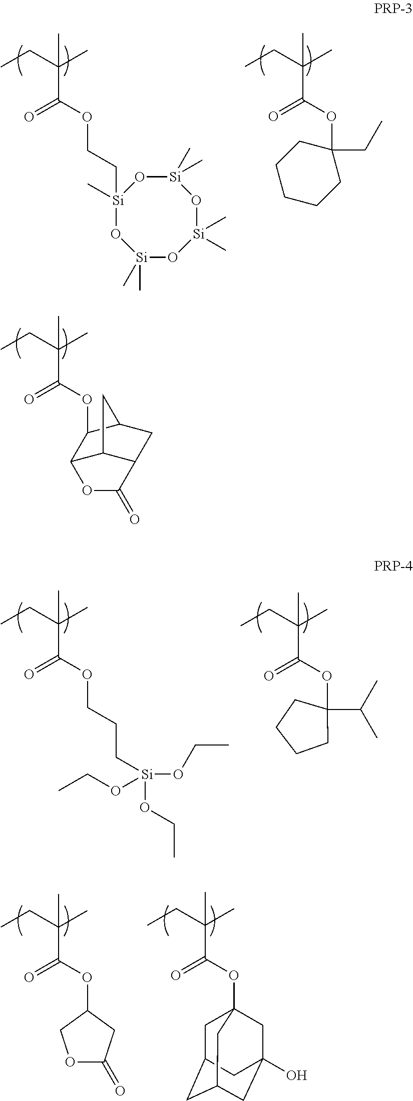

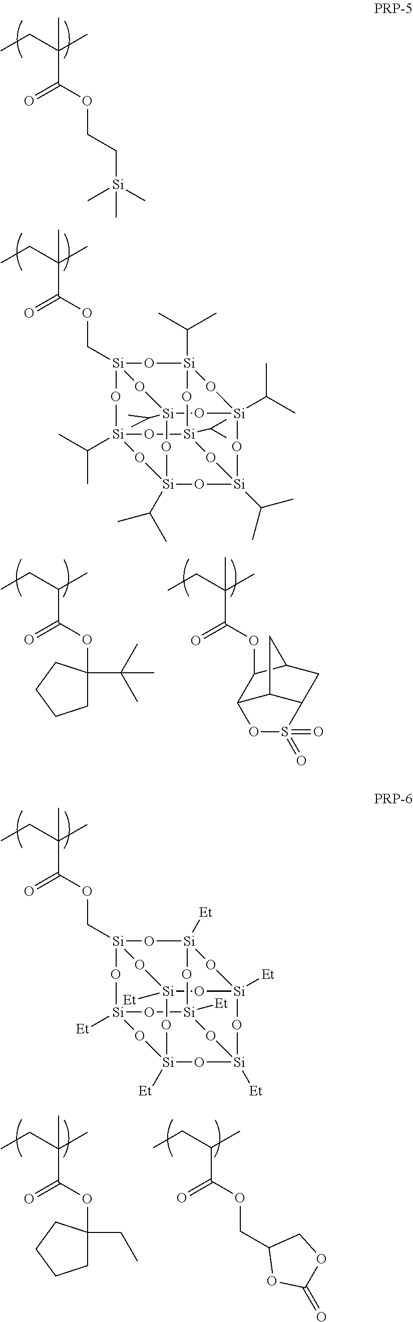

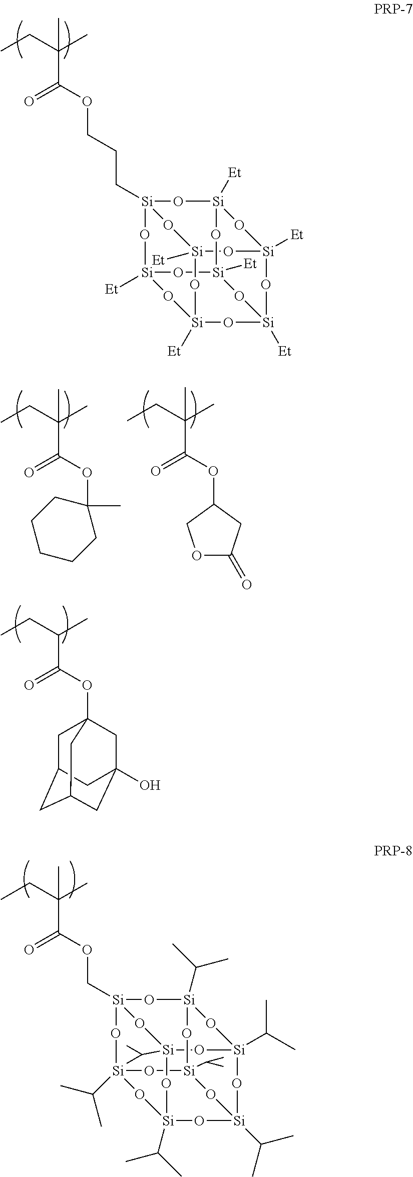

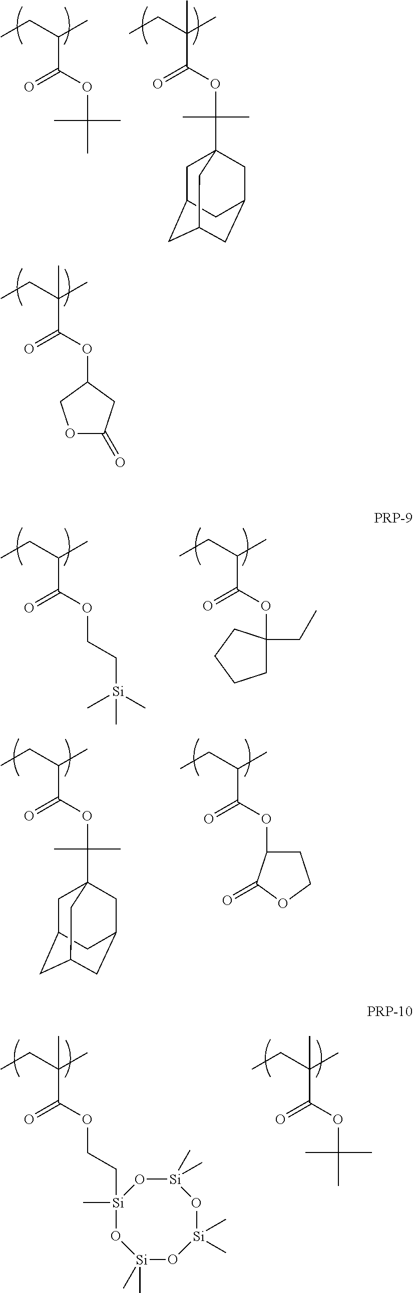

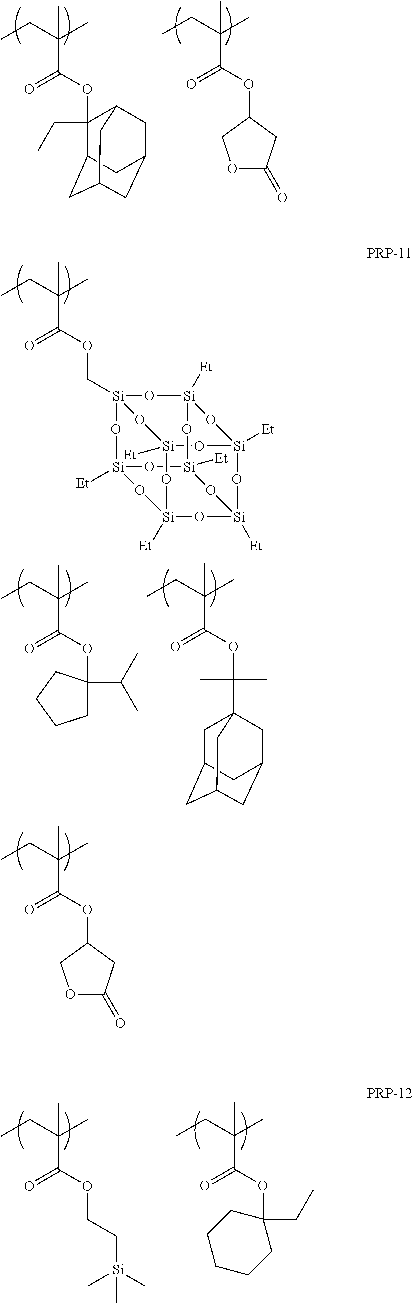

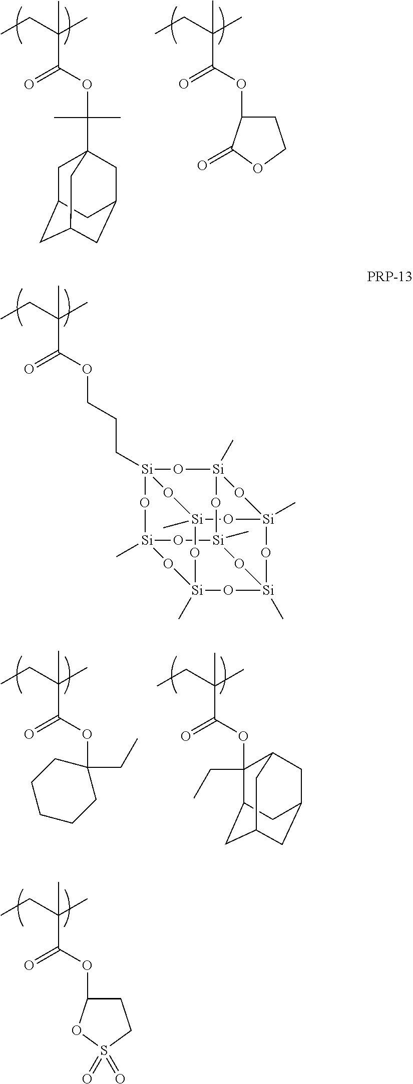

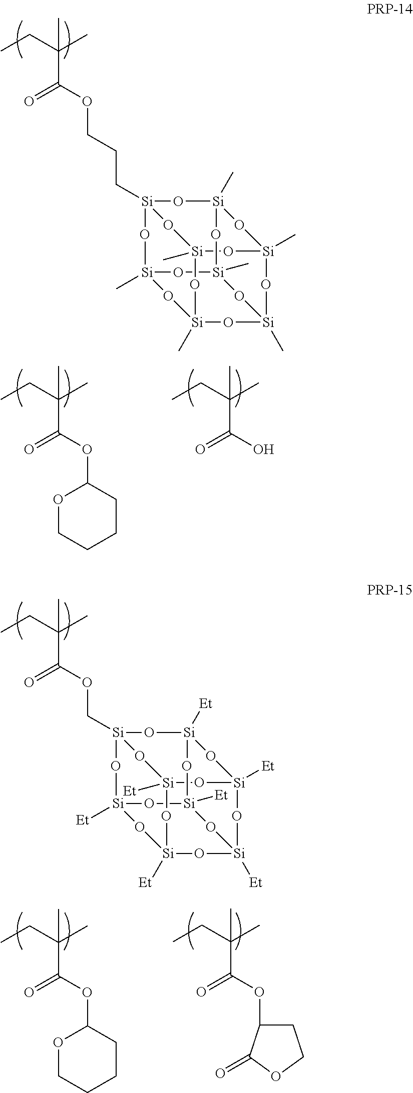

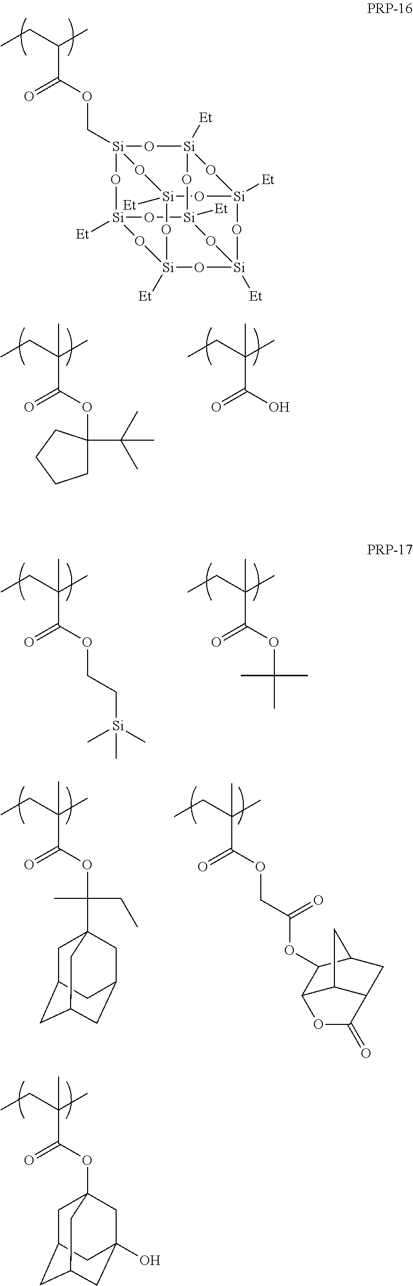

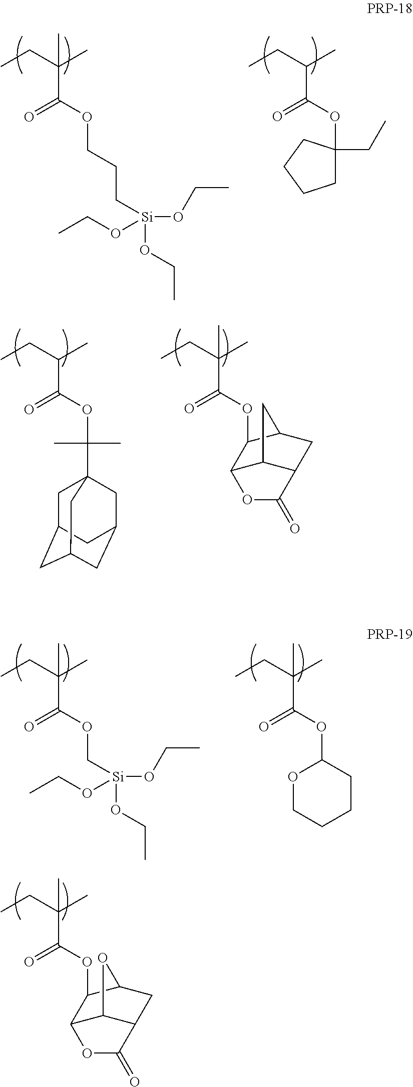

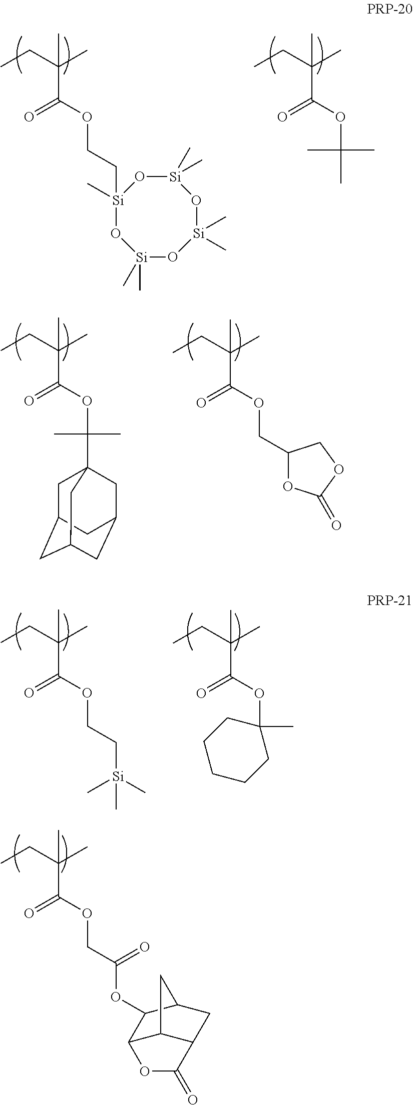

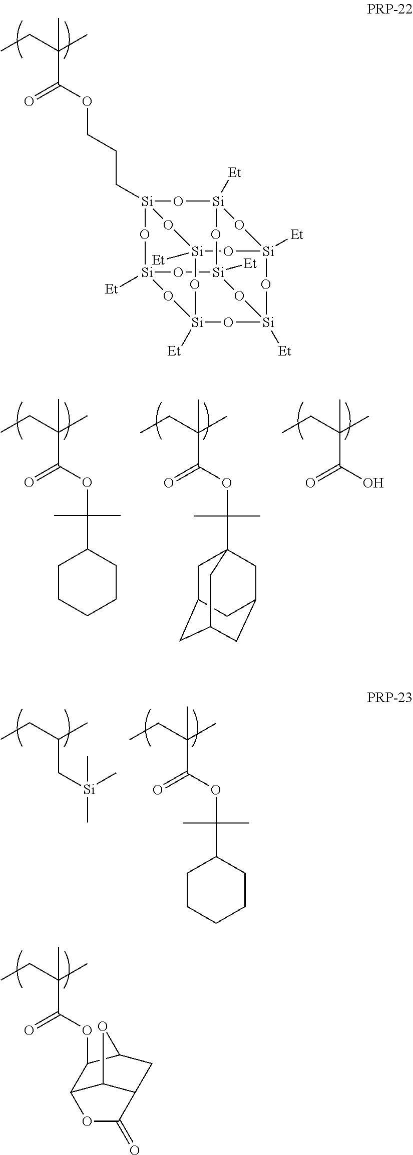

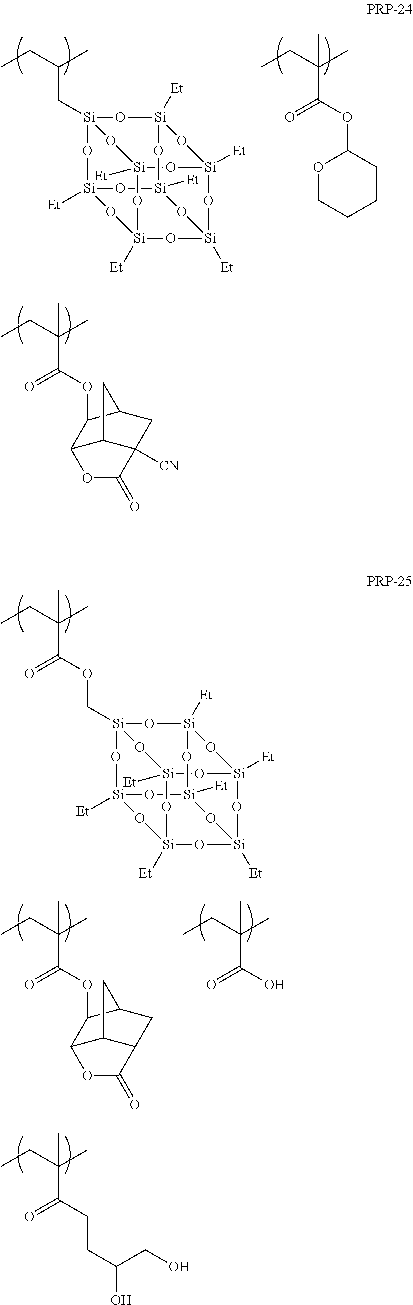

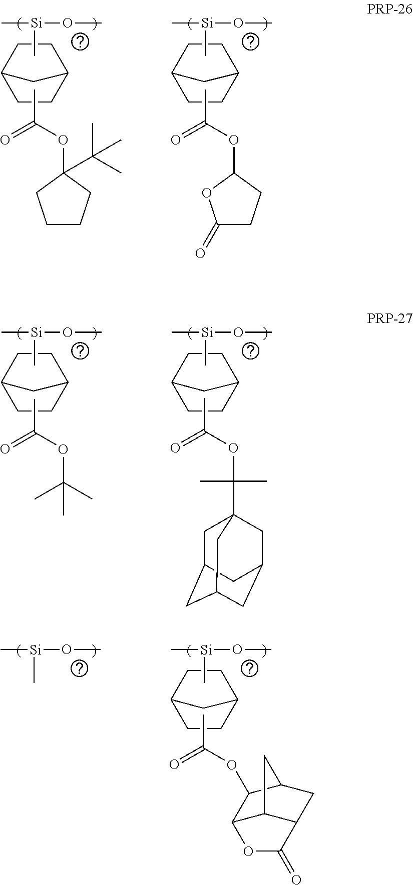

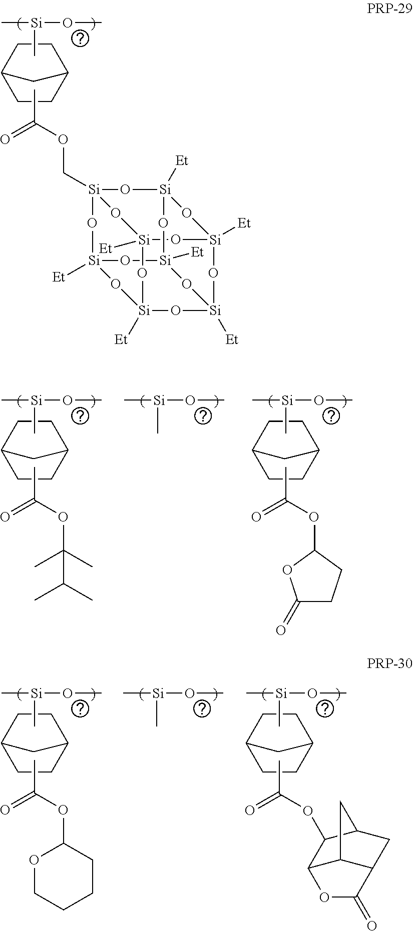

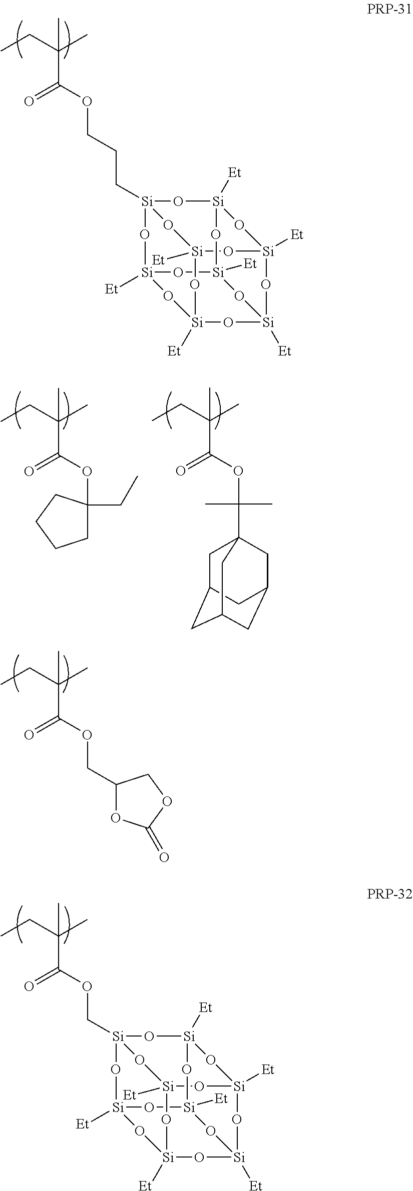

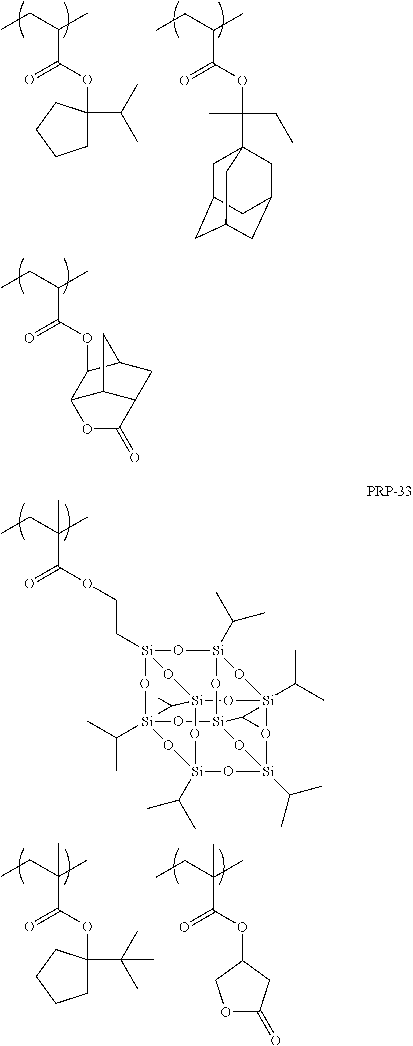

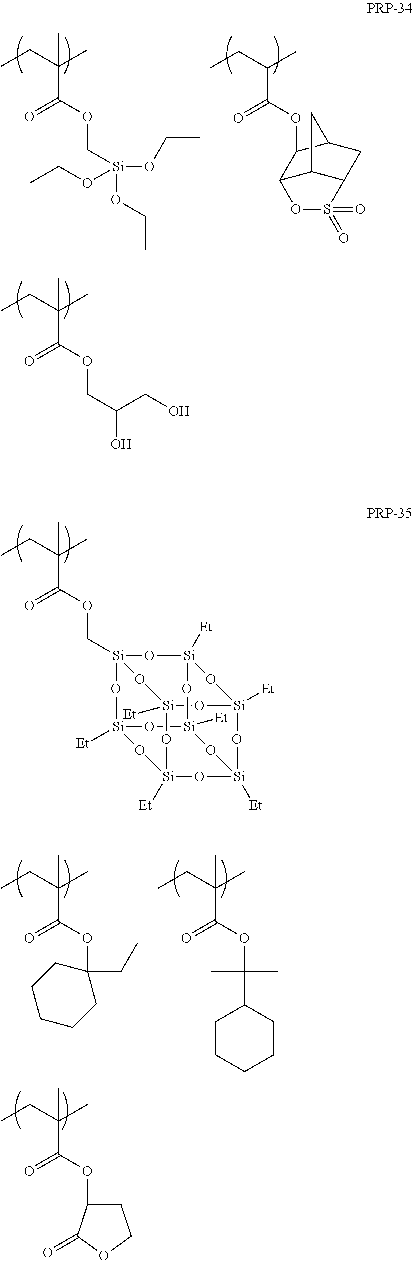

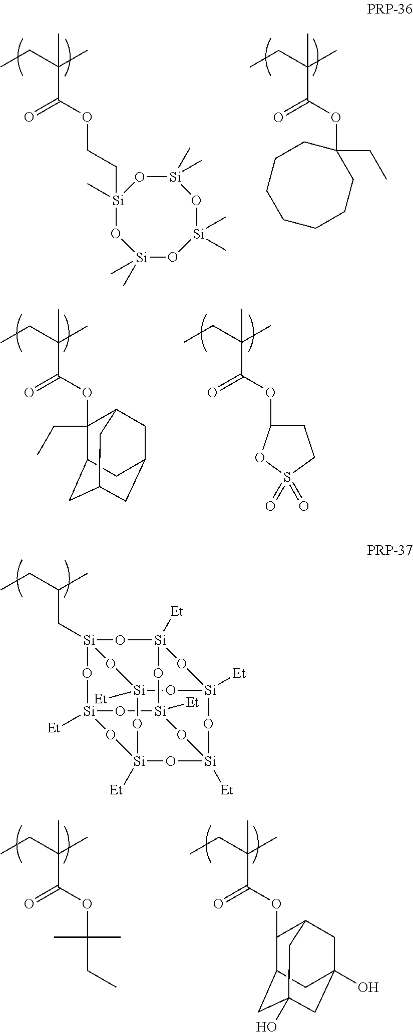

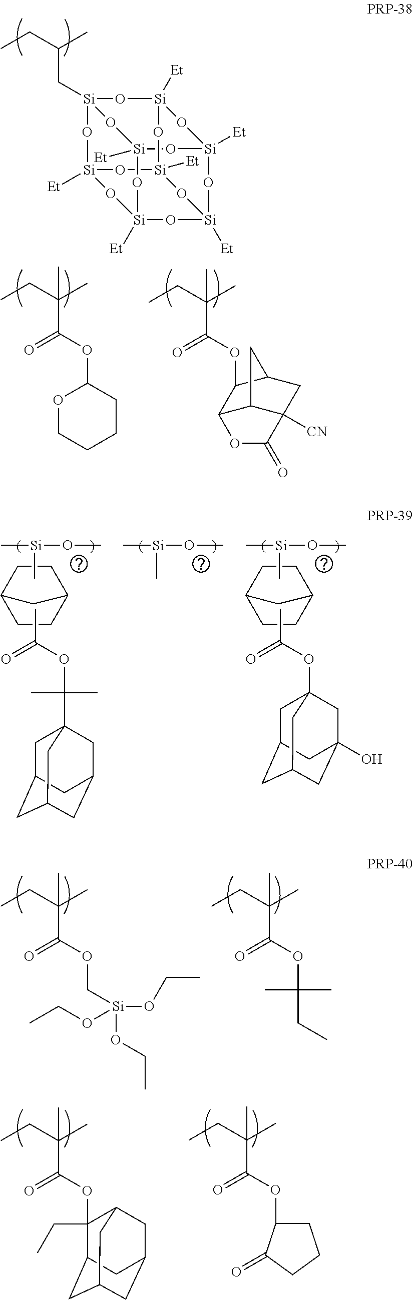

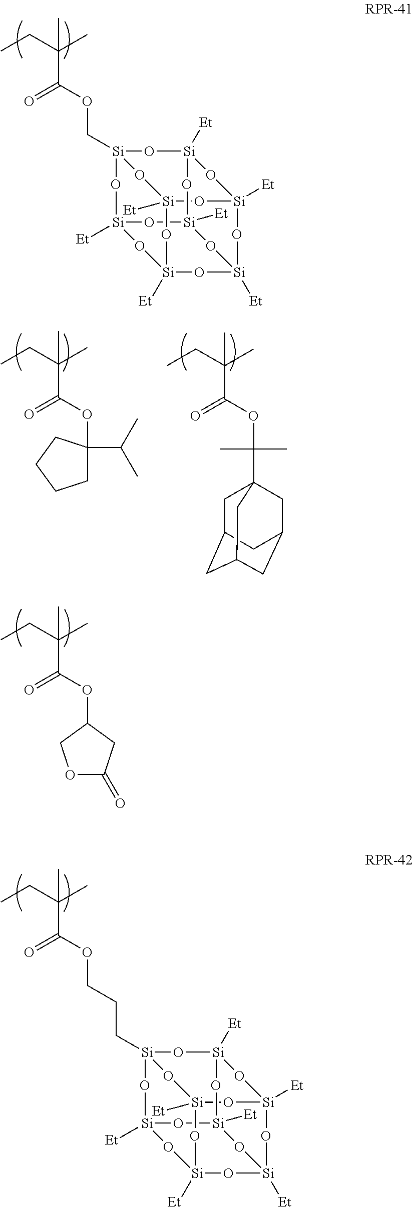

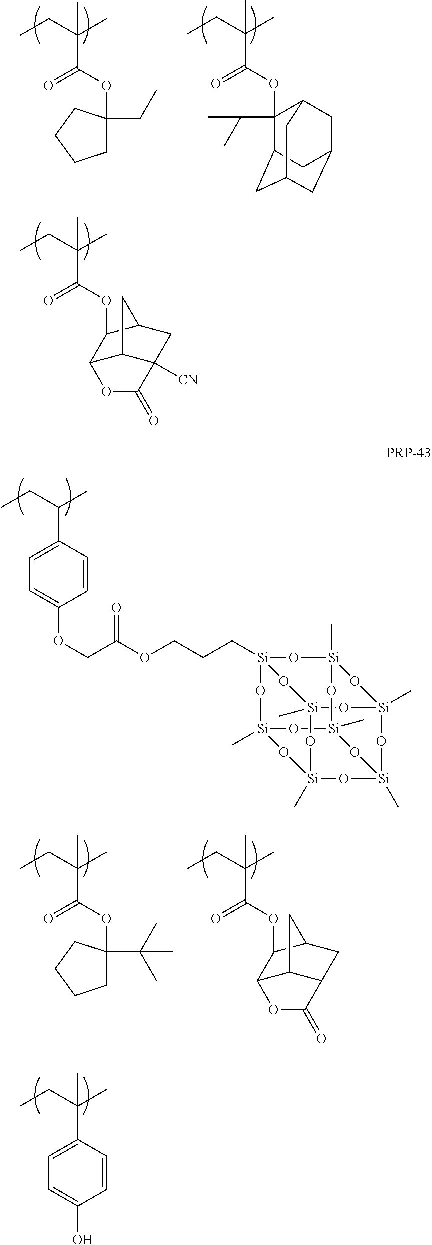

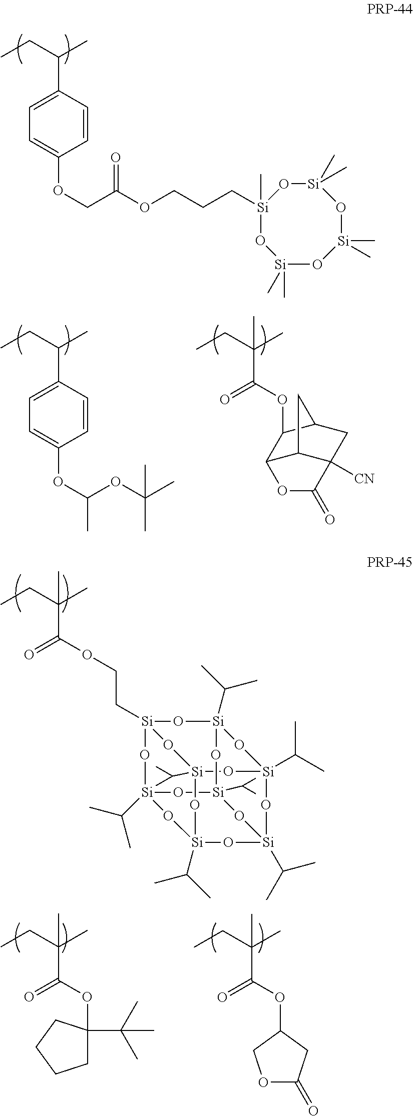

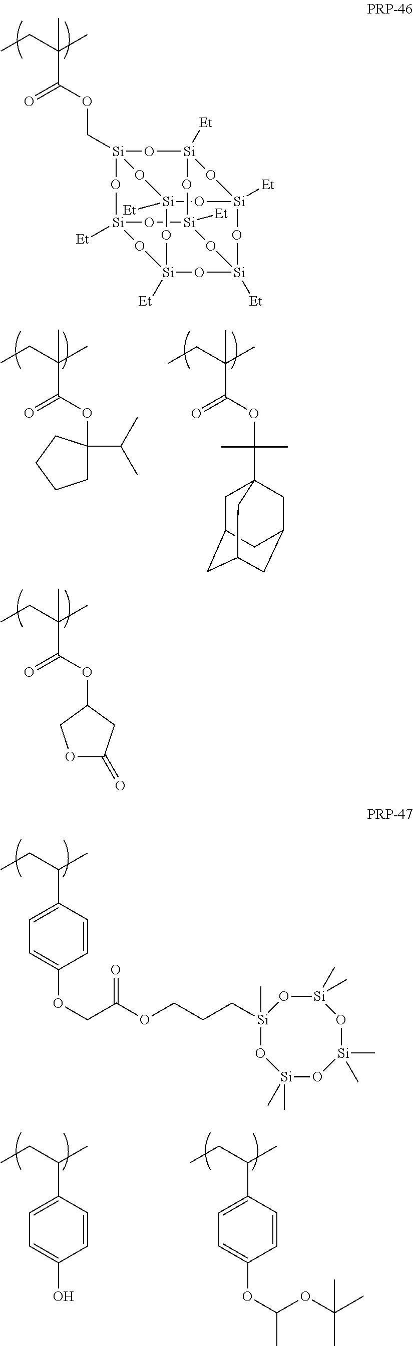

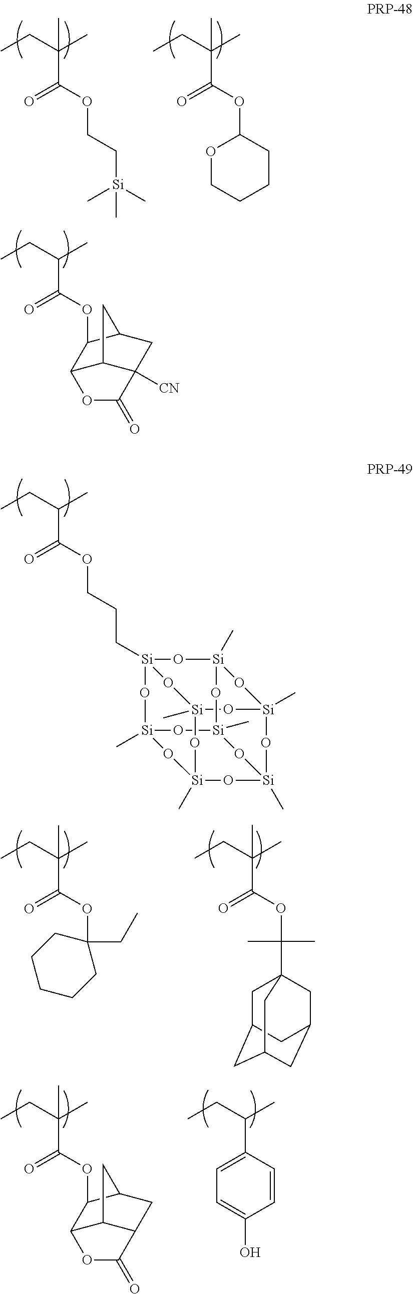

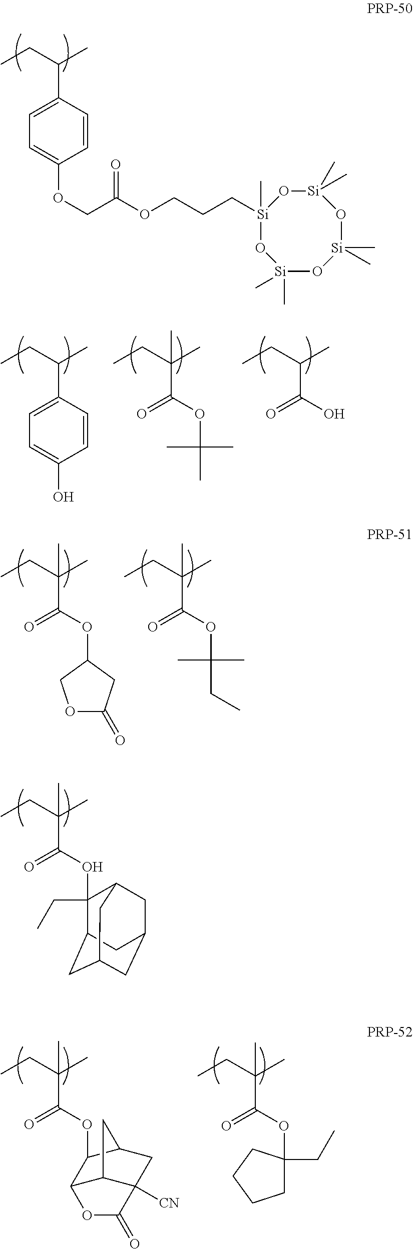

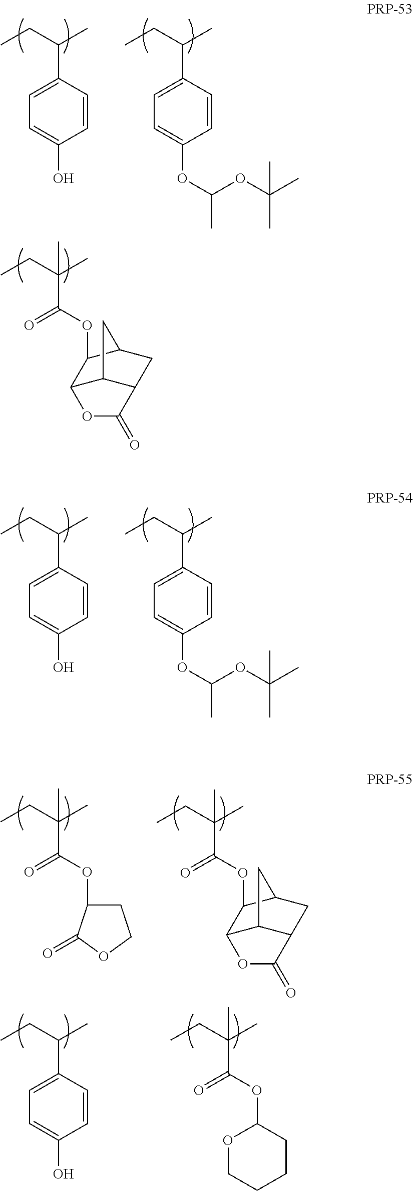

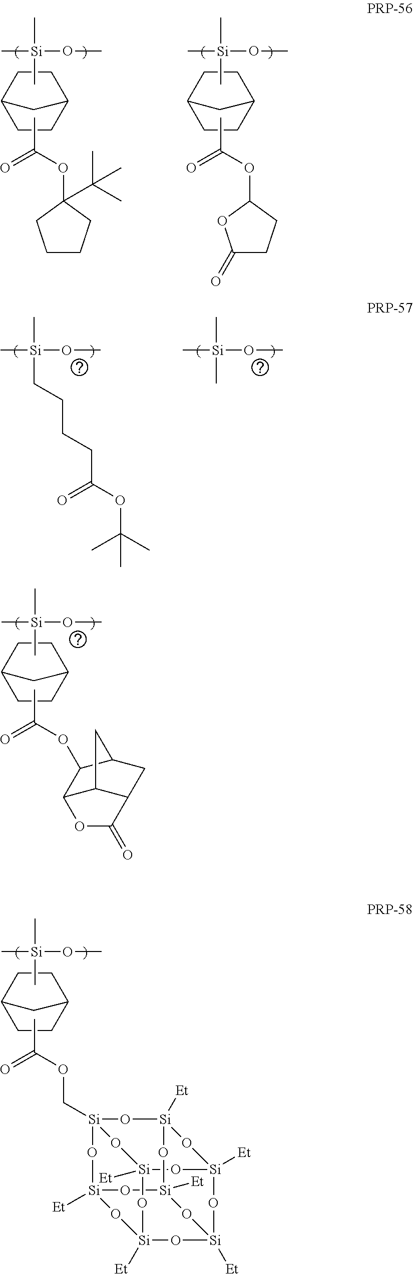

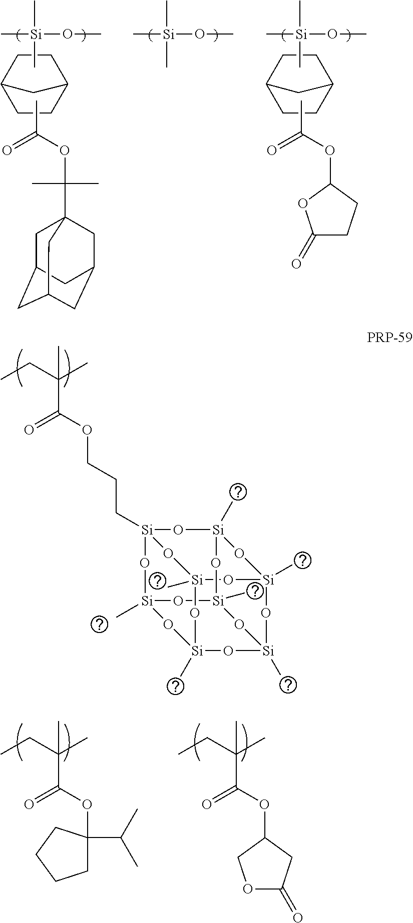

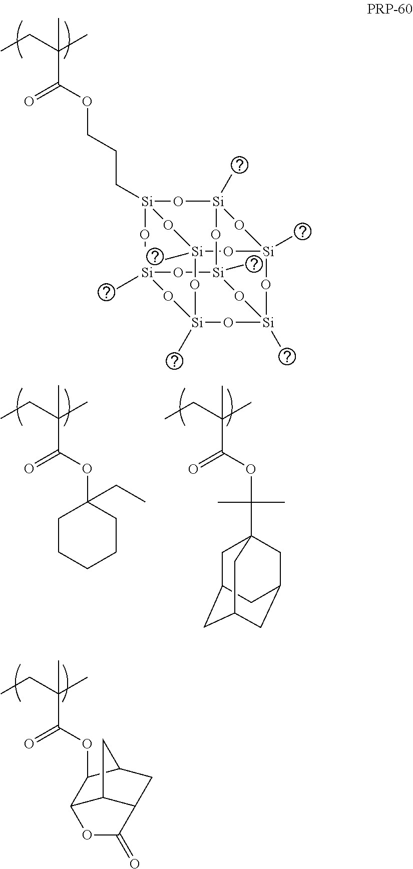

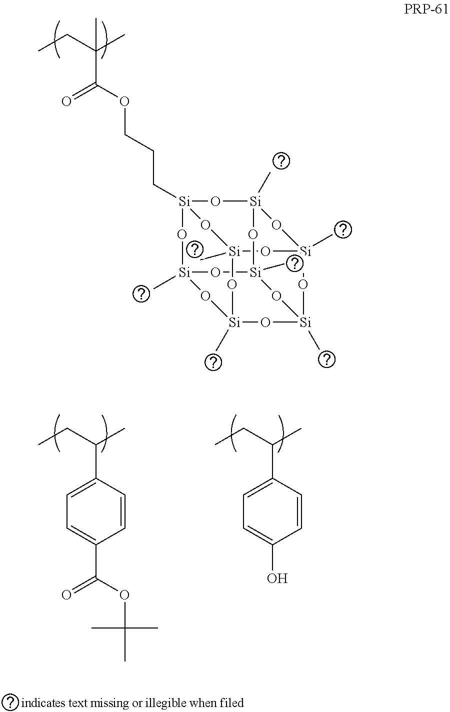

TABLE 1

| | | Weight- | | |
|---|---|---|---|---|
| | | average | | Content |
| | | molecular | | (% by mass) |
| | Compositional ratio | weight | Dispersity | of Si atoms |
| Resin | (molar ratio) | (Mw) | (Mw/Mn) | in resin |
| PRP-1 | 10/50/40 | 8,000 | 1.6 | 10.7 |
| PRP-2 | 5/70/25 | 12,000 | 1.6 | 5.9 |
| PRP-3 | 20/40/40 | 7,000 | 1.6 | 9.1 |
| PRP-4 | 30/40/10/20 | 20,000 | 1.9 | 3.7 |
| PRP-5 | 10/5/50/35 | 16,000 | 1.8 | 5.6 |
| PRP-6 | 10/40/50 | 10,000 | 1.6 | 9.7 |
| PRP-7 | 8/52/30/10 | 14,000 | 1.7 | 7.8 |
| PRP-8 | 5/30/30/35 | 9,000 | 1.6 | 5.1 |
| PRP-9 | 40/20/20/20 | 8,000 | 1.6 | 6.1 |
| PRP-10 | 20/40/20/20 | 7,000 | 1.6 | 10.2 |
| PRP-11 | 8/40/12/40 | 14,000 | 1.7 | 7.6 |
| PRP-12 | 35/10/35/20 | 8,000 | 1.6 | 4.8 |
| PRP-13 | 15/20/20/45 | 8,000 | 1.6 | 12.1 |
| PRP-14 | 10/60/30 | 10,000 | 1.6 | 11.7 |
| PRP-15 | 12/58/30 | 8,000 | 1.6 | 11.4 |
| PRP-16 | 20/50/30 | 20,000 | 1.9 | 16.5 |
| PRP-17 | 40/20/20/10/10 | 8,000 | 1.6 | 5.4 |
| PRP-18 | 30/20/25/25 | 14,000 | 1.7 | 3.5 |
| PRP-19 | 15/50/35 | 8,000 | 1.6 | 2.1 |
| PRP-20 | 15/20/20/45 | 10,000 | 1.6 | 7.5 |
| PRP-21 | 50/30/20 | 8,000 | 1.6 | 6.9 |
| PRP-22 | 4/30/30/36 | 14,000 | 1.7 | 4.4 |
| PRP-23 | 50/30/20 | 7,000 | 1.6 | 8.5 |
| PRP-24 | 15/50/35 | 10,000 | 1.6 | 12.4 |
| PRP-25 | 20/30/20/30 | 16,000 | 1.8 | 16.3 |
| PRP-26 | 50/50 | 6,000 | 1.5 | 8.6 |
| PRP-27 | 20/20/30/30 | 10,000 | 1.5 | 10.6 |
| PRP-29 | 3/47/10/40 | 3,000 | 1.4 | 11.6 |
| PRP-30 | 40/10/50 | 20,000 | 1.8 | 9.2 |
| PRP-31 | 4/26/40/30 | 10,000 | 1.6 | 3.8 |
| PRP-32 | 15/35/15/35 | 20,000 | 1.9 | 12.0 |
| PRP-33 | 4/46/50 | 10,000 | 1.6 | 4.2 |
| PRP-34 | 50/30/20 | 8,000 | 1.6 | 5.9 |
| PRP-35 | 10/30/20/40 | 14,000 | 1.7 | 9.3 |
| PRP-36 | 25/15/25/35 | 10,000 | 1.6 | 10.2 |
| PRP-37 | 10/70/20 | 10,000 | 1.6 | 9.9 |
| PRP-38 | 5/65/30 | 7,000 | 1.6 | 5.2 |
| PRP-39 | 50/25/25 | 10,000 | 1.6 | 10.0 |
| PRP-40 | 40/20/20/20 | 20,000 | 1.9 | 5.1 |
| PRP-41 | 10/40/10/40 | 10,000 | 1.6 | 9.2 |
| PRP-42 | 5/20/15/60 | 14,000 | 1.7 | 4.3 |
| PRP-43 | 8/42/30/20 | 20,000 | 1.9 | 7.5 |
| PRP-44 | 25/35/40 | 10,000 | 1.6 | 9.3 |
| PRP-45 | 5/50/45 | 10,000 | 1.6 | 5.0 |
| PRP-46 | 5/35/35/25 | 10,000 | 1.6 | 4.7 |
| PRP-47 | 20/30/50 | 7,000 | 1.6 | 9.1 |
| PRP-48 | 50/40/10 | 14,000 | 1.7 | 7.6 |
| PRP-49 | 15/20/20/20/25 | 10,000 | 1.6 | 12.8 |
| PRP-50 | 30/20/40/10 | 8,000 | 1.6 | 14.1 |
| PRP-51 | 40/40/20 | 10,000 | 1.6 | 0.0 |
| PRP-52 | 30/70 | 10,000 | 1.6 | 0.0 |
| PRP-53 | 30/40/30 | 14,000 | 1.7 | 0.0 |
| PRP-54 | 70/30 | 8,000 | 1.6 | 0.0 |
| PRP-55 | 20/30/10/40 | 10,000 | 1.6 | 0.0 |
| PRP-56 | 70/30 | 8,000 | 1.6 | 8.2 |
| PRP-57 | 40/10/50 | 20,000 | 1.8 | 10.4 |
| PRP-58 | 5/55/10/30 | 10,000 | 1.6 | 10.3 |
| PRP-59 | 4/46/50 | 10,000 | 1.6 | 5.5 |
| PRP-60 | 7.2/28.5/14.3/50 | 16,000 | 1.9 | 7.5 |
| PRP-61 | 10/45/45 | 8,000 | 1.5 | 10.4 |

<Preparation of Resin Composition>

The materials were mixed at the compositions shown in Tables 2, 3, and 4 to prepare an underlayer film material, a resist material, and a topcoat material, each of which was filtered through a polyethylene filter having a pore size of 0.03 μm to prepare a resin composition. In the following tables, (wt %) is a value with respect to the resin solid content of the composition. The concentration of the solid content of each resin composition was appropriately adjusted to a range from 2.0% to 8.0% by mass such that the composition could be applied at the film thickness shown in Tables 5 to 10.

TABLE 2

| Underlayer | | Crosslinking | Thermal acid | | |
|---|---|---|---|---|---|
| film material | Resin | agent | generator | Additive | Solvent |
| UL-1 | ULP-1 | CR-1 (15 wt %) | TAG-1 (3 wt %) | — | SL-1 = 100 |
| UL-2 | ULP-2 | CR-3 (10 wt %) | TAG-3 (3 wt %) | PBG-1 (1.5 wt %) | SL-1/SL-2 = 90/10 (mass ratio) |
| UL-3 | ULP-3 | CR-1 (15 wt %) | TAG-4 (1 wt %) | PAG-3 (2 wt %) | SL-1 = 100 |
| UL-4 | ULP-1 | CR-2 (7 wt %) | TAG-2 (3 wt %) | — | SL-1/SL-2 = 90/10 (mass ratio) |
| UL-5 | ULP-4 | CR-3 (20 wt %) | TAG-1 (1 wt %) | — | SL-1/SL-2 = 90/10 (mass ratio) |
| UL-6 | ULP-3 | CR-2 (10 wt %) | TAG-2 (0.5 wt %) | PAG-1 (1 wt %) | SL-1/SL-3 = 70/30 (mass ratio) |
| UL-7 | ULP-5 | CR-1 (20 wt %) | TAG-4 (1 wt %) | PBG-1 (1 wt %) | SL-1/SL-5 = 70/30 (mass ratio) |
| UL-8 | ULP-6 | CR-1 (15 wt %) | TAG-1 (3 wt %) | W-1 (0.01 wt %) | SL-1/SL-2 = 90/10 (mass ratio) |
| UL-9 | ULP-7 | CR-3 (10 wt %) | TAG-3 (3 wt %) | W-1 (0.01 wt %) | SL-1/SL-2 = 90/10 (mass ratio) |
| UL-10 | ULP-8 | CR-1 (10 wt %) | TAG-4 (1 wt %) | W-2 (0.01 wt %) | SL-1/SL-2 = 90/10 (mass ratio) |
| UL-11 | ULP-9 | CR-2 (15 wt %) | TAG-2 (3 wt %) | W-1 (0.01 wt %) | SL-1/SL-2 = 90/10 (mass ratio) |
| UL-12 | ULP-10 | CR-3 (10 wt %) | TAG-1 (1 wt %) | W-3 (0.01 wt %) | SL-1/SL-2 = 90/10 (mass ratio) |
| UL-13 | ULP-11 | CR-4 (10 wt %) | TAG-2 (0.5 wt %) | W-3 (0.01 wt %) | SL-1/SL-2/SL-4 = 80/10/10 (mass ratio) |
| UL-14 | ULP-12 | CR-5 (10 wt %) | TAG-4 (1 wt %) | W-1 (0.01 wt %) | SL-1/SL-2 = 90/10 (mass ratio) |
| UL-15 | ULP-13 | CR-6 (11 wt %) | TAG-1 (3 wt %) | W-2 (0.01 wt %) | SL-1/SL-2 = 90/10 (mass ratio) |
| UL-16 | ULP-14 | CR-5 (10 wt %) | TAG-4 (1 wt %) | W-2 (0.01 wt %) | SL-1/SL-3/SL-4 = 80/10/10 (mass ratio) |
| UL-17 | ULP-15 | CR-6 (11 wt %) | TAG-1 (3 wt %) | W-1 (0.01 wt %) | SL-1/SL-2 = 90/10 (mass ratio) |
| UL-18 | ULP-16 | CR-3 (10 wt %) | TAG-3 (3 wt %) | W-1 (0.01 wt %) | SL-1/SL-3 = 70/30 (mass ratio) |
| UL-19 | ULP-17 | CR-1 (15 wt %) | TAG-4 (1 wt %) | W-1 (0.01 wt %) | SL-1/SL-3 = 70/30 (mass ratio) |
| UL-20 | IN-01 | CR-2 (7 wt %) | TAG-2 (3 wt %) | W-1 (0.01 wt %) | SL-1/SL-2 = 90/10 (mass ratio) |
| UL-21 | PBO-01 | CR-4 (10 wt %) | TAG-1 (1 wt %) | W-1 (0.01 wt %) | SL-1/SL-3 = 70/30 (mass ratio) |
| UL-22 | PI-01 | CR-2 (10 wt %) | TAG-2 (0.5 wt %) | W-1 (0.01 wt %) | SL-1/SL-3 = 70/30 (mass ratio) |
| UL-23 | AN-01 | CR-1 (20 wt %) | TAG-4 (1 wt %) | W-1 (0.01 wt %) | SL-1/SL-2 = 90/10 (mass ratio) |
| UL-24 | AN-02 | CR-4 (10 wt %) | TAG-4 (1 wt %) | W-1 (0.01 wt %) | SL-1/SL-2 = 90/10 (mass ratio) |
| ULR-01 | ULP-18 | CR-1 (20 wt %) | TAG-4 (1 wt %) | W-3 (0.01 wt %) | SL-1/SL-2 = 90/10 (mass ratio) |

TABLE 3

| Resist | | | Acid diffusion | |
|---|---|---|---|---|
| composition | Resin | Photoacid generator | control agent | Additive |
| PR-1 | PRP-1 | PAG-1 (6 wt %) | PDB-1 (3 wt %) | — |
| PR-2 | PRP-2 | PAG-1 (8 wt %)/PAG-7 (4 wt %) | PDB-1 (2 wt %) | — |
| PR-3 | PRP-3 | PAG-4 (12 wt %) | Q-1 (0.5 wt %) | AD-1 (2 wt %) |
| PR-4 | PRP-4 | PAG-2 (10 wt %) | PDB-1 (1 wt %) | — |
| PR-5 | PRP-5 | PAG-1 (8 wt %) | PDB-1 (1.5 wt %) | — |
| PR-6 | PRP-6 | PAG-13 (12 wt %) | PDB-2 (2 wt %) | — |
| PR-7 | PRP-7 | PAG-5 (16 wt %) | Q-3 (1 wt %) | AD-2 (2 wt %) |
| PR-8 | PRP-8 | PAG-1 (8 wt %)/PAG-6 (4 wt %) | Q-2 (0.8 wt %) | — |
| PR-9 | PRP-9 | PAG-7 (20 wt %) | Q-2 (1.5 wt %) | — |
| PR-10 | PRP-10 | PAG-2 (6 wt %)/PAG-6 (2 wt %) | PDB-1 (1 wt %)/Q-1 | — |
| | | | (0.3 wt %) | |
| PR-11 | PRP-11 | PAG-1 (12 wt %)/PAG-3 (4 wt %) | PDB-1 (3 wt %) | — |
| PR-12 | PRP-12 | PAG-1 (16 wt %) | PDB-1 (3 wt %) | — |
| PR-13 | PRP-13 | PAG-13 (8 wt %)/PAG-8 (4 wt %) | Q-1 (0.5 wt %) | — |
| PR-14 | PRP-14 | PAG-5 (8 wt %)/PAG-6 (4 wt %) | PDB-1 (3 wt %) | — |
| PR-15 | PRP-15 | PAG-4 (4 wt %)/PAG-3 (12 wt %) | PDB-1 (3 wt %) | — |
| PR-16 | PRP-16 | PAG-2 (4 wt %)/PAG-10 (8 wt %) | PDB-1 (3 wt %) | — |
| PR-17 | PRP-17 | PAG-4 (4 wt %)/PAG-10 (12 wt %) | Q-2 (08 wt %) | — |
| PR-18 | PRP-18 | PAG-4 (4 wt %)/PAG-3 (4 wt %) | Q-2 (0.8 wt %) | AD-2 (3 wt %) |
| PR-19 | PRP-19 | PAG-2 (4 wt %)/PAG-4 (4 wt %) | PDB-1 (3 wt %) | — |
| PR-20 | PRP-20 | PAG-1 (4 wt %)/PAG-7 (12 wt %) | PDB-1 (3 wt %) | — |
| PR-21 | PRP-21 | PAG-4 (6 wt %) | PDB-1 (1 wt %) | — |
| PR-22 | PRP-22 | PAG-10 (10 wt %) | Q-2 (1 wt %)/Q-1 | — |
| | | | (0.3 wt %) | |
| PR-23 | PRP-23 | PAG-5 (6 wt %) | PDB-1 (1 wt %) | — |
| PR-24 | PRP-24 | PAG-3 (25 wt %) | Q-1 (1.5 wt %) | — |
| PR-25 | PRP-25 | PAG-1 (16 wt %) | PDB-1 (3 wt %) | — |
| PR-26 | PRP-26 | PAG-2 (13 wt %)/PAG-7 (3 wt %) | PDB-1 (3 wt %) | AD-1 (2 wt %) |
| PR-27 | PRP-27 | PAG-4 (16 wt %) | PDB-1 (3 wt %) | — |
| PR-28 | PRP-31/PRP-51 = | PAG-5 (4 wt %) | PDB-2 (0.4 wt %) | — |
| | 1/1 (mass ratio) | | | |
| PR-29 | PRP-29 | PAG-7 (16 wt %) | Q-3 (1 wt %) | — |
| PR-30 | PRP-30 | PAG-10 (1 wt %)/PAG-3 (7 wt %) | PDB-1 (1 wt %) | — |
| PR-31 | PRP-31 | PAG-10 (8 wt %) | Q-1 (1 wt %) | — |
| PR-32 | PRP-32 | PAG-2 (8 wt %)/PAG-3 (8 wt %) | PDB-1 (3 wt %) | — |
| PR-33 | PRP-33 | PAG-12 (10 wt %) | PDB-1 (1 wt %) | AD-1 (1 wt %) |
| PR-34 | PRP-34 | PAG-4 (2 wt %)/PAG-6 (10 wt %) | Q-2 (0.4 wt %) | — |
| PR-35 | PRP-35 | PAG-4 (4 wt %) | PDB-1 (0.5 wt %) | — |
| PR-36 | PRP-36 | PAG-10 (6 wt %)/PAG-7 (10 wt %) | PDB-1 (3 wt %) | — |
| PR-37 | PRP-37 | PAG-1 (2 wt %) | PDB-2 (0.2 wt %) | — |
| PR-38 | PRP-38 | PAG-2 (8 wt %)/PAG-6 (8 wt %) | PDB-1 (3 wt %) | — |
| PR-39 | PRP-39 | PAG-4 (2 wt %) | Q-1 (0.05 wt %) | AD-2 (4 wt %) |
| PR-40 | PRP-40 | PAG-11 (0.5 wt %)/PAG-4 (1.5 wt | PDB-2 (0.2 wt %) | — |
| | | %) | | |
| PR-41 | PRP-41 | PAG-12 (4 wt %) | PDB-1 (0.5 wt %) | — |
| PR-42 | PRP-42 | PAG-9 (4 wt %)/PAG-3 (4 wt %) | PDB-1 (1 wt %) | — |
| PR-43 | PRP-43 | PAG-5 (4 wt %) | Q-2 (0.4 wt %) | — |
| PR-44 | PRP-44 | PAG-1 (10 wt %)/PAG-7 (6 wt %) | PDB-1 (3 wt %) | AD-1 (1 wt %) |
| PR-45 | PRP-45 | PAG-1 (2 wt %) | PDB-1 (0.4 wt %) | — |
| PR-46 | PRP-46 | PAG-2 (8 wt %)/PAG-4 (8 wt %) | PDB-1 (3 wt %) | — |
| PR-47 | PRP-47 | PAG-2 (16 wt %) | PDB-1 (3 wt %) | AD-2 (4 wt %) |
| PR-48 | PRP-48 | PAG-11 (15 wt %)/PAG-7 (5 wt %) | PDB-1 (5 wt %) | — |
| PR-49 | PRP-49 | PAG-4 (16 wt %) | PDB-2 (2 wt %) | — |
| PR-50 | PRP-50 | PAG-12 (12 wt %) | Q-3 (1 wt %) | — |
| PR-51 | PRP-51 | PAG-2 (13 wt %)/PAG-7 (3 wt %) | PDB-1 (3 wt %) | — |
| PR-52 | PRP-52 | PAG-4 (4 wt %) | PDB-1 (0.5 wt %) | — |
| PR-53 | PRP-53 | PAG-12 (3 wt %) | Q-3 (02 wt %) | — |
| PR-54 | PRP-54 | PAG-2 (8 wt %)/PAG-4 (8 wt %) | PDB-1 (3 wt %) | — |
| PR-55 | PRP-55 | PAG-11 (15 wt %)/PAG-7 (5 wt %) | PDB-1 (5 wt %) | — |
| PR-56 | PRP-56 | PAG-1 (8 wt %) | Q-1 (0.5 wt %) | — |
| PR-57 | PRP-57 | PAG-2 (13 wt %)/PAG-7 (3 wt %) | PDB-1 (3 wt %) | AD-1 (2 wt %) |
| PR-58 | PRP-58 | PAG-4 (16 wt %) | PDB-1 (3 wt %) | — |
| PR-59 | PRP-59 | PAG-3 (3 wt %)/PAG-13 (1 wt %) | PDB-1 (3 wt %) | AD-3 (5 wt %) |
| PR-60 | PRP-60 | PAG-1 (2 wt %)/PAG-7 (11 wt %) | PDB-1 (1 wt %)/Q-1 | — |
| | | | (1 wt %) | |
| PR-61 | PRP-61 | PAG-4 (16 wt %) | PDB-2 (2 wt %) | — |

| Resist | | Crosslinking | | |
|---|---|---|---|---|
| composition | Hydrophobic resin | agent | Surfactant | Solvent |
| PR-1 | — | — | W-1 (0.3 wt | SL-1 = 100 |
| | | | %) | |
| PR-2 | ADP-1 (1 wt %) | — | — | SL-1 = 100 |
| PR-3 | — | — | — | SL-1 = 100 |
| PR-4 | — | — | — | SL-1/SL-2 = 90/10 (mass ratio) |
| PR-5 | ADP-2 (0.4 wt %) | — | — | SL-1 = 100 |
| PR-6 | — | CR-1 (10 wt | W-1 (0.3 wt | SL-1 = 100 |
| | | %) | %) | |
| PR-7 | — | — | W-1 (0.3 wt | SL-1 = 100 |
| | | | %) | |
| PR-8 | TCP-2 (2 wt %) | — | — | SL-1/SL-3 = 80/20 (mass ratio) |
| PR-9 | — | — | — | SL-1/SL-3 = 80/20 (mass ratio) |
| PR-10 | — | — | — | SL-1/SL-2 = 90/10 (mass ratio) |
| PR-11 | — | — | — | SL-1/SL-2 = 90/10 (mass ratio) |
| PR-12 | ADP-1 (0.5 wt %) | — | — | SL-1/SL-2 = 90/10 (mass ratio) |
| PR-13 | ADP-1 (2 wt %) | — | W-2 (0.5 wt | SL-1/SL-2 = 70/30 (mass ratio) |
| | | | %) | |
| PR-14 | — | — | W-3 (0.3 wt | SL-1/SL-2 = 90/10 (mass ratio) |
| | | | %) | |
| PR-15 | — | — | — | SL-1/SL-2 = 80/20 (mass ratio) |
| PR-16 | TCP-1 (4 wt %) | — | — | SL-1/SL-4 = 95/5 (mass ratio) |
| PR-17 | — | — | — | SL-1/SL-4 = 90/10 (mass ratio) |
| PR-18 | ADP-2 (2 wt %) | — | — | SL-1/SL-5 = 70/30 (mass ratio) |
| PR-19 | — | — | W-1 (0.3 wt | SL-1/SL-5 = 80/20 (mass ratio) |
| | | | %) | |
| PR-20 | ADP-2 (0.5 wt %) | — | — | SL-1 = 100 |
| PR-21 | — | — | — | SL-1 = 100 |
| PR-22 | — | — | — | SL-1 = 100 |
| PR-23 | ADP-1 (0.5 wt | — | W-2 (0.5 wt | SL-1/SL-2 = 90/10 (mass ratio) |
| | %)/TCP-2 (4 wt %) | | %) | |
| PR-24 | — | — | — | SL-1/SL-2 = 90/10 (mass ratio) |
| PR-25 | ADP-1 (0.5 wt %) | CR-2 (20 wt | — | SL-1 = 100 |
| | | %) | | |
| PR-26 | — | — | — | SL-1 = 100 |
| PR-27 | ADP-1 (0.5 wt %) | — | — | SL-1 = 100 |
| PR-28 | — | — | — | SL-1/SL-2 = 90/10 (mass ratio) |
| PR-29 | — | — | W-1 (0.3 wt | SL-1/SL-2 = 90/10 (mass ratio) |
| | | | %) | |
| PR-30 | ADP-1 (0.3 wt %) | — | — | SL-1/SL-2 = 90/10 (mass ratio) |
| PR-31 | — | — | — | SL-1 = 100 |
| PR-32 | — | — | — | SL-1 = 100 |
| PR-33 | TCP-2 (4 wt %) | — | — | SL-1 = 100 |
| PR-34 | — | CR-1 (20 wt | — | SL-1 = 100 |
| | | %) | | |
| PR-35 | ADP-2 (1 wt %) | — | — | SL-1/SL-2 = 90/10 (mass ratio) |
| PR-36 | — | — | — | SL-1/SL-2 = 90/10 (mass ratio) |
| PR-37 | — | — | — | SL-1/SL-2 = 90/10 (mass ratio) |
| PR-38 | — | — | — | SL-1 = 100 |
| PR-39 | TCP-2 (2 wt %) | — | — | SL-1 = 100 |
| PR-40 | — | — | W-1 (0.3 wt | SL-1 = 100 |
| | | | %) | |
| PR-41 | — | CR-1 (20 wt | — | SL-1 = 100 |
| | | %) | | |
| PR-42 | — | — | — | SL-1/SL-2 = 90/10 (mass ratio) |
| PR-43 | — | — | — | SL-1/SL-3 = 80/20 (mass ratio) |
| PR-44 | ADP-1 (0.3 wt %) | — | W-3 (0.3 wt | SL-1 = 100 |
| | | | %) | |
| PR-45 | — | CR-1 (15 wt | — | SL-1/SL-2 = 90/10 (mass ratio) |
| | | %) | | |
| PR-46 | — | — | — | SL-1/SL-3 = 70/30 (mass ratio) |
| PR-47 | — | — | — | SL-1 = 100 |
| PR-48 | — | — | — | SL-1/SL-2 = 90/10 (mass ratio) |
| PR-49 | — | — | W-1 (0.3 wt | SL-1/SL-3 = 70/30 (mass ratio) |
| | | | %) | |
| PR-50 | — | — | — | SL-1 = 100 |
| PR-51 | ADP-1 (0.3 wt %) | — | W-2 (0.5 wt | SL-1 = 100 |
| | | | %) | |
| PR-52 | — | — | W-1 (0.3 wt | SL-1/SL-2 = 90/10 (mass ratio) |
| | | | %) | |
| PR-53 | — | — | W-1 (0.1 wt | SL-1/SL-2 = 90/10 (mass ratio) |
| | | | %) | |
| PR-54 | — | — | — | SL-1/SL-3 = 70/30 (mass ratio) |
| PR-55 | — | — | — | SL-1/SL-2 = 90/10 (mass ratio) |
| PR-56 | ADP-1 (0.5 wt %) | — | — | SL-1/SL-2 = 90/10 (mass ratio) |
| PR-57 | — | — | — | SL-1 = 100 |
| PR-58 | ADP-1 (0.5 wt %) | — | — | SL-1 = 100 |
| PR-59 | — | — | W-1 (0.3 wt | SL-1/SL-3 = 70/30 (mass ratio) |
| | | | %) | |
| PR-60 | ADP-1 (1 wt %) | — | — | SL-1/SL-2 = 90/10 (mass ratio) |
| PR-61 | — | — | — | SL-1 = 100 |

TABLE 4

| Topcoat | | | |
|---|---|---|---|
| compo- | | | |
| sition | Resin | Additive | Solvent |
| TC-1 | TCP-2 | AD-3 (2 wt %)/ | SL-6/SL-8 = 80/20 (mass ratio) |
| | | AD-2 (1 wt %) | |
| TC-2 | TCP-1 | AD-3 (5 wt %) | SL-7/SL-9 = 50/50 (mass ratio) |
| TC-3 | TCP-1 | AD-3 (2 wt %)/ | SL-6/SL-8 = 80/20 (mass ratio) |
| | | Q-2 (1 wt %) | |
| TC-4 | TCP-2 | AD-3 (3 wt %)/ | SL-7/SL-9 = 50/50 (mass ratio) |
| | | PAG-2 (2 wt %) | |
| TC-5 | TCP-2 | AD-1 (5 wt %)/ | SL-6/SL-8 = 50/50 (mass ratio) |
| | | Q-3 (1 wt %) | |
| TC-6 | TCP-1 | AD-3 (5 wt %) | SL-6/SL-8 = 50/50 (mass ratio) |
| TC-7 | TCP-1 | AD-1 (5 wt %) | SL-6/SL-8 = 90/10 (mass ratio) |
| TC-8 | TCP-1 | AD-3 (5 wt %) | SL-6/SL-8 = 20/80 (mass ratio) |
| TC-9 | TCP-3 | AD-3 (5 wt %) | SL-7/SL-9 = 30/70 (mass ratio) |
| TC-10 | TCP-3 | Q-2 (0.5 wt %) | SL-6/SL-8 = 80/20 (mass ratio) |
| TC-11 | TCP-3 | AD-2 (2 wt %) | SL-6/SL-8 = 50/50 (mass ratio) |
| TC-12 | TCP-3 | AD-3 (15 wt %) | SL-8 = 100 |
| TC-13 | TCP-1 | AD-4 (1 wt %) | SL-6/SL-8 = 50/50 (mass ratio) |
| TC-14 | TCP-2 | AD-1 (8 wt %) | SL-8 = 100 |

The abbreviations in the trademarks are as follows. Further, the compositional ratios of the respective repeating units of the resin are expressed in molar ratios.

<Photoacid Generator>

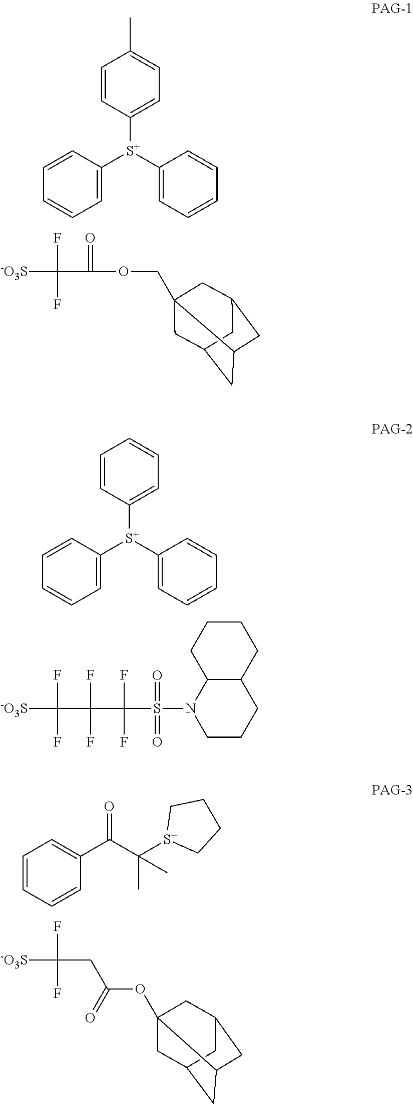

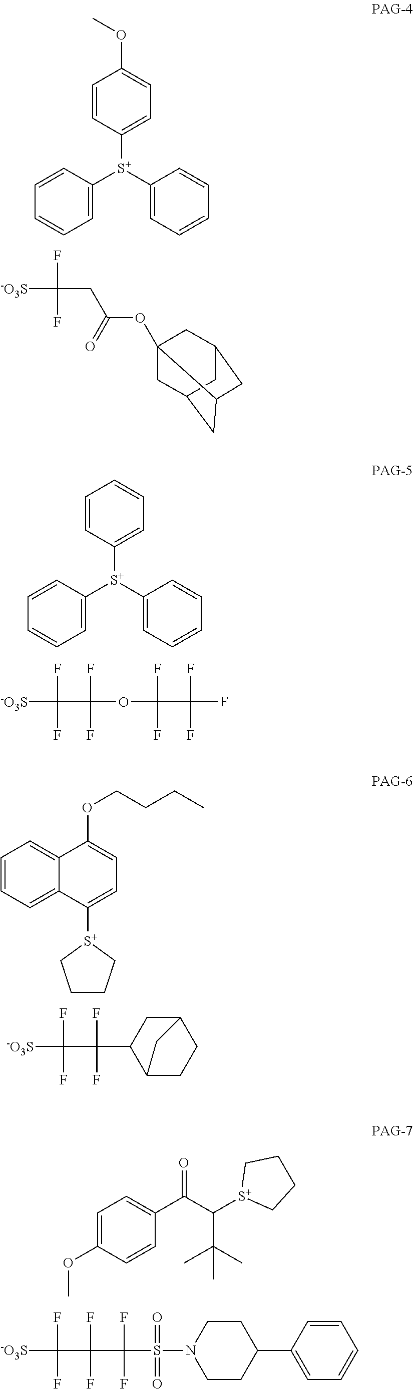

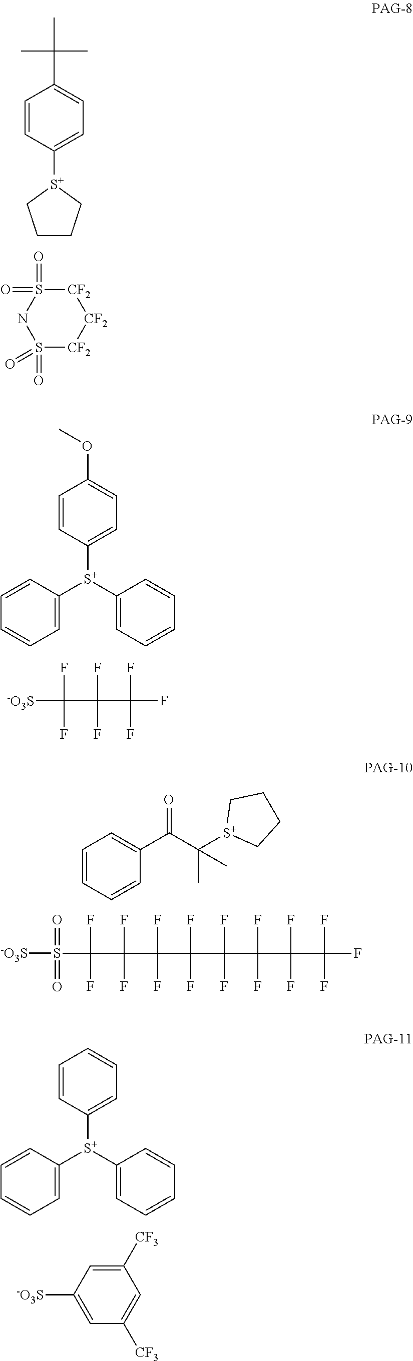

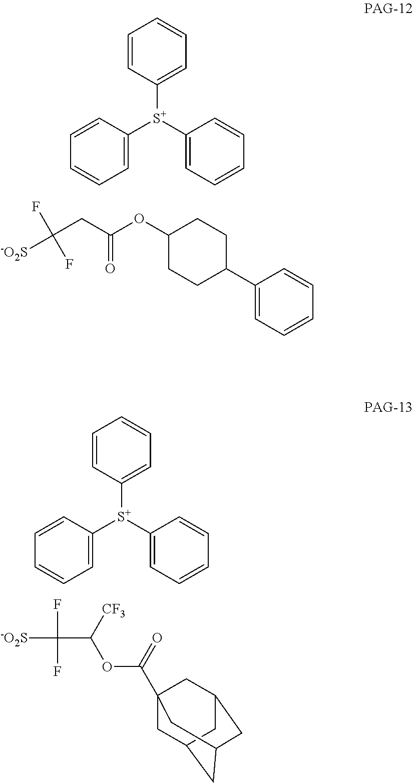

<Thermal Acid Generator>

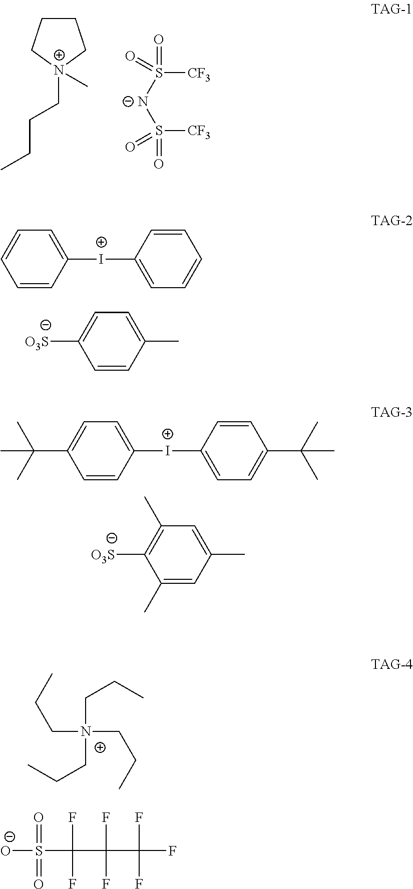

<Acid Diffusion Control Agent>

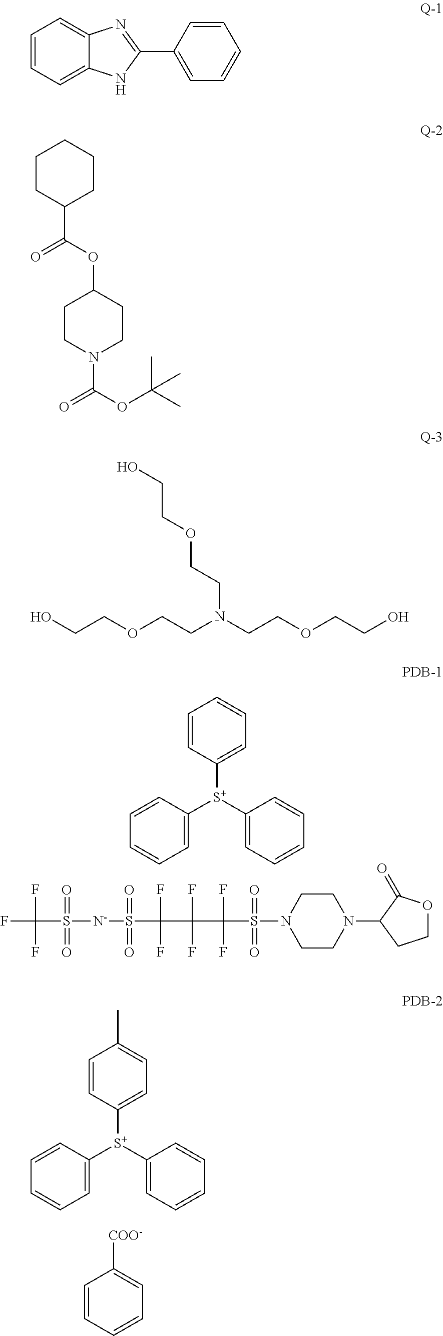

<Additive>

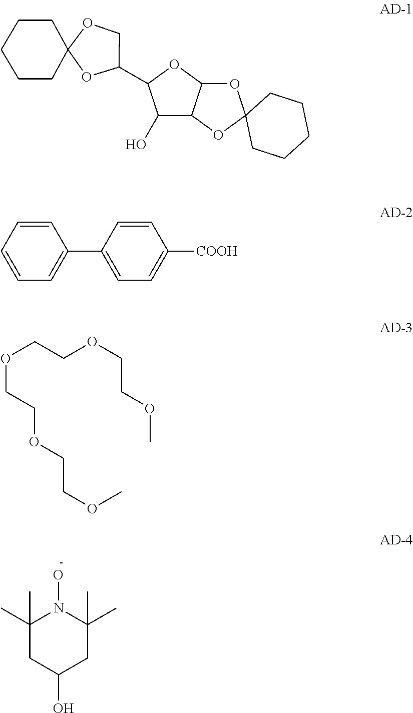

<Hydrophobic Resin>

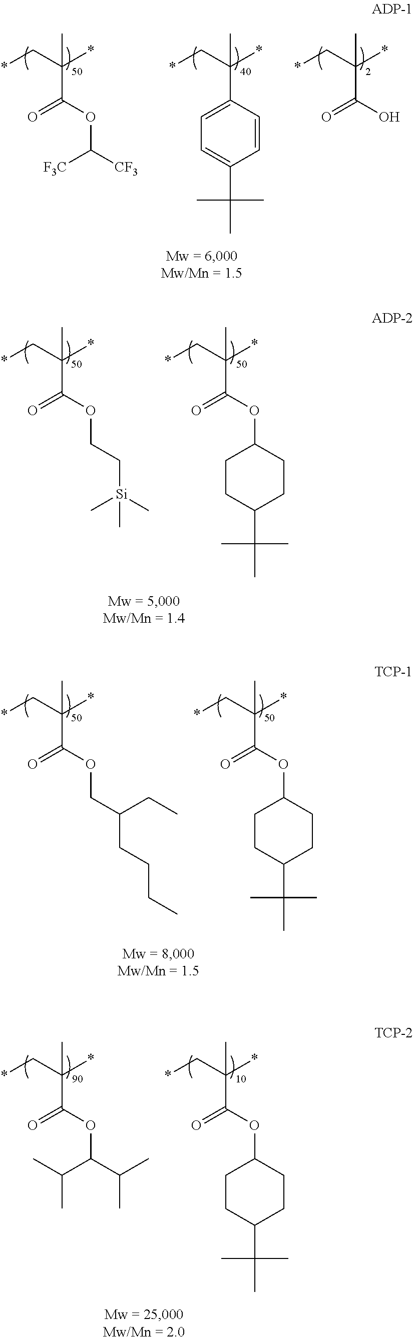

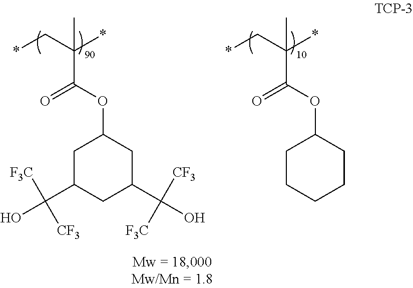

<Crosslinking Agent>

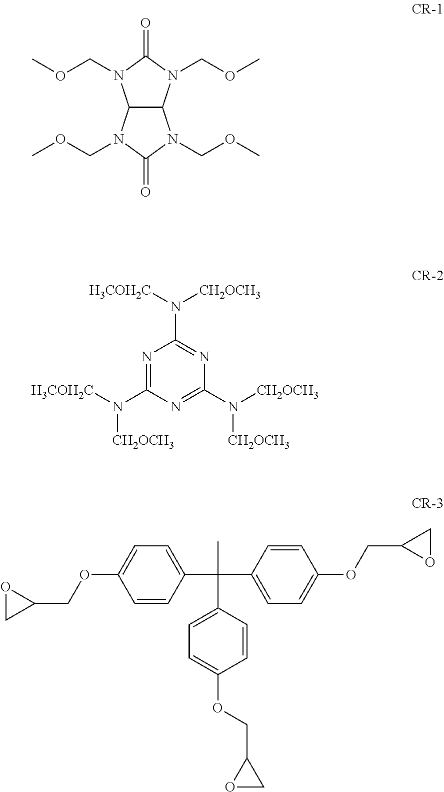

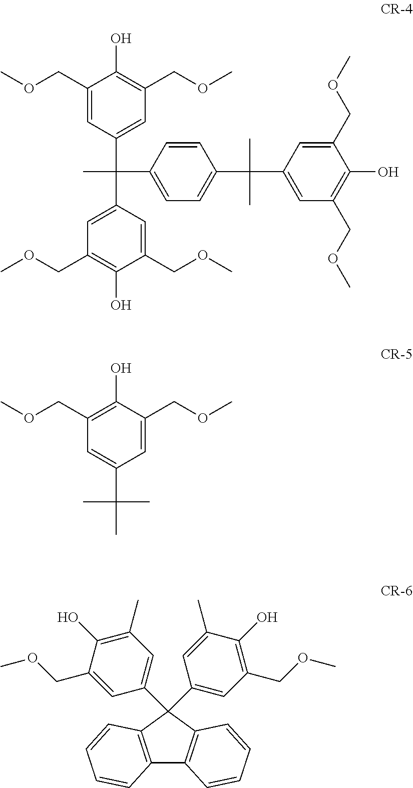

<Thermal Base Generator>

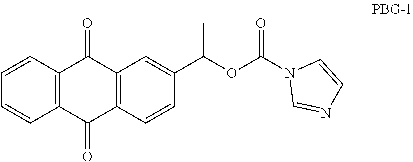 [SMILES: CC(OC(=O)n1ccnc1)c1ccc2c(c1)C(=O)c1ccccc1C2=O]

<Resin for Underlayer Film>

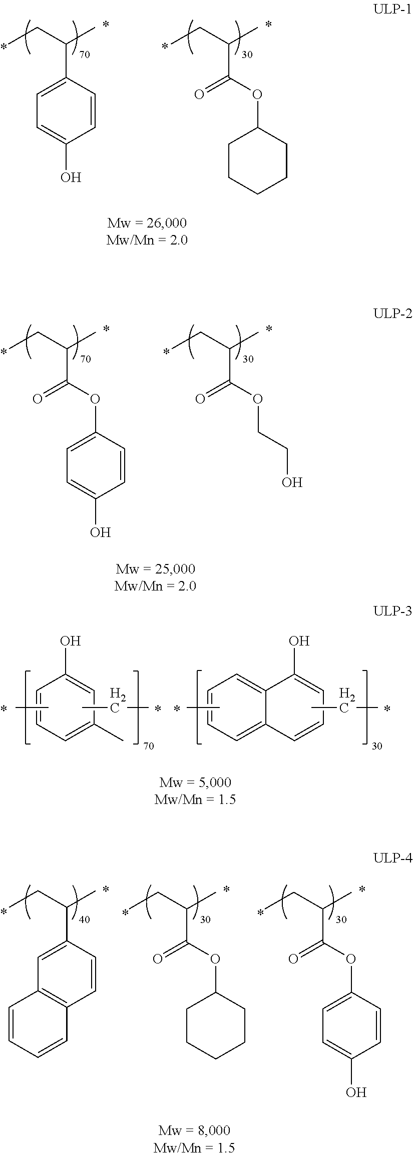

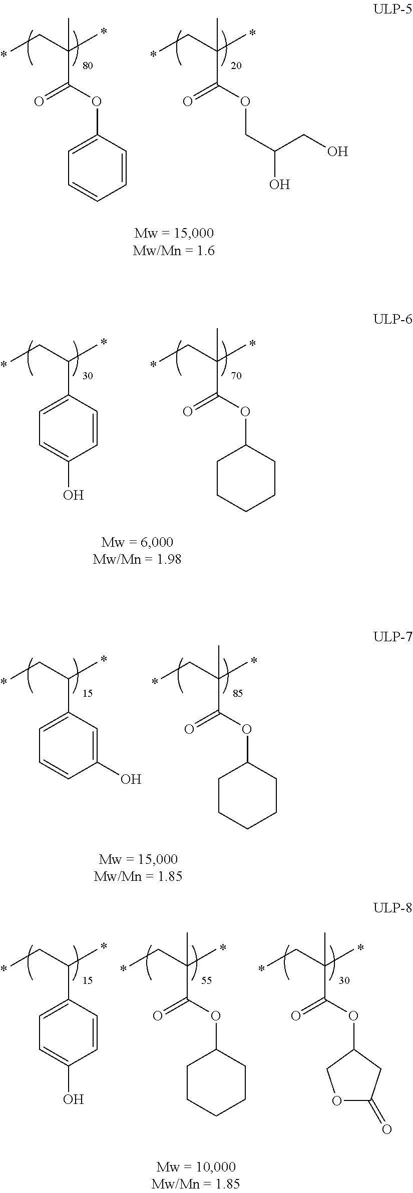

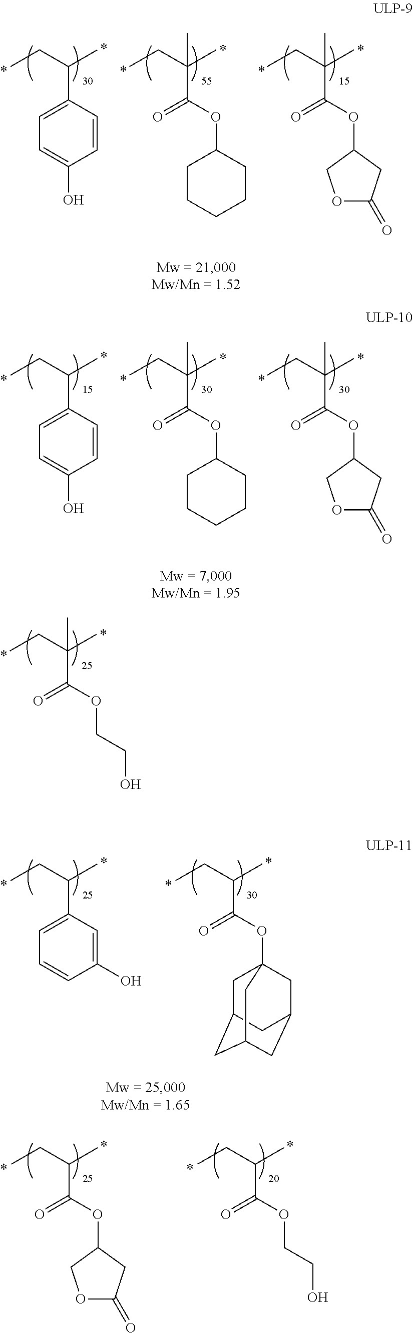

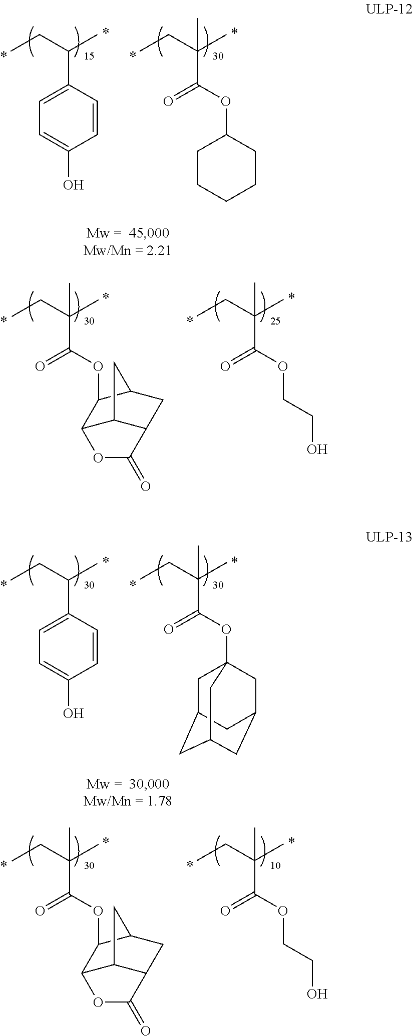

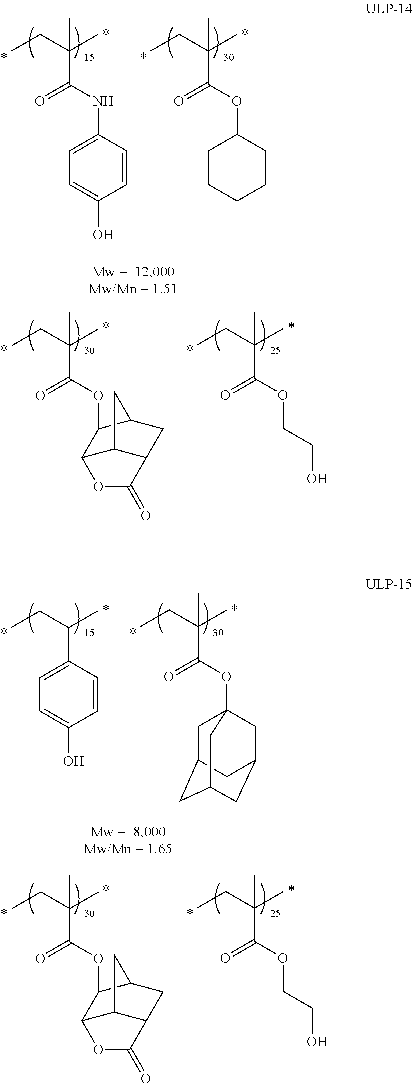

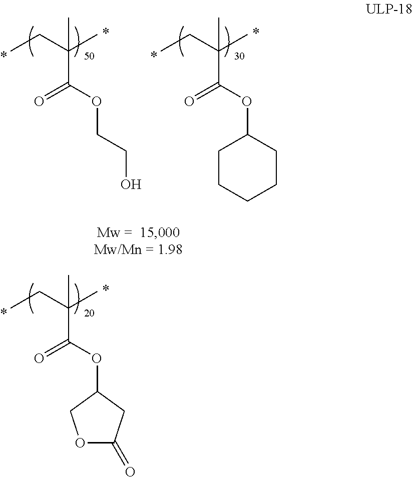

(Synthesis of Resin ULP-16)

In a nitrogen atmosphere, 40 parts of 2,7-dihydroxyl naphthalene, 20 parts of m-cresol, 10 parts of 1-naphthol, 30 parts of formalin, 300 parts of methyl isobutyl ketone, and 1 part of p-toluenesulfonic acid were added into a separable flask equipped with a thermometer, and the mixture was polymerized at 80° C. for 7 hours under stirring. Thereafter, the reaction solution was washed with a large amount of water, and the solvent was removed by distillation, thereby synthesizing a resin ULP-16 which is a novolac resin having Mw of 1,500 and Mw/Mn of 1.82.

(Synthesis of Resin ULP-17)

In a nitrogen atmosphere, 50 parts of 1,6-dihydroxyl pyrene, 35 parts of 2,7-dihydroxyl naphthalene, 25 parts of formalin, 1 part of p-toluenesulfonic acid, and 150 parts of propylene glycol monomethyl ether were added into a separable flask equipped with a thermometer, and the mixture was polymerized at 80° C. for 6 hours under stirring, thereby obtaining a reaction solution. Thereafter, the reaction solution was diluted with 100 parts of n-butyl acetate, and the organic layer was washed with a large amount of a mixed solvent of water/methanol (mass ratio: 1/2). Thereafter, the solvent was removed by distillation to synthesize a resin ULP-17 which is a novolac resin having Mw of 1,200 and Mw/Mn of 1.53.

(Synthesis of Resin IN-01)

5.00 g of tris-(2,3-epoxypropyl)-isocyanurate (manufactured by Nissan Chemical Industries, Ltd., trade name: TEPIC [registered trademark]), 5.01 g of succinic anhydride (Tokyo Kasei Kogyo Co.), and 0.47 g of triphenyl monoethyl phosphonium bromide which is a quaternary phosphonium salt, as a catalyst, were dissolved in 24.45 g of propylene glycol monomethyl ether, and then the solution was warmed up to 120° C. and stirred for 4 hours in a nitrogen atmosphere. A varnish solution diluted with 17.46 g of propylene glycol monomethyl ether was subjected to GPC analysis, and was found to have an Mw of 1,280 and an Mw/Mn of 1.61. This reaction product has the following partial structure.

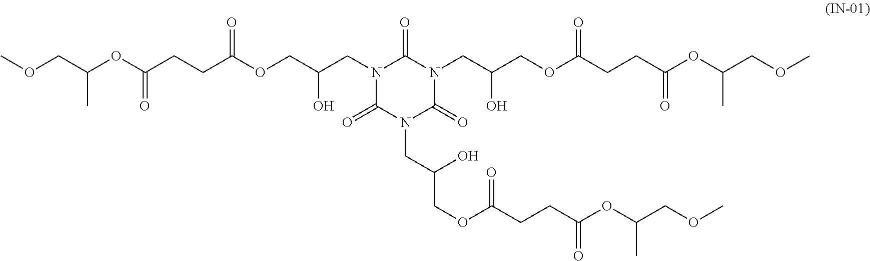

(Synthesis of Resin PBO-01)

32.96 g (0.09 moles) of 2,2-bis(3-amino-4-hydroxylphenyl)hexafluoropropane and 14.24 g (0.18 moles) of pyridine were dissolved in 132 g of N-methyl-2-pyrrolidone (NMP) in a four-neck flask equipped with a thermometer, a stirrer, and a dry nitrogen gas inlet tube.

Then, the separable flask was cooled, and a solution in which 5.38 g (0.0265 moles) of terephthaloyl chloride (manufactured by Tokyo Kasei Kogyo Co.), 12.91 g (0.0617 moles), and 0.64 g (0.0081 moles) of acetyl chloride were dissolved in 87.01 g of NMP was added dropwise thereto under stirring with an inflow of nitrogen while the temperature of the reaction system was kept at −10° C., and continuously stirred for 5 hours while the temperature of the reaction system was kept at −10° C.

Then, the temperature of the reaction system was returned to room temperature, the reaction solution was added dropwise to ion exchange water 20 times the amount of the reaction solution, and the resin fraction was precipitated.

After the resin fraction was filtered, it was dried in a vacuum drier at 50° C. for 24 hours, thereby obtaining a resin PBO-01 (polyhydroxyamide, weight-average molecular weight (Mw): 15,000, dispersity: weight-average molecular weight (Mw)/number-average molecular weight (Mn)=1.95) having a repeating unit represented by the following formula.

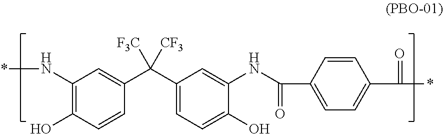

(Synthesis of Resin PI-01)

A resin PI-01 of the following formula was synthesized in accordance to Synthesis Example 2 described in paragraphs [0067] to [0068] of JP2013-137334A. The weight-average molecular weight Mw and the polydispersity Mw/Mn, measured by GPC in terms of polystyrene, were 11,000 and 1.45, respectively.

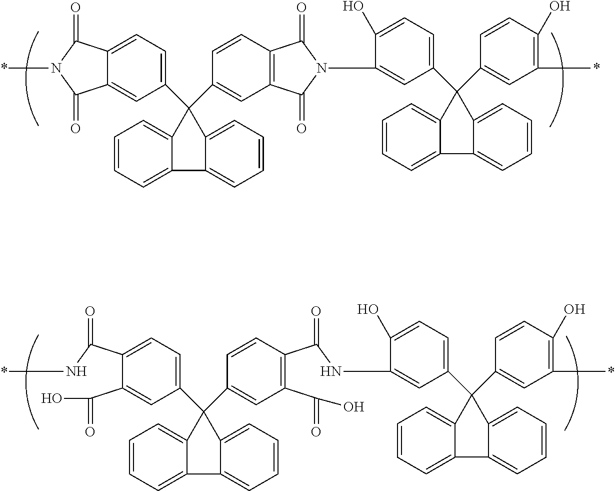

(Synthesis of Resin AN-01)

A resin AN-01 was synthesized in accordance with Synthesis Example 1 described in paragraphs [0099] and [0100] of JP4388429B.

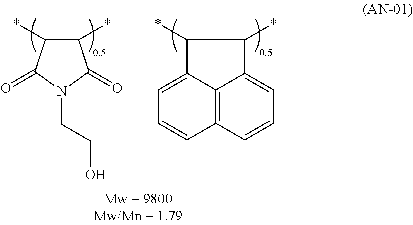

(Synthesis of Resin AN-02)

A resin AN-02 was synthesized in accordance with Synthesis Example 4 described in paragraphs [0108] and [0109] of JP4388429B.

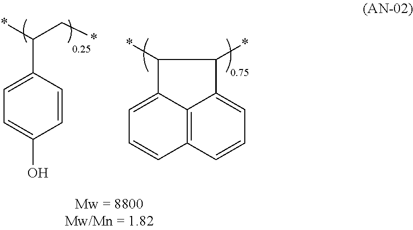

<Surfactant>

W-1: MEGAFACE F176 (manufactured by DIC, Inc.; fluorine-based)

W-2: MEGAFACE R08 (manufactured by DIC, Inc.; fluorine- and silicon-based)

W-3: Polysiloxane polymer KP-341 (manufactured by Shin-Etsu Chemical Co., Ltd.; silicon-based)

<Solvent>

SL-1: Propylene glycol monomethyl ether acetate (PGMEA)

SL-2: Propylene glycol monomethyl ether (PGME)

SL-3: Cyclohexanone

SL-4: γ-Butyrolactone

SL-5: Ethyl lactate

SL-6: Diisoamyl ether

SL-7: n-Decane

SL-8: 4-Methyl-2-pentanol

SL-9: Isobutyl isobutyrate

Using the prepared resin composition, evaluation was performed by the following method.

The abbreviations in the developers and the rinsing liquids in the following tables are as follows.

<Developers and Rinsing Liquids>

D-1: Butyl acetate

D-2: Isoamyl acetate

D-3: 2-Heptanone

D-4: Isobutyl isobutyrate

D-5: 2.38%-by-mass aqueous tetramethylammoniumhydroxide solution

D-6: 4-Methyl-2-pentanol

D-7: n-Undecane

D-8: Diisoamyl ether

D-9: Pure water

D-10: Diisobutyl ketone

D-11: n-Decane

D-12: Propylene glycol monomethyl ether acetate (PGMEA)

D-13: Propylene glycol monomethyl ether (PGME)

In addition, for UL-25 and ML-1, the following ones were used.

UL-25: FHi-028DD Resist (resist for an i-line, manufactured by Fujifilm Electronics Materials)

ML-1: SHB-A940 (Silicon-containing spin-on-hard mask, manufactured by Shin-Etsu Chemical Co., Ltd.)

### [ArF Liquid Immersion Exposure Example] (Examples 1-1 to 1-53, Comparative Examples 1-1 to 1-2, and Reference Example 1-1)

A silicon wafer was subjected to a hexamethyldisilazane (HMDS) treatment (110° C., 35 seconds), and an underlayer film, an interlayer film, a resist film, and a topcoat film were formed in this order thereon under the conditions described in Tables 5 and 6, thereby forming a wafer having a laminate film including a plurality of layers. Further, in a case where there is no description of the layer in the tables, the above-mentioned layers were not formed, but the following layers were formed.

The obtained wafer was subjected to pattern exposure, using an ArF excimer laser liquid immersion scanner (manufactured by ASML; XT1700i, NA1.20, Dipole, outer sigma 0.900, inner sigma 0.700, and Y deflection). Further, as a reticle, a 6% halftone mask with a line size=50 nm and line:space=1:1 was used. Incidentally, ultrapure water was used as the immersion liquid. Thereafter, baking (Post Exposure Bake: PEB) was carried out under the conditions described in Tables 5 and 6, development was carried out by puddling for 30 seconds using the developer described in Tables 5 and 6, and rinsing was carried out by puddling using the rinsing liquid described in Tables 5 and 6 only in a case where there is a description about the rinsing. Then, the wafer was rotated for 30 seconds at a rotation speed of 4,000 rpm to obtain a line-and-space pattern having a pitch of 100 nm, a space width of 35 nm (corresponding to “a desired space width dimension” which will be described later), and a line width of 65 nm. The results are summarized in Tables 5 and 6. In addition, in Comparative Example 1-1, a desired space width could not be resolved, and therefore, DOF, development defects, and etching properties of the resist underlayer film were not measured.

TABLE 5

| | | | | Conditions for applying | | | | | | Conditions for | |
|---|---|---|---|---|---|---|---|---|---|---|---|
| | Conditions for applying underlayer film | | | intermediate film | | | Conditions for applying resist | | | applying topcoat | |
| | | | Film | | | Film | | | Film | Com- | |
| Example | Composition | Bake | thickness | Composition | Bake | thickness | Composition | Bake | thickness | position | Bake |
| 1-1 | UL-1 | 200° C./60 s | 120 nm | — | — | — | PR-1 | 100° C./60 s | 80 nm | — | — |
| 1-2 | UL-1 | 200° C./60 s | 120 nm | — | — | — | PR-2 | 130° C./60 s | 80 nm | — | — |
| 1-3 | UL-3 | 220° C./60 s | 200 nm | — | — | — | PR-3 | 120° C./60 s | 100 nm | — | — |
| 1-4 | UL-1 | 200° C./60 s | 120 nm | — | — | — | PR-4 | 100° C./60 s | 100 nm | TC-1 | 120° C./60 s |
| 1-5 | UL-1 | 180° C./60 s | 120 nm | — | — | — | PR-5 | 100° C./60 s | 100 nm | TC-2 | 80° C./60 s |
| 1-6 | UL-3 | 200° C./60 s | 200 nm | — | — | — | PR-6 | 80° C./60 s | 80 nm | TC-3 | 100° C./60 s |
| 1-7 | UL-1 | 150° C./60 s | 120 nm | — | — | — | PR-7 | 100° C./60 s | 80 nm | TC-4 | 120° C./60 s |
| 1-8 | UL-3 | 200° C./60 s | 200 nm | — | — | — | PR-8 | 100° C./60 s | 80 nm | TC-5 | 80° C./60 s |
| 1-9 | UL-4 | 200° C./60 s | 300 nm | — | — | — | PR-9 | 100° C./90 s | 150 nm | TC-6 | 100° C./60 s |
| 1-10 | UL-1 | 200° C./90 s | 120 nm | — | — | — | PR-10 | 100° C./90 s | 60 nm | TC-6 | 80° C./90 s |
| 1-11 | UL-1 | 200° C./60 s | 120 nm | — | — | — | PR-11 | 100° C./60 s | 80 nm | TC-6 | 120° C./60 s |
| 1-12 | UL-1 | 200° C./50 s | 120 nm | — | — | — | PR-12 | 100° C./60 s | 60 nm | — | — |
| 1-13 | UL-4 | 200° C./60 s | 300 nm | — | — | — | PR-13 | 100° C./60 s | 120 nm | — | — |
| 1-14 | UL-4 | 150° C./60 s | 300 nm | — | — | — | PR-14 | 100° C./60 s | 140 nm | — | — |
| 1-15 | UL-5 | 200° C./60 s | 100 nm | — | — | — | PR-15 | 100° C./60 s | 100 nm | TC-7 | 120° C./60 s |
| 1-16 | UL-2 | 200° C./60 s | 250 nm | — | — | — | PR-16 | 100° C./60 s | 100 nm | TC-8 | 100° C./60 s |
| 1-17 | UL-1 | 200° C./60 s | 120 nm | — | — | — | PR-17 | 120° C./60 s | 100 nm | — | — |
| 1-18 | UL-1 | 180° C./60 s | 120 nm | — | — | — | PR-18 | 100° C./60 s | 60 nm | — | — |
| 1-19 | UL-1 | 200° C./60 s | 120 nm | — | — | — | PR-19 | 80° C./60 s | 60 nm | TC-9 | 80° C./60 s |
| 1-20 | UL-4 | 150° C./60 s | 80 nm | — | — | — | PR-20 | 100° C./60 s | 60 nm | — | — |
| 1-21 | UL-6 | 200° C./60 s | 250 nm | — | — | — | PR-21 | 100° C./60 s | 80 nm | TC-10 | 120° C./60 s |
| 1-22 | UL-1 | 220° C./60 s | 120 nm | — | — | — | PR-22 | 100° C./60 s | 80 nm | TC-11 | 80° C./60 s |
| 1-23 | UL-1 | 200° C./60 s | 120 nm | — | — | — | PR-23 | 100° C./60 s | 80 nm | — | — |
| 1-24 | UL-1 | 220° C./45 s | 120 nm | — | — | — | PR-24 | 100° C./45 s | 60 nm | — | — |
| 1-25 | UL-1 | 200° C./60 s | 120 nm | — | — | — | PR-25 | 100° C./45 s | 60 nm | TC-12 | 130° C./45 s |
| 1-26 | UL-25 | 200° C./60 s | 300 nm | — | — | — | PR-26 | 120° C./60 s | 120 nm | — | — |
| 1-27 | UL-1 | 180° C./60 s | 120 nm | — | — | — | PR-27 | 100° C./60 s | 100 nm | — | — |
| 1-28 | UL-1 | 200° C./60 s | 150 nm | — | — | — | PR-28 | 100° C./60 s | 100 nm | — | — |
| 1-29 | UL-1 | 200° C./90 s | 120 nm | — | — | — | PR-29 | 80° C./60 s | 100 nm | — | — |
| 1-30 | UL-1 | 200° C./60 s | 100 nm | — | — | — | PR-30 | 70° C./60 s | 100 nm | — | — |

| | Conditions | | | | | | | | |
|---|---|---|---|---|---|---|---|---|---|
| | for | | | | | | | | |
| | applying | | | | | | | | |
| | topcoat | Conditions for PEB-development | | | Evaluation results | | | | |
| | Film | | | Rinsing | Resolving | | Development | | |
| Example | thickness | PEB | Developer | liquid | power | DOF | defects | Etching | Exposure |
| 1-1 | — | 80° C./60 s | D-1 | — | 28 nm | 200 nm | A | A | Liquid immersion |
| 1-2 | — | 70° C./60 s | D-1 | — | 25 nm | 220 nm | A | A | Liquid immersion |
| 1-3 | — | 90° C./60 s | D-2 | D-6 | 28 nm | 250 nm | A | A | Liquid immersion |
| 1-4 | 90 nm | 90° C./60 s | D-1 | — | 30 nm | 220 nm | B | B | Liquid immersion |
| 1-5 | 30 nm | 100° C./60 s | D-3 | D-7 | 28 nm | 220 nm | A | A | Liquid immersion |
| 1-6 | 60 nm | 95° C./60 s | D-1 | D-7 | 28 nm | 220 nm | A | A | Liquid immersion |
| 1-7 | 60 nm | 120° C./60 s | D-2 | D-8 | 28 nm | 220 nm | A | A | Liquid immersion |
| 1-8 | 90 nm | 100° C./60 s | D-1 | — | 25 nm | 250 nm | A | A | Liquid immersion |
| 1-9 | 90 nm | 120° C./60 s | D-1 | — | 28 nm | 200 nm | A | A | Liquid immersion |
| 1-10 | 90 nm | 100° C./90 s | D-1 | — | 25 nm | 220 nm | A | A | Liquid immersion |
| 1-11 | 90 nm | 95° C./60 s | D-1 | — | 25 nm | 250 nm | A | A | Liquid immersion |
| 1-12 | — | 90° C./60 s | D-1 | — | 28 nm | 220 nm | A | A | Liquid immersion |
| 1-13 | — | 85° C./60 s | D-1 | D-6 | 25 nm | 250 nm | A | A | Liquid immersion |
| 1-14 | — | 100° C./60 s | D-2 | — | 28 nm | 220 nm | A | A | Liquid immersion |
| 1-15 | 30 nm | 95° C./60 s | D-1 | — | 28 nm | 250 nm | A | A | Liquid immersion |
| 1-16 | 60 nm | 130° C./60 s | D-1 | — | 28 nm | 220 nm | A | A | Liquid immersion |
| 1-17 | — | 95° C./60 s | D-1 | D-7 | 28 nm | 220 nm | A | A | Liquid immersion |
| 1-18 | — | 80° C./60 s | D-2 | D-7 | 28 nm | 220 nm | A | A | Liquid immersion |
| 1-19 | 90 nm | 120° C./60 s | D-4 | — | 30 nm | 220 nm | A | A | Liquid immersion |
| 1-20 | — | 110° C./60 s | D-1 | — | 25 nm | 250 nm | B | A | Liquid immersion |
| 1-21 | 120 nm | 85° C./60 s | D-1 | — | 30 nm | 220 nm | A | A | Liquid immersion |
| 1-22 | 60 nm | 90° C./60 s | D-3 | — | 28 nm | 200 nm | A | B | Liquid immersion |
| 1-23 | — | 75° C./60 s | D-1 | D-8 | 30 nm | 220 nm | A | A | Liquid immersion |
| 1-24 | — | 80° C./45 s | D-1 | — | 28 nm | 200 nm | A | A | Liquid immersion |
| 1-25 | 30 nm | 70° C./60 s | D-1 | D-6 | 30 nm | 220 nm | A | A | Liquid immersion |
| 1-26 | — | 90° C./60 s | D-1 | — | 25 nm | 220 nm | A | A | Liquid immersion |
| 1-27 | — | 90° C./60 s | D-1 | — | 28 nm | 220 nm | A | A | Liquid immersion |
| 1-28 | — | 100° C./60 s | D-2 | — | 28 nm | 200 nm | A | A | Liquid immersion |
| 1-29 | — | 95° C./60 s | D-1 | D-7 | 30 nm | 220 nm | A | B | Liquid immersion |
| 1-30 | — | 120° C./60 s | D-3 | — | 28 nm | 200 nm | A | A | Liquid immersion |

TABLE 6

| | Conditions for applying | | | Conditions for applying | | | | | |
|---|---|---|---|---|---|---|---|---|---|
| | underlayer film | | | intermediate film | | | Conditions for applying resist | | |
| | | | Film | | | Film | | | Film |
| Example | Composition | Bake | thickness | Composition | Bake | thickness | Composition | Bake | thickness |
| 1-31 | UL-8 | 200° C./60 s | 120 nm | — | — | — | PR-1 | 100° C./60 s | 80 nm |
| 1-32 | UL-9 | 200° C./60 s | 120 nm | — | — | — | PR-2 | 130° C./60 s | 80 nm |
| 1-33 | UL-10 | 220° C./60 s | 200 nm | — | — | — | PR-3 | 120° C./60 s | 100 nm |
| 1-34 | UL-11 | 200° C./60 s | 120 nm | — | — | — | PR-4 | 100° C./60 s | 100 nm |
| 1-35 | UL-12 | 200° C./60 s | 120 nm | — | — | — | PR-1 | 100° C./60 s | 80 nm |
| 1-36 | UL-13 | 200° C./60 s | 120 nm | — | — | — | PR-2 | 130° C./60 s | 80 nm |
| 1-37 | UL-14 | 220° C./60 s | 200 nm | — | — | — | PR-3 | 120° C./60 s | 100 nm |
| 1-38 | UL-15 | 200° C./60 s | 120 nm | — | — | — | PR-4 | 100° C./60 s | 100 nm |
| 1-39 | UL-16 | 200° C./60 s | 120 nm | — | — | — | PR-1 | 100° C./60 s | 80 nm |
| 1-40 | UL-17 | 200° C./60 s | 120 nm | — | — | — | PR-2 | 130° C./60 s | 80 nm |
| 1-41 | UL-18 | 220° C./60 s | 200 nm | — | — | — | PR-3 | 120° C./60 s | 100 nm |
| 1-42 | UL-19 | 200° C./60 s | 120 nm | — | — | — | PR-4 | 100° C./60 s | 100 nm |
| 1-43 | UL-20 | 200° C./60 s | 120 nm | — | — | — | PR-1 | 100° C./60 s | 80 nm |
| 1-44 | UL-21 | 200° C./60 s | 120 nm | — | — | — | PR-2 | 130° C./60 s | 80 nm |
| 1-45 | UL-22 | 220° C./60 s | 200 nm | — | — | — | PR-3 | 120° C./60 s | 100 nm |
| 1-46 | UL-23 | 200° C./60 s | 120 nm | — | — | — | PR-4 | 100° C./60 s | 100 nm |
| 1-47 | UL-24 | 200° C./60 s | 120 nm | — | — | — | PR-1 | 100° C./60 s | 80 nm |
| 1-48 | UL-1 | 200° C./60 s | 120 nm | — | — | — | PR-56 | 100° C./45 s | 60 nm |
| 1-49 | UL-8 | 200° C./60 s | 300 nm | — | — | — | PR-57 | 120° C./60 s | 120 nm |
| 1-50 | UL-1 | 180° C./60 s | 120 nm | — | — | — | PR-58 | 100° C./60 s | 100 nm |
| 1-51 | UL-1 | 200° C./60 s | 300 nm | — | — | — | PR-1 | 100° C./60 s | 80 nm |
| 1-52 | UL-1 | 200° C./60 s | 120 nm | — | — | — | PR-59 | 100° C./60 s | 100 nm |
| 1-53 | UL-3 | 220° C./60 s | 200 nm | — | — | — | PR-60 | 100° C./60 s | 80 nm |
| Comparative | UL-1 | 200° C./60 s | 120 nm | — | — | — | PR-1 | 100° C./60 s | 80 nm |
| Example 1 | | | | | | | | | |
| Comparative | UL-1 | 200° C./60 s | 120 nm | — | — | — | PR-51 | 100° C./60 s | 80 nm |
| Example 2 | | | | | | | | | |
| Reference | UL-1 | 200° C./60 s | 120 nm | ML-1 | 220° C./60 s | 35 nm | PR-51 | 100° C./60 s | 80 nm |
| Example 1 | | | | | | | | | |

| | Conditions for applying topcoat | | | Conditions for PEB-development | | | Evaluation |
|---|---|---|---|---|---|---|---|
| | | | Film | | | | results |
| Example | Composition | Bake | thickness | PEB | Developer | Rinsing liquid | Resolving power |
| 1-31 | — | — | — | 80° C./60 s | D-1 | — | 28 nm |
| 1-32 | — | — | — | 70° C./60 s | D-1 | — | 25 nm |
| 1-33 | — | — | — | 90° C./60 s | D-2 | D-6 | 28 nm |
| 1-34 | TC-1 | 120° C./60 s | 90 nm | 90° C./60 s | D-1 | — | 30 nm |
| 1-35 | — | — | — | 80° C./60 s | D-1 | — | 28 nm |
| 1-36 | — | — | — | 70° C./60 s | D-1 | — | 25 nm |
| 1-37 | — | — | — | 90° C./60 s | D-2 | D-6 | 28 nm |
| 1-38 | TC-1 | 120° C./60 s | 90 nm | 90° C./60 s | D-1 | — | 30 nm |
| 1-39 | — | — | — | 80° C./60 s | D-1 | — | 28 nm |
| 1-40 | — | — | — | 70° C./60 s | D-1 | — | 25 nm |
| 1-41 | — | — | — | 90° C./60 s | D-2 | D-6 | 28 nm |
| 1-42 | TC-1 | 120° C./60 s | 90 nm | 90° C./60 s | D-1 | — | 30 nm |
| 1-43 | — | — | — | 80° C./60 s | D-1 | — | 28 nm |
| 1-44 | — | — | — | 70° C./60 s | D-1 | — | 25 nm |
| 1-45 | — | — | — | 90° C./60 s | D-2 | D-6 | 28 nm |
| 1-46 | TC-1 | 120° C./60 s | 90 nm | 90° C./60 s | D-1 | — | 30 nm |
| 1-47 | — | — | — | 80° C./60 s | D-1 | — | 28 nm |
| 1-48 | TC-12 | 130° C./45 s | 30 nm | 70° C./60 s | D-1 | D-6 | 30 nm |
| 1-49 | — | — | — | 90° C./60 s | D-1 | — | 25 nm |
| 1-50 | — | — | — | 90° C./60 s | D-1 | — | 28 nm |
| 1-51 | — | — | — | 90° C./60 s | D-1 | D-1/D-12/D-13 (mass | 28 nm |
| | | | | | | ratio 95/3/2) | |
| 1-52 | TC-1 | 120° C./60 s | 90 nm | 100° C./60 s | D-10 | — | 28 nm |
| 1-53 | — | — | — | 95° C./60 s | D-1 | — | 30 nm |
| Comparative | TC-7 | 100° C./60 s | 90 nm | 100° C./60 s | D-5 | D-9 | 40 nm |
| Example 1 | | | | | | | |
| Comparative | — | — | — | 95° C./60 s | D-1 | — | 28 nm |
| Example 2 | | | | | | | |
| Reference | TC-1 | 120° C./60 s | 90 nm | 100° C./60 s | D-5 | D-9 | 30 nm |
| Example 1 | | | | | | | |

| | Evaluation results | | | |
|---|---|---|---|---|
| | | Development | | |
| Example | DOF | defects | Etching | Exposure |
| 1-31 | 200 nm | A | A | Liquid immersion |
| 1-32 | 220 nm | A | A | Liquid immersion |
| 1-33 | 250 nm | A | A | Liquid immersion |
| 1-34 | 220 nm | B | B | Liquid immersion |
| 1-35 | 200 nm | A | A | Liquid immersion |
| 1-36 | 220 nm | A | A | Liquid immersion |
| 1-37 | 250 nm | A | A | Liquid immersion |
| 1-38 | 220 nm | B | B | Liquid immersion |
| 1-39 | 200 nm | A | A | Liquid immersion |
| 1-40 | 220 nm | A | A | Liquid immersion |
| 1-41 | 250 nm | A | A | Liquid immersion |
| 1-42 | 220 nm | B | B | Liquid immersion |
| 1-43 | 200 nm | A | A | Liquid immersion |
| 1-44 | 220 nm | A | A | Liquid immersion |
| 1-45 | 250 nm | A | A | Liquid immersion |
| 1-46 | 220 nm | B | B | Liquid immersion |
| 1-47 | 200 nm | A | A | Liquid immersion |
| 1-48 | 200 nm | A | A | Liquid immersion |
| 1-49 | 220 nm | B | A | Liquid immersion |
| 1-50 | 220 nm | A | B | Liquid immersion |
| 1-51 | 200 nm | A | A | Liquid immersion |
| 1-52 | 200 nm | A | A | Liquid immersion |
| 1-53 | 250 nm | A | A | Liquid immersion |
| Comparative | — | — | — | Liquid immersion |
| Example 1 | | | | |
| Comparative | 200 nm | A | C | Liquid immersion |
| Example 2 | | | | |
| Reference | 220 nm | B | A | Liquid immersion |
| Example 1 | | | | |

### [ArF Exposure Examples] (Examples 2-1 to 2-26, Comparative Examples 2-1 and 2-2, and Reference Example 2-1)

A silicon wafer was subjected to a hexamethyldisilazane (HMDS) treatment (110° C., 35 seconds), and an underlayer film, an interlayer film, a resist film, and a topcoat film were formed in this order thereon under the conditions described in Table 7, thereby forming a wafer having a laminate film including a plurality of layers. Further, in a case where there is no description of the layer in the tables, the above-mentioned layers were not formed, but the following layers were formed.

The obtained wafer was subjected to pattern exposure, using an ArF excimer laser liquid immersion scanner (manufactured by ASML; PAS5500/1100, NA0.75, Dipole, outer sigma 0.890, inner sigma 0.650). Further, as a reticle, a 6% halftone mask with a line size=75 nm and line:space=1:1 was used. Thereafter, baking (Post Exposure Bake: PEB) was carried out under the conditions described in Table 7, development was carried out by puddling for 30 seconds using the developer described in Table 7, and rinsing was carried out by puddling using the rinsing liquid described in Table 7 only in a case where there is a description about the rinsing. Then, the wafer was rotated for 30 seconds at a rotation speed of 4,000 rpm to obtain a line-and-space pattern having a pitch of 150 nm, a space width of 50 nm (corresponding to “a desired space width dimension” which will be described later), and a line width of 100 nm. The results are summarized in Table 7.

TABLE 7

| | Conditions for | | | | | | | | |
|---|---|---|---|---|---|---|---|---|---|
| | applying underlayer film | | | Conditions for applying | | | Conditions for applying resist | | |
| | | | Film | intermediate film | | | | | Film |
| Example | Composition | Bake | thickness | Composition | Bake | Film thickness | Composition | Bake | thickness |
| 2-1 | UL-1 | 200° C./60 s | 250 nm | — | — | — | PR-31 | 100° C./60 s | 100 nm |
| 2-2 | UL-6 | 200° C./60 s | 250 nm | — | — | — | PR-32 | 100° C./60 s | 120 nm |
| 2-3 | UL-1 | 200° C./60 s | 140 nm | — | — | — | PR-33 | 100° C./60 s | 60 nm |
| 2-4 | UL-1 | 200° C./60 s | 120 nm | — | — | — | PR-34 | 100° C./60 s | 80 nm |
| 2-5 | UL-1 | 200° C./60 s | 120 nm | — | — | — | PR-35 | 100° C./60 s | 100 nm |
| 2-6 | UL-1 | 200° C./60 s | 140 nm | — | — | — | PR-36 | 100° C./60 s | 120 nm |
| 2-7 | UL-1 | 180° C./60 s | 120 nm | — | — | — | PR-37 | 100° C./60 s | 80 nm |
| 2-8 | UL-1 | 150° C./60 s | 140 nm | — | — | — | PR-38 | 100° C./60 s | 120 nm |
| 2-9 | UL-1 | 200° C./60 s | 120 nm | — | — | — | PR-39 | 100° C./60 s | 100 nm |
| 2-10 | UL-8 | 200° C./60 s | 250 nm | — | — | — | PR-31 | 100° C./60 s | 100 nm |
| 2-11 | UL-9 | 200° C./60 s | 250 nm | — | — | — | PR-32 | 100° C./60 s | 120 nm |
| 2-12 | UL-10 | 200° C./60 s | 140 nm | — | — | — | PR-33 | 100° C./60 s | 60 nm |
| 2-13 | UL-11 | 200° C./60 s | 120 nm | — | — | — | PR-34 | 100° C./60 s | 80 nm |
| 2-14 | UL-12 | 200° C./60 s | 250 nm | — | — | — | PR-31 | 100° C./60 s | 100 nm |
| 2-15 | UL-13 | 200° C./60 s | 250 nm | — | — | — | PR-32 | 100° C./60 s | 120 nm |
| 2-16 | UL-14 | 200° C./60 s | 140 nm | — | — | — | PR-33 | 100° C./60 s | 60 nm |
| 2-17 | UL-15 | 200° C./60 s | 120 nm | — | — | — | PR-34 | 100° C./60 s | 80 nm |
| 2-18 | UL-16 | 200° C./60 s | 250 nm | — | — | — | PR-31 | 100° C./60 s | 100 nm |
| 2-19 | UL-17 | 200° C./60 s | 250 nm | — | — | — | PR-32 | 100° C./60 s | 120 nm |
| 2-20 | UL-18 | 200° C./60 s | 140 nm | — | — | — | PR-33 | 100° C./60 s | 60 nm |
| 2-21 | UL-19 | 200° C./60 s | 120 nm | — | — | — | PR-34 | 100° C./60 s | 80 nm |
| 2-22 | UL-20 | 200° C./60 s | 250 nm | — | — | — | PR-31 | 100° C./60 s | 100 nm |
| 2-23 | UL-21 | 200° C./60 s | 250 nm | — | — | — | PR-32 | 100° C./60 s | 120 nm |
| 2-24 | UL-22 | 200° C./60 s | 140 nm | — | — | — | PR-33 | 100° C./60 s | 60 nm |
| 2-25 | UL-23 | 200° C./60 s | 120 nm | — | — | — | PR-34 | 100° C./60 s | 80 nm |
| 2-26 | UL-24 | 200° C./60 s | 250 nm | — | — | — | PR-34 | 100° C./60 s | 80 nm |
| Comparative | UL-1 | 200° C./60 s | 250 nm | — | — | — | PR-31 | 100° C./60 s | 100 nm |
| Example 2-1 | | | | | | | | | |
| Comparative | UL-1 | 200° C./60 s | 250 nm | — | — | — | PR-52 | 100° C./60 s | 100 nm |
| Example 2-2 | | | | | | | | | |
| Reference Example | UL-1 | 200° C./60 s | 250 nm | ML-1 | 220° C./60 s | 35 nm | PR-52 | 100° C./60 s | 100 nm |
| 2-1 | | | | | | | | | |

| | Conditions for applying topcoat | | | Conditions for PEB-development | | | Evaluation results | | | |
|---|---|---|---|---|---|---|---|---|---|---|
| | | | Film | | | Rinsing | Resolving | | Development | |
| Example | Composition | Bake | thickness | PEB | Developer | liquid | power | DOF | defects | Etching |
| 2-1 | — | — | — | 100° C./45 s | D-2 | — | 40 nm | 360 nm | A | A |
| 2-2 | — | — | — | 120° C./60 s | D-1 | D-8 | 30 nm | 400 nm | A | A |
| 2-3 | — | — | — | 100° C./60 s | D-1 | — | 35 nm | 360 nm | A | A |
| 2-4 | — | — | — | 95° C./60 s | D-1 | — | 35 nm | 360 nm | A | A |
| 2-5 | TC-1 | 120° C./60 s | 90 nm | 90° C./60 s | D-3 | — | 35 nm | 360 nm | B | B |
| 2-6 | TC-3 | 80° C./60 s | 60 nm | 85° C./60 s | D-1 | — | 30 nm | 400 nm | A | A |
| 2-7 | — | — | — | 100° C./60 s | D-1 | — | 35 nm | 320 nm | A | A |
| 2-8 | — | — | — | 95° C./60 s | D-1 | — | 35 nm | 360 nm | A | A |
| 2-9 | — | — | — | 130° C./60 s | D-2 | D-6 | 40 nm | 360 nm | A | A |
| 2-10 | — | — | — | 100° C./45 s | D-2 | — | 40 nm | 360 nm | A | A |
| 2-11 | — | — | — | 120° C./60 s | D-1 | D-8 | 30 nm | 400 nm | A | A |
| 2-12 | — | — | — | 100° C./60 s | D-1 | — | 35 nm | 360 nm | A | A |
| 2-13 | — | — | — | 95° C./60 s | D-1 | — | 35 nm | 360 nm | A | A |
| 2-14 | — | — | — | 100° C./45 s | D-2 | — | 40 nm | 360 nm | A | A |
| 2-15 | — | — | — | 120° C./60 s | D-1 | D-8 | 30 nm | 400 nm | A | A |
| 2-16 | — | — | — | 100° C./60 s | D-1 | — | 35 nm | 360 nm | A | A |
| 2-17 | — | — | — | 95° C./60 s | D-1 | — | 35 nm | 360 nm | A | A |
| 2-18 | — | — | — | 100° C./45 s | D-2 | — | 40 nm | 360 nm | A | A |
| 2-19 | — | — | — | 120° C./60 s | D-1 | D-8 | 30 nm | 400 nm | A | A |
| 2-20 | — | — | — | 100° C./60 s | D-1 | — | 35 nm | 360 nm | A | A |
| 2-21 | — | — | — | 95° C./60 s | D-1 | — | 35 nm | 360 nm | A | A |
| 2-22 | — | — | — | 100° C./45 s | D-2 | — | 40 nm | 360 nm | A | A |
| 2-23 | — | — | — | 120° C./60 s | D-1 | D-8 | 30 nm | 400 nm | A | A |
| 2-24 | — | — | — | 100° C./60 s | D-1 | — | 35 nm | 360 nm | A | A |
| 2-25 | — | — | — | 95° C./60 s | D-1 | — | 35 nm | 360 nm | A | A |
| 2-26 | — | — | — | 95° C./60 s | D-1 | — | 35 nm | 360 nm | A | A |
| Comparative | — | — | — | 100° C./45 s | D-5 | D-9 | 50 nm | 150 nm | D | A |
| Example 2-1 | | | | | | | | | | |
| Comparative | — | — | — | 100° C./45 s | D-2 | — | 40 nm | 360 nm | B | C |
| Example 2-2 | | | | | | | | | | |
| Reference Example | — | — | — | 100° C./45 s | D-5 | D-9 | 35 nm | 320 nm | A | A |
| 2-1 | | | | | | | | | | |

### [KrF Exposure Example] (Examples 3-1 to 3-22, Comparative Examples 3-1 to 3-2, and Reference Example 3-1)

A silicon wafer was subjected to a hexamethyldisilazane (HMDS) treatment (110° C., 35 seconds), and an underlayer film, an interlayer film, a resist film, and a topcoat film were formed in this order thereon under the conditions described in Table 8, thereby forming a wafer having a laminate film including a plurality of layers. Further, in a case where there is no description of the layer in the tables, the above-mentioned layers were not formed, but the following layers were formed.

The obtained wafer was subjected to pattern exposure, using a KrF excimer laser liquid immersion scanner (manufactured by ASML; PAS5500/850) (NA0.80). Further, as a reticle, a binary mask of a line-and-space pattern with a line size=175 nm and a space size=263 nm was used. Thereafter, baking (Post Exposure Bake: PEB) was carried out under the conditions described in Table 8, development was carried out by puddling for 30 seconds using the developer described in Table 8, and rinsing was carried out by puddling using the rinsing liquid described in Table 8 only in a case where there is a description about the rinsing. Then, the wafer was rotated for 30 seconds at a rotation speed of 4,000 rpm to obtain a line-and-space pattern having a pitch of 438 nm, a space width of 130 nm (corresponding to “a desired space width dimension” which will be described later), and a line width of 308 nm. The results are summarized in Table 8.

TABLE 8

| | | | | | | | | | | Conditions |
|---|---|---|---|---|---|---|---|---|---|---|
| | Conditions for applying | | | Conditions for applying | | | Conditions for | | | for |
| | underlayer film | | | intermediate film | | | applying resist | | | applying |
| | | | Film | | | Film | | | Film | topcoat |
| Example | Composition | Bake | thickness | Composition | Bake | thickness | Composition | Bake | thickness | Composition |
| 3-1 | UL-1 | 220° C./60 s | 100 nm | — | — | — | PR-40 | 80° C./60 s | 150 nm | — |
| 3-2 | UL-1 | 200° C./60 s | 120 nm | — | — | — | PR-41 | 100° C./60 s | 200 nm | — |
| 3-3 | UL-1 | 200° C./90 s | 120 nm | — | — | — | PR-42 | 100° C./60 s | 180 nm | TC-6 |
| 3-4 | UL-1 | 180° C./60 s | 120 nm | — | — | — | PR-43 | 100° C./60 s | 180 nm | — |
| 3-5 | UL-7 | 180° C./60 s | 300 nm | — | — | — | PR-44 | 100° C./60 s | 200 nm | — |
| 3-6 | UL-8 | 220° C./60 s | 100 nm | — | — | — | PR-40 | 80° C./60 s | 150 nm | — |
| 3-7 | UL-9 | 200° C./60 s | 120 nm | — | — | — | PR-41 | 100° C./60 s | 200 nm | — |
| 3-8 | UL-10 | 220° C./60 s | 100 nm | — | — | — | PR-40 | 80° C./60 s | 150 nm | — |
| 3-9 | UL-11 | 200° C./60 s | 120 nm | — | — | — | PR-41 | 100° C./60 s | 200 nm | — |
| 3-10 | UL-12 | 220° C./60 s | 100 nm | — | — | — | PR-40 | 80° C./60 s | 150 nm | — |
| 3-11 | UL-13 | 200° C./60 s | 120 nm | — | — | — | PR-41 | 100° C./60 s | 200 nm | — |
| 3-12 | UL-14 | 220° C./60 s | 100 nm | — | — | — | PR-40 | 80° C./60 s | 150 nm | — |
| 3-13 | UL-15 | 200° C./60 s | 120 nm | — | — | — | PR-41 | 100° C./60 s | 200 nm | — |
| 3-14 | UL-16 | 220° C./60 s | 100 nm | — | — | — | PR-40 | 80° C./60 s | 150 nm | — |
| 3-15 | UL-17 | 200° C./60 s | 120 nm | — | — | — | PR-41 | 100° C./60 s | 200 nm | — |
| 3-16 | UL-18 | 220° C./60 s | 100 nm | — | — | — | PR-40 | 80° C./60 s | 150 nm | — |
| 3-17 | UL-19 | 200° C./60 s | 120 nm | — | — | — | PR-41 | 100° C./60 s | 200 nm | — |
| 3-18 | UL-20 | 220° C./60 s | 100 nm | — | — | — | PR-40 | 80° C./60 s | 150 nm | — |
| 3-19 | UL-21 | 200° C./60 s | 120 nm | — | — | — | PR-41 | 100° C./60 s | 200 nm | — |
| 3-20 | UL-22 | 220° C./60 s | 100 nm | — | — | — | PR-40 | 80° C./60 s | 150 nm | — |
| 3-21 | UL-23 | 200° C./60 s | 120 nm | — | — | — | PR-41 | 100° C./60 s | 200 nm | — |
| 3-22 | UL-24 | 220° C./60 s | 100 nm | — | — | — | PR-40 | 80° C./60 s | 150 nm | — |
| Comparative | UL-1 | 220° C./60 s | 100 nm | — | — | — | PR-43 | 100° C./60 s | 180 nm | — |
| Example 3-1 | | | | | | | | | | |
| Comparative | UL-1 | 220° C./60 s | 100 nm | — | — | — | PR-53 | 80° C./60 s | 150 nm | — |
| Example 3-2 | | | | | | | | | | |
| Reference | UL-1 | 220° C./60 s | 100 nm | ML-1 | 220° C./60 s | 35 nm | PR-53 | 80° C./60 s | 150 nm | — |
| Example 3-1 | | | | | | | | | | |

| | Conditions for | | Conditions for | | | | | | |
|---|---|---|---|---|---|---|---|---|---|
| | applying topcoat | | PEB-development | | | Evaluation results | | | |
| | | Film | | | Rinsing | | | Development | |
| Example | Bake | thickness | PEB | Developer | liquid | Resolving power | DOF | defects | Etching |
| 3-1 | — | — | 95° C./60 s | D-1 | — | 100 nm | 130 nm | A | A |
| 3-2 | — | — | 80° C./60 s | D-1 | — | 90 nm | 130 nm | A | A |
| 3-3 | 100° C./60 s | 90 nm | 120° C./60 s | D-1 | — | 80 nm | 160 nm | A | A |
| 3-4 | — | — | 110° C./60 s | D-1 | — | 90 nm | 100 nm | B | B |
| 3-5 | — | — | 85° C./90 s | D-1 | — | 80 nm | 130 nm | B | A |
| 3-6 | — | — | 95° C./60 s | D-1 | — | 100 nm | 130 nm | A | A |
| 3-7 | — | — | 80° C./60 s | D-1 | — | 90 nm | 130 nm | A | A |
| 3-8 | — | — | 95° C./60 s | D-1 | — | 100 nm | 130 nm | A | A |
| 3-9 | — | — | 80° C./60 s | D-1 | — | 90 nm | 130 nm | A | A |
| 3-10 | — | — | 95° C./60 s | D-1 | — | 100 nm | 130 nm | A | A |
| 3-11 | — | — | 80° C./60 s | D-1 | — | 90 nm | 130 nm | A | A |
| 3-12 | — | — | 95° C./60 s | D-1 | — | 100 nm | 130 nm | A | A |
| 3-13 | — | — | 80° C./60 s | D-1 | — | 90 nm | 130 nm | A | A |
| 3-14 | — | — | 95° C./60 s | D-1 | — | 100 nm | 130 nm | A | A |
| 3-15 | — | — | 80° C./60 s | D-1 | — | 90 nm | 130 nm | A | A |
| 3-16 | — | — | 95° C./60 s | D-1 | — | 100 nm | 130 nm | A | A |
| 3-17 | — | — | 80° C./60 s | D-1 | — | 90 nm | 130 nm | A | A |
| 3-18 | — | — | 95° C./60 s | D-1 | — | 100 nm | 130 nm | A | A |
| 3-19 | — | — | 80° C./60 s | D-1 | — | 90 nm | 130 nm | A | A |
| 3-20 | — | — | 95° C./60 s | D-1 | — | 100 nm | 130 nm | A | A |
| 3-21 | — | — | 80° C./60 s | D-1 | — | 90 nm | 130 nm | A | A |
| 3-22 | — | — | 95° C./60 s | D-1 | — | 100 nm | 130 nm | A | A |
| Comparative | — | — | 95° C./60 s | D-5 | D-9 | 130 nm | 60 nm | C | A |
| Example 3-1 | | | | | | | | | |
| Comparative | — | — | 95° C./60 s | D-1 | — | 120 nm | 130 nm | B | C |
| Example 3-2 | | | | | | | | | |
| Reference | — | — | 95° C./60 s | D-5 | D-9 | 90 nm | 100 nm | B | A |
| Example 3-1 | | | | | | | | | |

### [EB Exposure Examples] (Examples 4-1 to 4-3, and Comparative Examples 4-1 to 4-2)

A silicon wafer was subjected to a hexamethyldisilazane (HMDS) treatment (110° C., 35 seconds), and an underlayer film and a resist film were formed in this order thereon under the conditions described in Table 9, thereby forming a wafer having a laminate film including two layers. Further, in a case where there is no description of the layer in the tables, the above-mentioned layers were not formed, but the following layers were formed.

The obtained wafer was subjected to pattern irradiation, using an electron beam lithography device (manufactured by Hitachi, Ltd., HL750, acceleration voltage 50 keV). At this time, lithography was carried out such that a 1:1 line-and-space was formed. Thereafter, baking (Post Exposure Bake: PEB) was carried out under the conditions described in Table 9, development was carried out by puddling for 30 seconds using the developer described in Table 9, and rinsing was carried out by puddling using the rinsing liquid described in Table 9 only in a case where there is a description about the rinsing. Then, the wafer was rotated for 30 seconds at a rotation speed of 4,000 rpm to obtain a line-and-space pattern having a pitch of 100 nm, a space width of 50 nm (corresponding to “a desired space width dimension” which will be described later), and a line width of 50 nm. The results are summarized in Table 9.

TABLE 9

| | Conditions for applying | | | Conditions for | | |
|---|---|---|---|---|---|---|
| | underlayer film | | | applying resist | | |
| | | | Film | | | Film |
| Example | Composition | Bake | thickness | Composition | Bake | thickness |
| 4-1 | UL-1 | 150° C./60 s | 120 nm | PR-45 | 100° C./60 s | 100 nm |
| 4-2 | UL-1 | 200° C./60 s | 120 nm | PR-46 | 100° C./60 s | 80 nm |
| 4-3 | UL-1 | 200° C./60 s | 100 nm | PR-47 | 100° C./60 s | 60 nm |
| Comparative | UL-1 | 150° C./60 s | 120 nm | PR-45 | 100° C./60 s | 100 nm |
| Example 4-1 | | | | | | |
| Comparative | UL-1 | 150° C./60 s | 120 nm | PR-54 | 110° C./60 s | 100 nm |
| Example 4-2 | | | | | | |

| | Conditions for | | | | | | |
|---|---|---|---|---|---|---|---|
| | PEB-development | | | Evaluation results | | | |
| | | | Rinsing | Resolving | | Development | |
| Example | PEB | Developer | liquid | power | DOF | defects | Etching |
| 4-1 | 90° C./60 s | D-1 | D-8 | 34 nm | 100 nm | A | A |
| 4-2 | 75° C./60 s | D-1 | — | 32 nm | 130 nm | B | A |
| 4-3 | 90° C./60 s | D-1 | — | 36 nm | 100 nm | A | B |
| Comparative | 90° C./60 s | D-5 | D-9 | 39 nm | 60 nm | D | A |
| Example 4-1 | | | | | | | |
| Comparative | 90° C./60 s | D-1 | D-8 | 36 nm | 100 nm | A | C |
| Example 4-2 | | | | | | | |

### [EUV Exposure Examples] (Examples 5-1 to 5-21, and Comparative Examples 5-1 to 5-2)

A silicon wafer was subjected to a hexamethyldisilazane (HMDS) treatment (110° C., 35 seconds), and an underlayer film, a resist film, and a topcoat film were formed in this order thereon under the conditions described in Table 10, thereby forming a wafer having a laminate film including a plurality of layers. Further, in a case where there is no description of the layer in the tables, the above-mentioned layers were not formed, but the following layers were formed.

The obtained wafer was subjected to pattern irradiation, using an EUV exposure device (manufactured by Exitech; Micro Exposure Tool, NA0.3, Quadrupol, outer sigma 0.68, inner sigma 0.36). Further, as a reticle, a mask with line:space=1:1 was used. Thereafter, baking (Post Exposure Bake: PEB) was carried out under the conditions described in Table 10, development was carried out by puddling for 30 seconds using the developer described in Table 10, and rinsing was carried out by puddling using the rinsing liquid described in Table 10 only in a case where there is a description about the rinsing. Then, the wafer was rotated for 30 seconds at a rotation speed of 4,000 rpm to obtain a line-and-space pattern having a pitch of 100 nm, a space width of 50 nm (corresponding to “a desired space width dimension” which will be described later), and a line width of 50 nm. The results are summarized in Table 10.

TABLE 10

| | Conditions for applying | | | Conditions for | | | Conditions for | | |
|---|---|---|---|---|---|---|---|---|---|
| | underlayer film | | | applying resist | | | applying topcoat | | |
| Example | Composition | Bake | Film thickness | Composition | Bake | Film thickness | Composition | Bake | Film thickness |
| 5-1 | UL-1 | 200° C./60 s | 120 nm | PR-48 | 100° C./60 s | 50 nm | TC-2 | 100° C./60 s | 30 nm |
| 5-2 | UL-4 | 200° C./60 s | 80 nm | PR-49 | 80° C./60 s | 40 nm | — | — | — |
| 5-3 | UL-4 | 180° C./60 s | 65 nm | PR-50 | 100° C./60 s | 30 nm | — | — | — |
| 5-4 | UL-8 | 200° C./60 s | 120 nm | PR-48 | 100° C./60 s | 50 nm | — | — | — |
| 5-5 | UL-9 | 200° C./60 s | 80 nm | PR-49 | 80° C./60 s | 40 nm | — | — | — |
| 5-6 | UL-10 | 200° C./60 s | 80 nm | PR-50 | 100° C./60 s | 30 nm | — | — | — |
| 5-7 | UL-11 | 200° C./60 s | 120 nm | PR-48 | 100° C./60 s | 50 nm | — | — | — |
| 5-8 | UL-12 | 200° C./60 s | 80 nm | PR-49 | 80° C./60 s | 40 nm | — | — | — |
| 5-9 | UL-13 | 200° C./60 s | 80 nm | PR-50 | 100° C./60 s | 30 nm | — | — | — |
| 5-10 | UL-14 | 200° C./60 s | 120 nm | PR-48 | 100° C./60 s | 50 nm | — | — | — |
| 5-11 | UL-15 | 200° C./60 s | 80 nm | PR-49 | 80° C./60 s | 40 nm | — | — | — |
| 5-12 | UL-16 | 200° C./60 s | 80 nm | PR-50 | 100° C./60 s | 30 nm | — | — | — |
| 5-13 | UL-17 | 200° C./60 s | 120 nm | PR-48 | 100° C./60 s | 50 nm | — | — | — |
| 5-14 | UL-18 | 200° C./60 s | 80 nm | PR-49 | 80° C./60 s | 40 nm | — | — | — |
| 5-15 | UL-19 | 200° C./60 s | 80 nm | PR-50 | 100° C./60 s | 30 nm | — | — | — |
| 5-16 | UL-20 | 200° C./60 s | 120 nm | PR-48 | 100° C./60 s | 50 nm | — | — | — |
| 5-17 | UL-21 | 200° C./60 s | 80 nm | PR-49 | 80° C./60 s | 40 nm | — | — | — |
| 5-18 | UL-22 | 200° C./60 s | 80 nm | PR-48 | 100° C./60 s | 50 nm | — | — | — |
| 5-19 | UL-23 | 200° C./60 s | 120 nm | PR-49 | 80° C./60 s | 40 nm | — | — | — |
| 5-20 | UL-24 | 200° C./60 s | 80 nm | PR-50 | 100° C./60 s | 30 nm | — | — | — |
| 5-21 | UL-1 | 200° C./60 s | 120 nm | PR-61 | 100° C./60 s | 40 nm | — | — | — |
| Comparative | UL-1 | 200° C./60 s | 120 nm | PR-49 | 80° C./60 s | 40 nm | — | — | — |
| Example 5-1 | | | | | | | | | |
| Comparative | UL-4 | 200° C./60 s | 80 nm | PR-55 | 100° C./60 s | 50 nm | TC-7 | 100° C./60 s | 90 nm |
| Example 5-2 | | | | | | | | | |

| | Conditions | | | | | | |
|---|---|---|---|---|---|---|---|
| | for PEB-development | | | Evaluation results | | | |
| | | | Rinsing | | | Development | |
| Example | PEB | Developer | liquid | Resolving power | DOF | defects | Etching |
| 5-1 | 110° C./60 s | D-1 | — | 24 nm | 130 nm | B | A |
| 5-2 | 90° C./60 s | D-2 | D-7 | 22 nm | 130 nm | A | A |
| 5-3 | 75° C./60 s | D-2 | D-7 | 26 nm | 100 nm | A | B |
| 5-4 | 110° C./60 s | D-1 | — | 24 nm | 130 nm | B | A |
| 5-5 | 90° C./60 s | D-2 | D-7 | 22 nm | 130 nm | A | A |
| 5-6 | 75° C./60 s | D-2 | D-7 | 26 nm | 100 nm | A | B |
| 5-7 | 110° C./60 s | D-1 | — | 24 nm | 130 nm | B | A |
| 5-8 | 90° C./60 s | D-2 | D-7 | 22 nm | 130 nm | A | A |
| 5-9 | 75° C./60 s | D-2 | D-7 | 26 nm | 100 nm | A | B |
| 5-10 | 110° C./60 s | D-1 | — | 24 nm | 130 nm | B | A |
| 5-11 | 90° C./60 s | D-2 | D-7 | 22 nm | 130 nm | A | A |
| 5-12 | 75° C./60 s | D-2 | D-7 | 26 nm | 100 nm | A | B |
| 5-13 | 110° C./60 s | D-1 | — | 24 nm | 130 nm | B | A |
| 5-14 | 90° C./60 s | D-2 | D-7 | 22 nm | 130 nm | A | A |
| 5-15 | 75° C./60 s | D-2 | D-7 | 26 nm | 100 nm | A | B |
| 5-16 | 110° C./60 s | D-1 | — | 24 nm | 130 nm | B | A |
| 5-17 | 90° C./60 s | D-2 | D-7 | 22 nm | 130 nm | A | A |
| 5-18 | 110° C./60 s | D-1 | — | 24 nm | 130 nm | B | A |
| 5-19 | 90° C./60 s | D-2 | D-7 | 22 nm | 130 nm | A | A |
| 5-20 | 75° C./60 s | D-2 | D-7 | 26 nm | 100 nm | A | B |
| 5-21 | 100° C./60 s | D-10 | D-11 | 26 nm | 110 nm | A | A |
| Comparative | 110° C./60 s | D-5 | D-9 | 29 nm | 100 nm | C | A |
| Example 5-1 | | | | | | | |
| Comparative | 110° C./60 s | D-2 | — | 26 nm | 100 nm | A | C |
| Example 5-2 | | | | | | | |

Evaluations in the tables above were carried out according to the following evaluation methods.

[Method for Evaluating Resolving Power (Cases for ArF Liquid Immersion, and ArF or KrF Exposure)]

With the exposure doses varying, the formed line-and-space patterns were observed using a length-measuring scanning electron microscope (SEM) (Hitachi, Ltd., S-9380II), and a minimum space dimension with which the patterns can be resolved without bridging was defined as a resolving power. As the value is smaller, a finer pattern can be formed, which indicates good performance.

[Method for Evaluating Resolving Power (Cases for EB or EUV Exposure)]

The formed line-and-space patterns were observed using a length-measuring scanning electron microscope (SEM) (Hitachi, Ltd., S-9380II), and an irradiation energy at a time when a 1:1 line-and-space pattern with a line width of 50 nm was resolved was defined as a sensitivity. With this sensitivity, a minimum line width of the separated (1:1) line-and-space pattern was defined as a resolving power. As the value is smaller, a finer pattern can be formed, which indicates good performance.

[Depth of Focus (DOF)]

A variation in the line width in a case where a focal depth was changed was measured, using a scanning electron microscope (Hitachi Ltd., S-9380II), and a depth of focal focus reproducing a space width of ±10% of a desired space width dimension was measured as DOF (nm). A larger value thereof is preferable due to a large desirable tolerance of defocus.

[Evaluation of Development Defects]

For a silicon wafer on which a pattern with a desired space width dimension had been formed, the number of development defects was counted using a defect inspection apparatus KLA-2360 (manufactured by KLA-Tencor Co., Ltd.), and the number development defects per unit area [1 cm²] was counted. A smaller value thereof means better performance.

A: Less than 1/cm²

B: 1/cm² or more and less than 5/cm²

C: 5/cm² or more and less than 10/cm² D: 10/cm² or more

[Evaluation of Etching Properties of Resist Underlayer Film]

For a silicon wafer on which a pattern with a desired space width dimension had been formed, a resist underlayer film was etched under the following etching condition, using a plasma-system parallel plate-type reactive ion etching apparatus DES-245R. Etching was stopped at a point of time when the resist upper layer film was lost or when the resist underlayer film was processed to the bottom, and the shape of the resist underlayer film in this state was observed by means of cross-sectional SEM (manufactured by Hitachi, Ltd., S4800). Further, in the experiments of Reference Examples, first, the interlayer was processed with the resist upper layer film as a mask under the etching condition 2, and then the resist underlayer film was processed with the interlayer using as a mask under the etching condition 1.

A: The resist underlayer film was well-processed up to the bottom with rectangularity.

B: The resist underlayer film was processed up to the bottom and was in a tapered shape.

C: Etching of the resist underlayer film did not reach the bottom.

(Etching Condition 1)
Etching gas: O₂
Pressure: 20 mTorr
Applied power: 100 mW/cm²

(Etching Condition 2)
Etching gas: CF₄
Pressure: 20 mTorr
Applied power: 100 mW/cm²

As apparent from the evaluation results of Examples under any of the exposure and irradiation conditions, in a case of carrying out organic solvent development using a resist containing Si as an upper layer resist, patterning performance including resolving power, DOF performance, and development defect performance is good, and the etching properties of the resist underlayer film are also good.

On the other hand, it can be seen that in Comparative Examples 1-1, 2-1, 3-1, 4-1, and 5-1, in which an alkali developer was used in the step of developing the resist film, various types of performance regarding the patterning was insufficient, and Comparative Examples 1-2, 2-2, 3-2, 4-2, and 5-2 in which a resist composition not containing the resin (A) of the present invention resin was used, etching properties were insufficient.

Moreover, in Reference Examples 1-1, 2-1, and 3-1 in which a hard mask was provided as an interlayer between the resist underlayer film and the resist film, and then an alkali developer was used in the step of developing the resist film, good results were exhibited in each of the evaluations, which require a step of forming and etching the hard mask, and cost for forming the resist pattern cannot be sufficiently suppressed.

### [ArF Liquid Immersion Exposure Examples] (Examples 6-1 to 6-8, and Comparative Examples 6-1 and 6-2)

An underlayer film and a resist film were formed in this order on a substrate under the conditions described in Table 11, thereby forming a wafer having a laminate film including a plurality of layers.

Subsequently, exposure was carried out according to the method described in Example 1-1 except that the reticle was changed, baking (Post Exposure Bake; PEB) was carried out under the conditions shown in Table 11, and then development was carried out according to the method described in Example 1-1 (provided that the developer shown in Table 11 was used as a developer), thereby forming a line-and-space (LAS) resist pattern with a line width of 75 nm and a space width of 75 nm (that is, an LAS resist pattern with a half pitch (HP) of 75 nm).

Then, the resist underlayer film was subjected to plasma etching using an oxygen gas, using the resist pattern as a mask, under the conditions shown in Table 11, and further, a SiO₂ film on the silicon wafer was subjected to etching using a fluorocarbon gas, employing the pattern of the formed resist underlayer film as a mask.

TABLE 11

| | | Example 6-1 | Example 6-2 | Example 6-3 | Example 6-4 | Example 6-5 | Example 6-6 |
|---|---|---|---|---|---|---|---|
| Substrate | | Substrate A | Substrate A | Substrate A | Substrate A | Substrate A | Substrate A |
| Resist underlayer | Prescription | UL-1 | UL-1 | UL-1 | UL-8 | UL-11 | UL-13 |
| film | | | | | | | |
| | Bake | 200° C./60 s | 200° C./60 s | 200° C./60 s | 200° C./60 s | 200° C./60 s | 200° C./60 s |
| | Film thickness | 110 nm | 110 nm | 110 nm | 110 nm | 110 nm | 110 nm |
| Resist film | Type | Silicon-based | Silicon-based | Silicon-based | Silicon-based | Silicon-based | Silicon-based |
| | | resist film | resist film | resist film | resist film | resist film | resist film |
| | Prescription | PR-23 | PR-23 | PR-23 | PR-23 | PR-23 | PR-23 |
| | Bake | 100° C./60 s | 100° C./60 s | 100° C./60 s | 100° C./60 s | 100° C./60 s | 100° C./60 s |
| | Film thickness | 50 nm | 50 nm | 50 nm | 50 nm | 50 nm | 50 nm |
| Exposure-development | Exposure | ArF liquid | ArF liquid | ArF liquid | ArF liquid | ArF liquid | ArF liquid |
| | | immersion | immersion | immersion | immersion | immersion | immersion |
| | PEB | 80° C./60 s | 80° C./60 s | 80° C./60 s | 80° C./60 s | 80° C./60 s | 80° C./60 s |
| | Developer | D-1 | D-1 | D-1 | D-1 | D-1 | D-1 |
| | Pattern | HP 75 nm | HP 75 nm | HP 75 nm | HP 75 nm LAS | HP 75 nm | HP 75 nm LAS |
| | | LAS | LAS | LAS | | LAS | |
| Etching for resist | Condition | Condition A | Condition B | Condition C | Condition A | Condition A | Condition A |
| underlayer film | | (O₂ 3%) | (O₂ 10%) | (O₂ 30%) | (O₂ 3%) | (O₃ 3%) | (O₃ 3%) |
| | Residual film of resist | 10 nm | 25 nm | 30 nm | 10 nm | 10 nm | 10 nm |
| | Shape (rectangle) of | Rectangle | Rectangle | Rectangle | Rectangle | Rectangle | Rectangle |
| | underlayer film | | | | | | |
| | Trimming amount | 0 nm | 10 nm | 20 nm | 0 nm | 0 nm | 0 nm |
| Etching for SiO₂ film | Condition | Condition D | Condition D | Condition D | Condition D | Condition D | Condition D |
| | | (C₄F₆) | (C₄F₆) | (C₄F₆) | (C₄F₆) | (C₄F₆) | (C₄F₆) |
| | Residual film of | 100 nm | 100 nm | 100 nm | 100 nm | 100 nm | 100 nm |
| | underlayer film | | | | | | |
| | Shape (rectangle) of | Rectangle | Rectangle | Rectangle | Rectangle | Rectangle | Rectangle |
| | SiO₂ film | | | | | | |
| | Presence or absence | Absence | Absence | Absence | Absence | Absence | Absence |
| | of wiggling in SiO₂ | | | | | | |
| | film | | | | | | |

| | | | | Comparative | Comparative Example |
|---|---|---|---|---|---|
| | | Example 6-7 | Example 6-8 | Example 6-1 | 6-2 |
| Substrate | | Substrate A | Substrate A | Substrate A | Substrate A |
| Resist underlayer | Prescription | UL-15 | UL-18 | UL-1 | ULR-01 |
| film | | | | | |
| | Bake | 200° C./60 s | 200° C./60 s | 200° C./60 s | 200° C./60 s |
| | Film thickness | 110 nm | 110 nm | 110 nm | 40 nm |
| Resist film | Type | Silicon-based | Silicon-based | Hydrocarbon-based | Hydrocarbon-based |
| | | resist film | resist film | resist film | resist film |
| | Prescription | PR-23 | PR-23 | PR-51 | PR-51 |
| | Bake | 100° C./60 s | 100° C./60 s | 100° C./60 s | 100° C./60 s |
| | Film thickness | 50 nm | 50 nm | 50 nm | 50 nm |
| Exposure-development | Exposure | ArF liquid | ArF liquid | ArF liquid immersion | ArF liquid immersion |
| | | immersion | immersion | | |
| | PEB | 80° C./60 s | 80° C./60 s | 95° C./60 s | 95° C./60 s |
| | Developer | D-1 | D-1 | D-1 | D-1 |
| | Pattern | HP 75 nm | HP 75 nm | HP 75 nm LAS | HP 75 nm LAS |
| | | LAS | LAS | | |
| Etching for resist | Condition | Condition A | Condition A | Condition A (O₃ 3%) | Condition B (O₃ 10%) |
| underlayer film | | (O₃ 3%) | (O₃ 3%) | | |
| | Residual film of resist | 10 nm | 10 nm | None | 10 nm |
| | Shape (rectangle) of | Rectangle | Rectangle | Insufficient rectangle | Insufficient rectangle |
| | underlayer film | | | | |
| | Trimming amount | 0 nm | 0 nm | — | 20 nm |
| Etching for SiO₂ film | Condition | Condition D | Condition D | Condition D (C₄F₆) | Condition D (C₄F₆) |
| | | (C₄F₆) | (C₄F₆) | | |
| | Residual film of | 100 nm | 100 nm | 10 nm | 30 nm |
| | underlayer film | | | | |
| | Shape (rectangle) of | Rectangle | Rectangle | Insufficient rectangle | Insufficient rectangle |
| | SiO₂ film | | | | |
| | Presence or absence | Absence | Absence | Absence | Presence |
| | of wiggling in SiO₂ | | | | |
| | film | | | | |

In the trademarks, the substrate A is as follows.

Substrate A: A substrate obtained by forming a SiO₂ film (oxide film) having a film thickness of 100 nm on a silicon substrate

An apparatus used in etching for the resist underlayer film is as follows.

Etching apparatus: UHF-Wave ECR Plasma Etching Apparatus U-621, manufactured by Hitachi High-Technologies Corporation

The etching conditions using an oxygen gas for the resist underlayer film are shown in Table 12.

TABLE 12

| Items of condition | Unit | Condition A | Condition B | Condition C |
|---|---|---|---|---|
| O₂ Flow rate | ml/min | 30 | 100 | 300 |
| Ar Flow rate | ml/min | 970 | 900 | 700 |
| Pressure | Pa | 4 | 4 | 4 |
| Source power | W | 400 | 400 | 400 |
| Bias power | W | 100 | 100 | 100 |
| Antenna power | W | 200 | 200 | 200 |
| Electrode height | mm | 70 | 70 | 70 |
| Electrode | ° C. | 50 | 50 | 50 |
| temperature | | | | |

By observing the cross-sectional shape with a field emission scanning electron microscope S4800 manufactured by Hitachi High-Technologies Corporation, the thickness (described as “Residual film of resist” in Table 11) and the trimming amount of the resist pattern after the etching were measured, and the shape of the pattern (described as “Shape of underlayer film” in Table 11) of the resist underlayer film was also observed. Here, the trimming amount refers to a difference between the line width of the resist pattern before etching and the line width of the etching-processed underlayer film.

An apparatus used in etching for the SiO₂ film is as follows.

Etching apparatus: UHF-Wave ECR Plasma Etching Apparatus U-621, manufactured by Hitachi High-Technologies Corporation

The etching conditions using a fluorocarbon gas for the SiO₂ film are shown in Table 13.

TABLE 13

| Items of condition | Unit | Condition D |
|---|---|---|
| C₄F₆ Flow rate | ml/min | 10 |
| O₂ Flow rate | ml/min | 20 |
| Ar Flow rate | ml/min | 500 |
| Pressure | Pa | 1 |
| Source power | W | 500 |
| Bias power | W | 700 |
| Antenna power | W | 600 |
| Electrode height | mm | 128 |
| Electrode | ° C. | 50 |
| temperature | | |

By observing the cross-sectional shape with a field emission scanning electron microscope S₄₈₀₀ manufactured by Hitachi High-Technologies Corporation, the thickness (described as “Residual film of resist underlayer film” in Table 11) of the pattern of the resist underlayer film after the etching were measured, and the shape of the SiO₂ film after processing, and the presence and absence of wiggling in the SiO₂ film after processing were also observed.

As shown in Table 11, in Examples 6-1 to 6-8 in which a silicon-based resist film was used, the rectangularity of the pattern of the formed resist underlayer film was excellent, and the rectangularity of the processed SiO₂ film was also excellent. In particular, in Examples 6-2 and 6-3 in which a trimming treatment was carried out, the rectangularity of the pattern of the formed resist underlayer film was excellent, and the rectangularity of the processed SiO₂ film was also excellent.

On the other hand, in Comparative Examples 6-1 and 6-2 in which a hydrocarbon-based resist film was used, the thickness of the pattern of the resist underlayer film could not be sufficiently secured, and thus, a SiO₂ film having excellent rectangularity could not be processed. In addition, in Comparative Example 6-2, Wiggling also occurred in the SiO₂ film.

From the above description, it could be seen that the present invention is suitable for formation of a core material (core) in the formation of a fine pattern using a spacer process as well as the formation of a trench (groove) pattern or a contact hole pattern.

According to the present invention, it is possible to provide a pattern forming method which can satisfy resolution, DOF performance, development defect performance, and etching resistance performance at the same time at high levels in the formation of a resist pattern of a trench (groove) pattern or a contact hole pattern, particularly having a small dissolution region of a resist film, while reducing cost for forming the resist pattern; and a laminate and a resist composition for organic solvent development, each applied to the pattern forming method.

While the present invention has been described in detail and with reference to specific embodiments thereof, it will be apparent to one skilled in the art that various changes and modifications can be made therein without departing from the spirit and scope of the invention.

What is claimed is:

1. A pattern forming method comprising:
(1) a step of forming a resist underlayer film on a substrate to be processed;
(2) a step of forming a resist film on the resist underlayer film, using a resist composition containing (A) a resin having a repeating unit containing a Si atom, and (B) a compound which generates an acid upon irradiation with actinic rays or radiation;
(3) a step of exposing the resist film;
(4) a step of developing the exposed resist film using a developer including an organic solvent, thereby forming a negative tone resist pattern; and
(5) a step of processing the resist underlayer film and the substrate to be processed, using the resist pattern as a mask, thereby forming a pattern,
wherein the content of the resin (A) is 20% by mass or more with respect to the total solid content of the resist composition.

2. The pattern forming method according to claim 1,
wherein the resin (A) has a repeating unit having an acid-decomposable group.

3. The pattern forming method according to claim 2,
wherein the acid-decomposable group has a structure in which a polar group is protected with a leaving group capable of leaving upon decomposition by the action of an acid, and the leaving group does not contain a Si atom.

4. The pattern forming method according to claim 1,
wherein the content of Si atoms in the resin (A) is 1.0% to 30% by mass with respect to the total amount of the resin (A).

5. The pattern forming method according to claim 1,
wherein the resist composition further contains a crosslinking agent.

6. The pattern forming method according to claim 1,
wherein the resin (A) has at least one selected from the group consisting of a lactone structure, a sultone structure, and a carbonate structure.

7. The pattern forming method according to claim 1,
wherein the developer including an organic solvent includes at least one of butyl acetate or isoamyl acetate.

8. The pattern forming method according to claim 1,
wherein in the step (3), the resist film is exposed by any one of ArF liquid immersion exposure, ArF exposure, and KrF exposure.

9. The pattern forming method according to claim 1,
wherein in the step (3), the resist film is exposed by ArF liquid immersion exposure or ArF exposure.

10. The pattern forming method according to claim 1,
wherein the step (5) is a step of subjecting the resist underlayer film and the substrate to be processed to dry etching, using the resist pattern as a mask, thereby forming the pattern.

11. The pattern forming method according to claim 10,
wherein the dry etching for the resist underlayer film is oxygen plasma etching.

12. A laminate, applied to the pattern forming method according to claim 1,
comprising:
a resist underlayer film laminated on a substrate to be processed; and
a resist film laminated on the resist underlayer, the resist film being formed of a resist composition containing (A) a resin having a repeating unit containing a Si atom and (B) a compound which generates an acid upon irradiation with actinic rays or radiation.

13. A resist composition for organic solvent development, applied to the pattern forming method according to claim 1.
